(19) United States
(12) Patent Application Publication
(10) Pub. No.: US 2025/0057043 A1
(43) Pub. Date: Feb. 13, 2025

(54) ORAGNIC COMPOUNDS, MIXTURES, COMPOSITIONS, LIGHT-EMITTING ELEMENTS, AND DISPLAY PANELS

(71) Applicant: Shenzhen China Star Optoelectronics Semiconductor Display Technology Co., Ltd., Shenzhen (CN)

(72) Inventors: Ruifeng HE, Shenzhen (CN); Canjie WU, Shenzhen (CN); Yan LI, Shenzhen (CN); Jingyao SONG, Shenzhen (CN)

(73) Assignee: Shenzhen China Star Optoelectronics Semiconductor Display Technology Co., Ltd., Shenzhen (CN)

(21) Appl. No.: 18/468,685

(22) Filed: Sep. 16, 2023

(30) Foreign Application Priority Data
Jul. 25, 2023 (CN) 202310924008.6

(51) Int. Cl. H10K 85/60; C07F 5/02; C09K 11/06

(52) U.S. Cl. CPC H10K 85/658; C07F 5/027; C09K 11/06; H10K 85/633; C09K 2211/1018; H10K 50/11; H10K 85/6572

(57) ABSTRACT

Embodiments of the present disclosure provide an organic compound, a mixture, a composition, a light-emitting element, and a display panel. The organic compound has a structure represented by the following formula (1). In the formula (1), Z is selected from CR₁R₂, NR₃, O, or S; X and Y are each independently selected from O or NR₄, R₁—R₄ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group; and R₁ and R₂ are connected to form a ring or independent of each other.

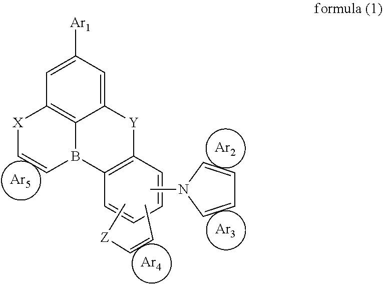

### CROSS-REFERENCE TO RELATED APPLICATION

The present disclosure claims priority to and the benefit of Chinese Patent Application No. 202310924008.6, filed on Jul. 25, 2023, the present disclosure of which is incorporated herein by reference in its entirety.

### TECHNICAL FIELD

The present disclosure relates to the field of display, in particular to organic compounds, mixtures, compositions, light-emitting elements, and display panels.

### BACKGROUND

At present, an organic electroluminescent element generally has a positive electrode, a negative electrode, and an organic layer disposed between the positive electrode and the negative electrode. The organic substance in the organic layer is used to convert electrical energy into light energy, thereby realizing organic electroluminescence. In order to improve luminous efficiency and service life of the organic electroluminescent element, the organic layer generally includes multiple layers, and organic substances in the multiple layers are different. Specifically, the organic layer mainly includes a hole injection layer, a hole transport layer, a light-emitting layer, an electron transport layer, an electron injection layer, and the like. A voltage is applied between the positive electrode and the negative electrode of the organic electroluminescent element, holes in the positive electrode are injected into the organic layer, and electrons in the negative electrode are injected into the organic layer, then the injected holes meet with the injected electrons to form excitons, which emit light when they transition back to a ground state, thus realizing luminescence of the organic electroluminescent element. The organic electroluminescent element has broad application prospect due to its characteristics such as autonomous luminescence, high brightness, high efficiency, low driving voltage, wide viewing angle, high contrast, high responsiveness, and the like.

Accordingly, development of materials for organic light-emitting diodes (OLEDs) has received widespread attention due to their advantages such as diversity in synthesis, simple composition, and simple process. At the same time, in order to improve the luminous efficiency of the organic electroluminescent element, various material systems with energy transmission and conversion mechanisms have been attempted. However, the luminous efficiency, stability, and life of light-emitting materials used in OLED elements, especially the light-emitting materials for OLED elements that emit blue light, are still low, resulting in limitations on improvement of performance of the OLED elements.

Therefore, there is an urgent need for an organic compound, a mixture, a composition, a light-emitting element, and a display panel to solve the above-mentioned technical problems.

### SUMMARY

Embodiments of the present disclosure provide an organic compound, which has a structure represented by formula (1):

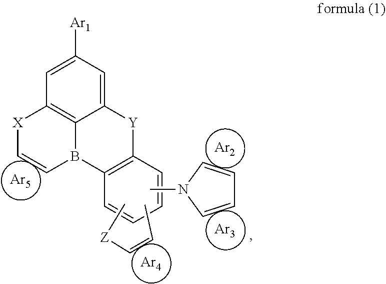

in which Z is selected from CR₁R₂, NR₃, O, or S;
X and Y are each independently selected from O or NR₄;
R₁—R₄ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group;
R₁ and R₂ are connected to form a ring or independent of each other;
Ar₁ is selected from H, D, a substituted or unsubstituted C₁-C₂₀ alkyl group, a substituted or unsubstituted C₆-C₃₀ aromatic group, or a substituted or unsubstituted C₅-C₃₀ heteroaromatic group;
Ar₂ and Arₙ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group; and
Ar₄ and Ar₅ are each independently selected from a substituted or unsubstituted C₆-C₃₀ aromatic group, or a substituted or unsubstituted C₅-C₃₀ heteroaromatic group.

Embodiments of the present disclosure further provide a composition, which includes the above-mentioned organic compound and at least one organic solvent.

Embodiments of the present disclosure further provide a light-emitting element, which includes:
a pair of electrodes including a first electrode and a second electrode; and
an organic functional layer disposed between the first electrode and the second electrode;
in which a material of the organic functional layer includes the above-mentioned organic compound or the organic functional layer is prepared from the above-mentioned composition.

### BRIEF DESCRIPTION OF THE DRAWINGS

In order to illustrate technical solutions in embodiments of the present disclosure more clearly, the following briefly introduces drawings needed to be used in description of the embodiments. Apparently, the drawings in the following description are only some embodiments of the present disclosure. For those skilled in the art, other drawings can be obtained from these drawings without paying creative effort.

FIG. 1 is a schematic structural diagram of a light-emitting element according to some embodiments of the present disclosure.

### DETAILED DESCRIPTION

In combination with drawings in embodiments of the present disclosure, technical solutions in the embodiments of the present disclosure will be described clearly and completely. Apparently, the described embodiments are only part of the embodiments of the present disclosure, not all of them. Based on the embodiments of the present disclosure, all other embodiments obtained by those skilled in the art without creative effort belong to a scope of the present disclosure. In addition, it should be understood that specific embodiments described herein are only used to explain and interpret the present disclosure and are not used to limit the present disclosure. In the present disclosure, location terms used, such as “up” and “down”, generally refer to up and down in actual using or working state of devices, in particular drawing directions in the drawings, unless otherwise described; terms “inside” and “outside” refer to outlines of the devices. In the present disclosure, “optional” and “optionally” refer to any one of two parallel schemes of “having” and “not having”. If there are multiple “optional” or “optionally” in a technical solution, unless otherwise specified, and there are no contradictions or mutual constraints, each “optional” or “optionally” is independent. In the present disclosure, technical features described in an open form include both a closed technical solution composed of the listed features and an open technical solution containing the listed features.

In the present disclosure, an aryl group, an aromatic group, and an aromatic ring have the same meaning and may be interchanged. “The aryl group, the aromatic group, or the aromatic ring” refers to an aromatic hydrocarbon group derived from a basis of an aromatic ring compound removing one hydrogen atom. The aromatic ring compound may be an aryl group with a single ring, a fused ring aryl group, or a polycyclic aryl group. For a polycyclic ring type, at least one ring is an aromatic ring. For example, “a substituted or unsubstituted aryl group containing 6 to 40 ring atoms” refers to an aryl group containing 6 to 40 ring atoms, preferably a substituted or unsubstituted aryl group containing 6 to 30 ring atoms, a substituted or unsubstituted aryl group containing 6 to 18 ring atoms, or a substituted or unsubstituted aryl group containing 6 to 14 ring atoms, and the aryl group is optionally further substituted. Suitable examples include, but are not limited thereto: a phenyl group, a biphenyl group, a triphenyl group, a naphthyl group, an anthracyl group, a phenanthryl group, a fluoranthenyl group, a triphenylene group, a pyrenyl group, a perylene group, a tetraphenyl group, a fluorenyl group, a diphenyl group, an acenaphthenyl group, and derivatives thereof. Understandably, multiple aryl groups may further be disconnected by short non-aromatic units (for example, a non-hydrogenium atom contenting less than 10%, such as C, N, or O). In particular, an acenaphthene group, a fluorene group such as a 9,9-diarylfluorene group, a triarylamine group, and a diaryl ether system may be further included in a definition of the aryl group. Unless otherwise specified, the above-mentioned ring atoms are carbon atoms.

In the present disclosure, a heteroaryl group, a heteroaromatic group, and a heteroaromatic ring have the same meaning and may be interchanged. “The heteroaryl group, the heteroaromatic group, or the heteroaromatic ring” refers to a basis of an aryl group with at least one carbon atom substituted by a non-carbon atom, and the non-carbon atom may be N, O, S, or the like. For example, “a substituted or unsubstituted heteroaryl group containing 5 to 40 ring atoms” refers to a heteroaryl group containing 5 to 40 ring atoms, preferably a substituted or unsubstituted heteroaryl group containing 6 to 30 ring atoms, a substituted or unsubstituted heteroaryl group containing 6 to 18 ring atoms, or a substituted or unsubstituted heteroaryl group containing 6 to 14 ring atoms, and the heteroaryl group is optionally further substituted. Suitable examples include, but are not limited thereto: a thienyl group, a furyl group, a pyrrolyl group, a diazole group, a triazole group, an imidazolyl group, a pyridinyl group, a bipyridyl group, a pyrimidinyl group, a triazinyl group, an acridinyl group, a pyridazinyl group, a pyrazinyl group, a quinolinyl group, an isoquinolinyl group, a quinazolinyl group, a quinoxalinyl group, a phthalazinyl group, a pyridino pyrimidinyl group, a pyridino pyrazinyl group, a benzothiophenyl group, a benzofuranyl group, an indolyl group, a pyrrolo imidazolyl group, a pyrrolopyrrolyl group, a thiophenopyrrolyl group, a thiophenothiophenyl group, a furanopyrrolyl group, a furanofuranyl group, a thiophenofuranyl group, a benzoisoxazolyl group, a benzoisothiazolyl group, a benzimidazolyl group, an ortho-diazonaphthalyl group, a phenanthridinyl group, a berberine group, a quinazolinketone group, a dibenzothiophenyl group, a dibenzofuranyl group, a carbazolyl group, and derivatives thereof.

In the present disclosure, “substituted” means that one or more hydrogen atoms in one substituted group are substituted by a substituent group. A same substituent group at different substituent sites may be independently selected from different groups. For example, if a formula includes a plurality of R groups, each of the R groups may be independently selected from different groups. In the present disclosure, “substituted or unsubstituted” means that a defined group may be substituted or not be substituted. When the defined group is substituted, it can be understood that the defined group may be substituted by one or more substituent R groups. The substituent R is selected from, but not limited thereto: a deuterium atom (D), a cyanoyl group, an isocyanoyl group, a nitro group, a halogen group, a C₁-C₂₀ alkyl group, a heterocyclic group containing 3 to 20 ring atoms, an aromatic group containing 6 to 20 ring atoms, a heteroaromatic group containing 5 to 20 ring atoms, —NR′R″, a silyl group, a carbonyl group, an alkoxycarbonyl group, an aryloxycarbonyl group, an aminoformyl group, a haloformyl group, a formyl group, an isocyanate group, a thiocyanate group, an isothiocyanate group, a hydroxyl group, or a trifluoromethyl group. The above-mentioned groups may further be substituted by acceptable substituent groups in the art. Understandably, R′ and R″ in the NR′R″ are each independently selected from, but not limited thereto: H, D, a cyanoyl group, an isocyanoyl group, a nitro group, a halogen group, a C₁-C₁₀ alkyl group, a heterocyclic group containing 3 to 20 ring atoms, an aromatic group containing 6 to 20 ring atoms, or a heteroaromatic group containing 5 to 20 ring atoms. Preferably, R′ and R″ are each independently selected from, but not limited thereto: D, a cyanoyl group, an isocyanoyl group, a nitro group, a halogen group, a C₁-C₁₀ alkyl group, a heterocyclic group containing 3-10 ring atoms, an aromatic group containing 6-20 ring atoms, a heteroaromatic group containing 5-20 ring atoms, a silyl group, a carbonyl group, an alkoxycarbonyl group, an aryloxycarbonyl group, an aminoformyl group, a haloformyl group, a formyl group, an isocyanate group, a thiocyanate group, an isothiocyanate group, a hydroxyl group, or a trifluoromethyl group, and the above-mentioned groups may further be substituted by acceptable substituent groups in the art.

In the present disclosure, “an amino group” refers to a derivative of amine, has a feature of a group represented by formula —NR′R″, and the —NR′R″ has the meanings mentioned above.

In the present disclosure, “a ring atom number” refers to a number of atoms constituting a ring of a structural compound (such as a monocyclic compound, a fused ring compound, a cross-linked compound, a carbon ring compound, or a heterocyclic compound) obtained by atomic bonding. In a ring substituted by a substituent group, atoms contained in the substituent group are not included in the atoms forming the ring. The same applies to the “number of ring atoms” described below unless otherwise specified. For example, a ring atom number of a benzene ring is 6, a ring atom number of a naphthyl ring is 10, and a ring atom number of a thienyl group is 5.

In the present disclosure, “*” connected to a single bond indicates a linking site or a fused site.

In the present disclosure, when a linking site in a group is not specified, it means that any of connectable sites in the group may be selected as the linking site.

In the present disclosure, when a fused site in a group is not specified, it means that any of fusible sites in the group may be selected as the fused site. Preferably, two or more adjacent sites in the group are fused sites.

In the present disclosure, a same substituent group at different substituent sites may be the same or different. For example, in formula

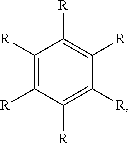

six R groups of a benzene ring may be same or different.

In the disclosure, a single bond connected to a substituent group and penetrated a corresponding ring indicates that the substituent group may be connected to any site of the ring. For example,

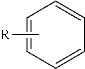

means that R may be connected to any substituent site of the benzene ring, and

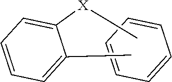

means that

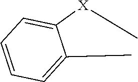

may be connected to any substituent site of

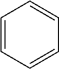

to form a union ring.

In the disclosure, a cyclic alkyl group and a cycloalkyl group have the same meaning and may be interchanged.

In the present disclosure, “adjacent group” refers to the absence of substitutable sites between two substituent groups.

In the present disclosure, “two adjacent R₁ and R₂ forming a ring with each other” indicates that a ring system is formed by connecting two adjacent R₁ and R₂, and the ring system may be selected from an aliphatic hydrocarbon ring, an aliphatic heterocyclic ring, an aromatic hydrocarbon ring, or an aromatic heterocyclic ring. Preferably, the ring system may be

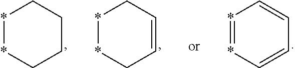

At present, due to low luminous efficiency, stability, and life of light-emitting materials used in OLED elements, there is a problem of difficulty in improving performance of the OLED elements.

Embodiments of the present disclosure provide an organic compound, which has a structure represented by the following formula (1):

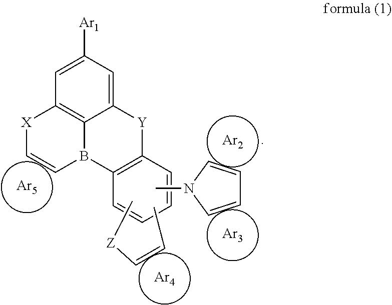

In the formula (1), Z is selected from CR₁R₂, NR₃, O, or S;
X and Y are each independently selected from O or NR₄;
R₁—R₄ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group;
R₁ and R₂ are connected to form a ring or independent of each other;
Ar₁ is selected from H, D, a substituted or unsubstituted C₁-C₂₀ alkyl group, a substituted or unsubstituted C₆-C₃₀ aromatic group, or a substituted or unsubstituted C₅-C₃₀ heteroaromatic group;
Ar₂ and Ar₃ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group; and
Ar₄ and Ar₅ are each independently selected from a substituted or unsubstituted C₆-C₃₀ aromatic group, or a substituted or unsubstituted C₅-C₃₀ heteroaromatic group.

The organic compound provided by the embodiments of the present disclosure, by introducing carbazole-like groups, especially those having both of the heterocyclic ring and the carbazole-like group, enhances the conjugation and resonance effects of the organic compound, improves the performance of the organic compound, increases the luminous efficiency of the light-emitting element applying the organic compound and extends the luminescent life of the light-emitting element.

In some embodiments, the organic compound has a structure represented by any one of the following formula (2) to formula (7):

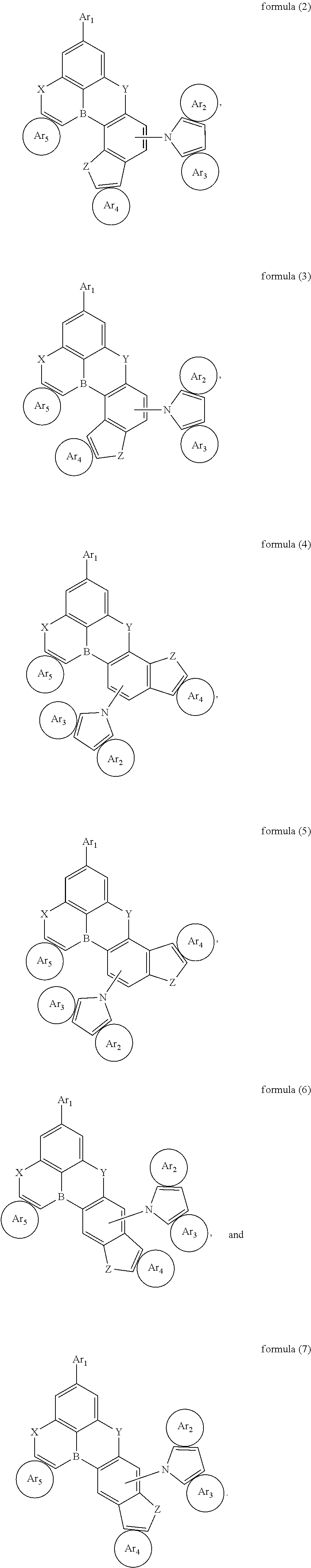

In some embodiments, the organic compound has a structure represented by any one of the following formula (8) to formula (13):

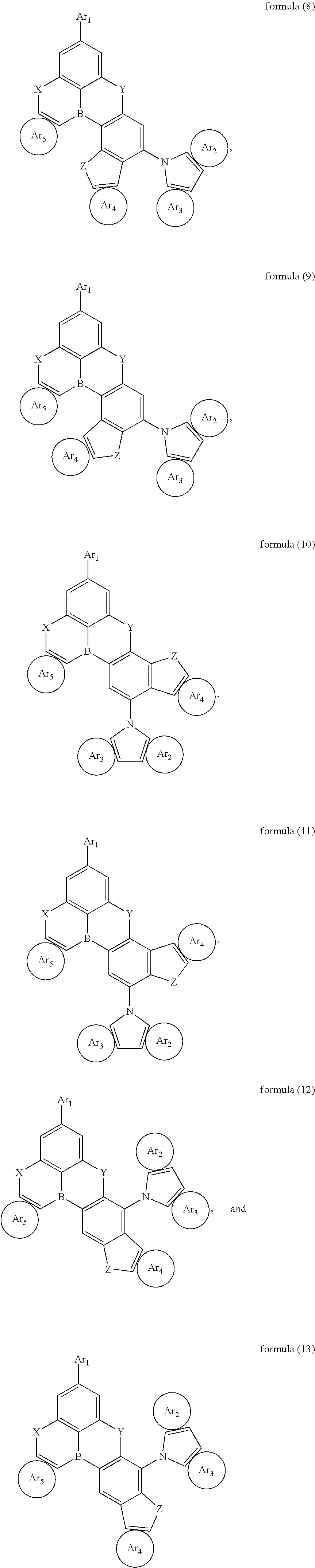

In some embodiments, the organic compound has a structure represented by the following formula (14) or formula (15):

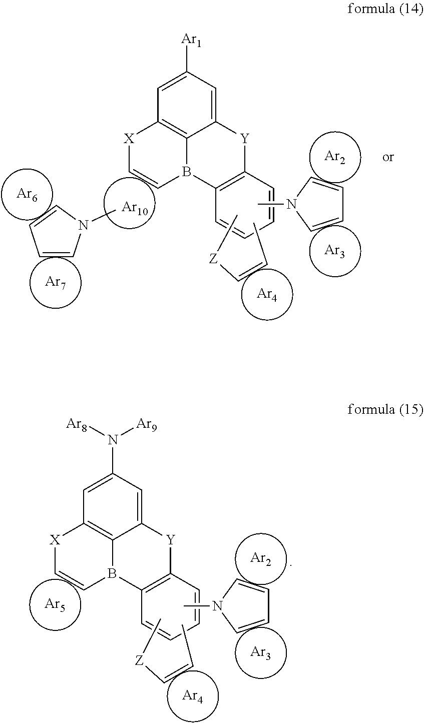

In the formula (14) and formula (15), Ar₆—Ar₉ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group; and
Ar₁₀ is independently selected from a substituted or unsubstituted C₆-C₃₀ aromatic group, or a substituted or unsubstituted C₅-C₃₀ heteroaromatic group.

Preferably, Ar₆ and Ar₇ are each independently selected from a phenyl group or

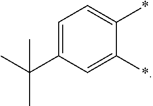

Preferably, Arg and Ar₉ are each independently selected from a phenyl group,

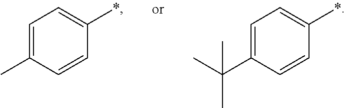

Preferably, Ar₁₀ is a phenyl group.

In the above-mentioned embodiments, Z is preferably selected from CR₁R₂, O, or S.

X and Y are each independently selected from O or NR₄, and X and Y are not O at the same time.

R₁—R₄ are each independently selected from a substituted or unsubstituted C₁-C₁₂ alkyl group, a substituted or unsubstituted C₆-C₂₀ aromatic group, or a substituted or unsubstituted C₅-C₂₀ heteroaromatic group. Preferably, R₁—R₄ are each independently selected from a substituted or unsubstituted C₁-C₈ alkyl group, a substituted or unsubstituted C₆-C₁₅ aromatic group, or a substituted or unsubstituted C₅-C₁₅ heteroaromatic group.

In some embodiments, R₁ and R₂ form a ring, such as

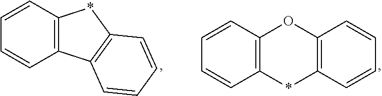

or the like.

In some embodiments, R₁ and R₂ are each independently selected from a methyl group, an ethyl group, a substituted or unsubstituted phenyl group, a substituted or unsubstituted naphthyl group, or a substituted or unsubstituted dibenzofuranyl group. Specifically, R₁ and R₂ may be each independently selected from a methyl group, an unsubstituted phenyl group, an ethyl group,

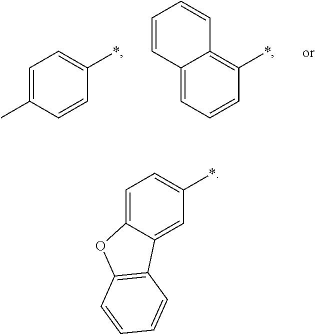

R₃ is selected from a methyl group, an ethyl group, a tert-butyl group, a substituted or unsubstituted phenyl group, a substituted or unsubstituted naphthyl group, or a substituted or unsubstituted dibenzofuranyl group. Specifically, R₃ may be selected from a methyl group, a tert-butyl group, a phenyl group,

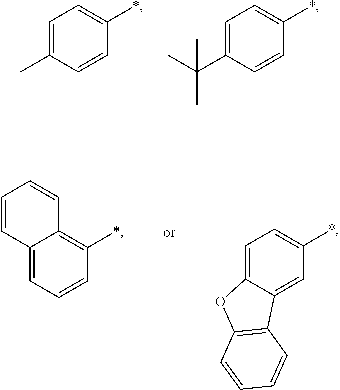

or the like. R₄ is selected from a methyl group, a substituted or unsubstituted phenyl group, a substituted or unsubstituted naphthyl group, a substituted or unsubstituted dibenzofuranyl group, a substituted or unsubstituted dibenzothiophenyl group, a substituted or unsubstituted fluorenyl group, or a substituted or unsubstituted carbazolyl group. Specifically, R₄ may be selected from a methyl group, a phenyl group,

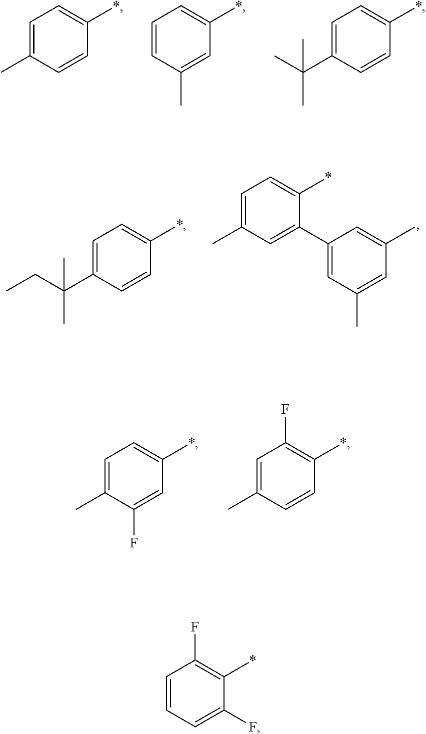

or the like.

In the above-mentioned embodiments, Ar₁ is selected from H, D, a substituted or unsubstituted C₁-C₁₂ alkyl group, a substituted or unsubstituted C₆-C₂₀ aromatic group, or a substituted or unsubstituted C₅-C₂₀ heteroaromatic group. Preferably, Ar₁ is selected from H, D, a substituted or unsubstituted C₁-C₈ alkyl group, a substituted or unsubstituted C₆-C₁₅ aromatic group, or a substituted or unsubstituted C₅-C₁₅ heteroaromatic group. More preferably, Ar₁ is selected from H, D, a methyl group, an isopropyl group, a tert-butyl group, a tert-pentyl group, a substituted or unsubstituted phenyl group, a substituted or unsubstituted naphthyl group, a substituted or unsubstituted triphenylene group, a substituted or unsubstituted phenanthryl group, a substituted or unsubstituted dibenzofuranyl group, a substituted or unsubstituted dibenzothiophenyl group, a substituted or unsubstituted fluorenyl group, a substituted or unsubstituted carbazolyl group, or a heteroaromatic group containing N. Specifically, Ar₁ may be selected from H, D, a methyl group, an isopropyl group, a tert-butyl group, a tert-pentyl group, a phenyl group,

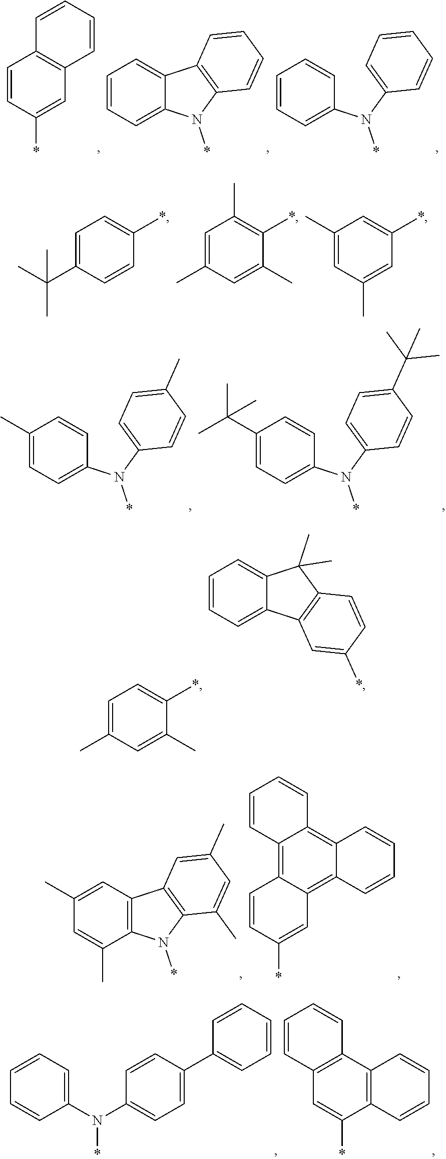

or the like.

In the above-mentioned embodiments, Ar₂ and Arₙ are each independently selected from a substituted or unsubstituted C₁-C₁₂ alkyl group, a substituted or unsubstituted C₆-C₂₀ aromatic group, or a substituted or unsubstituted C₅-C₂₀ heteroaromatic group. Preferably, Ar₂ and Arₙ are each independently selected from a substituted or unsubstituted C₁-C₈ alkyl group, a substituted or unsubstituted C₆-C₁₅ aromatic group, or a substituted or unsubstituted C₅-C₁₅ heteroaromatic group. More preferably, Ar₂ and Arₙ are each independently selected from a methyl group, a substituted or unsubstituted phenyl group, a substituted or unsubstituted cyclopentyl group, a substituted or unsubstituted cyclohexyl group, a substituted or unsubstituted naphthyl group, a substituted or unsubstituted a phenanthryl group, a substituted or unsubstituted triphenylene group, a substituted or unsubstituted dibenzofuranyl group, a substituted or unsubstituted dibenzothiophenyl group, a substituted or unsubstituted fluorenyl group, or a substituted or unsubstituted carbazolyl group. Specifically, Ar₂ may be selected from a methyl group, a phenyl group,

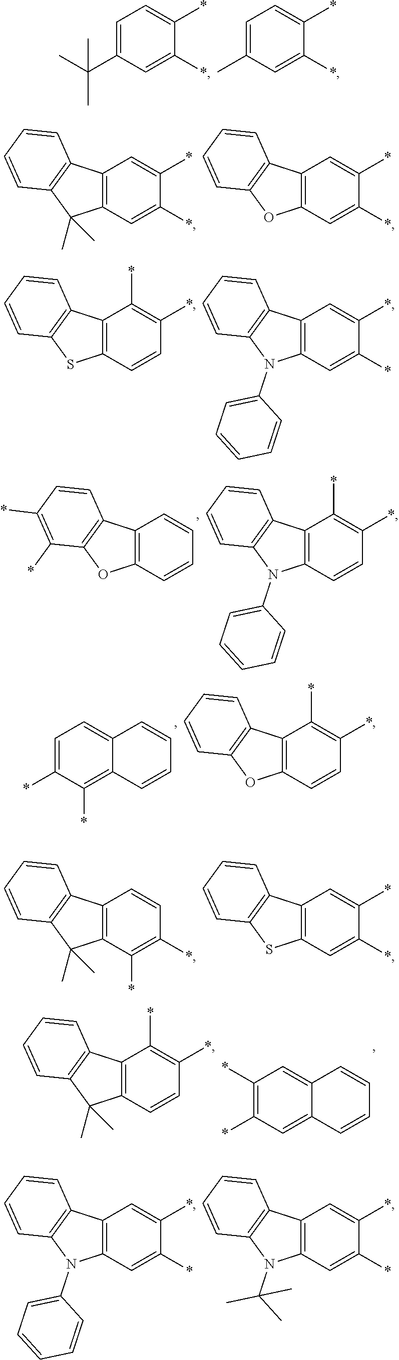

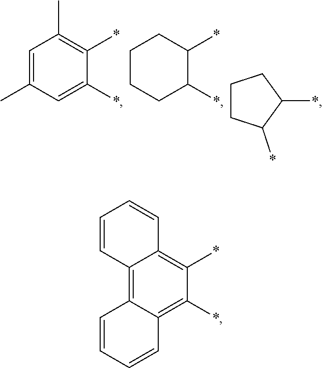

or the like; Ar₃ may be selected from a methyl group, a phenyl group,

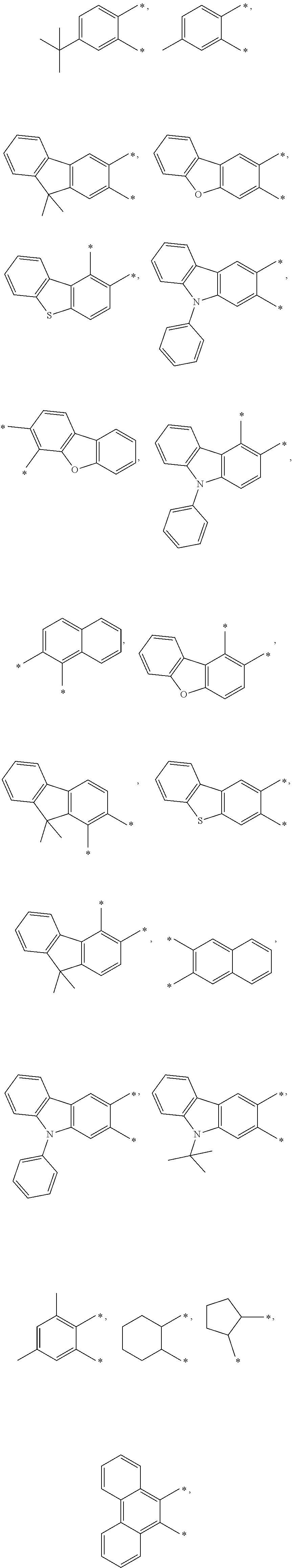

or the like.

In some embodiments, Ar₄ and Ar₅ are each independently selected from a substituted or unsubstituted C₆-C₂₀ aromatic group, or a substituted or unsubstituted C₅-C₂₀ heteroaromatic group. Preferably, Ar₄ and Ar₅ are each independently selected from a substituted or unsubstituted C₆-C₁₅ aromatic group, or a substituted or unsubstituted C₅-C₁₅ heteroaromatic group. More preferably, Ar₄ and Ar₅ are each independently selected from a substituted or unsubstituted phenyl group, a substituted or unsubstituted naphthyl group, a substituted or unsubstituted phenanthryl group, a substituted or unsubstituted triphenylene group, a substituted or unsubstituted pyrenyl group, a substituted or unsubstituted dibenzofuranyl group, a substituted or unsubstituted dibenzothiophenyl group, a substituted or unsubstituted fluorenyl group, a substituted or unsubstituted carbazolyl group, or a heteroaromatic group containing N. Specifically, Ar₄ may be a phenyl group; Ar₅ may be selected from a phenyl group,

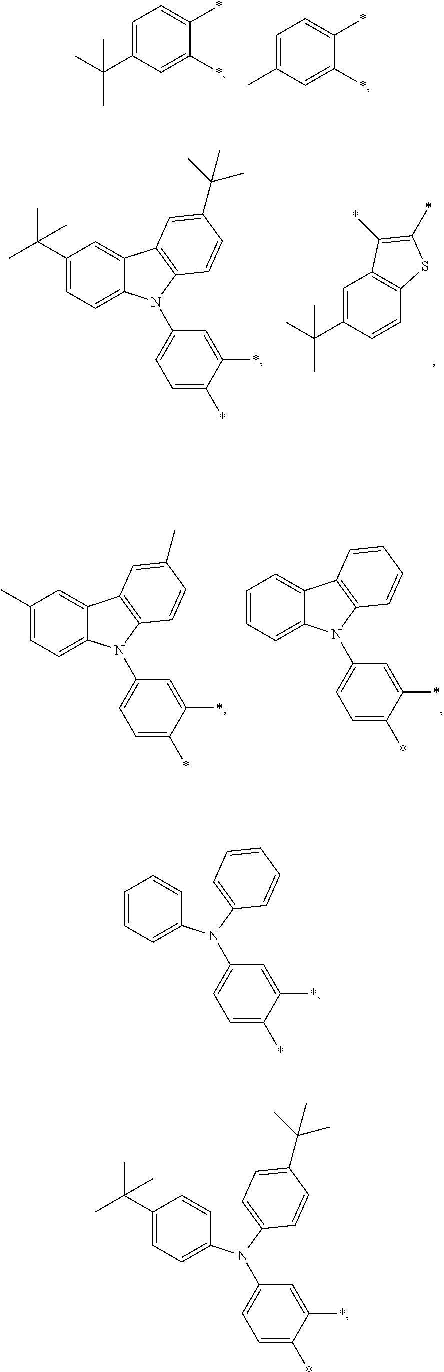

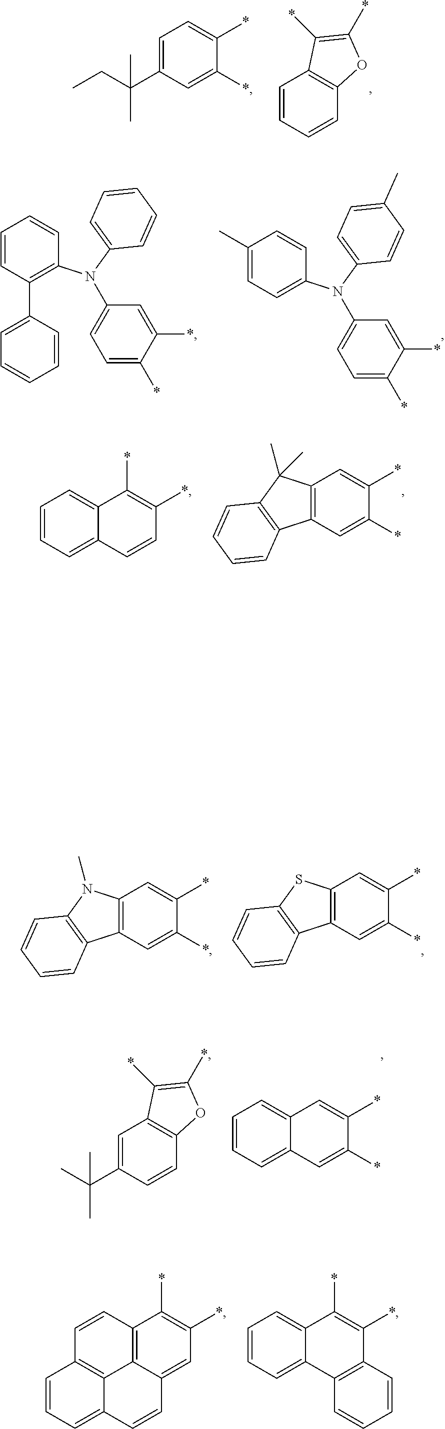

or the like.

In some embodiments, the organic compound has a structure represented by any one of the following structures:

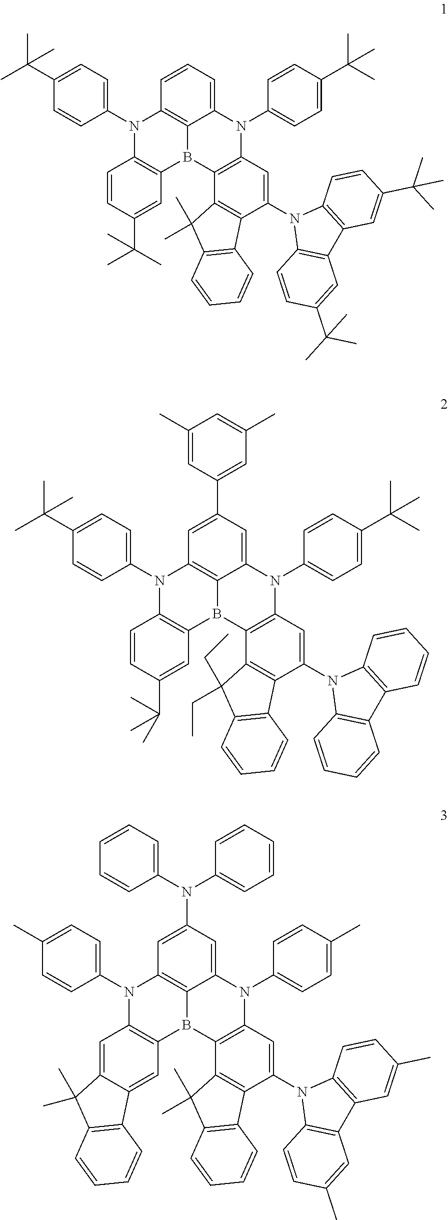

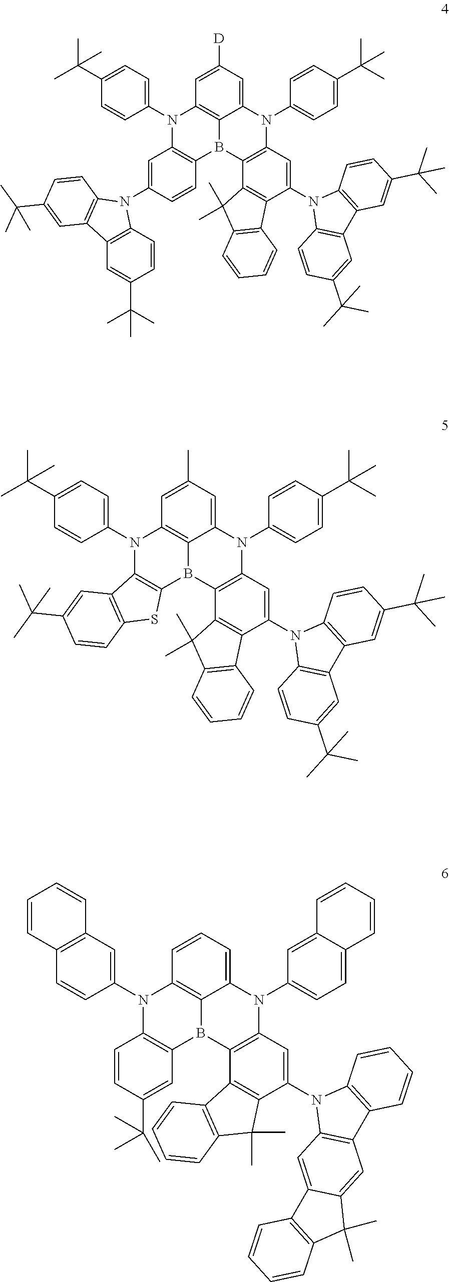

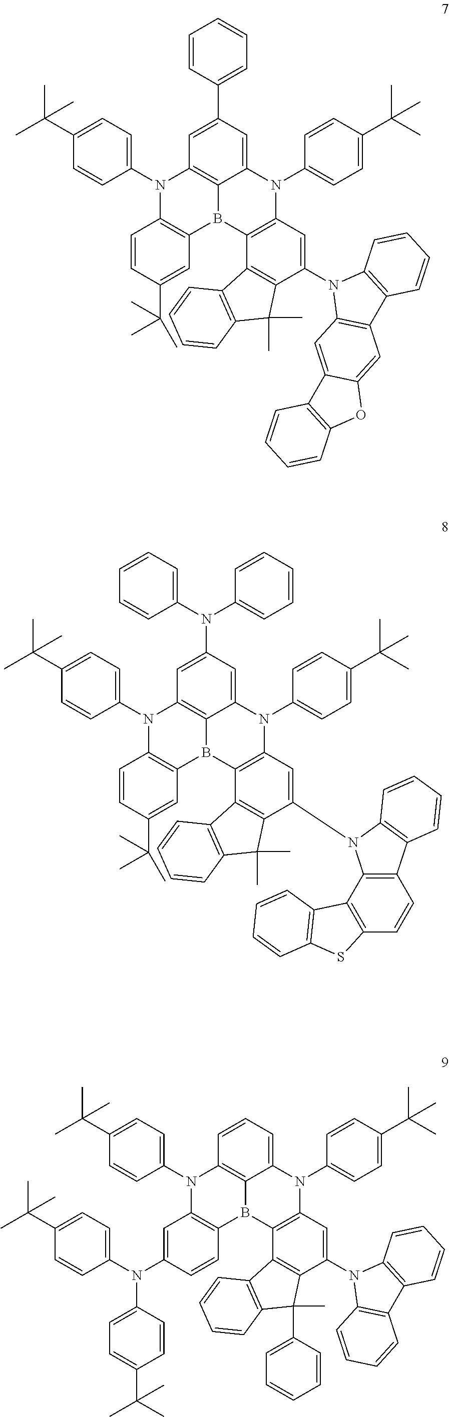 [SMILES: CC(C)(C)c1ccc(N2c3ccc(C(C)(C)C)cc3B3c4c2cc(-c2ccccc2)cc4N(c2ccc(C(C)(C)C)cc2)c2cc(-n4c5ccccc5c5cc6oc7ccccc7c6cc54)c4c(c23)-c2ccccc2C4(C)C)cc1 ; CC(C)(C)c1ccc(N2c3ccc(C(C)(C)C)cc3B3c4c2cc(N(c2ccccc2)c2ccccc2)cc4N(c2ccc(C(C)(C)C)cc2)c2cc(-n4c5ccccc5c5ccc6sc7ccccc7c6c54)c4c(c23)-c2ccccc2C4(C)C)cc1 ; CC(C)(C)c1ccc(N(c2ccc(C(C)(C)C)cc2)c2ccc3c(c2)N(c2ccc(C(C)(C)C)cc2)c2cccc4c2B3c2c(cc(-n3c5ccccc5c5ccccc53)c3c2-c2ccccc2C3(C)c2ccccc2)N4c2ccc(C(C)(C)C)cc2)cc1]

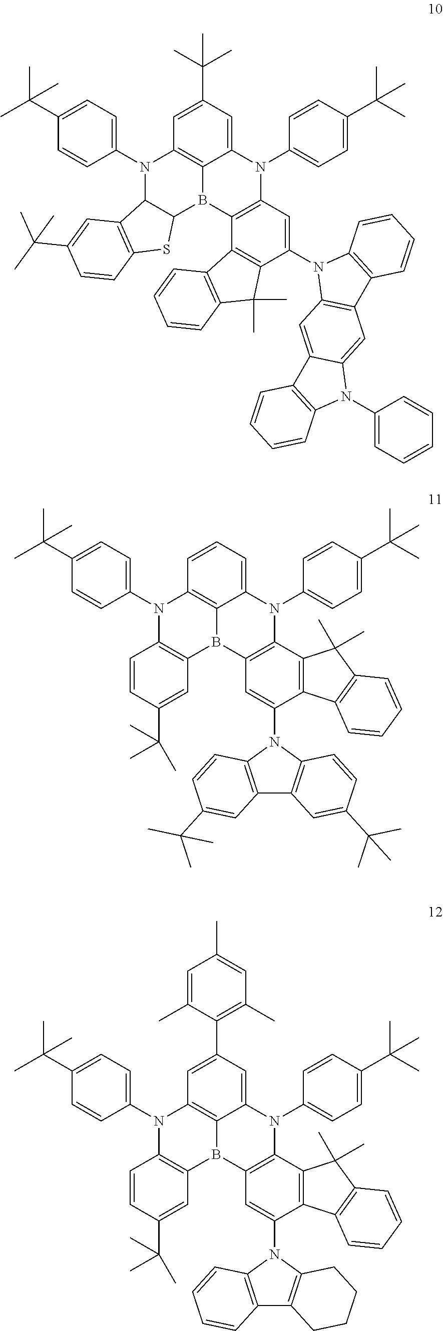

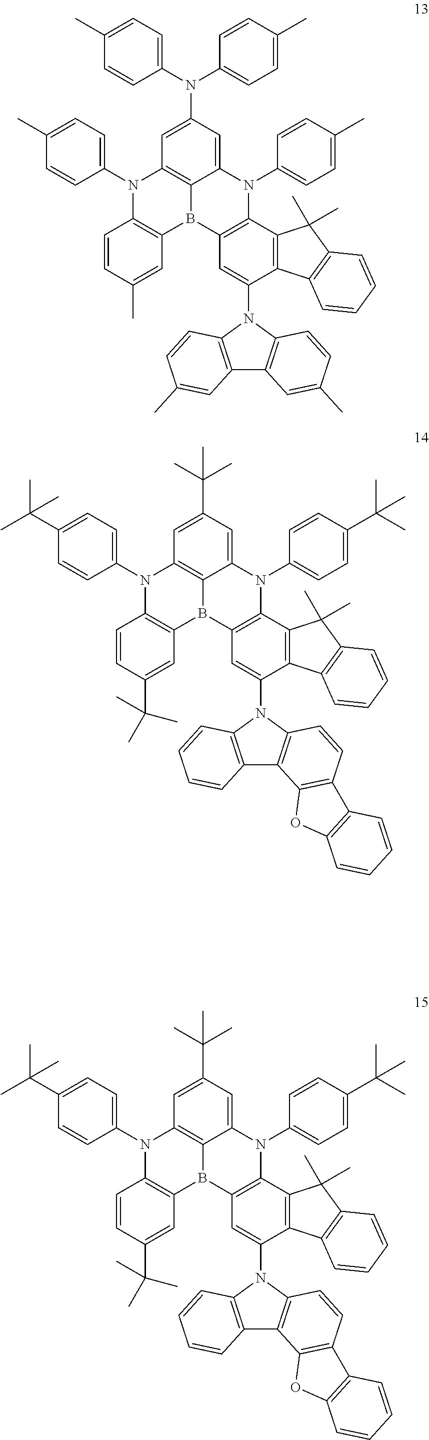

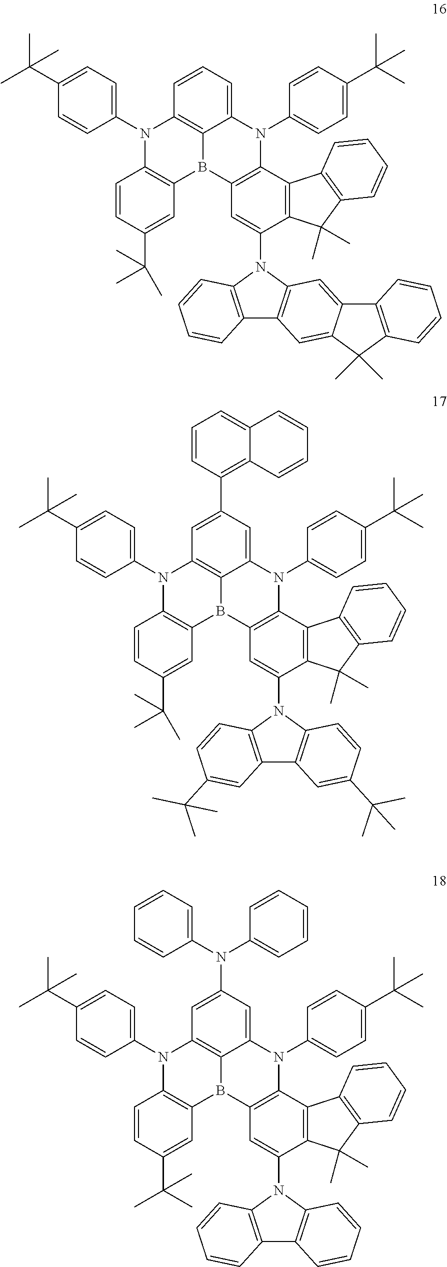

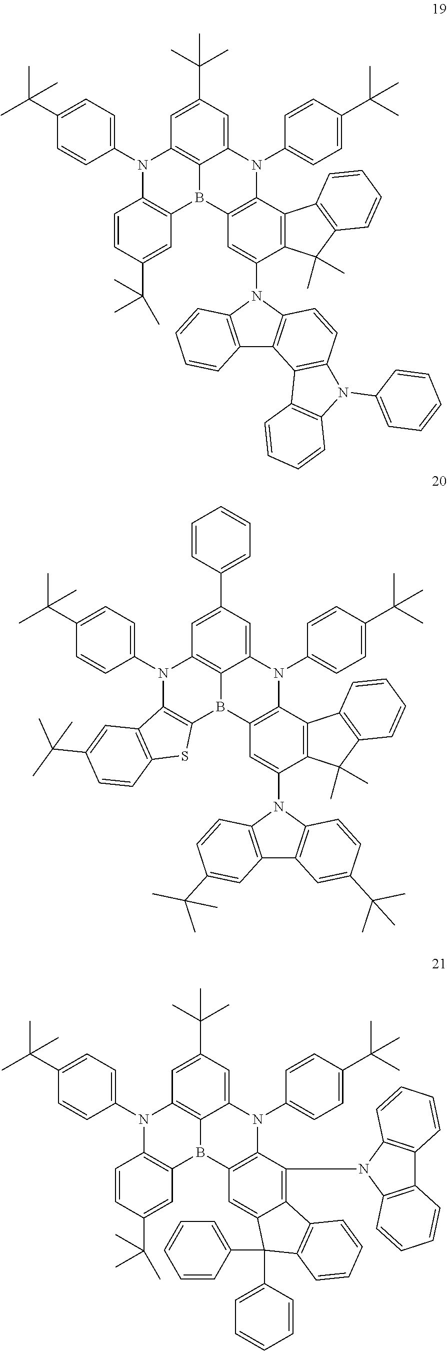

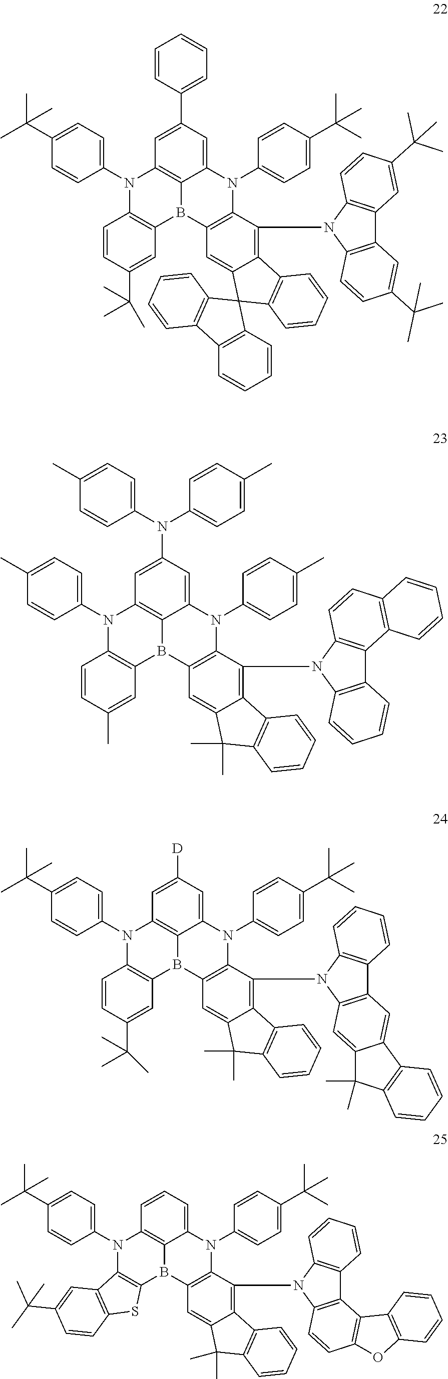

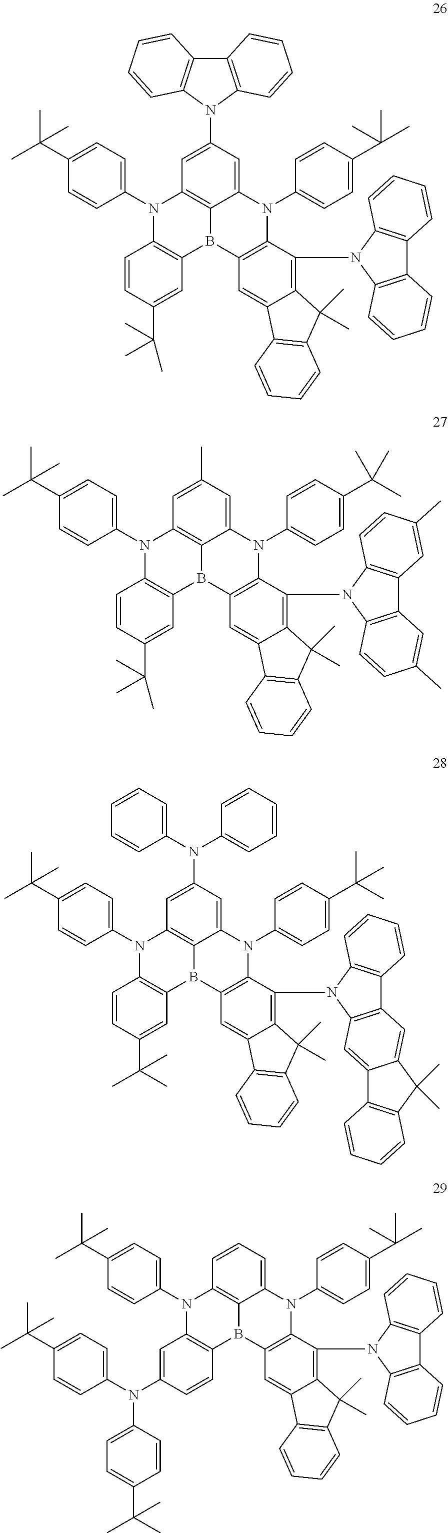

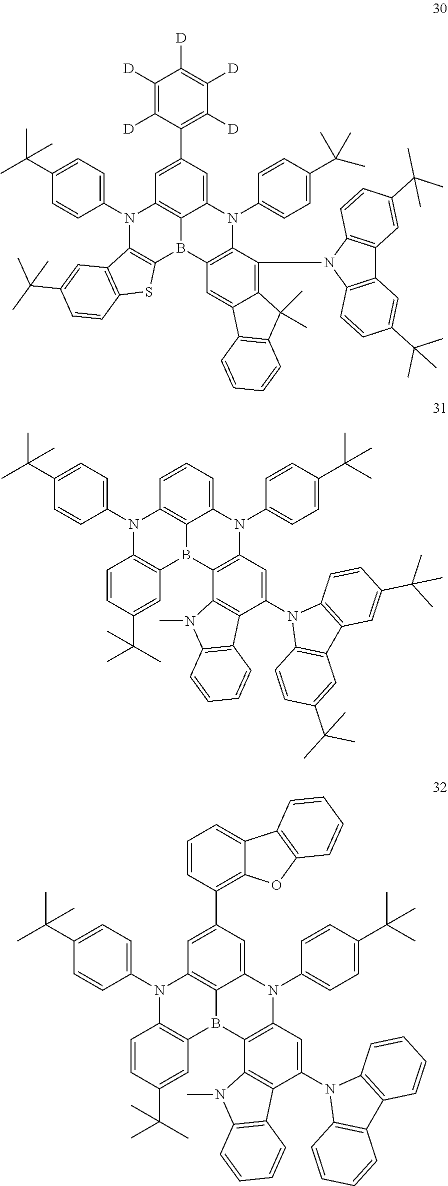

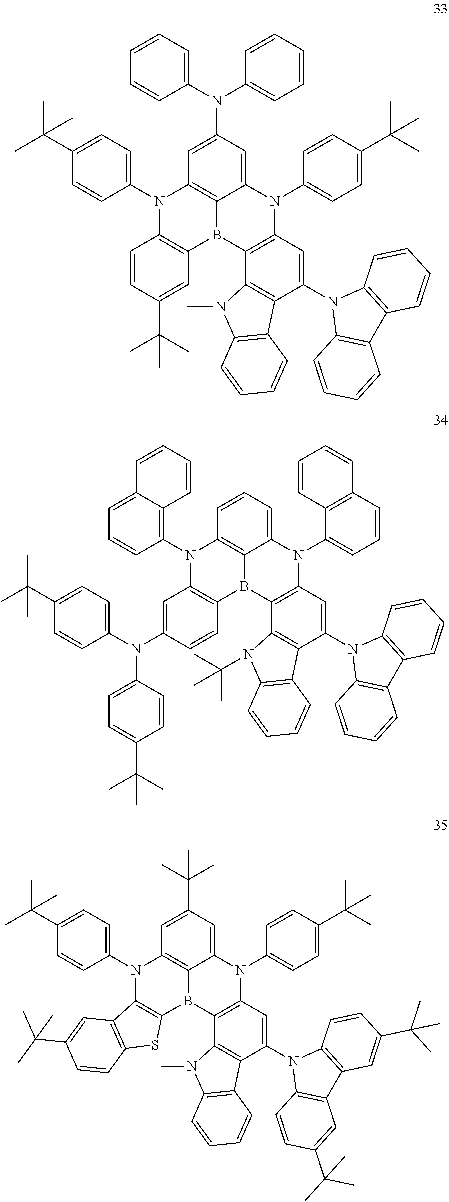 [SMILES: Cn1c2ccccc2c2c(-n3c4ccccc4c4ccccc43)cc3c(c21)B1c2cc(C(C)(C)C)ccc2N(c2ccc(C(C)(C)C)cc2)c2cc(N(c4ccccc4)c4ccccc4)cc(c21)N3c1ccc(C(C)(C)C)cc1 ; CC(C)(C)c1ccc(N(c2ccc(C(C)(C)C)cc2)c2ccc3c(c2)N(c2cccc4ccccc24)c2cccc4c2B3c2c(cc(-n3c5ccccc5c5ccccc53)c3c5ccccc5n(C(C)(C)C)c23)N4c2cccc3ccccc23)cc1 ; Cn1c2ccccc2c2c(-n3c4ccc(C(C)(C)C)cc4c4cc(C(C)(C)C)ccc43)cc3c(c21)B1c2sc4ccc(C(C)(C)C)cc4c2N(c2ccc(C(C)(C)C)cc2)c2cc(C(C)(C)C)cc(c21)N3c1ccc(C(C)(C)C)cc1]

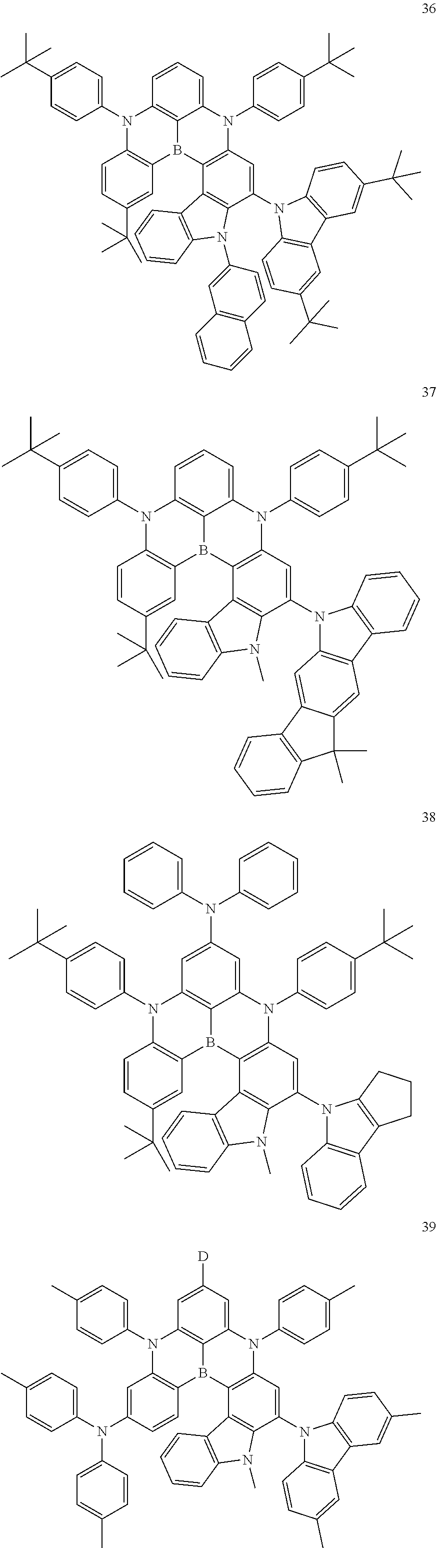

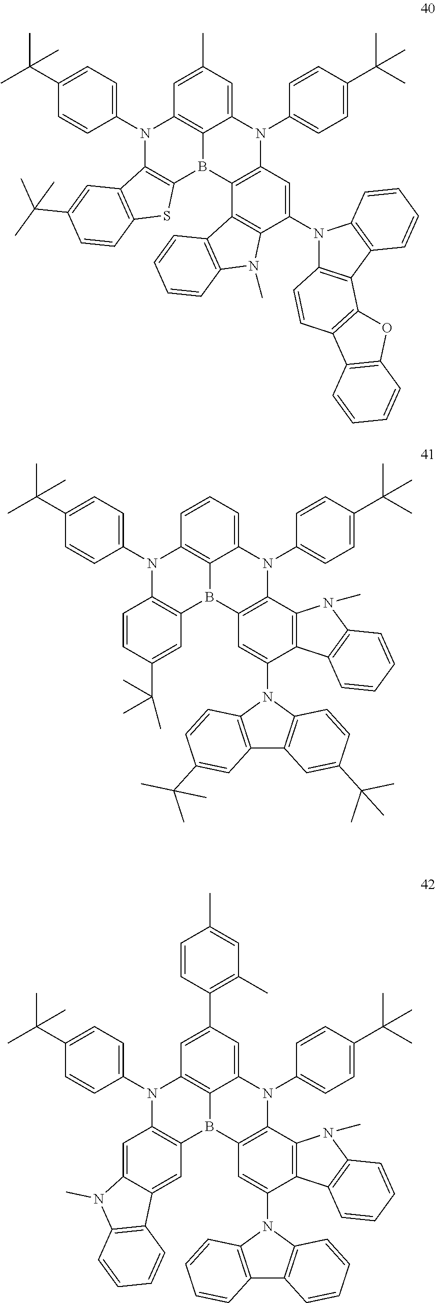

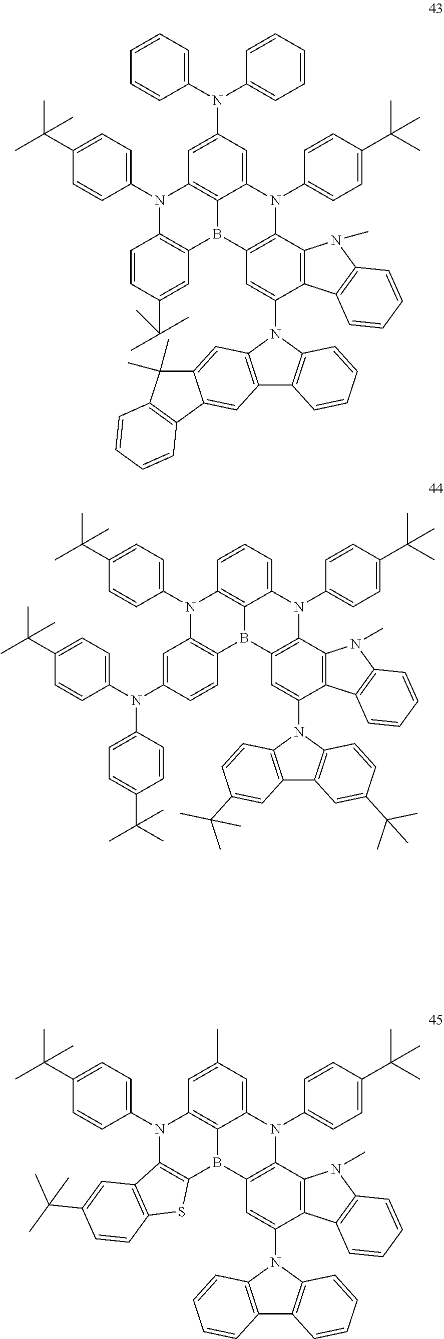

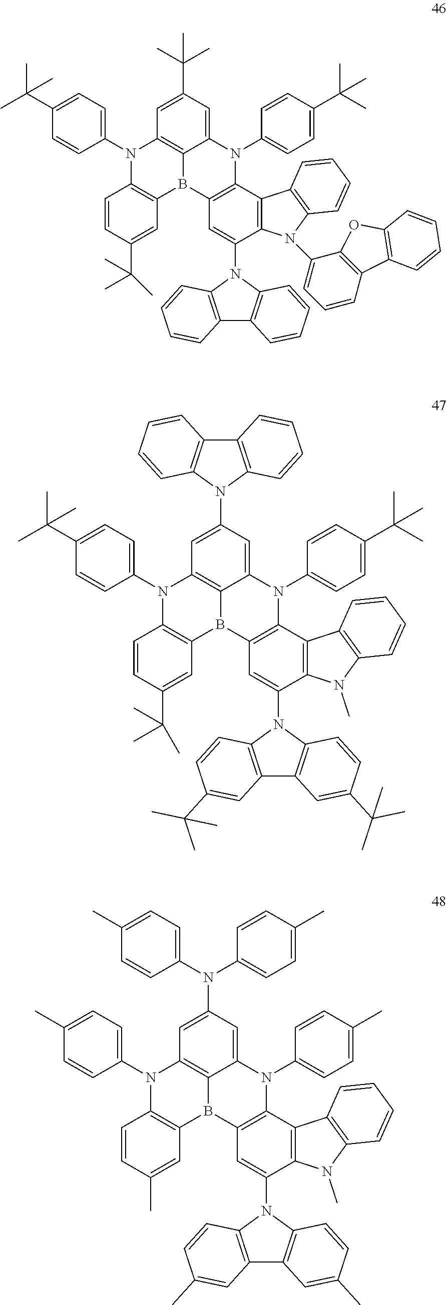

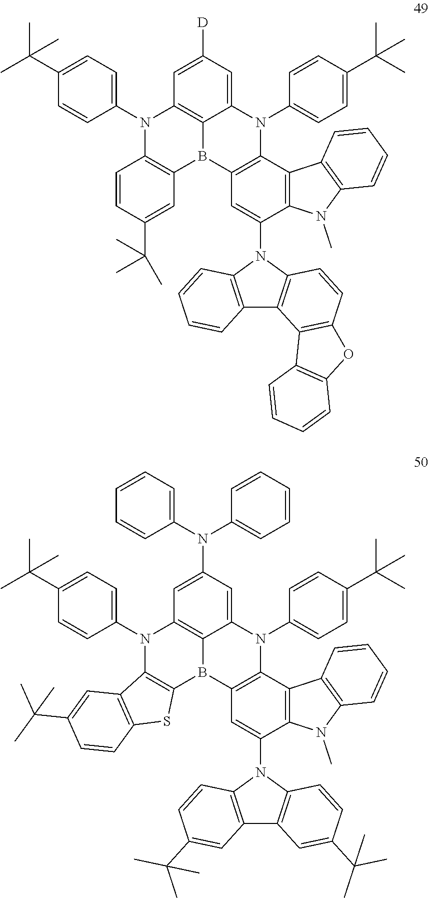

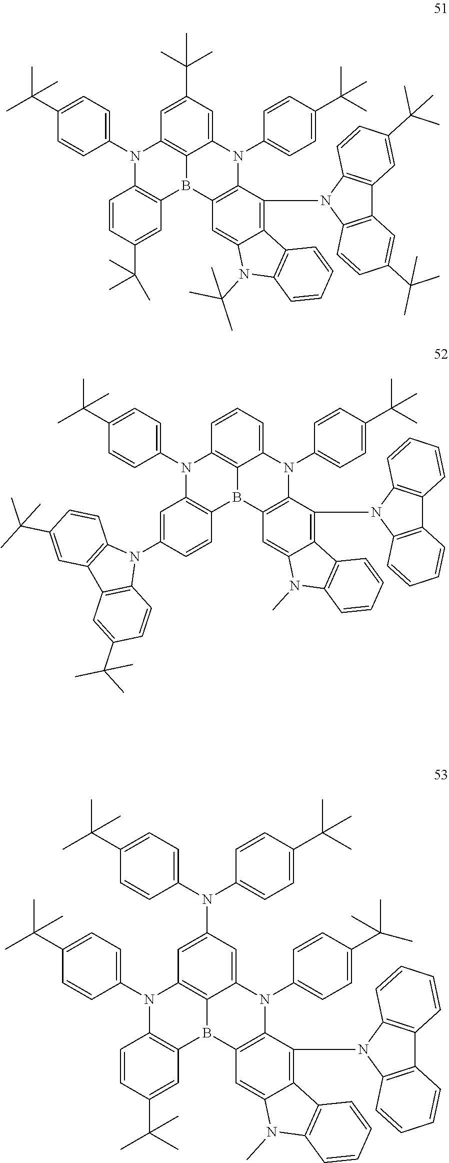

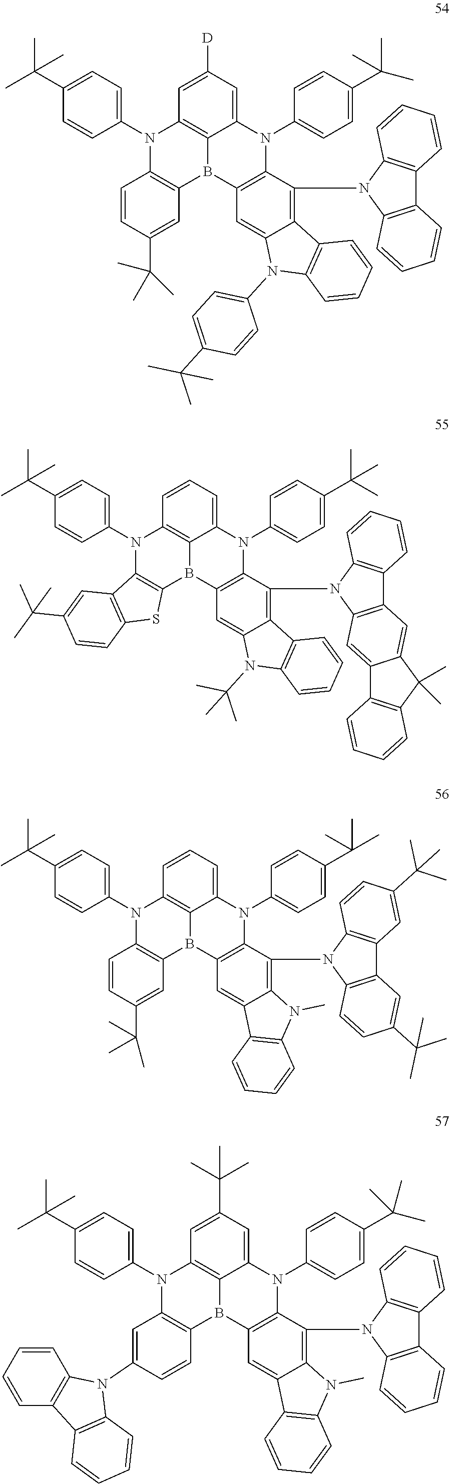

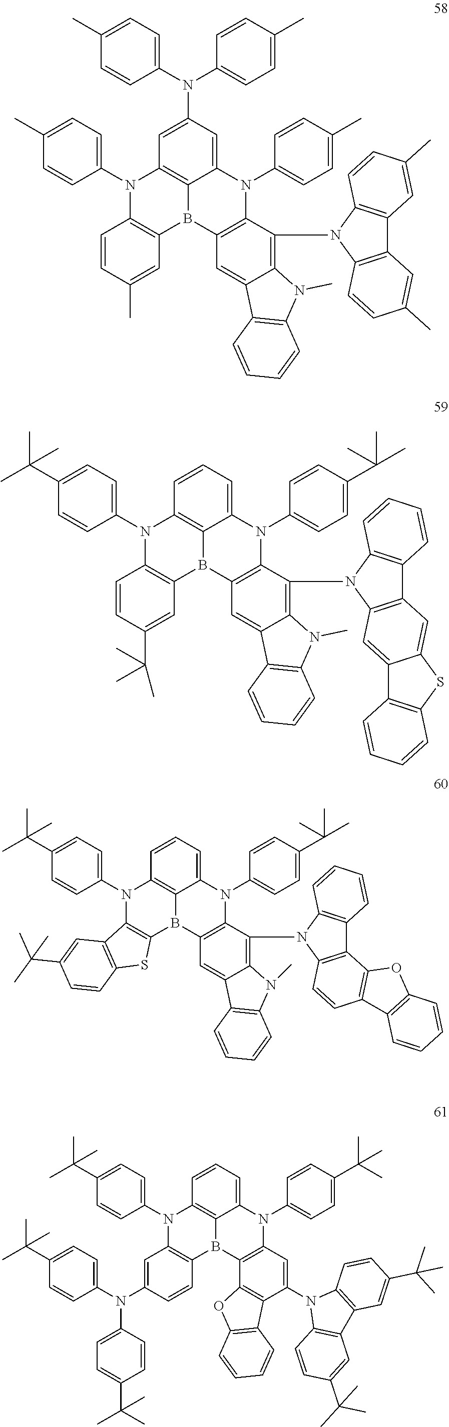

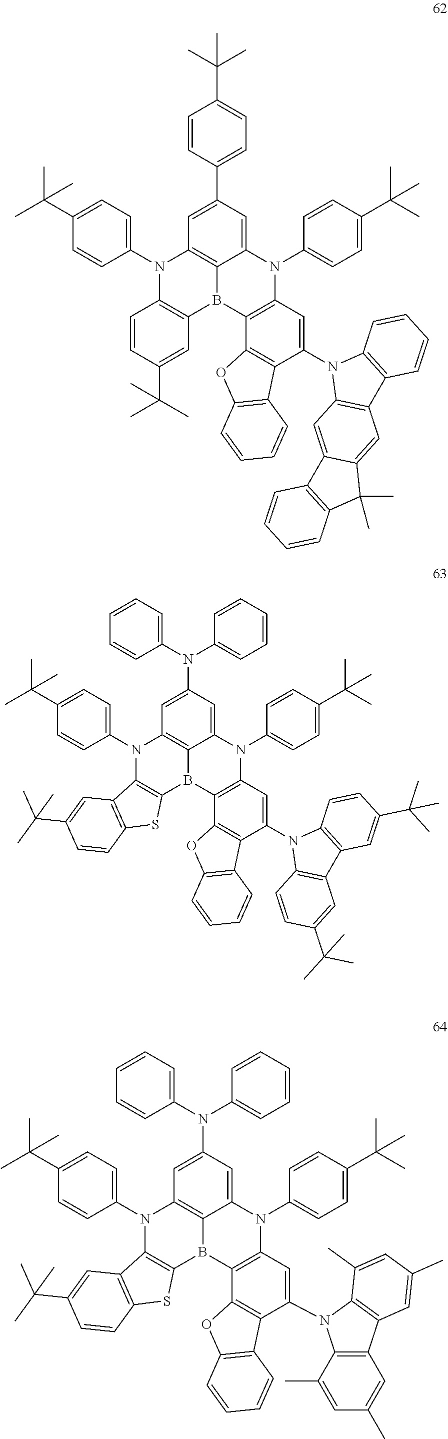

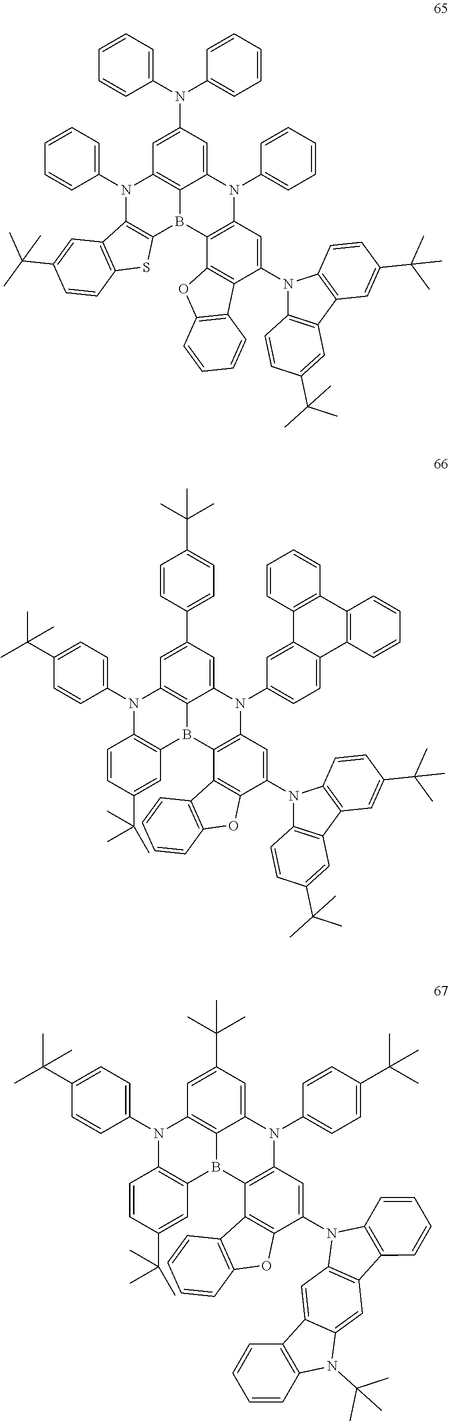

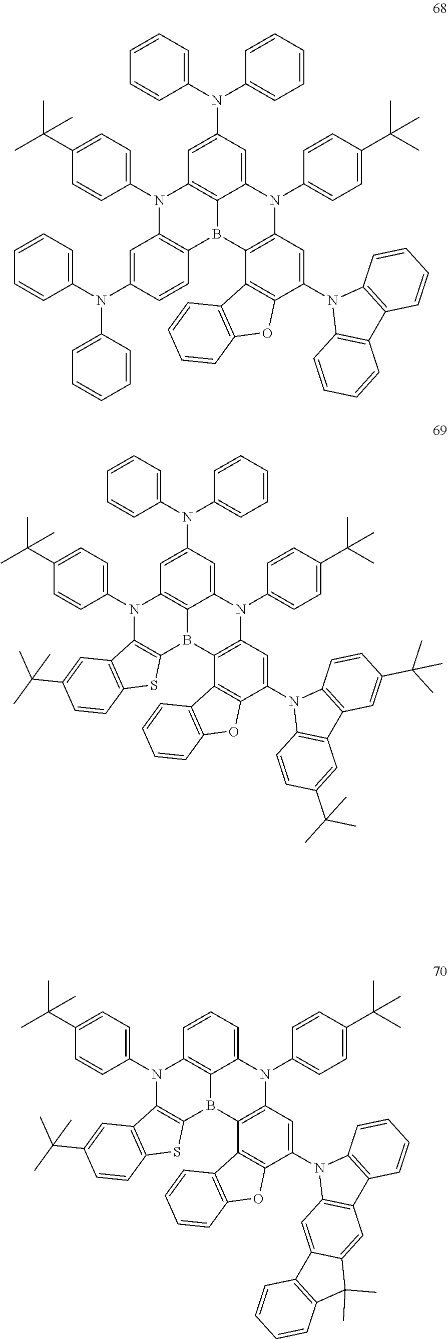

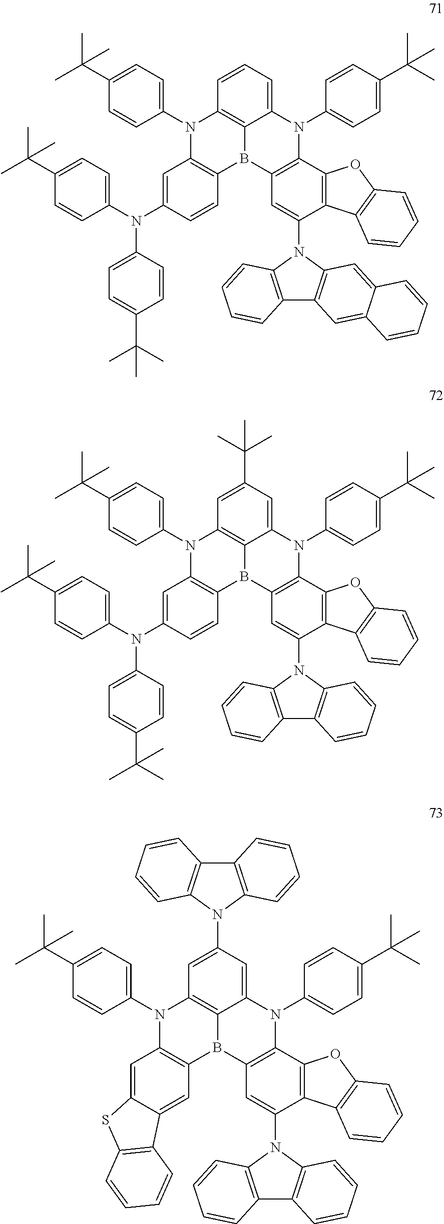

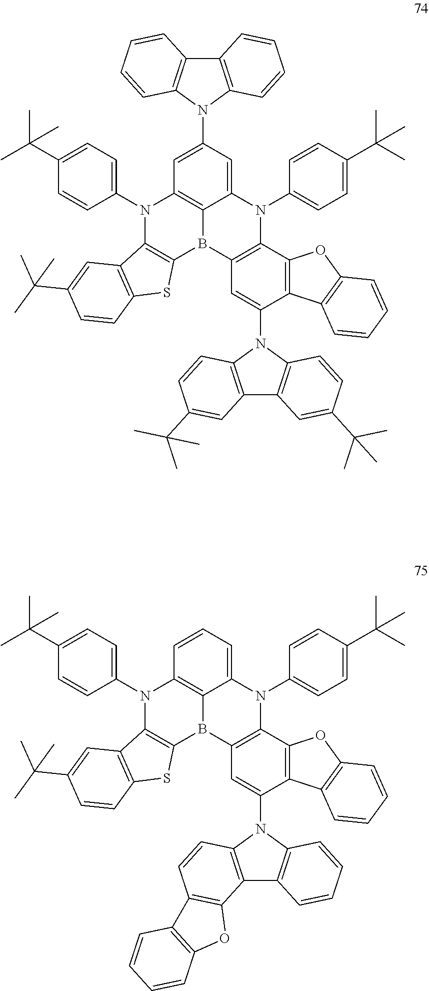

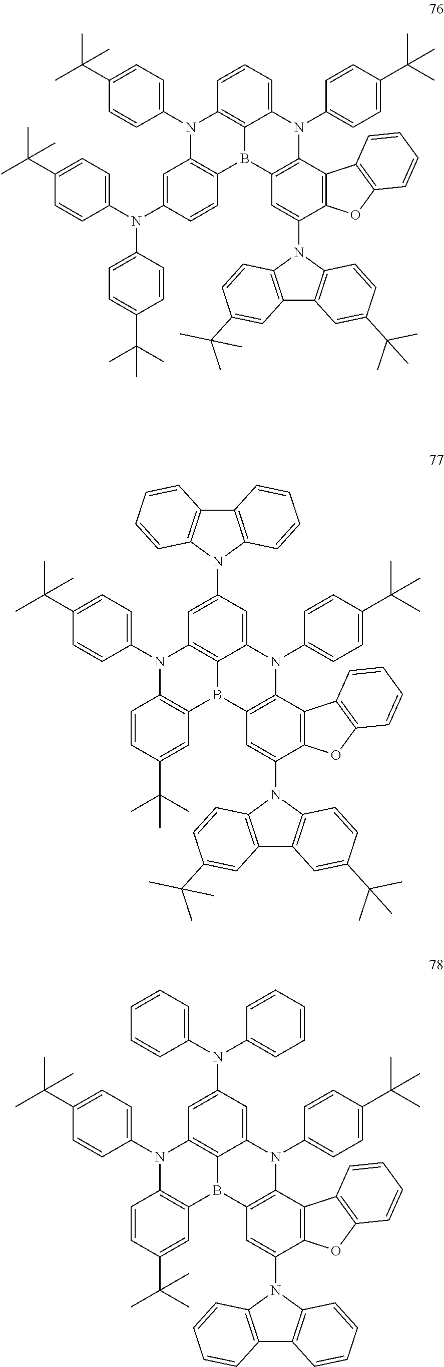

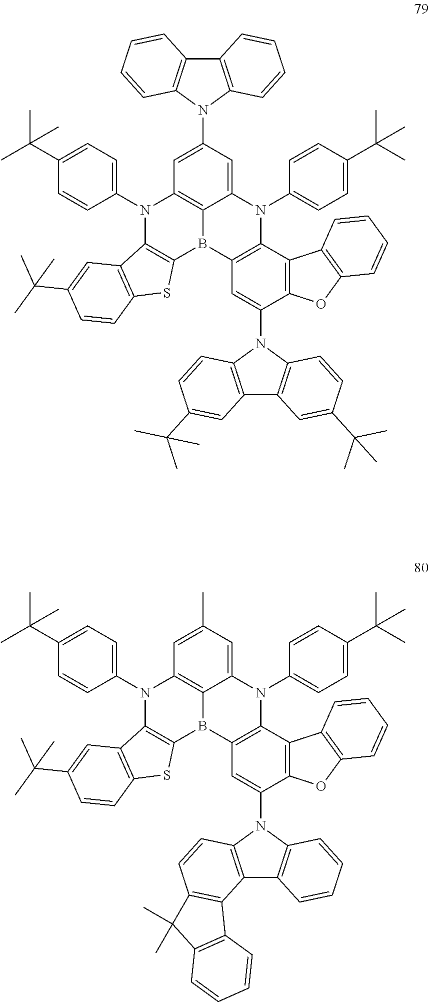

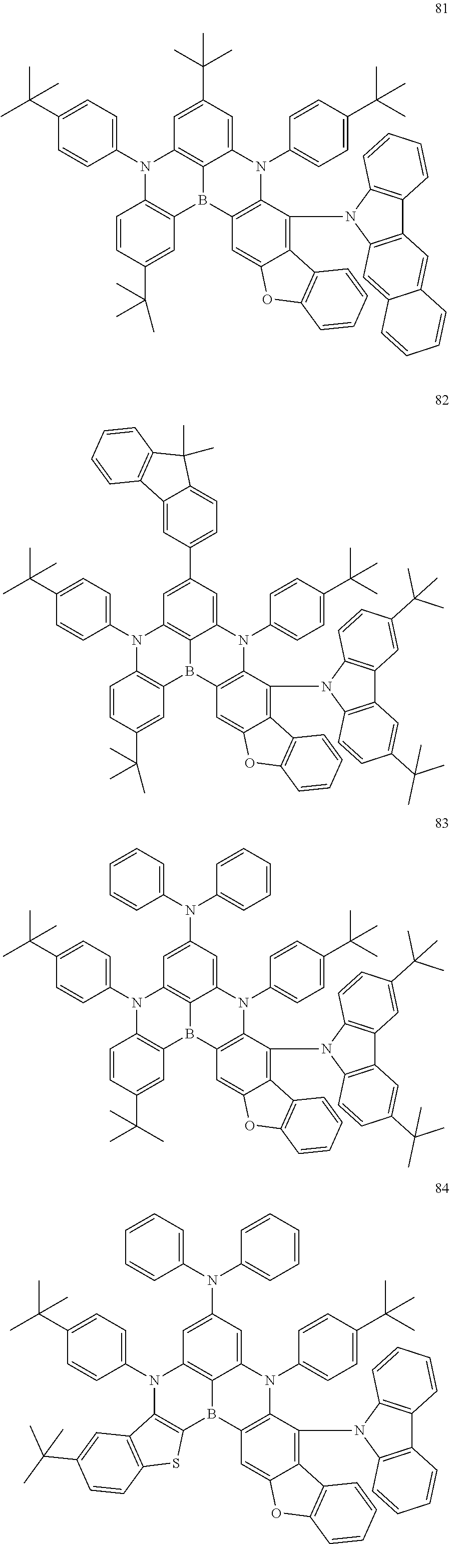

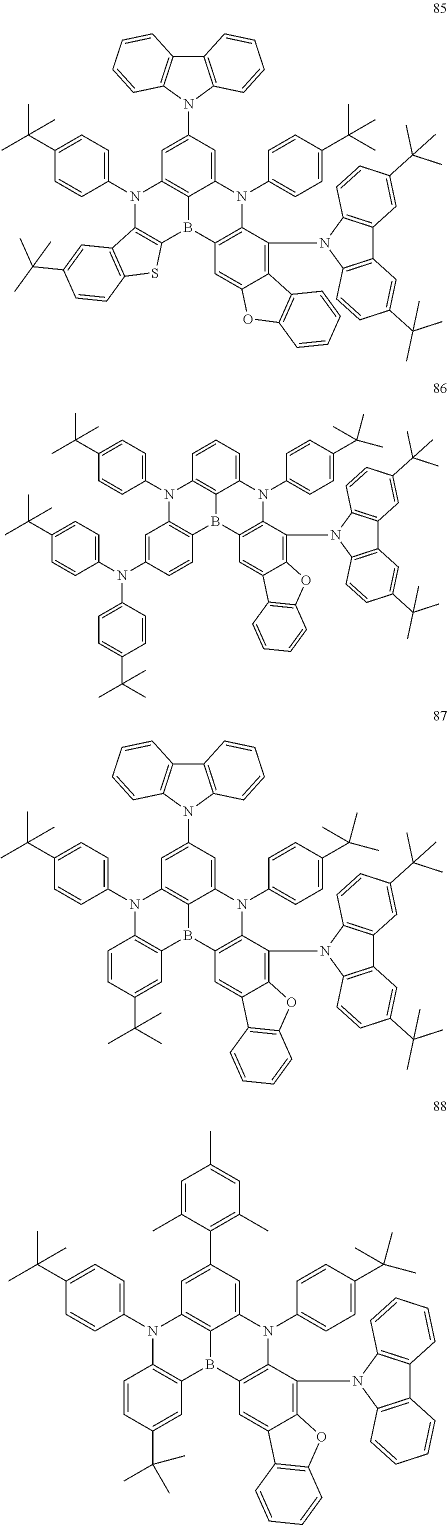

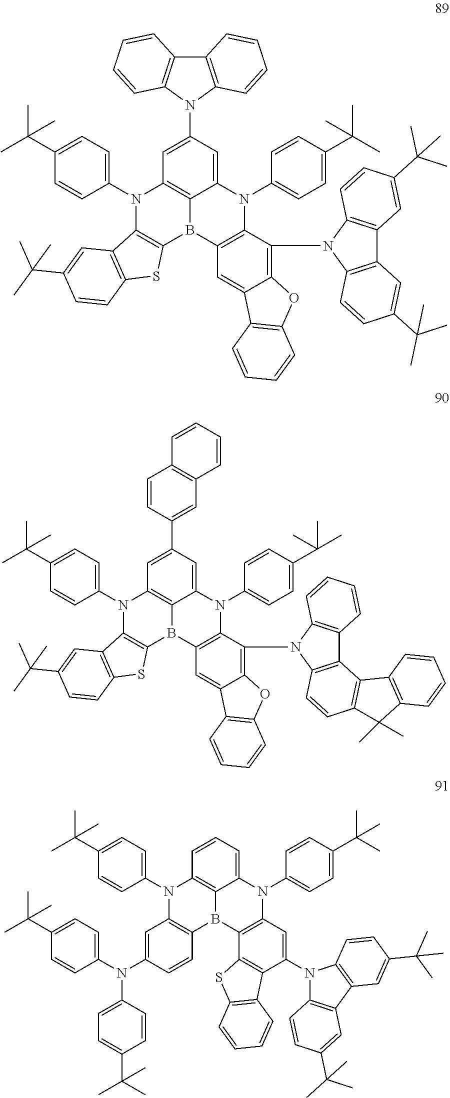

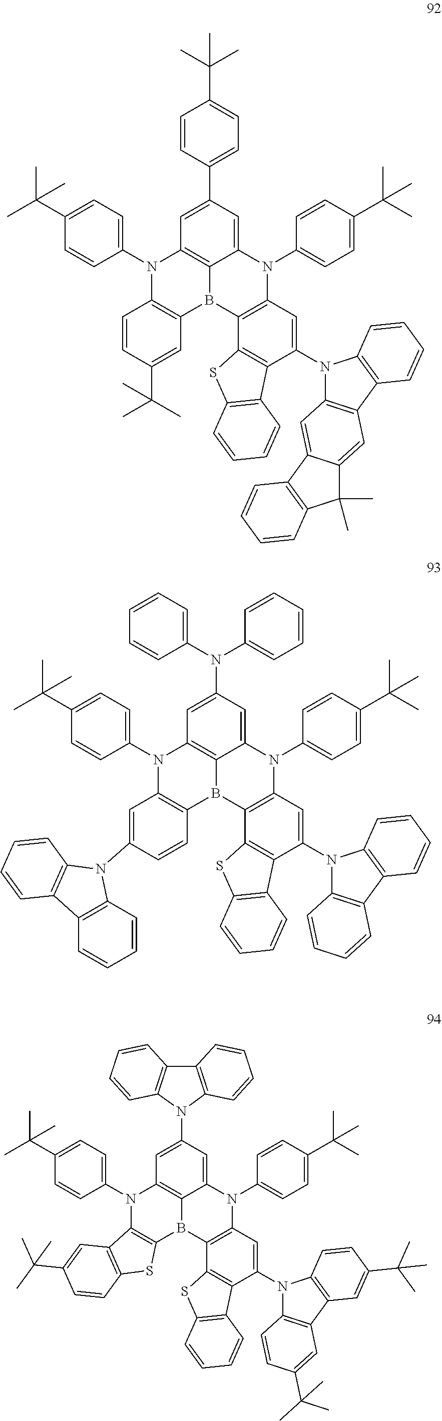 [SMILES: CC(C)(C)c1ccc(-c2cc3c4c(c2)N(c2ccc(C(C)(C)C)cc2)c2cc(-n5c6ccccc6c6cc7c(cc65)-c5ccccc5C7(C)C)c5c(sc6ccccc65)c2B4c2cc(C(C)(C)C)ccc2N3c2ccc(C(C)(C)C)cc2)cc1 ; CC(C)(C)c1ccc(N2c3cc(-n4c5ccccc5c5ccccc54)ccc3B3c4c2cc(N(c2ccccc2)c2ccccc2)cc4N(c2ccc(C(C)(C)C)cc2)c2cc(-n4c5ccccc5c5ccccc54)c4c(sc5ccccc54)c23)cc1 ; CC(C)(C)c1ccc(N2c3cc(-n4c5ccccc5c5ccccc54)cc4c3B(c3sc5ccc(C(C)(C)C)cc5c3N4c3ccc(C(C)(C)C)cc3)c3c2cc(-n2c4ccc(C(C)(C)C)cc4c4cc(C(C)(C)C)ccc42)c2c3sc3ccccc32)cc1]

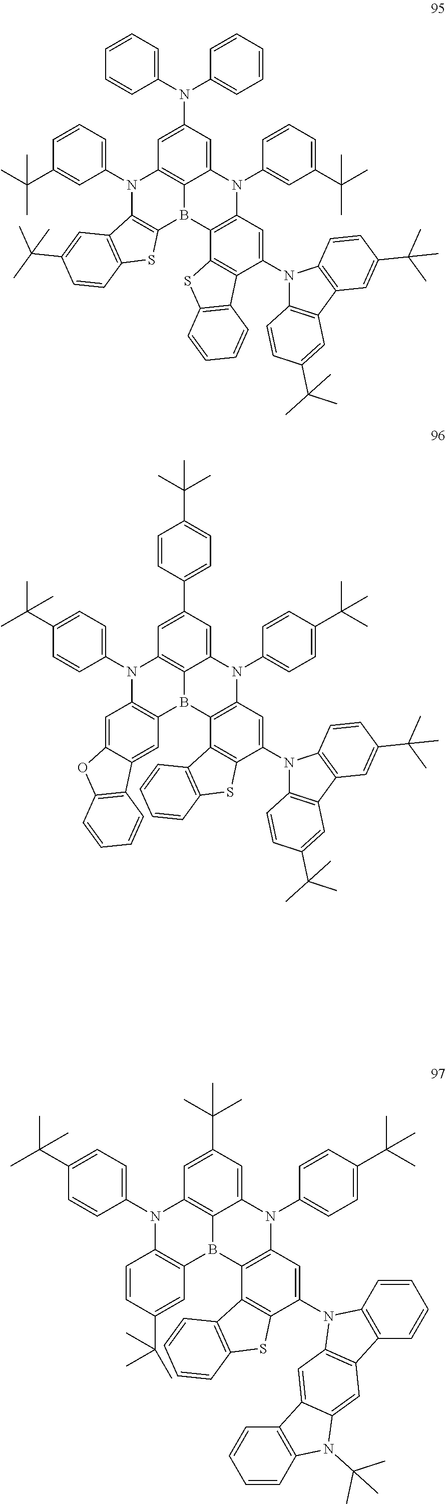

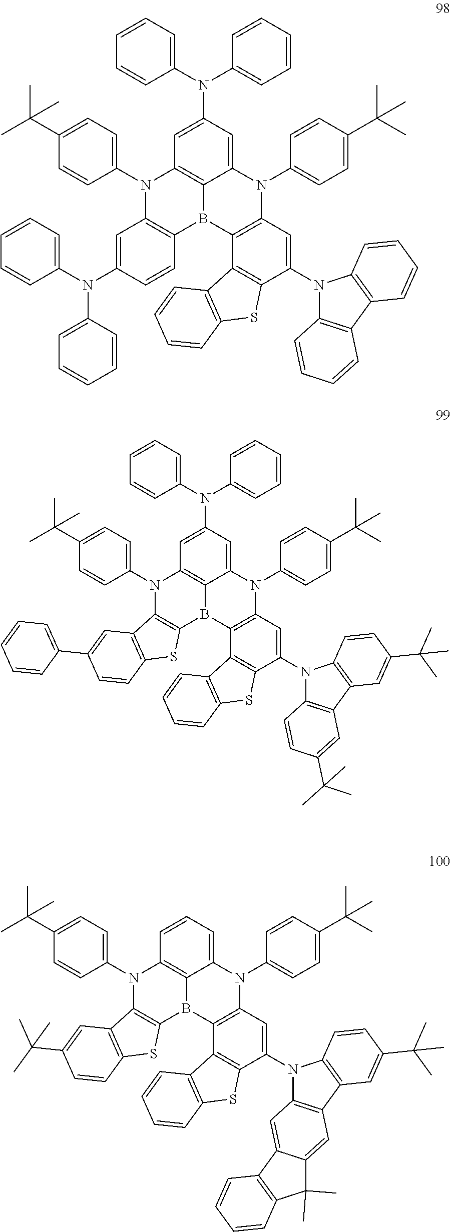

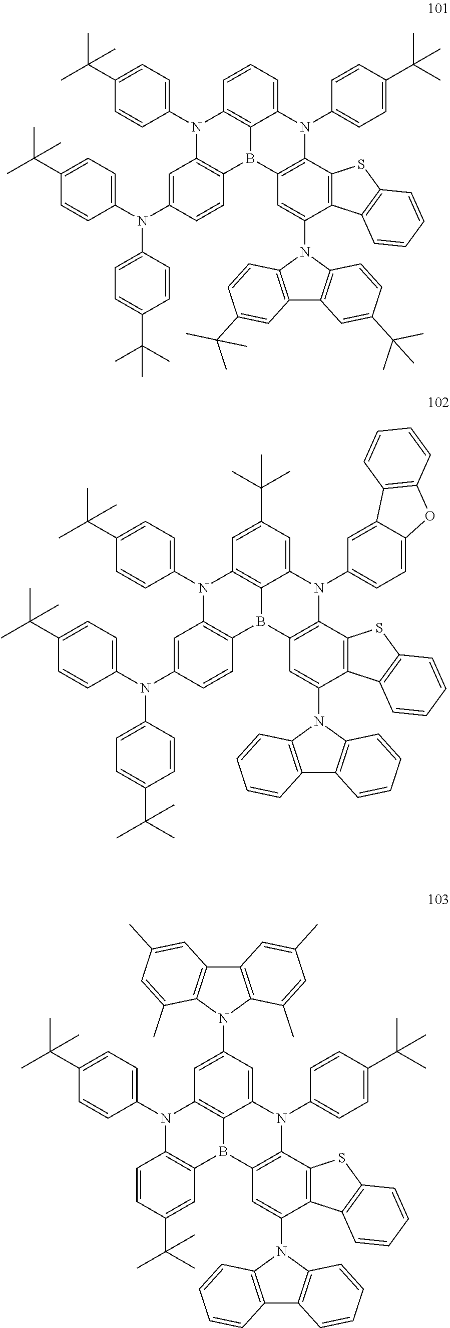

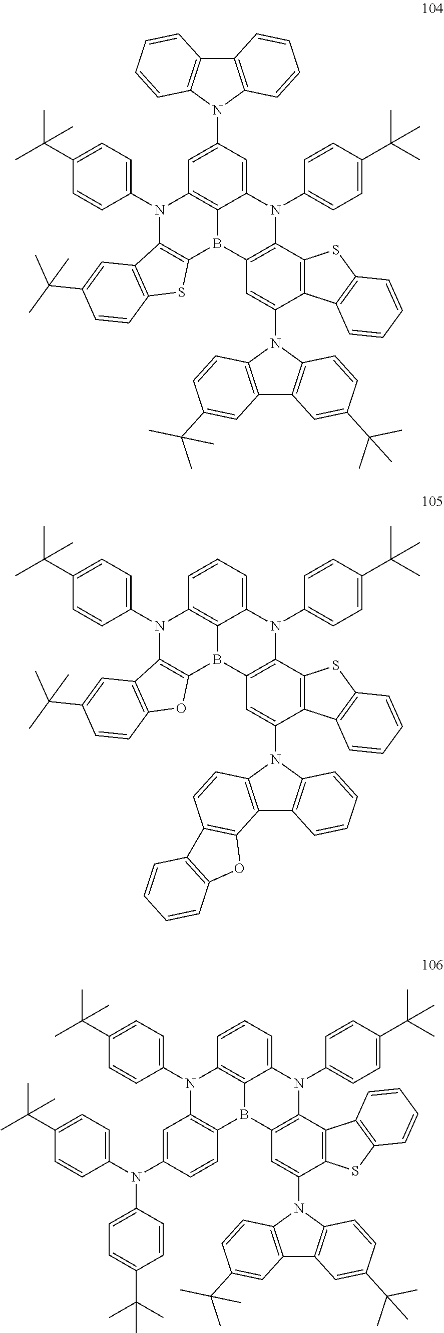

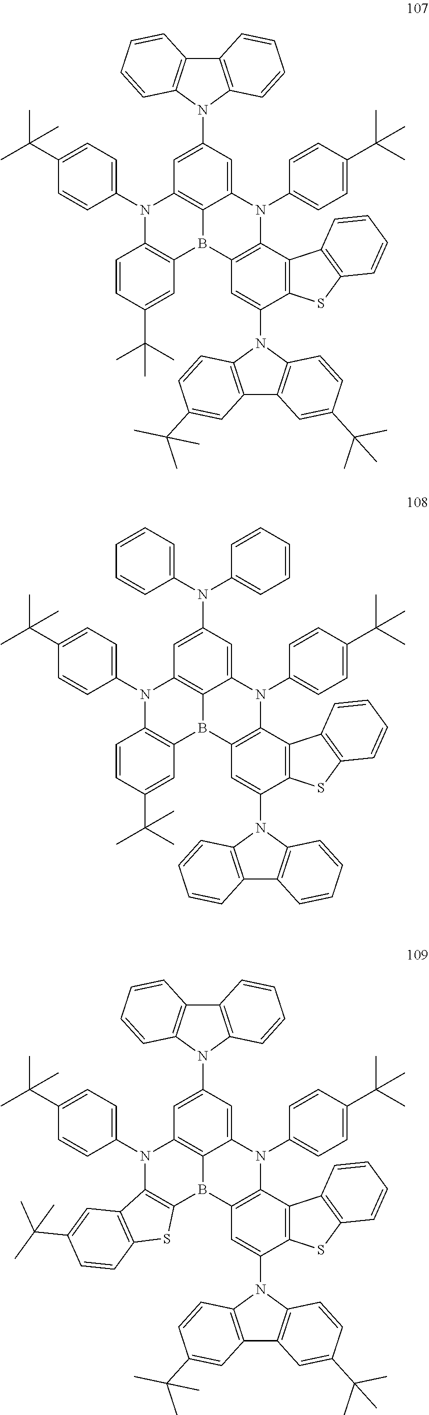

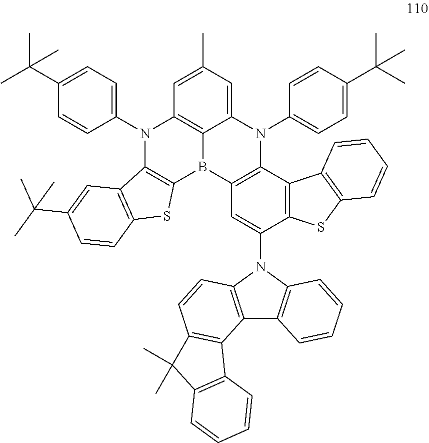 [SMILES: Cc1cc2c3c(c1)N(c1ccc(C(C)(C)C)cc1)c1c(cc(-n4c5ccccc5c5c6c(ccc54)C(C)(C)c4ccccc4-6)c4sc5ccccc5c14)B3c1sc3ccc(C(C)(C)C)cc3c1N2c1ccc(C(C)(C)C)cc1]

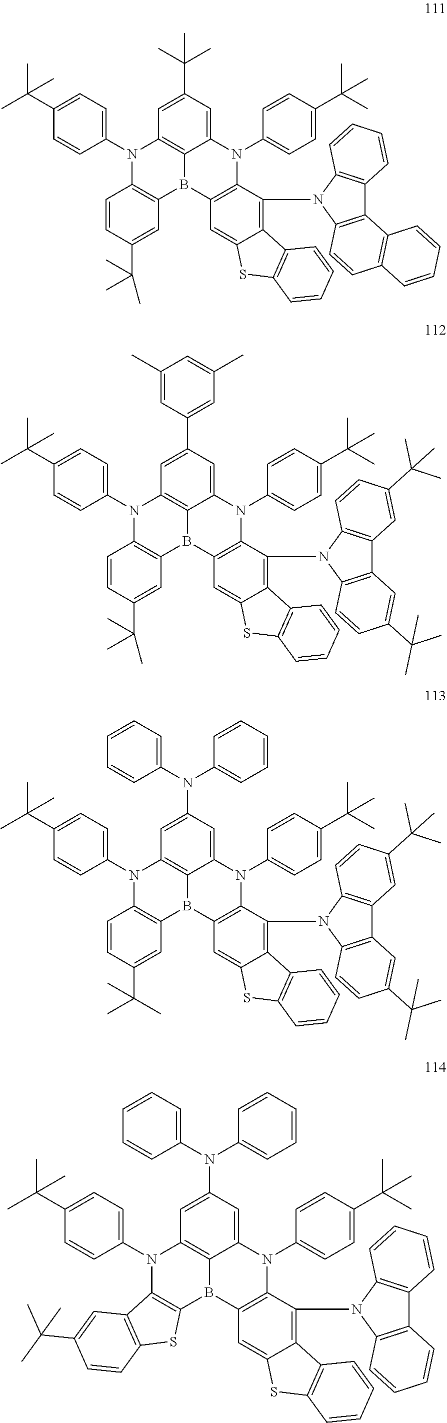

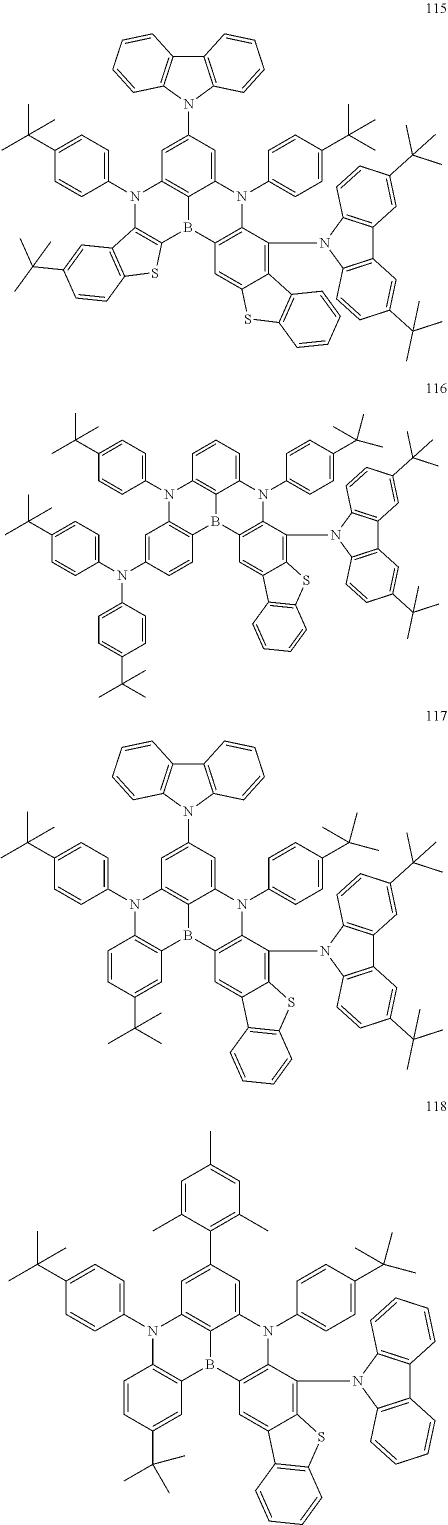

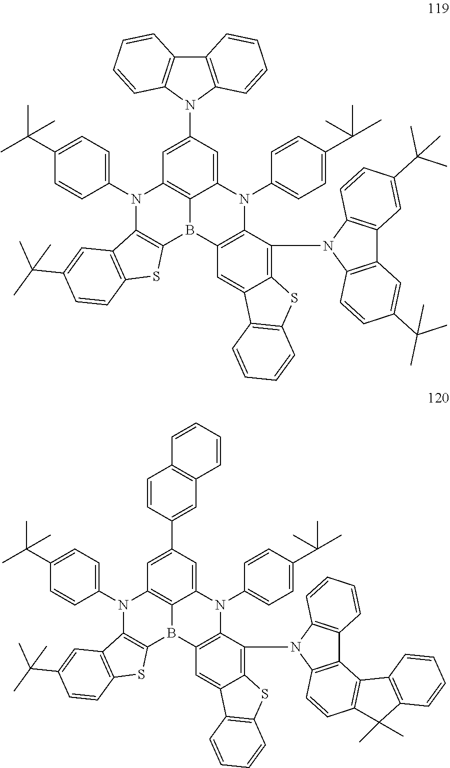

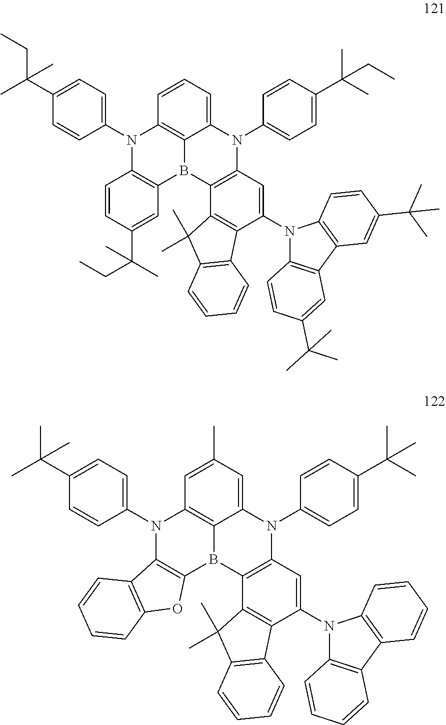

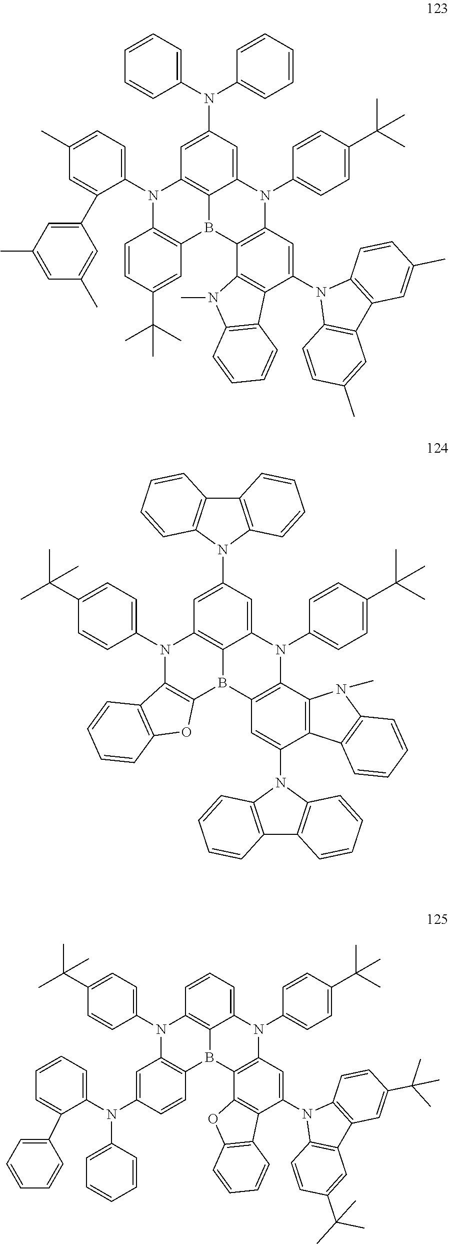

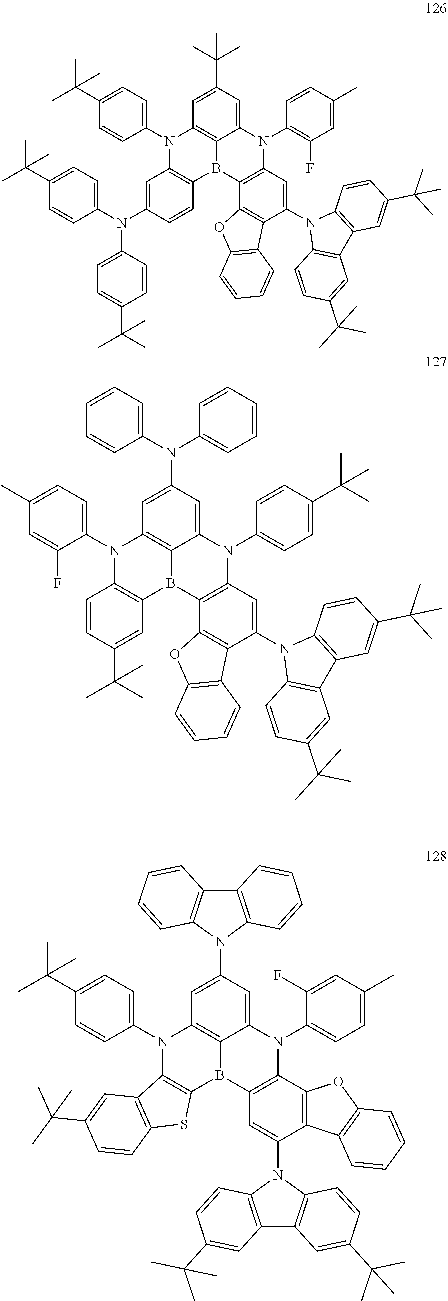

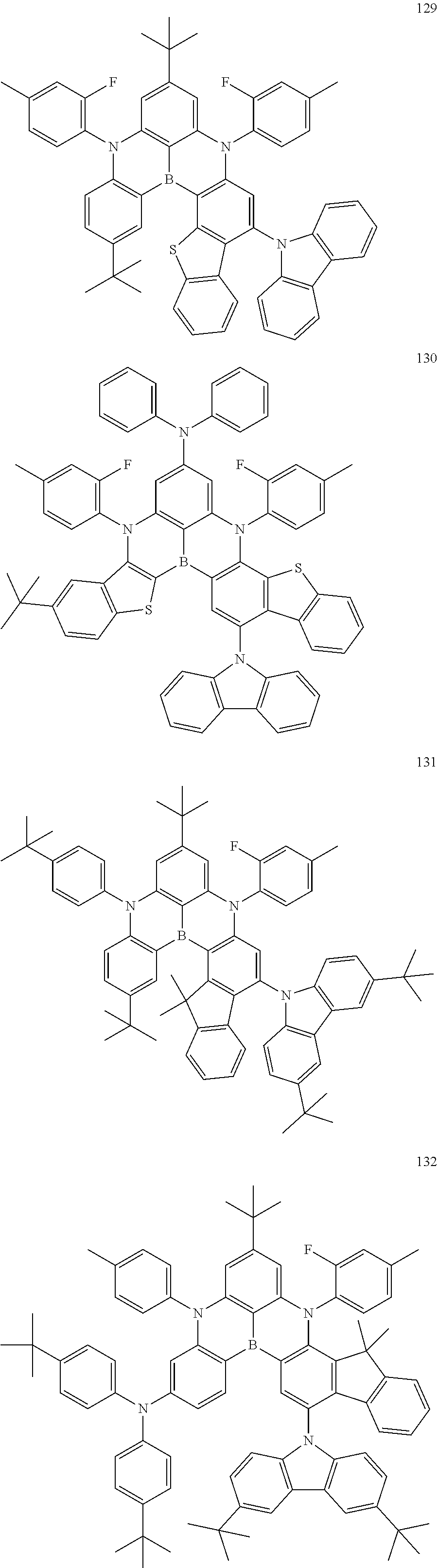

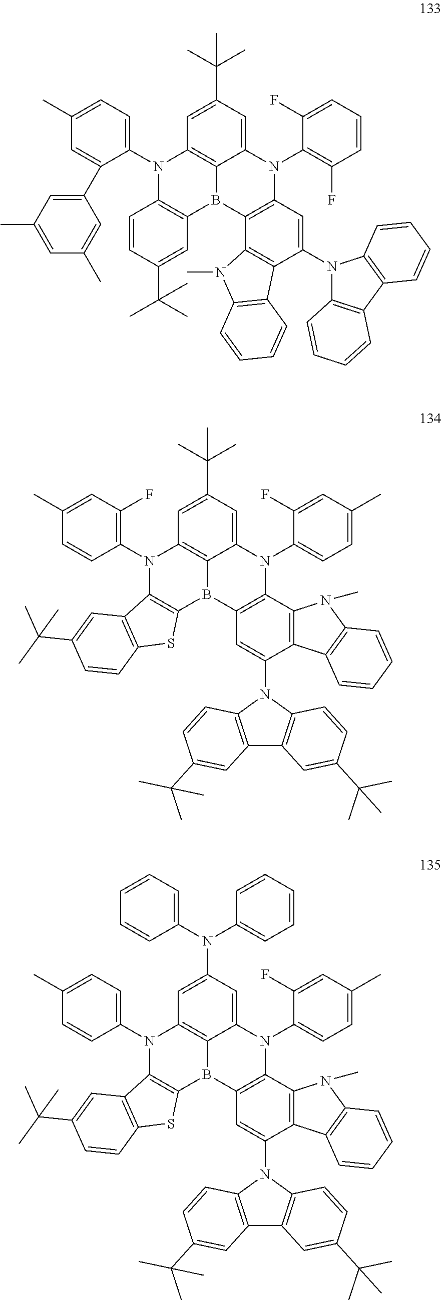 [SMILES: Cc1cc(C)cc(-c2cc(C)ccc2N2c3ccc(C(C)(C)C)cc3B3c4c2cc(C(C)(C)C)cc4N(c2c(F)cccc2F)c2cc(-n4c5ccccc5c5ccccc54)c4c5ccccc5n(C)c4c23)c1 ; Cc1ccc(N2c3cc(C(C)(C)C)cc4c3B(c3cc(-n5c6ccc(C(C)(C)C)cc6c6cc(C(C)(C)C)ccc65)c5c6ccccc6n(C)c5c3N4c3ccc(C)cc3F)c3sc4ccc(C(C)(C)C)cc4c32)c(F)c1 ; Cc1ccc(N2c3cc(N(c4ccccc4)c4ccccc4)cc4c3B(c3cc(-n5c6ccc(C(C)(C)C)cc6c6cc(C(C)(C)C)ccc65)c5c6ccccc6n(C)c5c3N4c3ccc(C)cc3F)c3sc4ccc(C(C)(C)C)cc4c32)cc1]

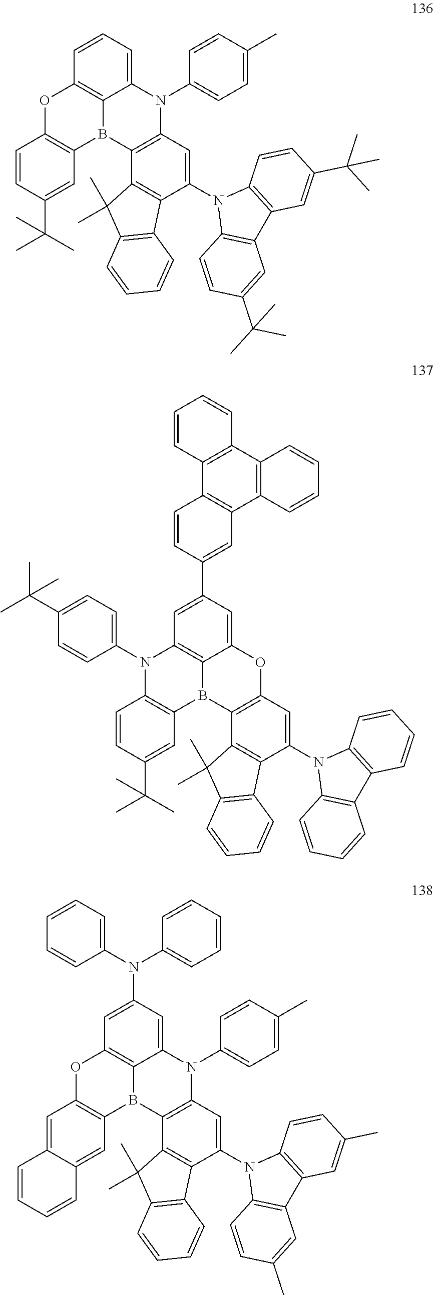

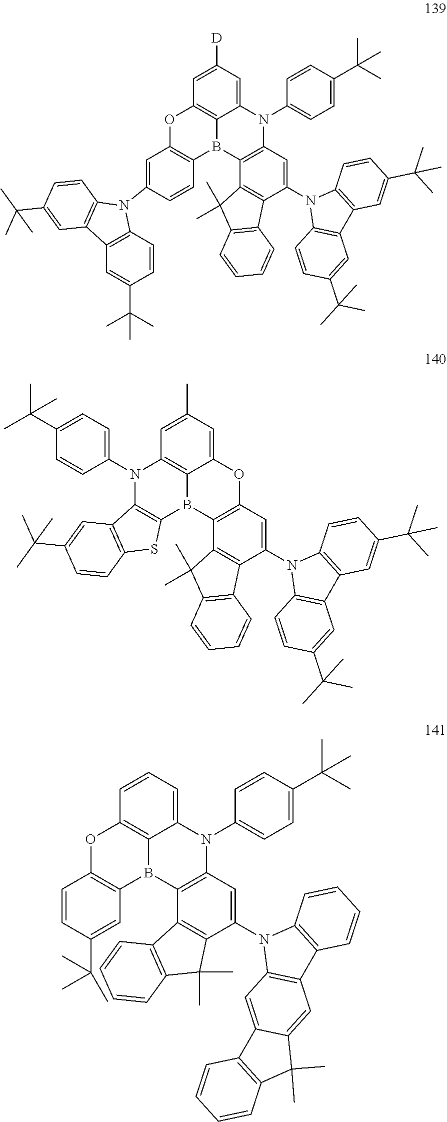

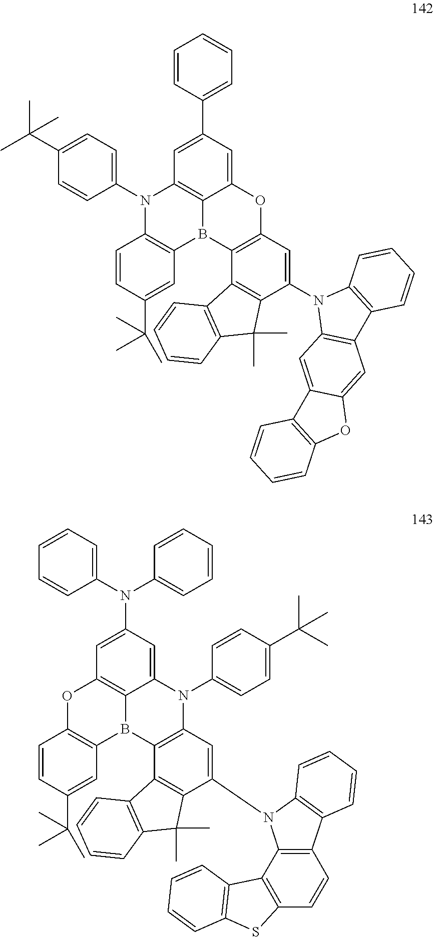 [SMILES: CC(C)(C)c1ccc(N2c3ccc(C(C)(C)C)cc3B3c4c(cc(-c5ccccc5)cc42)Oc2cc(-n4c5ccccc5c5cc6oc7ccccc7c6cc54)c4c(c23)-c2ccccc2C4(C)C)cc1 ; CC(C)(C)c1ccc(N2c3cc(N(c4ccccc4)c4ccccc4)cc4c3B(c3cc(C(C)(C)C)ccc3O4)c3c2cc(-n2c4ccccc4c4ccc5sc6ccccc6c5c42)c2c3-c3ccccc3C2(C)C)cc1]

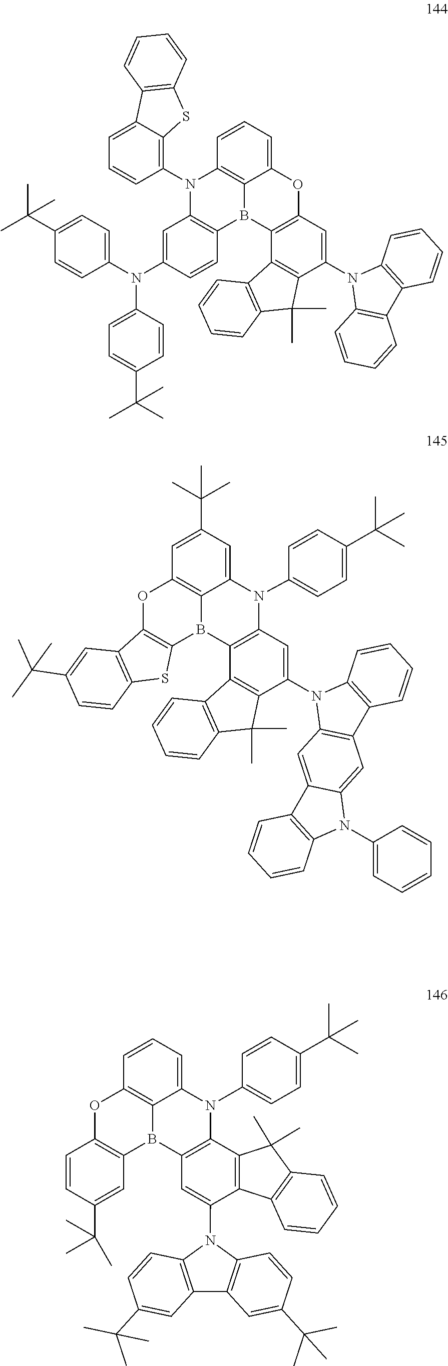 [SMILES: CC(C)(C)c1ccc(N(c2ccc(C(C)(C)C)cc2)c2ccc3c(c2)N(c2cccc4c2sc2ccccc24)c2cccc4c2B3c2c(cc(-n3c5ccccc5c5ccccc53)c3c2-c2ccccc2C3(C)C)O4)cc1 ; CC(C)(C)c1ccc(N2c3cc(C(C)(C)C)cc4c3B(c3sc5ccc(C(C)(C)C)cc5c3O4)c3c2cc(-n2c4ccccc4c4cc5c(cc42)c2ccccc2n5-c2ccccc2)c2c3-c3ccccc3C2(C)C)cc1 ; CC(C)(C)c1ccc(N2c3cccc4c3B(c3cc(C(C)(C)C)ccc3O4)c3cc(-n4c5ccc(C(C)(C)C)cc5c5cc(C(C)(C)C)ccc54)c4c(c32)C(C)(C)c2ccccc2-4)cc1]

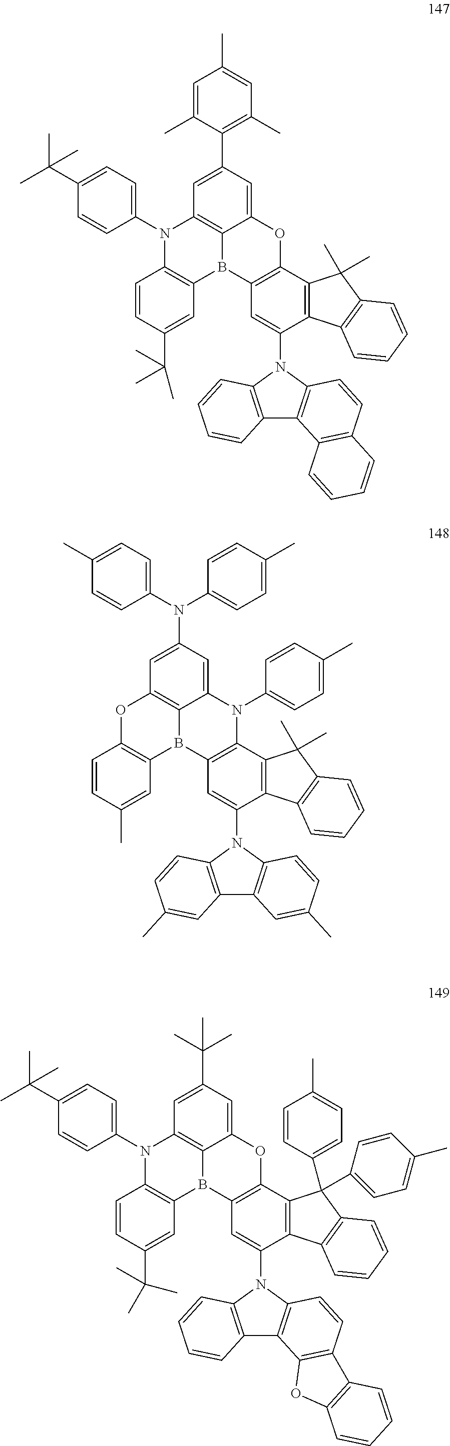 [SMILES: Cc1cc(C)c(-c2cc3c4c(c2)N(c2ccc(C(C)(C)C)cc2)c2ccc(C(C)(C)C)cc2B4c2cc(-n4c5ccccc5c5c6ccccc6ccc54)c4c(c2O3)C(C)(C)c2ccccc2-4)c(C)c1 ; Cc1ccc(N(c2ccc(C)cc2)c2cc3c4c(c2)N(c2ccc(C)cc2)c2c(cc(-n5c6ccc(C)cc6c6cc(C)ccc65)c5c2C(C)(C)c2ccccc2-5)B4c2cc(C)ccc2O3)cc1 ; Cc1ccc(C2(c3ccc(C)cc3)c3ccccc3-c3c(-n4c5ccccc5c5c6oc7ccccc7c6ccc54)cc4c(c32)Oc2cc(C(C)(C)C)cc3c2B4c2cc(C(C)(C)C)ccc2N3c2ccc(C(C)(C)C)cc2)cc1]

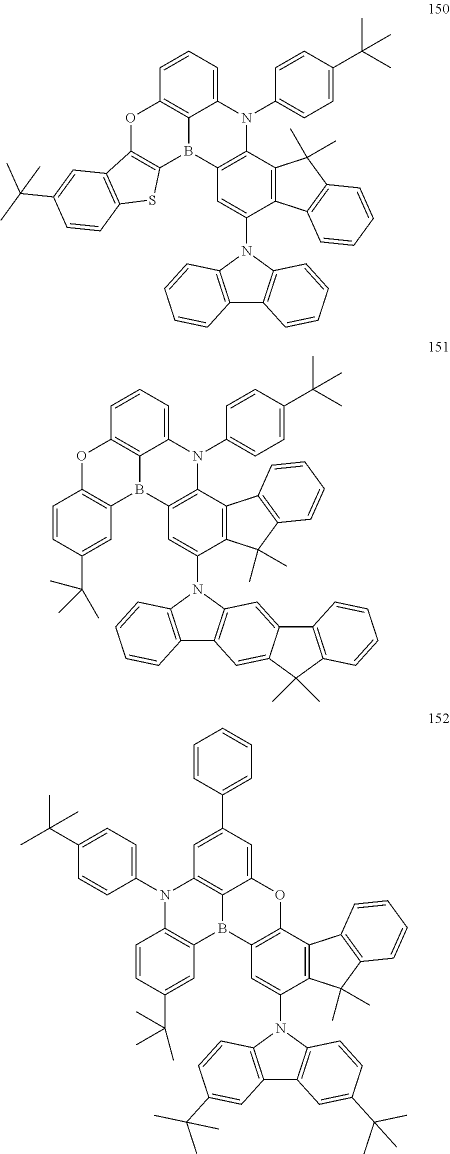

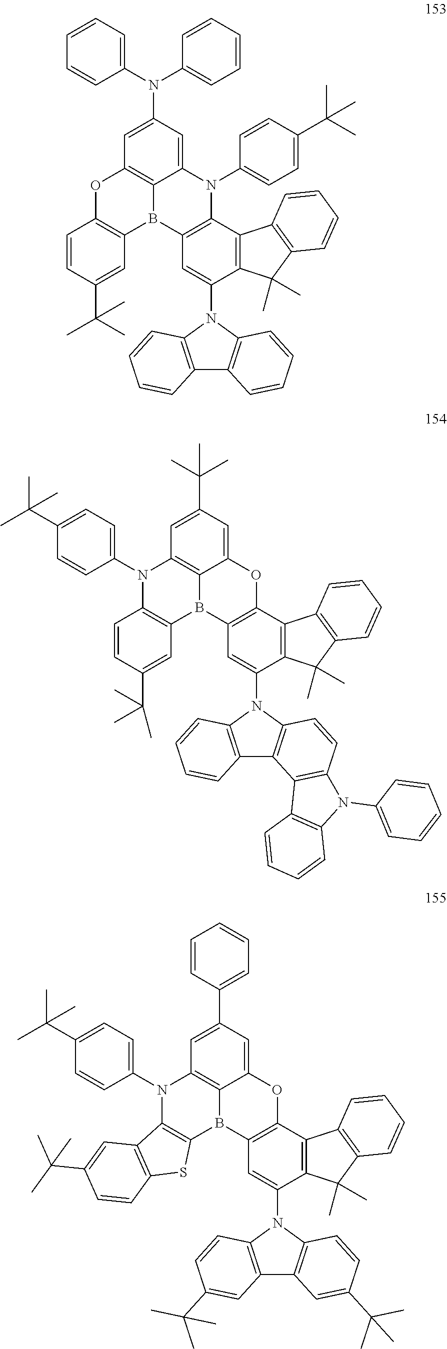

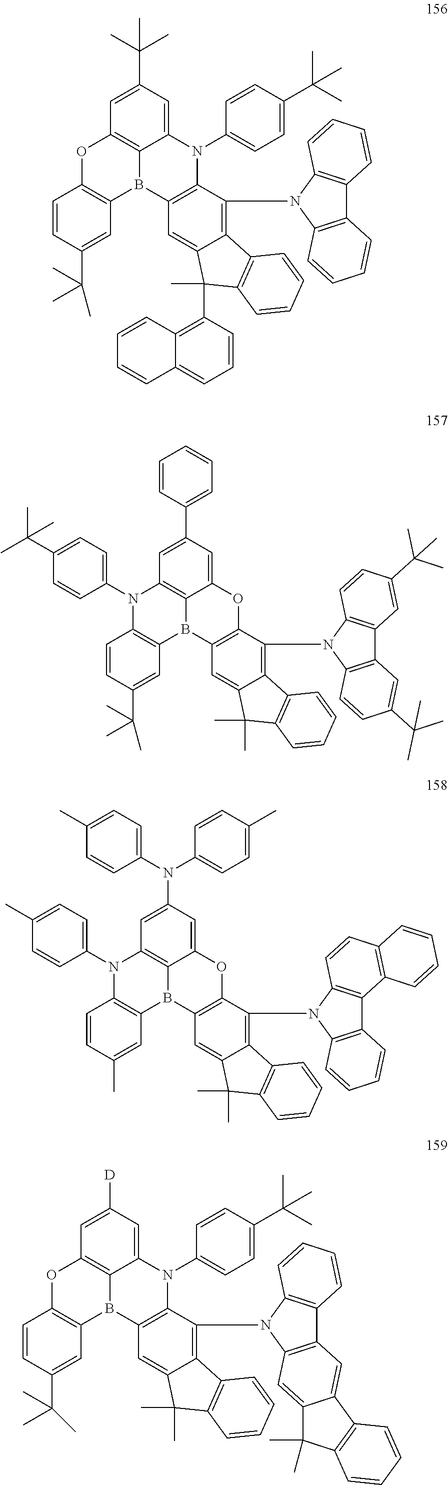

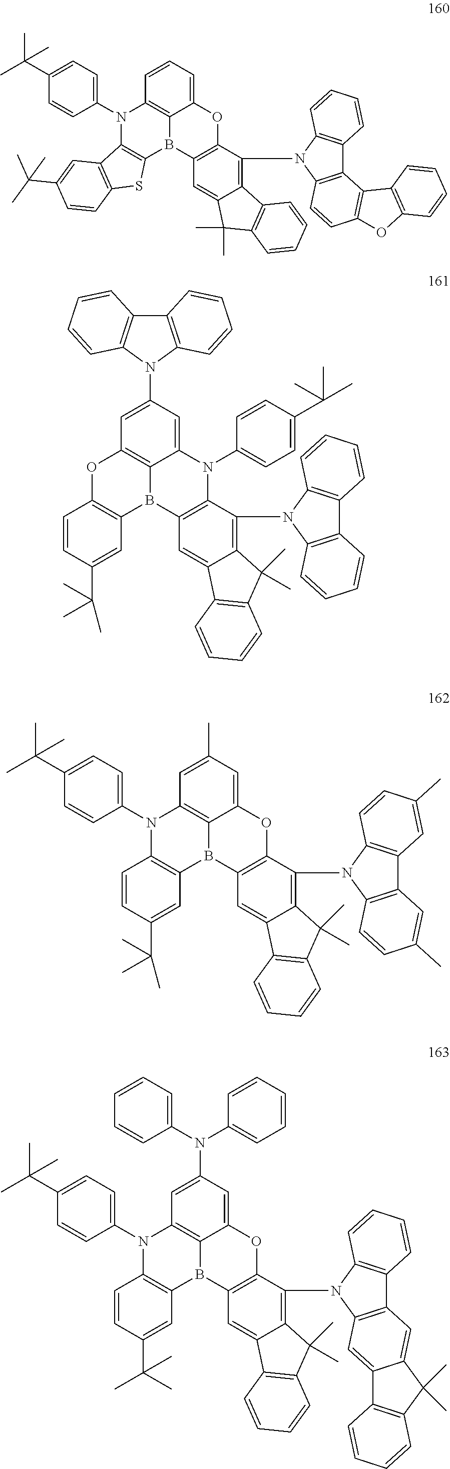

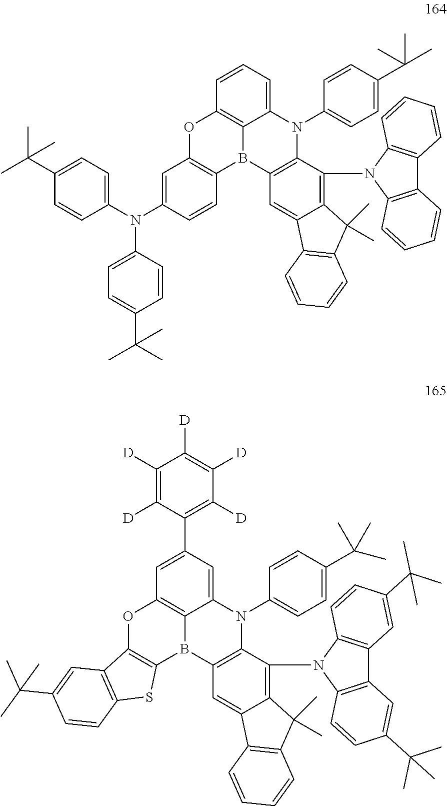 [SMILES: CC(C)(C)c1ccc(N(c2ccc(C(C)(C)C)cc2)c2ccc3c(c2)Oc2cccc4c2B3c2cc3c(c(-n5c6ccccc6c6ccccc65)c2N4c2ccc(C(C)(C)C)cc2)C(C)(C)c2ccccc2-3)cc1 ; [2H]c1c([2H])c([2H])c(-c2cc3c4c(c2)N(c2ccc(C(C)(C)C)cc2)c2c(cc5c(c2-n2c6ccc(C(C)(C)C)cc6c6cc(C(C)(C)C)ccc62)C(C)(C)c2ccccc2-5)B4c2sc4ccc(C(C)(C)C)cc4c2O3)c([2H])c1[2H]]

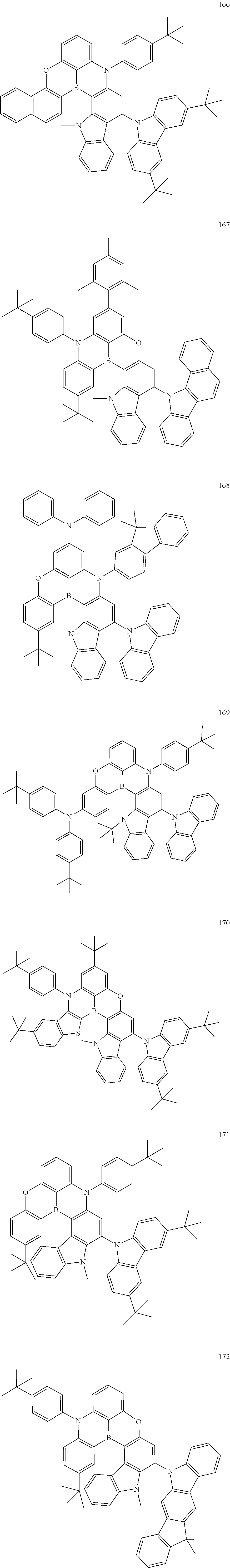

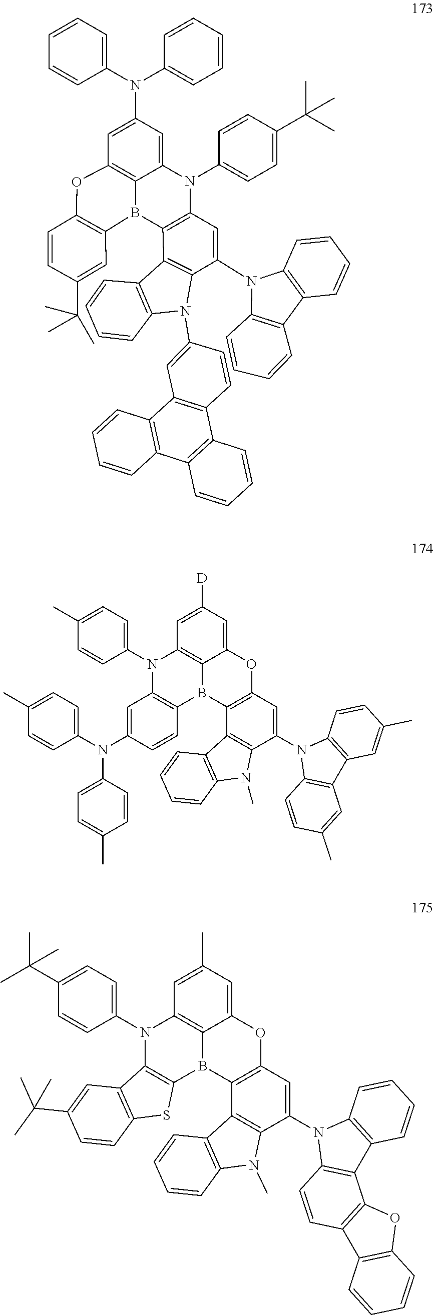

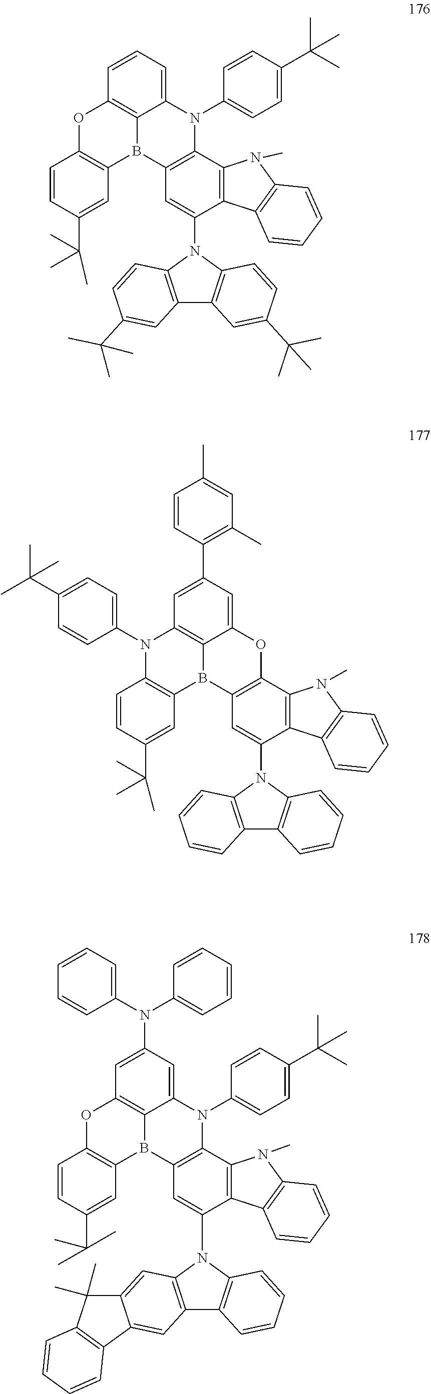

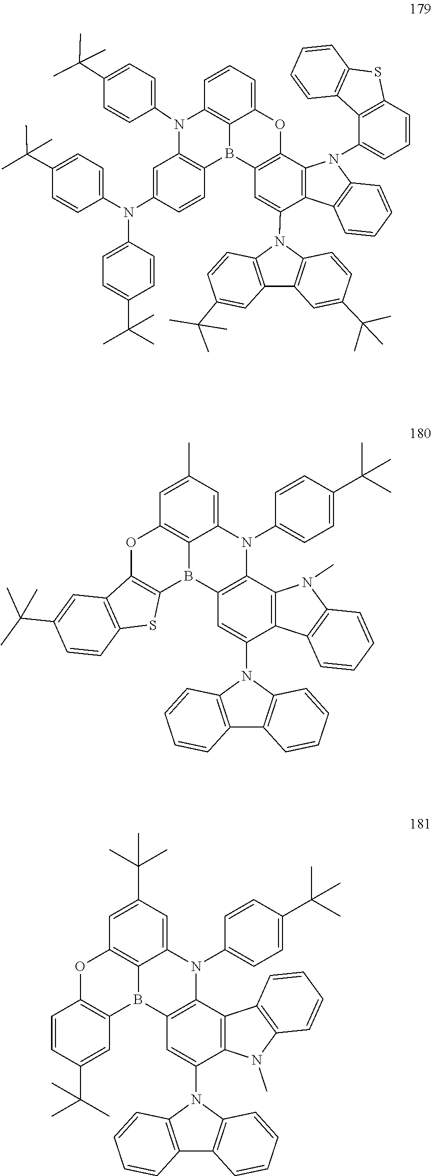 [SMILES: CC(C)(C)c1ccc(N(c2ccc(C(C)(C)C)cc2)c2ccc3c(c2)N(c2ccc(C(C)(C)C)cc2)c2cccc4c2B3c2cc(-n3c5ccc(C(C)(C)C)cc5c5cc(C(C)(C)C)ccc53)c3c5ccccc5n(-c5cccc6sc7ccccc7c56)c3c2O4)cc1 ; Cc1cc2c3c(c1)N(c1ccc(C(C)(C)C)cc1)c1c(cc(-n4c5ccccc5c5ccccc54)c4c5ccccc5n(C)c14)B3c1sc3ccc(C(C)(C)C)cc3c1O2 ; Cn1c2ccccc2c2c3c(cc(-n4c5ccccc5c5ccccc54)c21)B1c2cc(C(C)(C)C)ccc2Oc2cc(C(C)(C)C)cc(c21)N3c1ccc(C(C)(C)C)cc1]

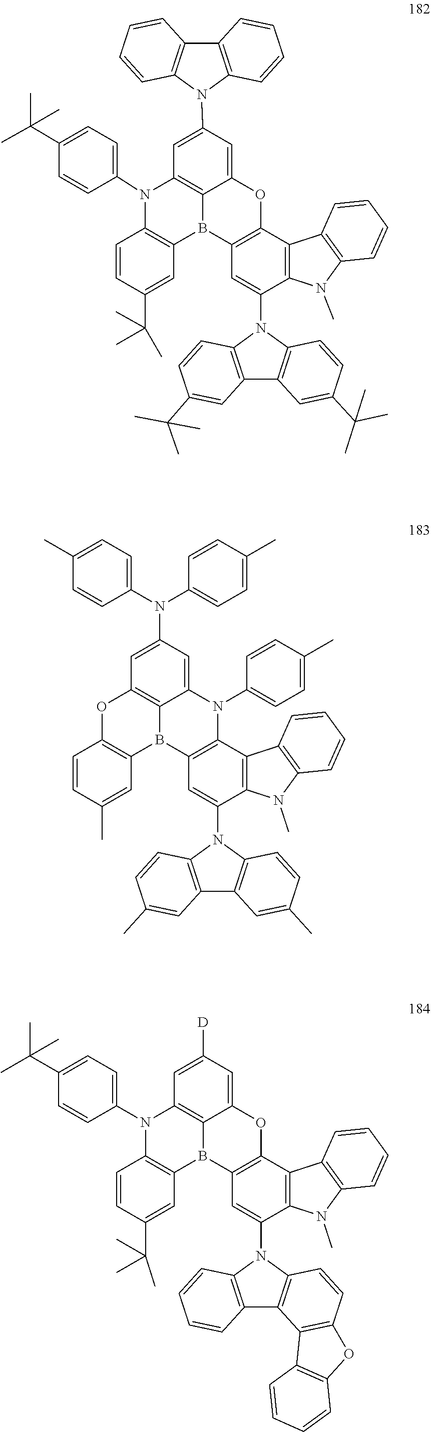

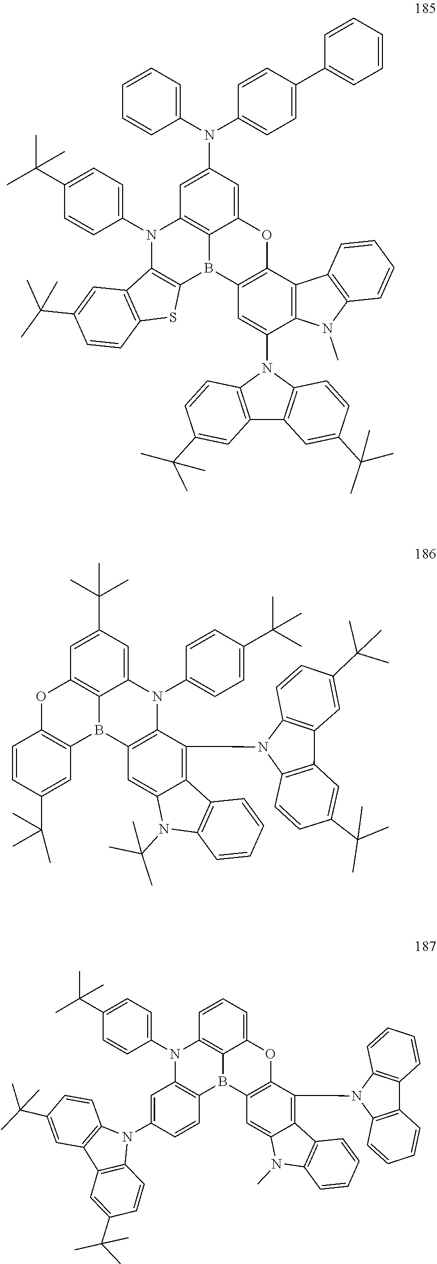

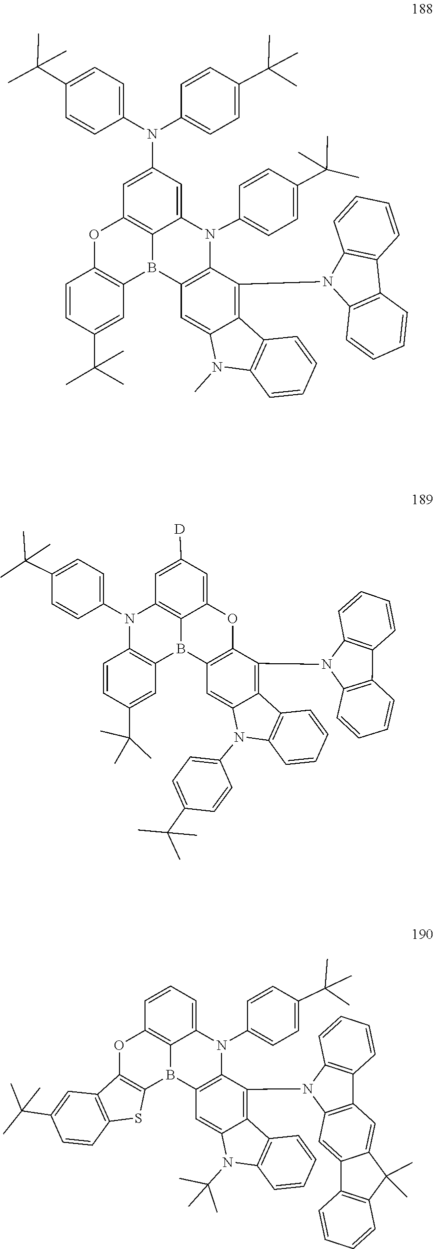 [SMILES: Cn1c2ccccc2c2c(-n3c4ccccc4c4ccccc43)c3c(cc21)B1c2cc(C(C)(C)C)ccc2Oc2cc(N(c4ccc(C(C)(C)C)cc4)c4ccc(C(C)(C)C)cc4)cc(c21)N3c1ccc(C(C)(C)C)cc1 ; [2H]c1cc2c3c(c1)N(c1ccc(C(C)(C)C)cc1)c1ccc(C(C)(C)C)cc1B3c1cc3c(c(-n4c5ccccc5c5ccccc54)c1O2)c1ccccc1n3-c1ccc(C(C)(C)C)cc1 ; CC(C)(C)c1ccc(N2c3cccc4c3B(c3cc5c(c(-n6c7ccccc7c7cc8c(cc76)-c6ccccc6C8(C)C)c32)c2ccccc2n5C(C)(C)C)c2sc3ccc(C(C)(C)C)cc3c2O4)cc1]

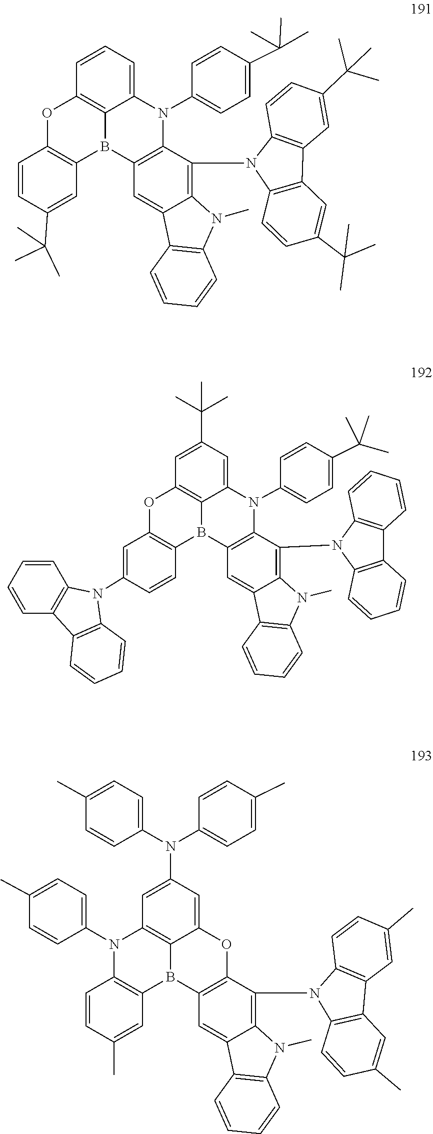

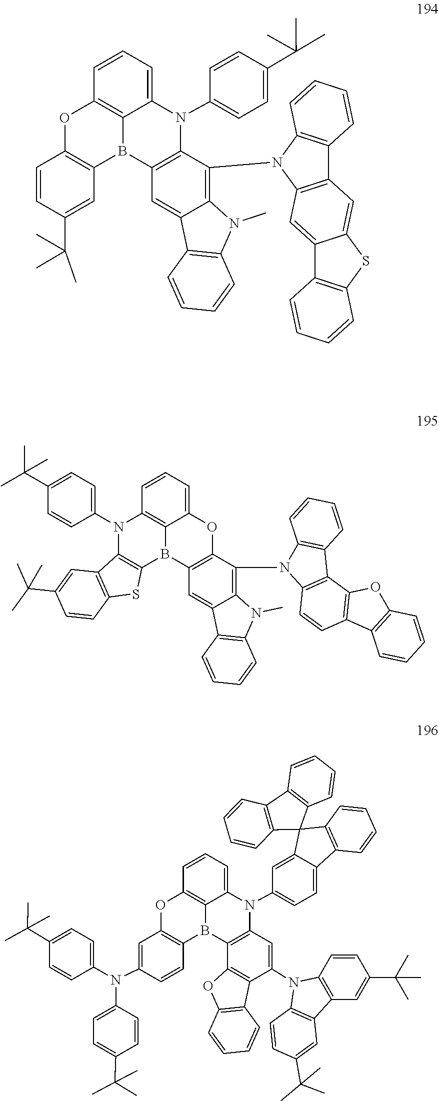 [SMILES: Cn1c2ccccc2c2cc3c(c(-n4c5ccccc5c5cc6sc7ccccc7c6cc54)c21)N(c1ccc(C(C)(C)C)cc1)c1cccc2c1B3c1cc(C(C)(C)C)ccc1O2 ; Cn1c2ccccc2c2cc3c(c(-n4c5ccccc5c5c6oc7ccccc7c6ccc54)c21)Oc1cccc2c1B3c1sc3ccc(C(C)(C)C)cc3c1N2c1ccc(C(C)(C)C)cc1 ; CC(C)(C)c1ccc(N(c2ccc(C(C)(C)C)cc2)c2ccc3c(c2)Oc2cccc4c2B3c2c(cc(-n3c5ccc(C(C)(C)C)cc5c5cc(C(C)(C)C)ccc53)c3c2oc2ccccc23)N4c2ccc3c(c2)C2(c4ccccc4-c4ccccc42)c2ccccc2-3)cc1]

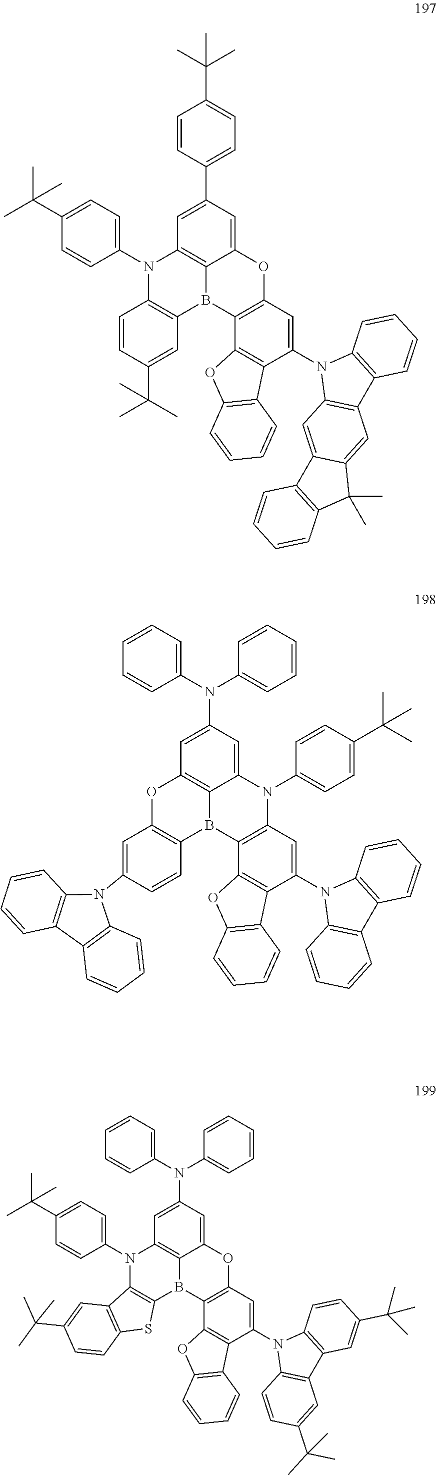 [SMILES: CC(C)(C)c1ccc(-c2cc3c4c(c2)N(c2ccc(C(C)(C)C)cc2)c2ccc(C(C)(C)C)cc2B4c2c(cc(-n4c5ccccc5c5cc6c(cc54)-c4ccccc4C6(C)C)c4c2oc2ccccc24)O3)cc1 ; CC(C)(C)c1ccc(N2c3cc(N(c4ccccc4)c4ccccc4)cc4c3B(c3ccc(-n5c6ccccc6c6ccccc65)cc3O4)c3c2cc(-n2c4ccccc4c4ccccc42)c2c3oc3ccccc32)cc1 ; CC(C)(C)c1ccc(N2c3cc(N(c4ccccc4)c4ccccc4)cc4c3B(c3sc5ccc(C(C)(C)C)cc5c32)c2c(cc(-n3c5ccc(C(C)(C)C)cc5c5cc(C(C)(C)C)ccc53)c3c2oc2ccccc23)O4)cc1]

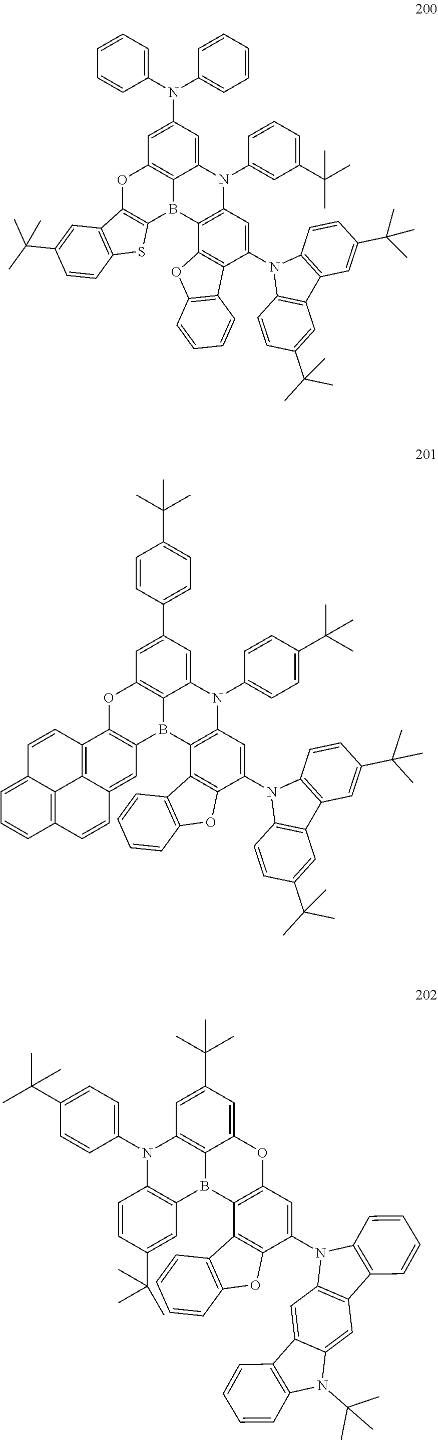

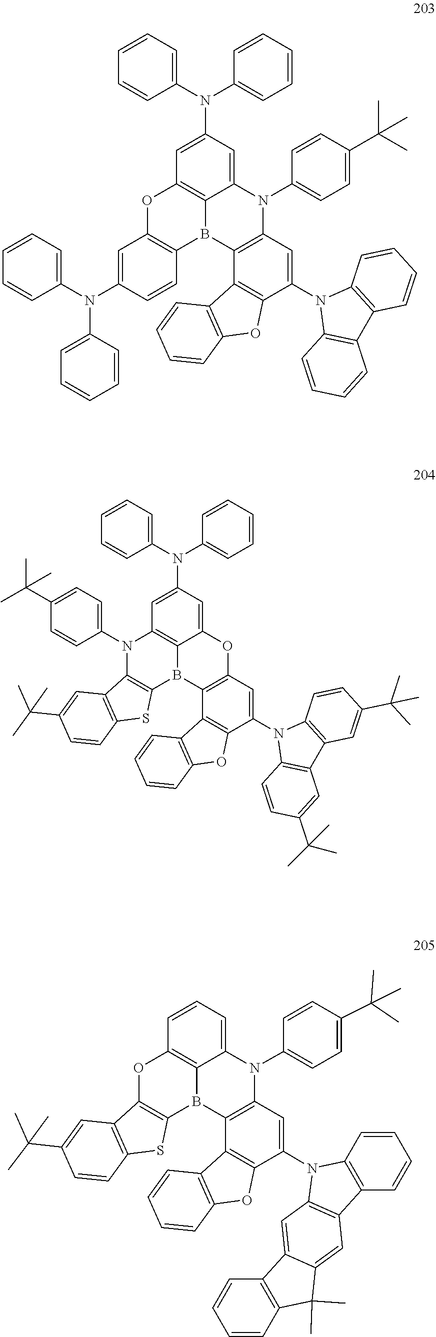

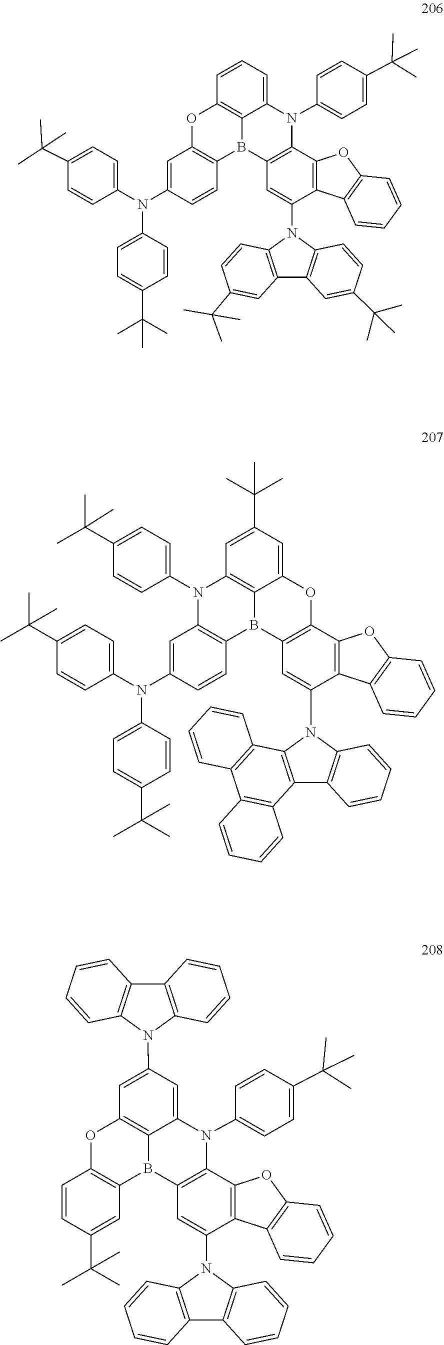

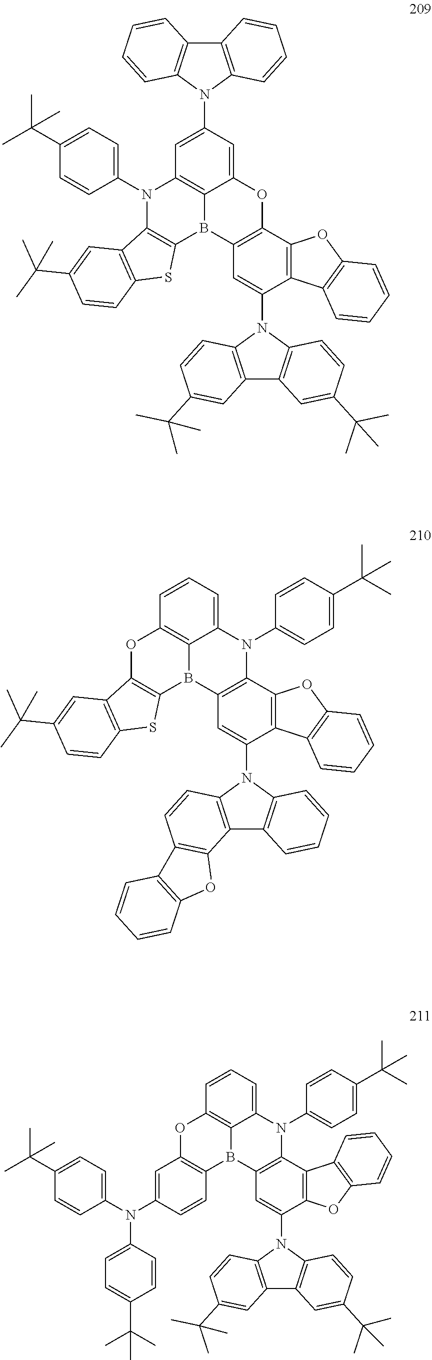

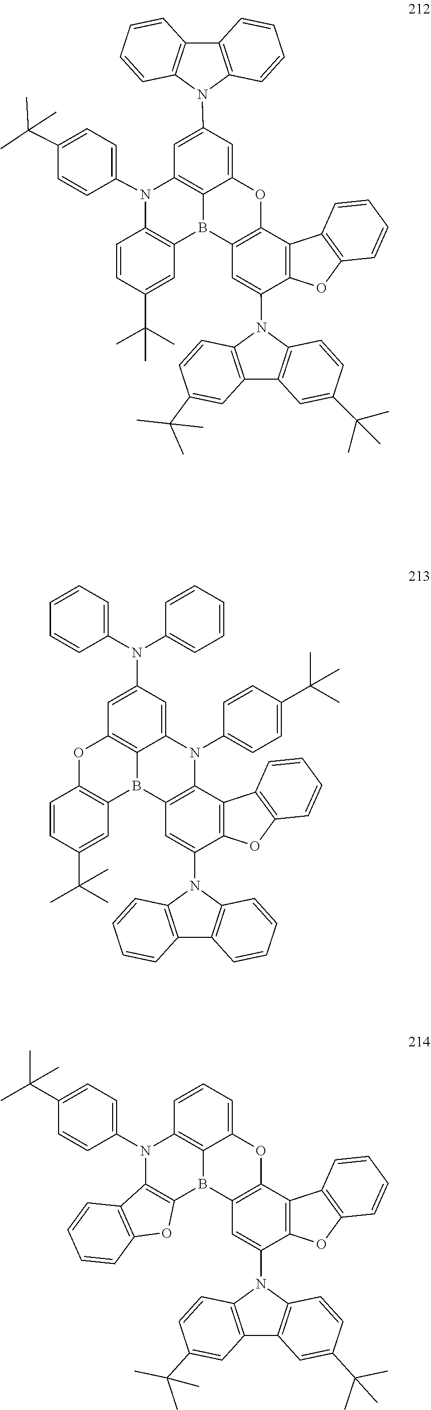

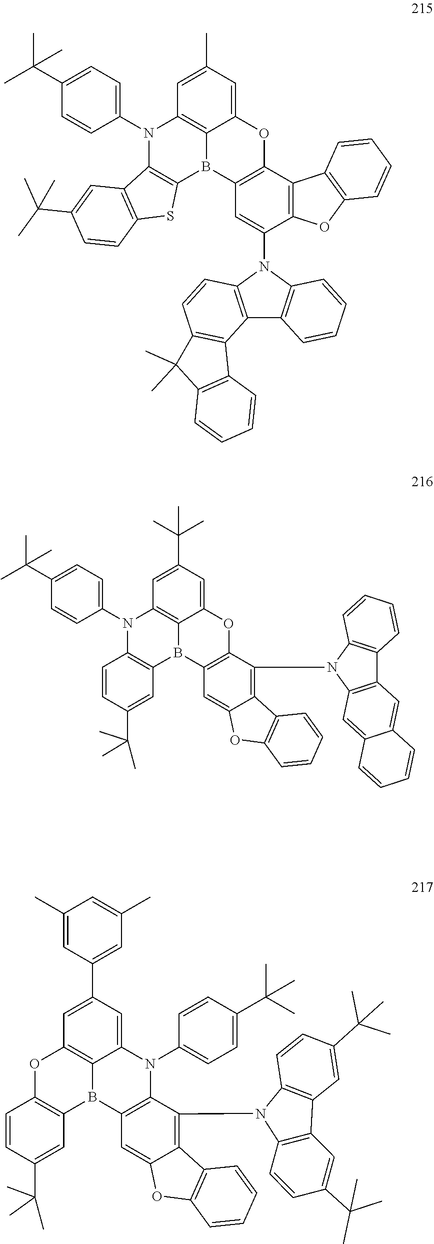 [SMILES: Cc1cc2c3c(c1)N(c1ccc(C(C)(C)C)cc1)c1c(sc4ccc(C(C)(C)C)cc14)B3c1cc(-n3c4ccccc4c4c5c(ccc43)C(C)(C)c3ccccc3-5)c3oc4ccccc4c3c1O2 ; CC(C)(C)c1ccc(N2c3ccc(C(C)(C)C)cc3B3c4cc5oc6ccccc6c5c(-n5c6ccccc6c6cc7ccccc7cc65)c4Oc4cc(C(C)(C)C)cc2c43)cc1 ; Cc1cc(C)cc(-c2cc3c4c(c2)N(c2ccc(C(C)(C)C)cc2)c2c(cc5oc6ccccc6c5c2-n2c5ccc(C(C)(C)C)cc5c5cc(C(C)(C)C)ccc52)B4c2cc(C(C)(C)C)ccc2O3)c1]

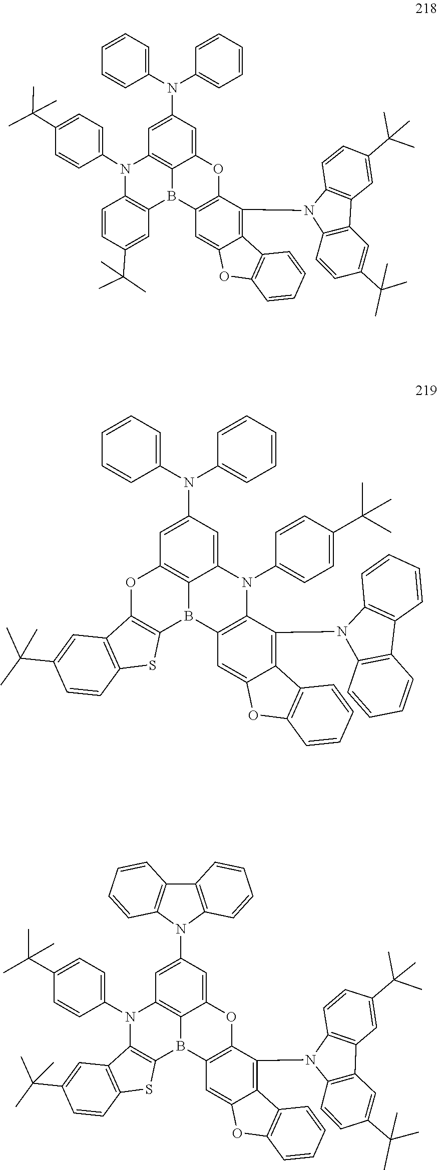

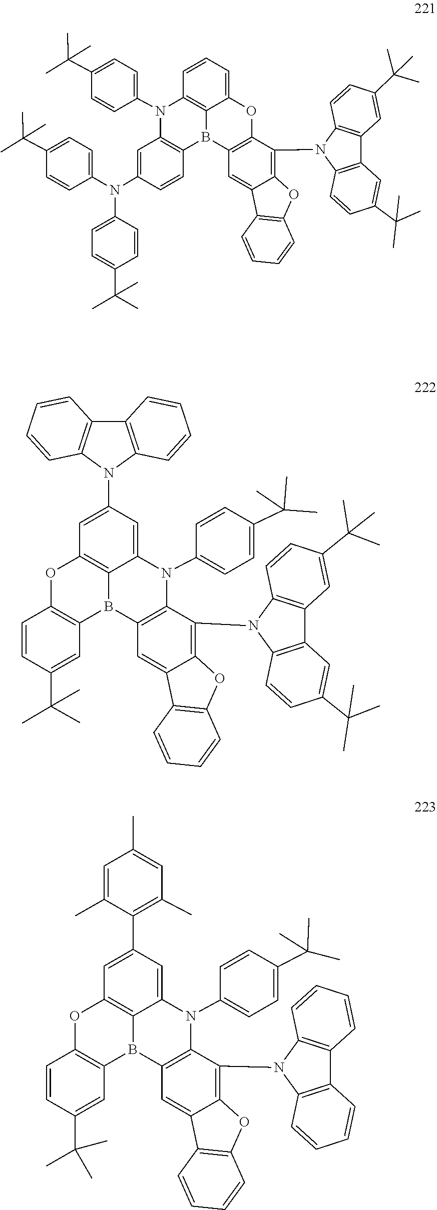 [SMILES: CC(C)(C)c1ccc(N(c2ccc(C(C)(C)C)cc2)c2ccc3c(c2)N(c2ccc(C(C)(C)C)cc2)c2cccc4c2B3c2cc3c(oc5ccccc53)c(-n3c5ccc(C(C)(C)C)cc5c5cc(C(C)(C)C)ccc53)c2O4)cc1 ; CC(C)(C)c1ccc(N2c3cc(-n4c5ccccc5c5ccccc54)cc4c3B(c3cc(C(C)(C)C)ccc3O4)c3cc4c(oc5ccccc54)c(-n4c5ccc(C(C)(C)C)cc5c5cc(C(C)(C)C)ccc54)c32)cc1 ; Cc1cc(C)c(-c2cc3c4c(c2)N(c2ccc(C(C)(C)C)cc2)c2c(cc5c(oc6ccccc65)c2-n2c5ccccc5c5ccccc52)B4c2cc(C(C)(C)C)ccc2O3)c(C)c1]

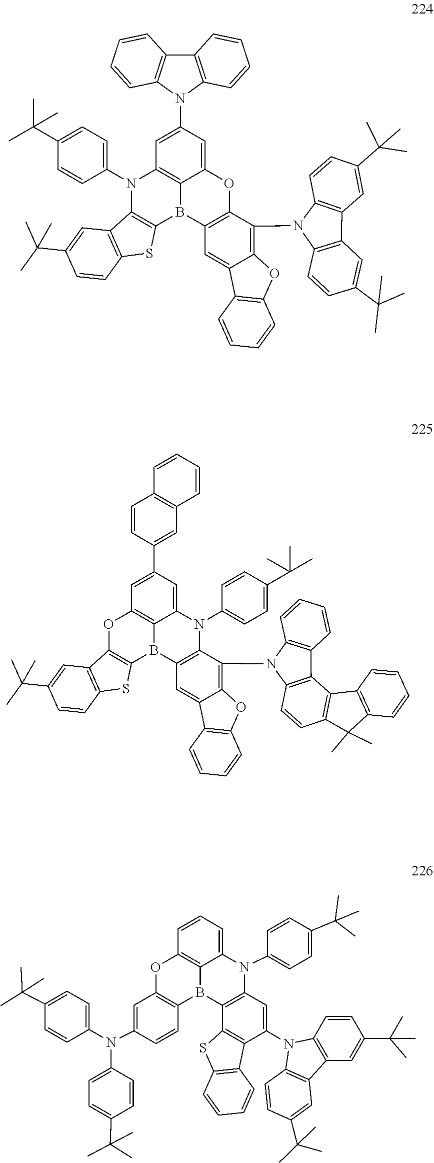

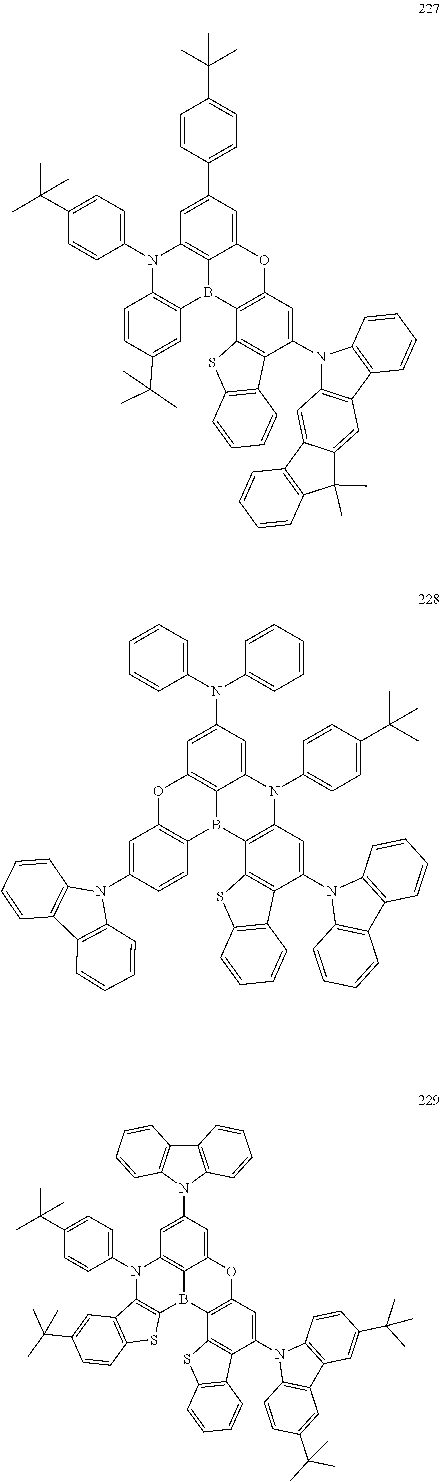 [SMILES: CC(C)(C)c1ccc(-c2cc3c4c(c2)N(c2ccc(C(C)(C)C)cc2)c2ccc(C(C)(C)C)cc2B4c2c(cc(-n4c5ccccc5c5cc6c(cc54)-c4ccccc4C6(C)C)c4c2sc2ccccc24)O3)cc1 ; CC(C)(C)c1ccc(N2c3cc(N(c4ccccc4)c4ccccc4)cc4c3B(c3ccc(-n5c6ccccc6c6ccccc65)cc3O4)c3c2cc(-n2c4ccccc4c4ccccc42)c2c3sc3ccccc32)cc1 ; CC(C)(C)c1ccc(N2c3cc(-n4c5ccccc5c5ccccc54)cc4c3B(c3sc5ccc(C(C)(C)C)cc5c32)c2c(cc(-n3c5ccc(C(C)(C)C)cc5c5cc(C(C)(C)C)ccc53)c3c2sc2ccccc23)O4)cc1]

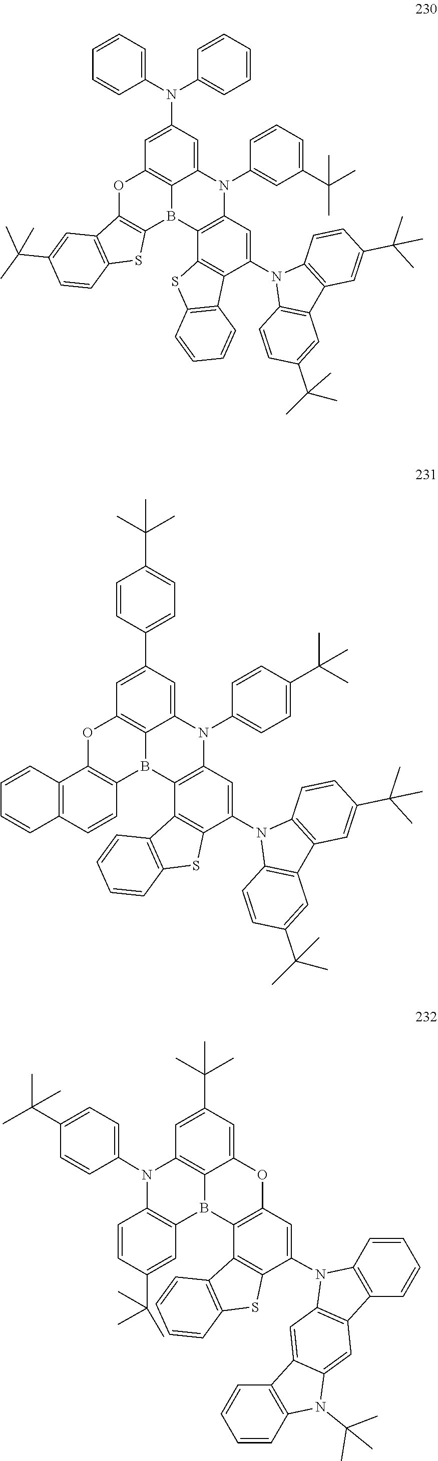

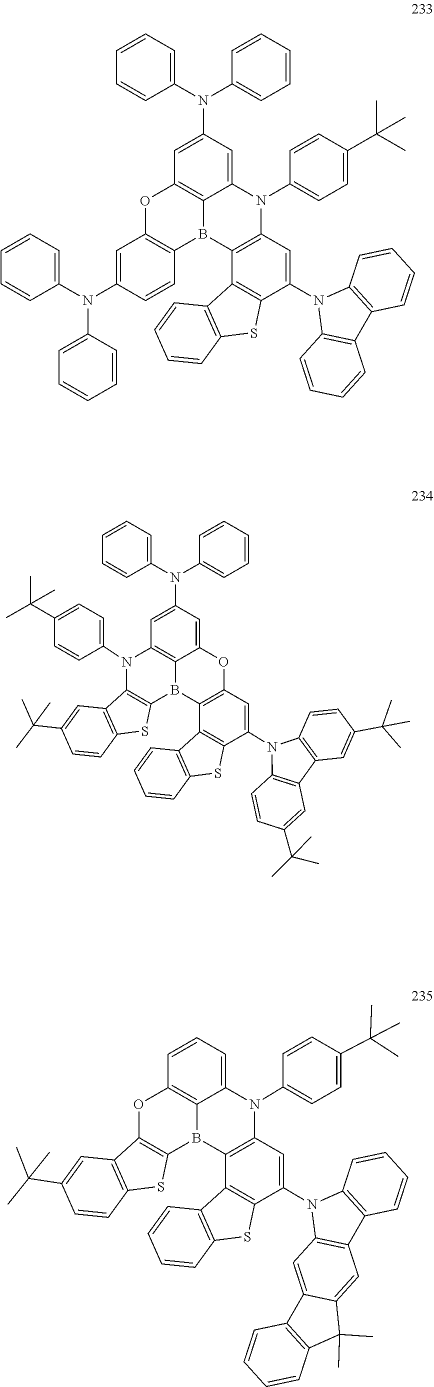

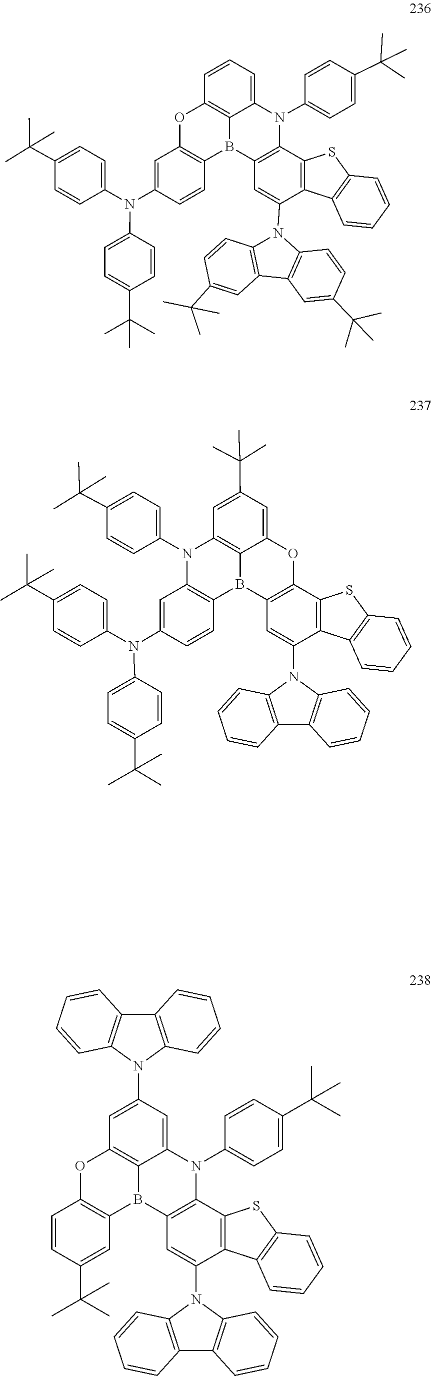

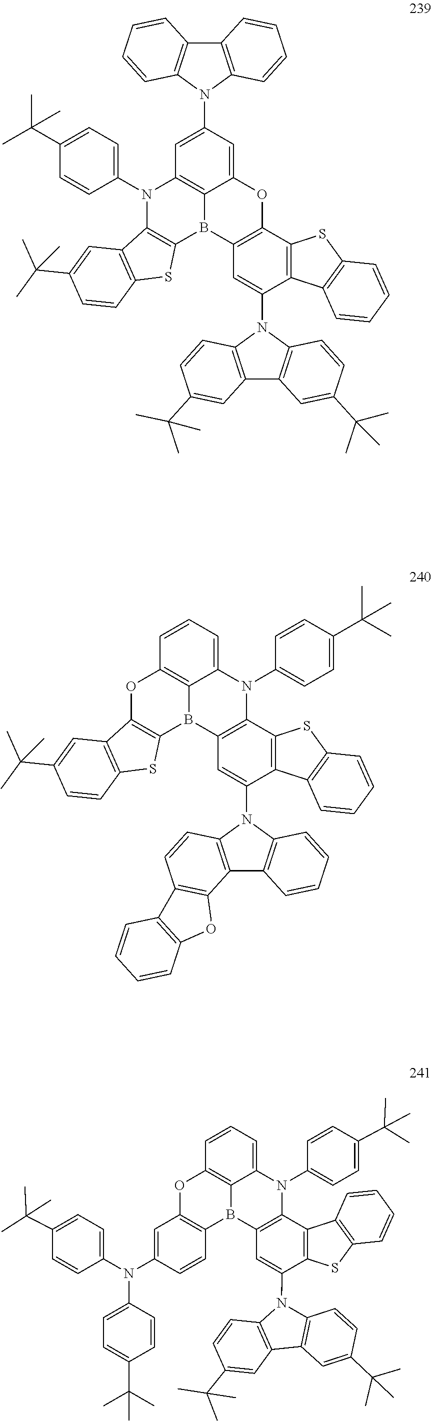

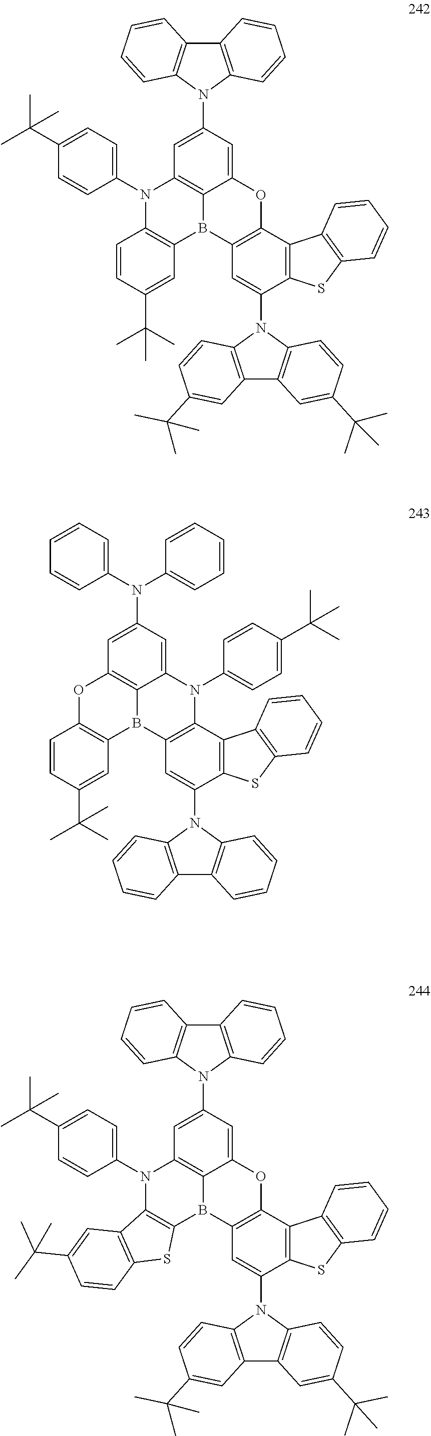

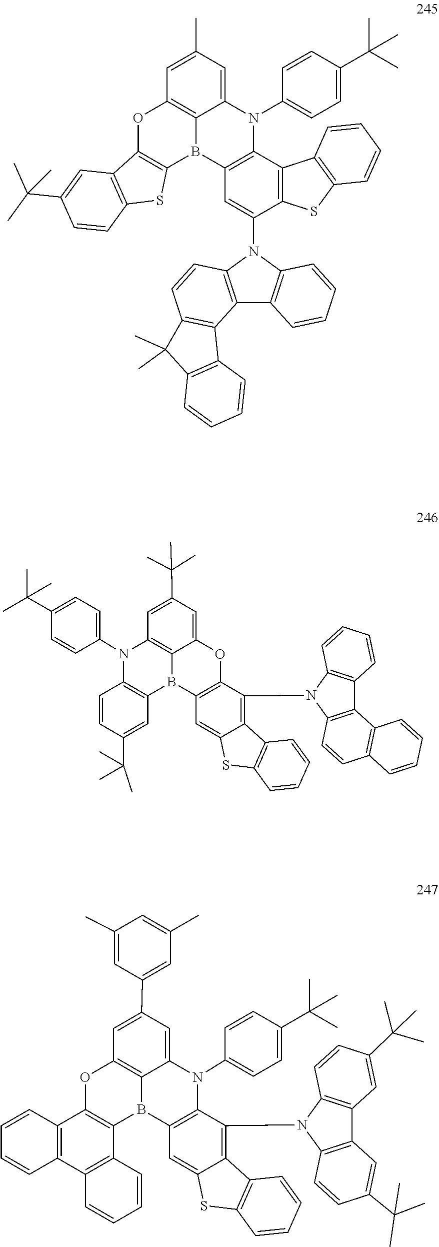

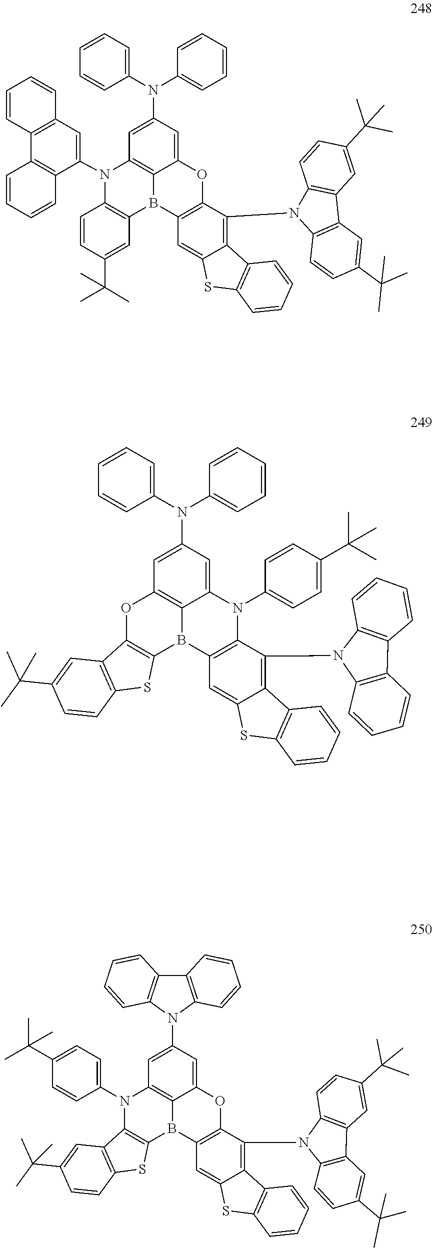

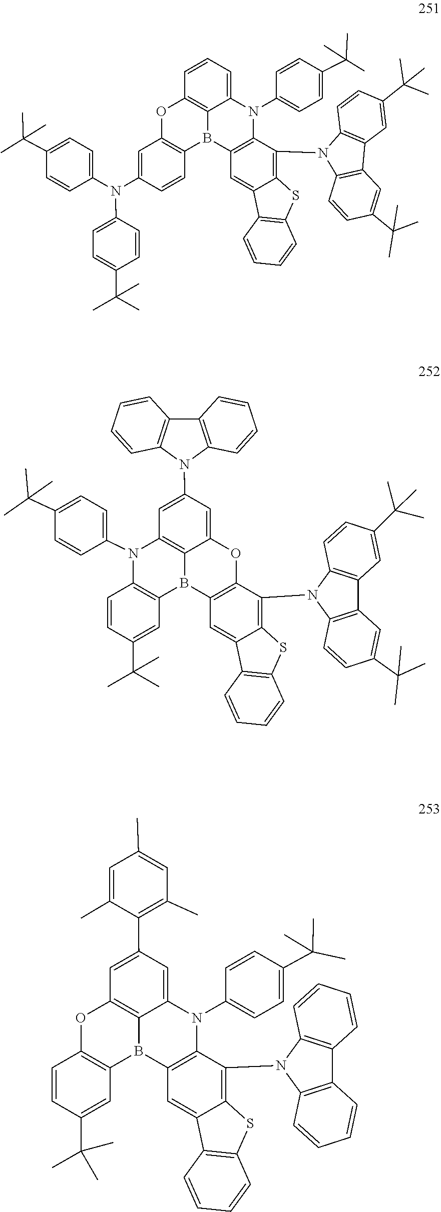

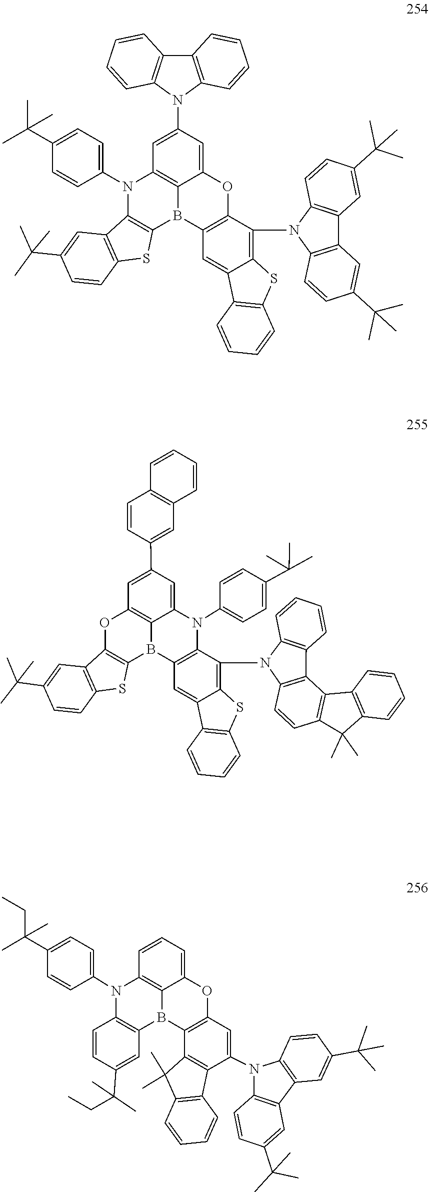

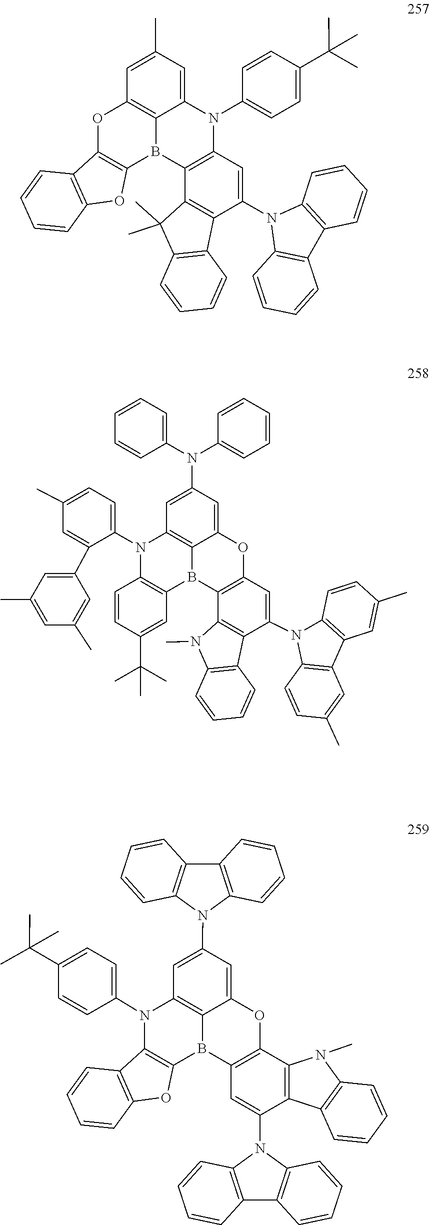

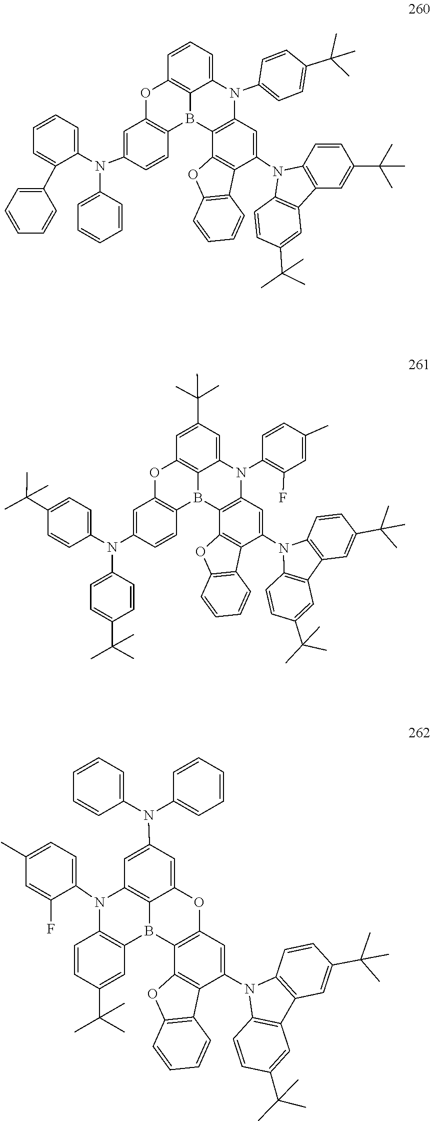

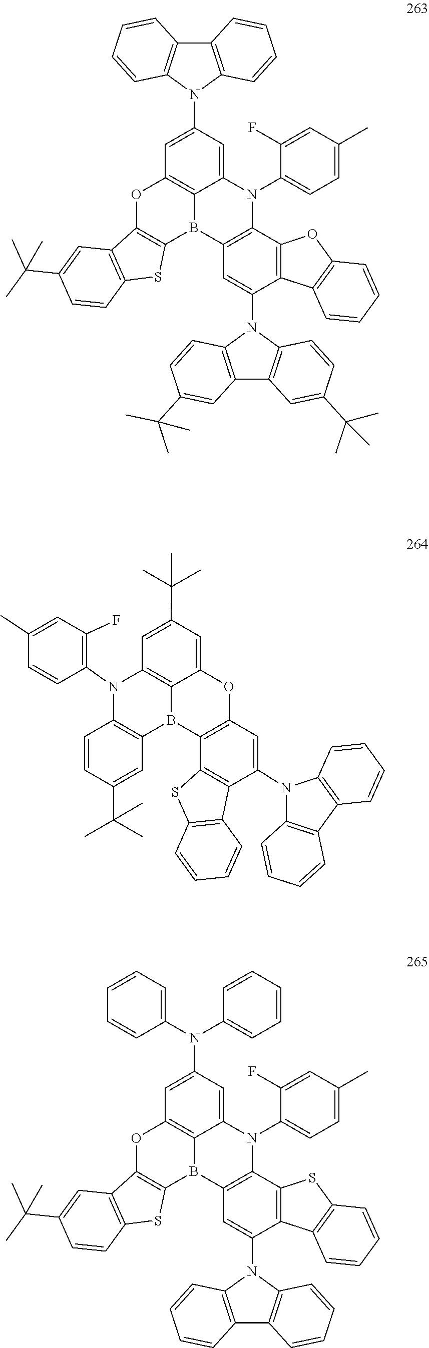 [SMILES: Cc1ccc(N2c3cc(-n4c5ccccc5c5ccccc54)cc4c3B(c3cc(-n5c6ccc(C(C)(C)C)cc6c6cc(C(C)(C)C)ccc65)c5c(oc6ccccc65)c32)c2sc3ccc(C(C)(C)C)cc3c2O4)c(F)c1 ; Cc1ccc(N2c3ccc(C(C)(C)C)cc3B3c4c(cc(C(C)(C)C)cc42)Oc2cc(-n4c5ccccc5c5ccccc54)c4c(sc5ccccc54)c23)c(F)c1 ; Cc1ccc(N2c3cc(N(c4ccccc4)c4ccccc4)cc4c3B(c3cc(-n5c6ccccc6c6ccccc65)c5c(sc6ccccc65)c32)c2sc3ccc(C(C)(C)C)cc3c2O4)c(F)c1]

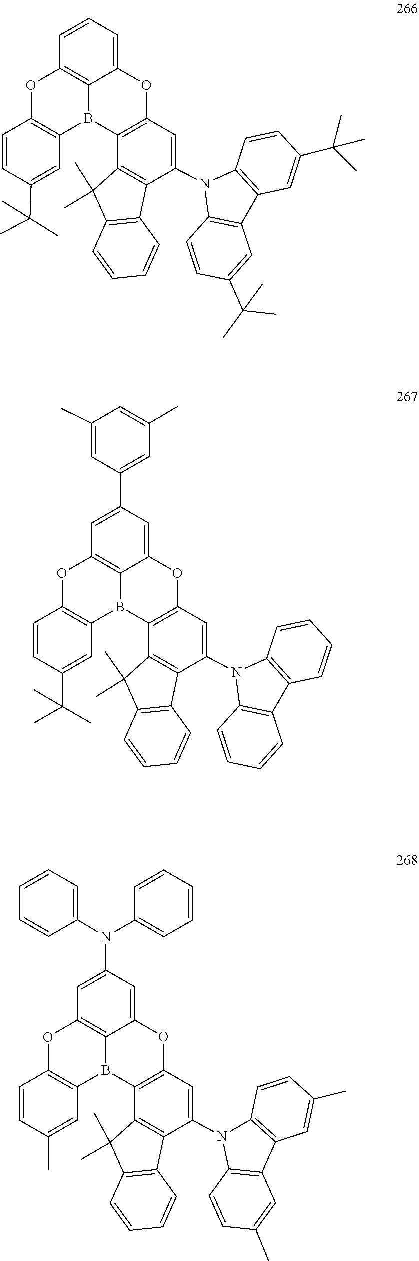 [SMILES: CC(C)(C)c1ccc2c(c1)B1c3c(cccc3Oc3cc(-n4c5ccc(C(C)(C)C)cc5c5cc(C(C)(C)C)ccc54)c4c(c31)C(C)(C)c1ccccc1-4)O2 ; Cc1cc(C)cc(-c2cc3c4c(c2)Oc2cc(-n5c6ccccc6c6ccccc65)c5c(c2B4c2cc(C(C)(C)C)ccc2O3)C(C)(C)c2ccccc2-5)c1 ; Cc1ccc2c(c1)B1c3c(cc(N(c4ccccc4)c4ccccc4)cc3Oc3cc(-n4c5ccc(C)cc5c5cc(C)ccc54)c4c(c31)C(C)(C)c1ccccc1-4)O2]

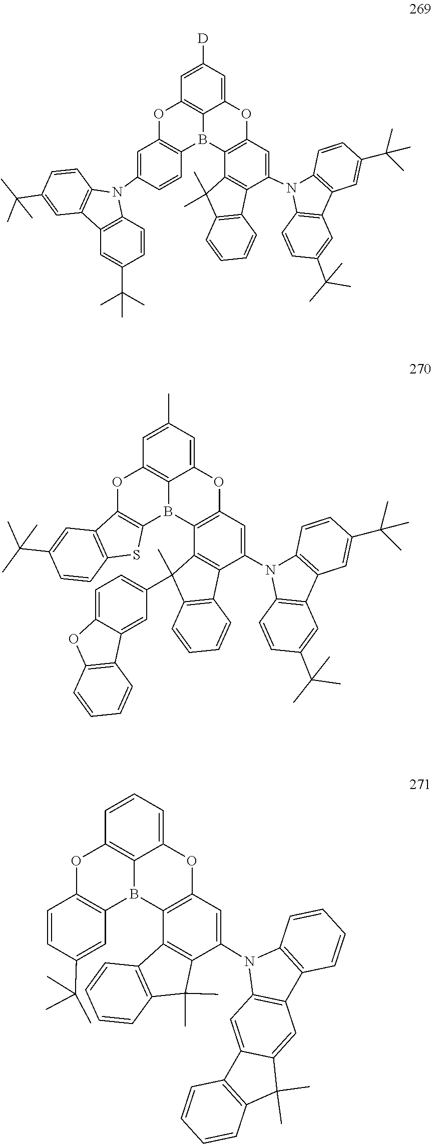

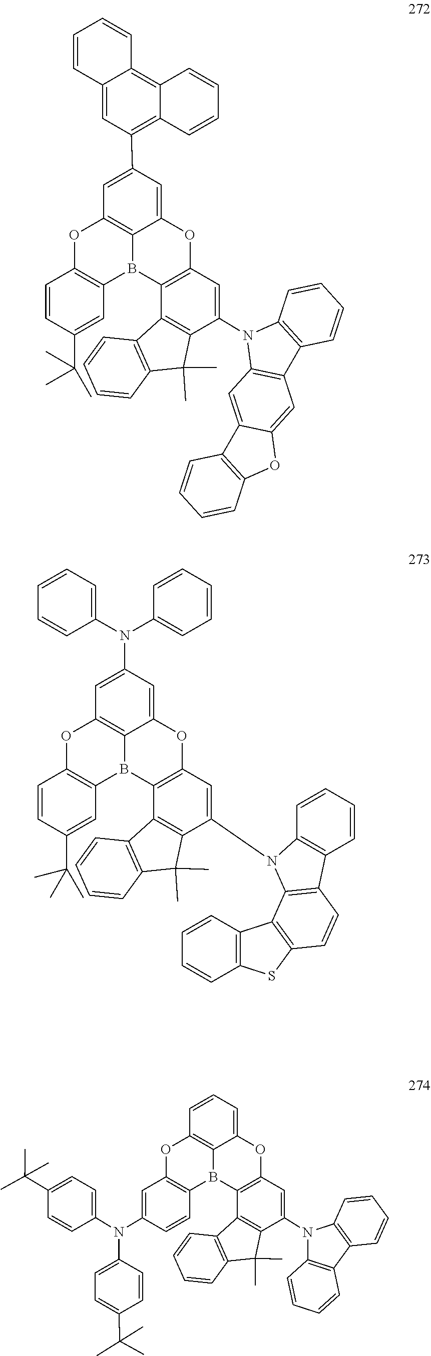 [SMILES: CC(C)(C)c1ccc2c(c1)B1c3c(cc(-c4cc5ccccc5c5ccccc45)cc3Oc3cc(-n4c5ccccc5c5cc6oc7ccccc7c6cc54)c4c(c31)-c1ccccc1C4(C)C)O2 ; CC(C)(C)c1ccc2c(c1)B1c3c(cc(N(c4ccccc4)c4ccccc4)cc3Oc3cc(-n4c5ccccc5c5ccc6sc7ccccc7c6c54)c4c(c31)-c1ccccc1C4(C)C)O2 ; CC(C)(C)c1ccc(N(c2ccc(C(C)(C)C)cc2)c2ccc3c(c2)Oc2cccc4c2B3c2c(cc(-n3c5ccccc5c5ccccc53)c3c2-c2ccccc2C3(C)C)O4)cc1]

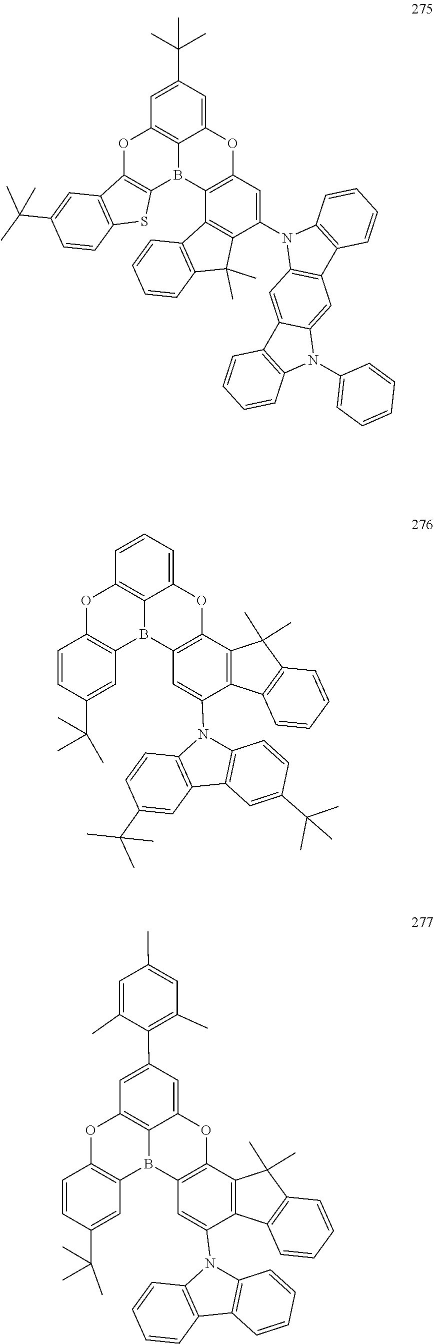 [SMILES: CC(C)(C)c1cc2c3c(c1)Oc1c(sc4ccc(C(C)(C)C)cc14)B3c1c(cc(-n3c4ccccc4c4cc5c(cc43)c3ccccc3n5-c3ccccc3)c3c1-c1ccccc1C3(C)C)O2 ; CC(C)(C)c1ccc2c(c1)B1c3cc(-n4c5ccc(C(C)(C)C)cc5c5cc(C(C)(C)C)ccc54)c4c(c3Oc3cccc(c31)O2)C(C)(C)c1ccccc1-4 ; Cc1cc(C)c(-c2cc3c4c(c2)Oc2c(cc(-n5c6ccccc6c6ccccc65)c5c2C(C)(C)c2ccccc2-5)B4c2cc(C(C)(C)C)ccc2O3)c(C)c1]

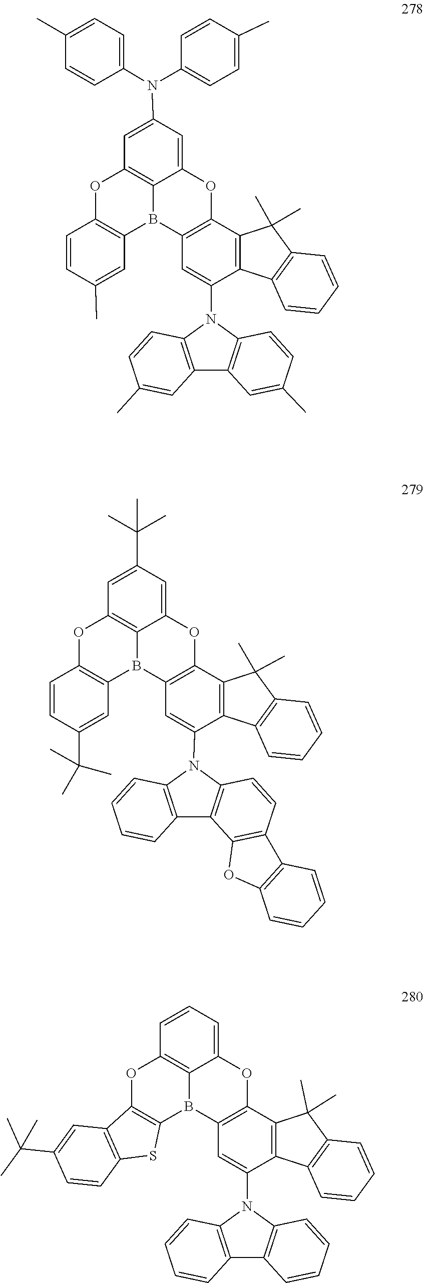 [SMILES: Cc1ccc(N(c2ccc(C)cc2)c2cc3c4c(c2)Oc2c(cc(-n5c6ccc(C)cc6c6cc(C)ccc65)c5c2C(C)(C)c2ccccc2-5)B4c2cc(C)ccc2O3)cc1 ; CC(C)(C)c1cc2c3c(c1)Oc1c(cc(-n4c5ccccc5c5c6oc7ccccc7c6ccc54)c4c1C(C)(C)c1ccccc1-4)B3c1cc(C(C)(C)C)ccc1O2 ; CC(C)(C)c1ccc2sc3c(c2c1)Oc1cccc2c1B3c1cc(-n3c4ccccc4c4ccccc43)c3c(c1O2)C(C)(C)c1ccccc1-3]

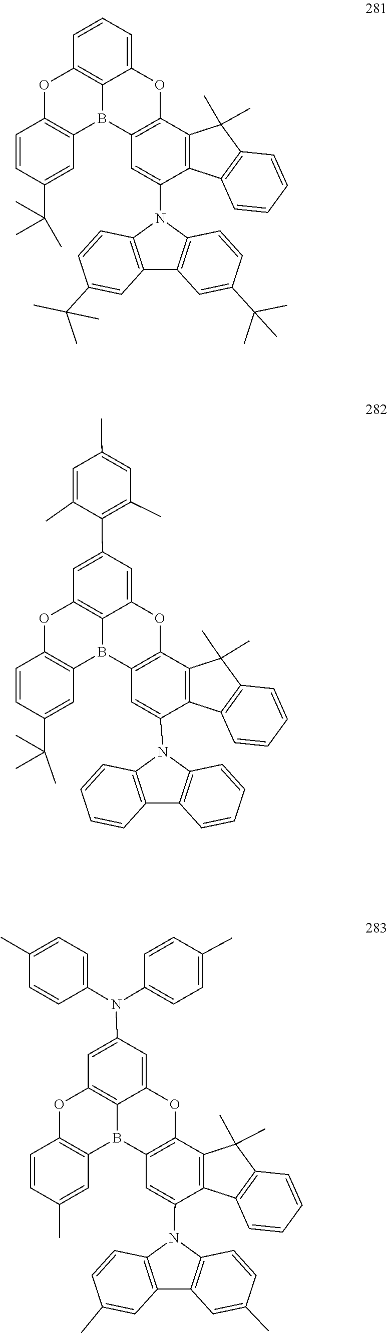 [SMILES: CC(C)(C)c1ccc2c(c1)B1c3cc(-n4c5ccc(C(C)(C)C)cc5c5cc(C(C)(C)C)ccc54)c4c(c3Oc3cccc(c31)O2)C(C)(C)c1ccccc1-4 ; Cc1cc(C)c(-c2cc3c4c(c2)Oc2c(cc(-n5c6ccccc6c6ccccc65)c5c2C(C)(C)c2ccccc2-5)B4c2cc(C(C)(C)C)ccc2O3)c(C)c1 ; Cc1ccc(N(c2ccc(C)cc2)c2cc3c4c(c2)Oc2c(cc(-n5c6ccc(C)cc6c6cc(C)ccc65)c5c2C(C)(C)c2ccccc2-5)B4c2cc(C)ccc2O3)cc1]

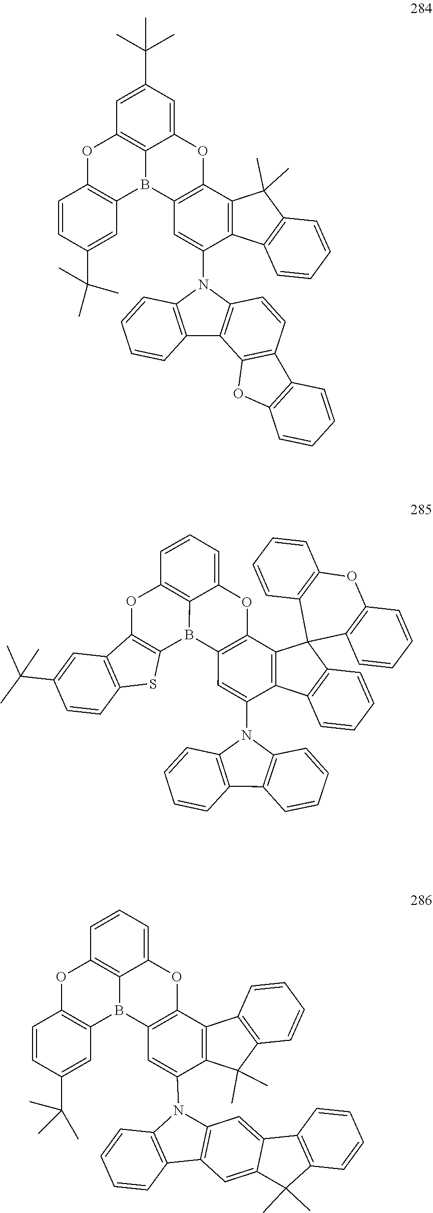 [SMILES: CC(C)(C)c1cc2c3c(c1)Oc1c(cc(-n4c5ccccc5c5c6oc7ccccc7c6ccc54)c4c1C(C)(C)c1ccccc1-4)B3c1cc(C(C)(C)C)ccc1O2 ; CC(C)(C)c1ccc2sc3c(c2c1)Oc1cccc2c1B3c1cc(-n3c4ccccc4c4ccccc43)c3c(c1O2)C1(c2ccccc2Oc2ccccc21)c1ccccc1-3 ; CC(C)(C)c1ccc2c(c1)B1c3cc(-n4c5ccccc5c5cc6c(cc54)-c4ccccc4C6(C)C)c4c(c3Oc3cccc(c31)O2)-c1ccccc1C4(C)C]

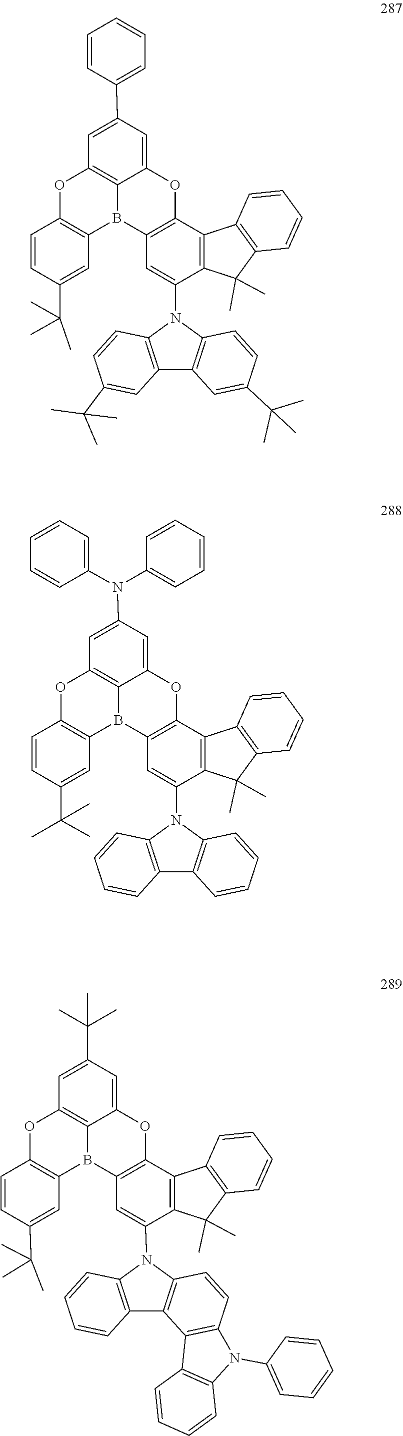 [SMILES: CC(C)(C)c1ccc2c(c1)B1c3cc(-n4c5ccc(C(C)(C)C)cc5c5cc(C(C)(C)C)ccc54)c4c(c3Oc3cc(-c5ccccc5)cc(c31)O2)-c1ccccc1C4(C)C ; CC(C)(C)c1ccc2c(c1)B1c3cc(-n4c5ccccc5c5ccccc54)c4c(c3Oc3cc(N(c5ccccc5)c5ccccc5)cc(c31)O2)-c1ccccc1C4(C)C ; CC(C)(C)c1cc2c3c(c1)Oc1c(cc(-n4c5ccccc5c5c6c7ccccc7n(-c7ccccc7)c6ccc54)c4c1-c1ccccc1C4(C)C)B3c1cc(C(C)(C)C)ccc1O2]

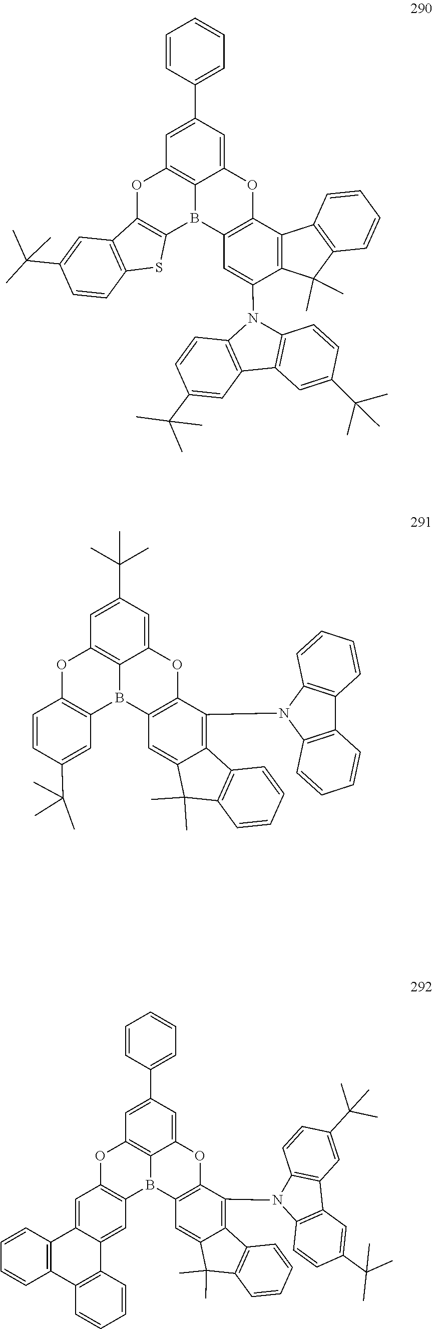 [SMILES: CC(C)(C)c1ccc2sc3c(c2c1)Oc1cc(-c2ccccc2)cc2c1B3c1cc(-n3c4ccc(C(C)(C)C)cc4c4cc(C(C)(C)C)ccc43)c3c(c1O2)-c1ccccc1C3(C)C ; CC(C)(C)c1cc2c3c(c1)Oc1c(cc4c(c1-n1c5ccccc5c5ccccc51)-c1ccccc1C4(C)C)B3c1cc(C(C)(C)C)ccc1O2 ; CC(C)(C)c1ccc2c(c1)c1cc(C(C)(C)C)ccc1n2-c1c2c(cc3c1-c1ccccc1C3(C)C)B1c3cc4c5ccccc5c5ccccc5c4cc3Oc3cc(-c4ccccc4)cc(c31)O2]

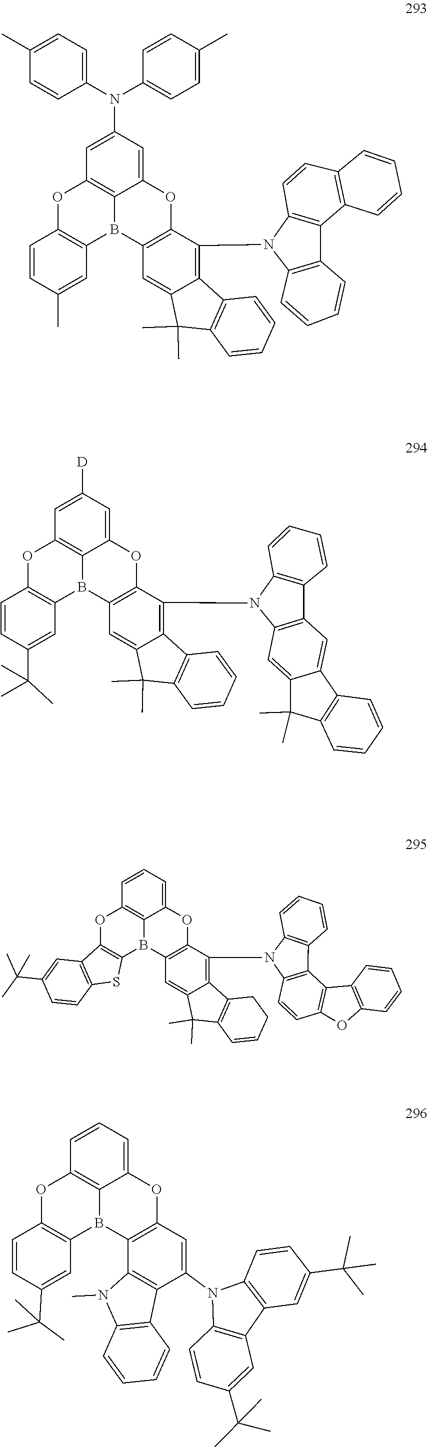 [SMILES: Cc1ccc(N(c2ccc(C)cc2)c2cc3c4c(c2)Oc2c(cc5c(c2-n2c6ccccc6c6c7ccccc7ccc62)-c2ccccc2C5(C)C)B4c2cc(C)ccc2O3)cc1 ; [2H]c1cc2c3c(c1)Oc1c(cc4c(c1-n1c5ccccc5c5cc6c(cc51)C(C)(C)c1ccccc1-6)-c1ccccc1C4(C)C)B3c1cc(C(C)(C)C)ccc1O2 ; CC(C)(C)c1ccc2sc3c(c2c1)Oc1cccc2c1B3c1cc3c(c(-n4c5ccccc5c5c6c(ccc54)oc4ccccc46)c1O2)C1=C(C=CCC1)C3(C)C ; Cn1c2ccccc2c2c(-n3c4ccc(C(C)(C)C)cc4c4cc(C(C)(C)C)ccc43)cc3c(c21)B1c2cc(C(C)(C)C)ccc2Oc2cccc(c21)O3]

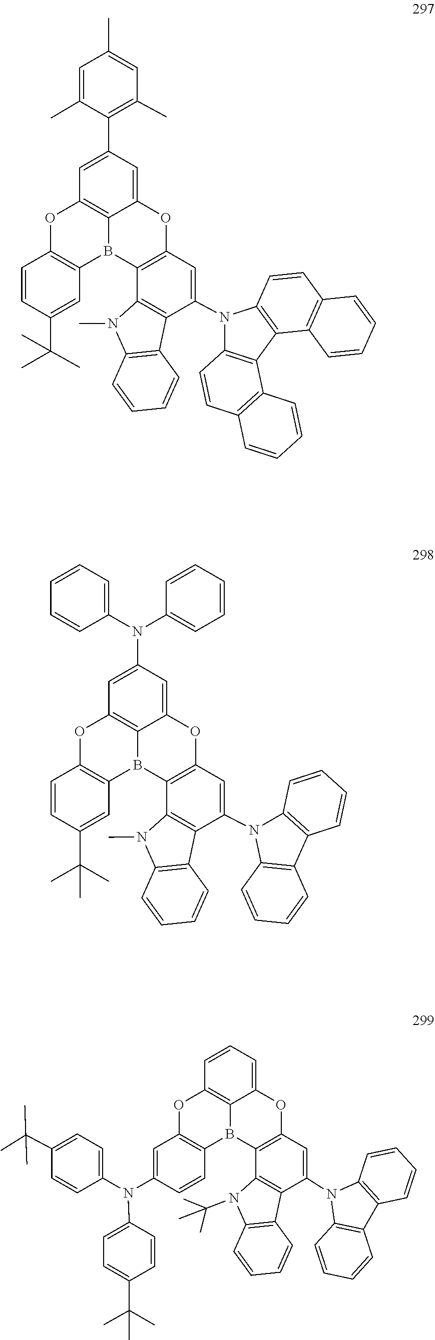 [SMILES: Cc1cc(C)c(-c2cc3c4c(c2)Oc2cc(-n5c6ccc7ccccc7c6c6c7ccccc7ccc65)c5c6ccccc6n(C)c5c2B4c2cc(C(C)(C)C)ccc2O3)c(C)c1 ; Cn1c2ccccc2c2c(-n3c4ccccc4c4ccccc43)cc3c(c21)B1c2cc(C(C)(C)C)ccc2Oc2cc(N(c4ccccc4)c4ccccc4)cc(c21)O3 ; CC(C)(C)c1ccc(N(c2ccc(C(C)(C)C)cc2)c2ccc3c(c2)Oc2cccc4c2B3c2c(cc(-n3c5ccccc5c5ccccc53)c3c5ccccc5n(C(C)(C)C)c23)O4)cc1]

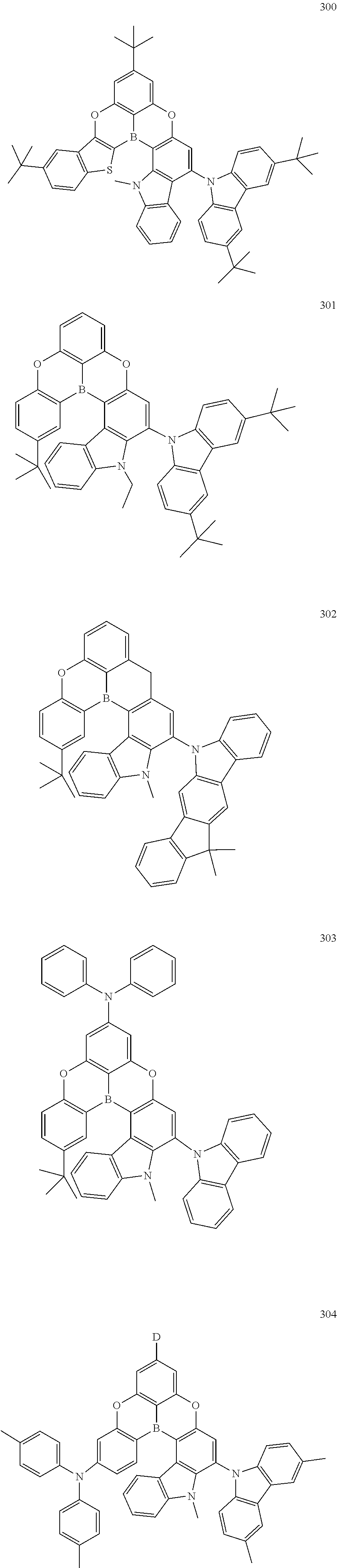

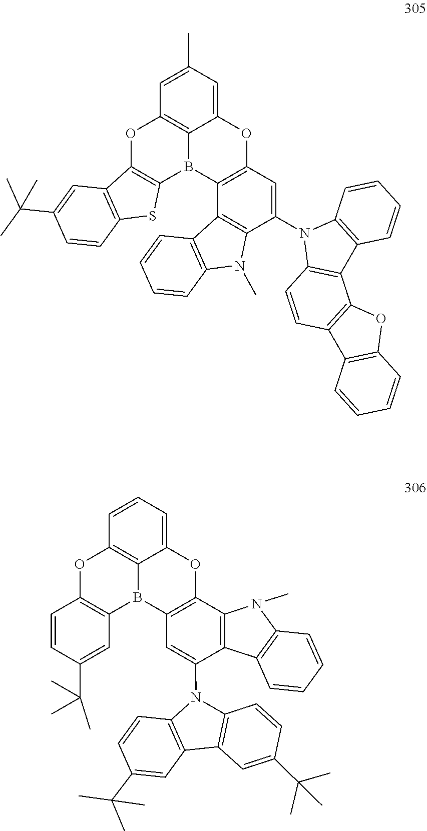 [SMILES: Cc1cc2c3c(c1)Oc1c(sc4ccc(C(C)(C)C)cc14)B3c1c(cc(-n3c4ccccc4c4c5oc6ccccc6c5ccc43)c3c1c1ccccc1n3C)O2 ; Cn1c2ccccc2c2c(-n3c4ccc(C(C)(C)C)cc4c4cc(C(C)(C)C)ccc43)cc3c(c21)Oc1cccc2c1B3c1cc(C(C)(C)C)ccc1O2]

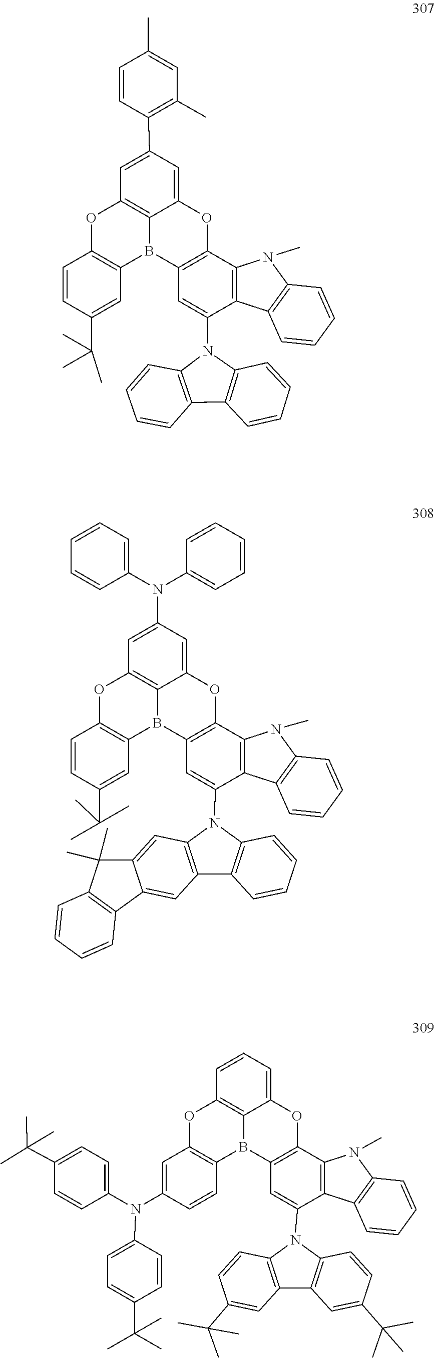 [SMILES: Cc1ccc(-c2cc3c4c(c2)Oc2c(cc(-n5c6ccccc6c6ccccc65)c5c6ccccc6n(C)c25)B4c2cc(C(C)(C)C)ccc2O3)c(C)c1 ; Cn1c2ccccc2c2c(-n3c4ccccc4c4cc5c(cc43)C(C)(C)c3ccccc3-5)cc3c(c21)Oc1cc(N(c2ccccc2)c2ccccc2)cc2c1B3c1cc(C(C)(C)C)ccc1O2 ; Cn1c2ccccc2c2c(-n3c4ccc(C(C)(C)C)cc4c4cc(C(C)(C)C)ccc43)cc3c(c21)Oc1cccc2c1B3c1ccc(N(c3ccc(C(C)(C)C)cc3)c3ccc(C(C)(C)C)cc3)cc1O2]

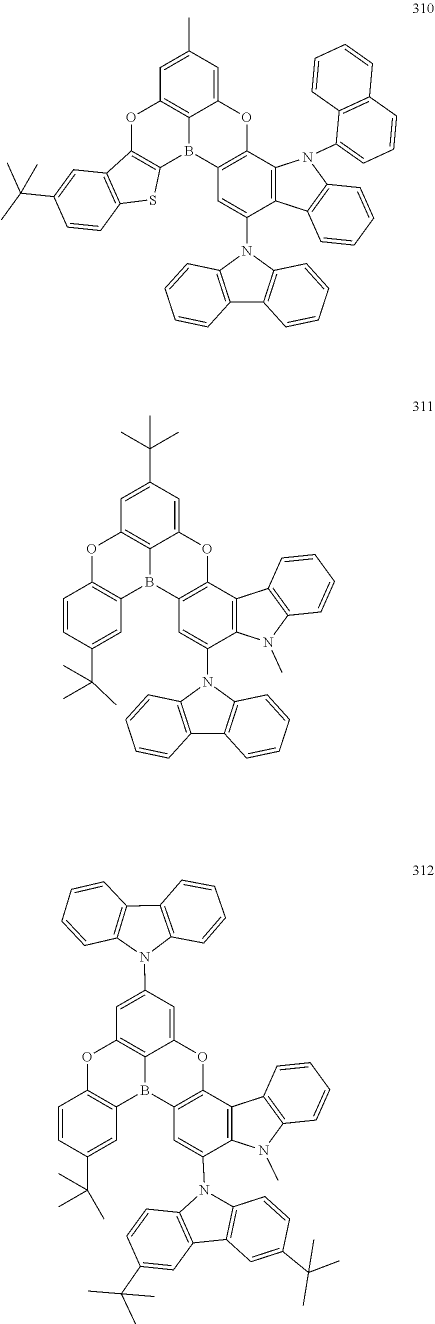 [SMILES: Cc1cc2c3c(c1)Oc1c(cc(-n4c5ccccc5c5ccccc54)c4c5ccccc5n(-c5cccc6ccccc56)c14)B3c1sc3ccc(C(C)(C)C)cc3c1O2 ; Cn1c2ccccc2c2c3c(cc(-n4c5ccccc5c5ccccc54)c21)B1c2cc(C(C)(C)C)ccc2Oc2cc(C(C)(C)C)cc(c21)O3 ; Cn1c2ccccc2c2c3c(cc(-n4c5ccc(C(C)(C)C)cc5c5cc(C(C)(C)C)ccc54)c21)B1c2cc(C(C)(C)C)ccc2Oc2cc(-n4c5ccccc5c5ccccc54)cc(c21)O3]

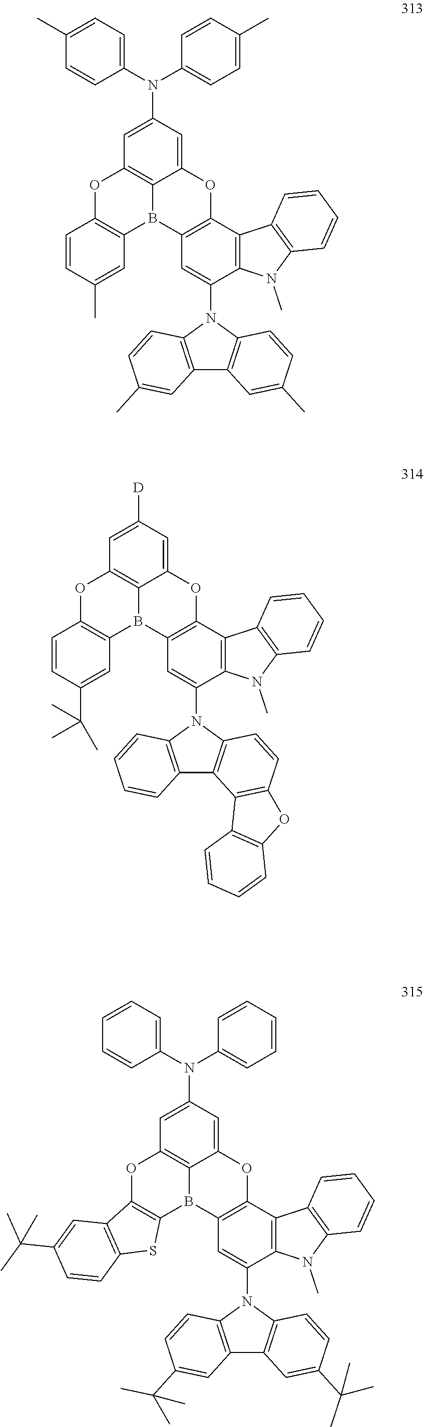 [SMILES: Cc1ccc(N(c2ccc(C)cc2)c2cc3c4c(c2)Oc2c(cc(-n5c6ccc(C)cc6c6cc(C)ccc65)c5c2c2ccccc2n5C)B4c2cc(C)ccc2O3)cc1 ; [2H]c1cc2c3c(c1)Oc1c(cc(-n4c5ccccc5c5c6c(ccc54)oc4ccccc46)c4c1c1ccccc1n4C)B3c1cc(C(C)(C)C)ccc1O2 ; Cn1c2ccccc2c2c3c(cc(-n4c5ccc(C(C)(C)C)cc5c5cc(C(C)(C)C)ccc54)c21)B1c2sc4ccc(C(C)(C)C)cc4c2Oc2cc(N(c4ccccc4)c4ccccc4)cc(c21)O3]

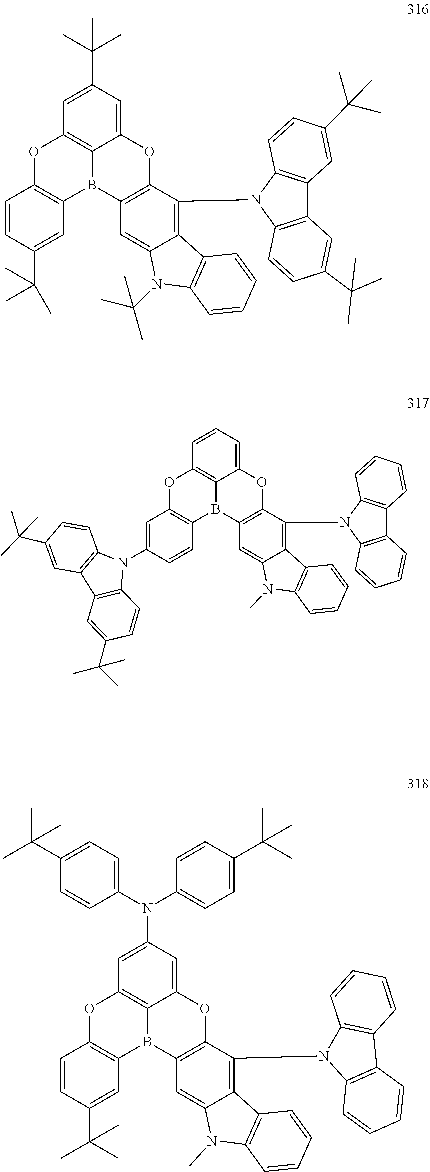

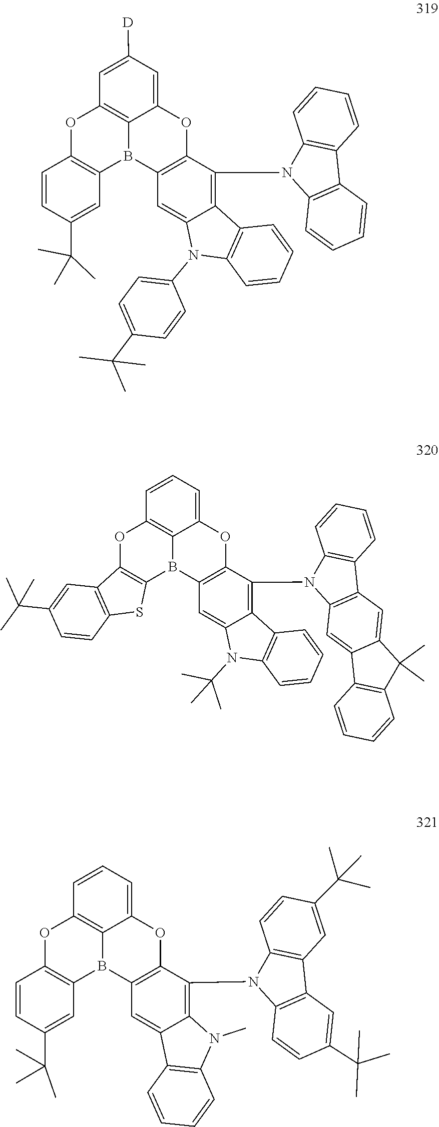 [SMILES: [2H]c1cc2c3c(c1)Oc1c(cc4c(c1-n1c5ccccc5c5ccccc51)c1ccccc1n4-c1ccc(C(C)(C)C)cc1)B3c1cc(C(C)(C)C)ccc1O2 ; CC(C)(C)c1ccc2sc3c(c2c1)Oc1cccc2c1B3c1cc3c(c(-n4c5ccccc5c5cc6c(cc54)-c4ccccc4C6(C)C)c1O2)c1ccccc1n3C(C)(C)C ; Cn1c2ccccc2c2cc3c(c(-n4c5ccc(C(C)(C)C)cc5c5cc(C(C)(C)C)ccc54)c21)Oc1cccc2c1B3c1cc(C(C)(C)C)ccc1O2]

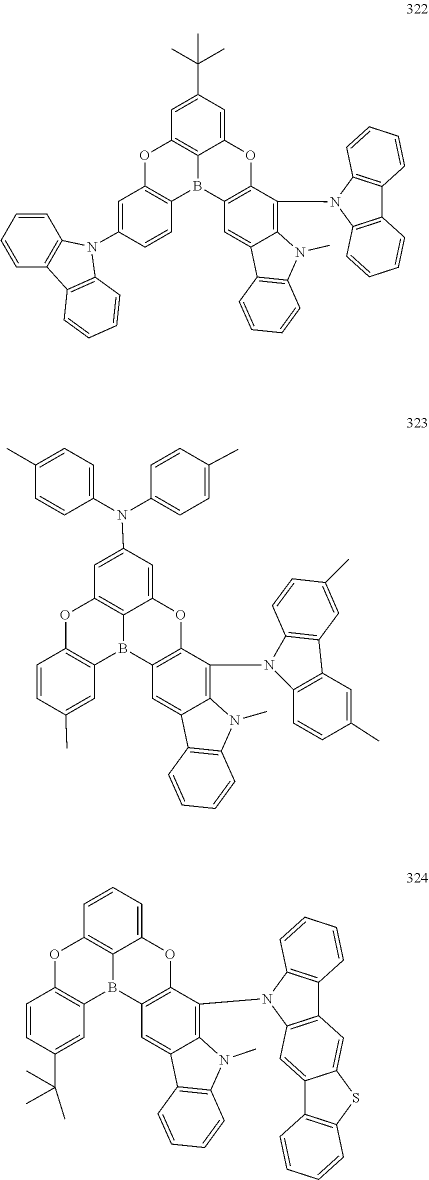

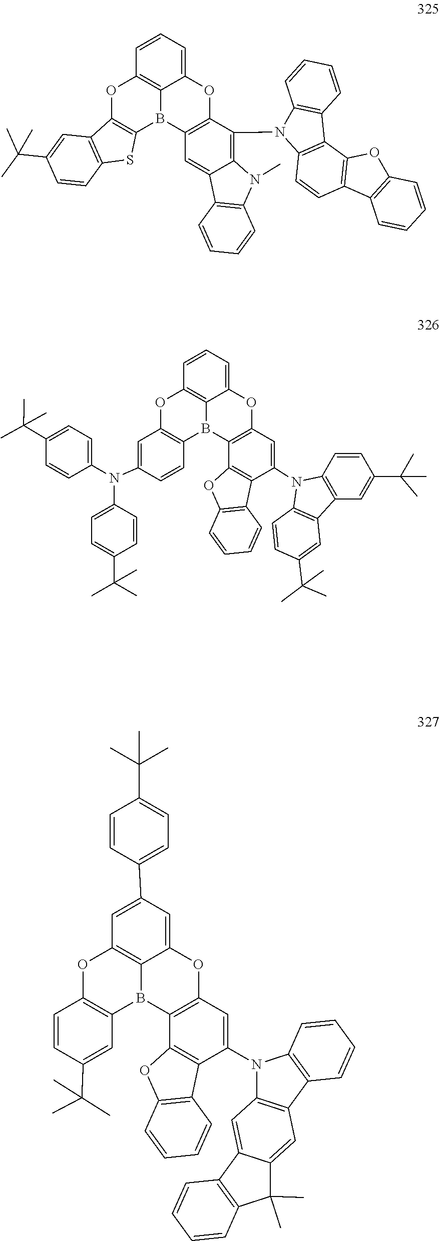

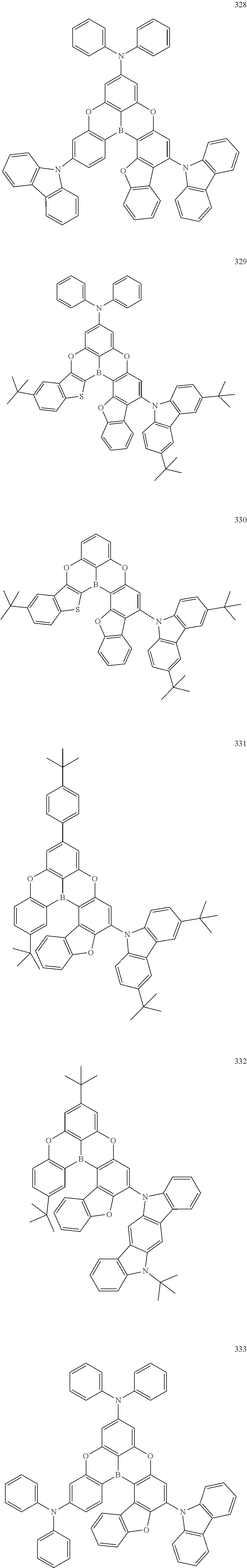

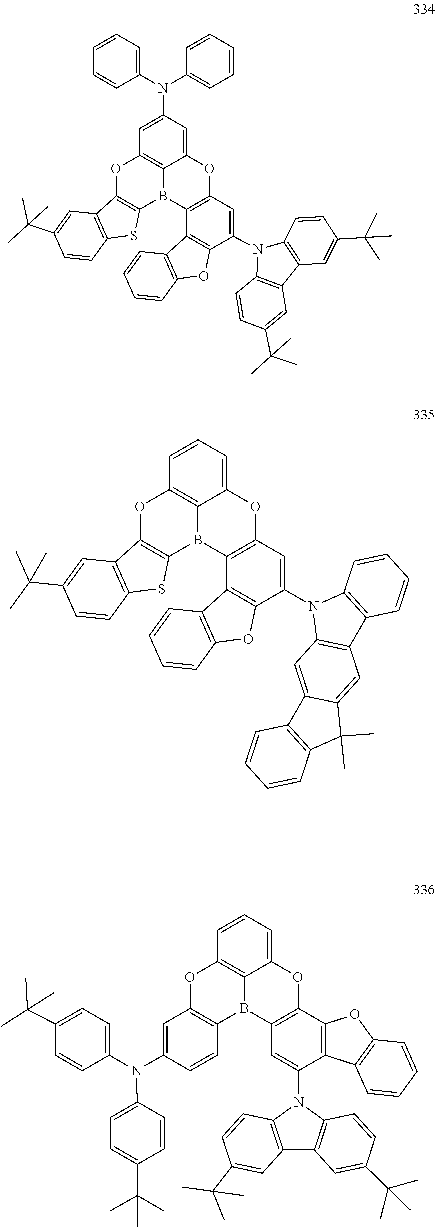

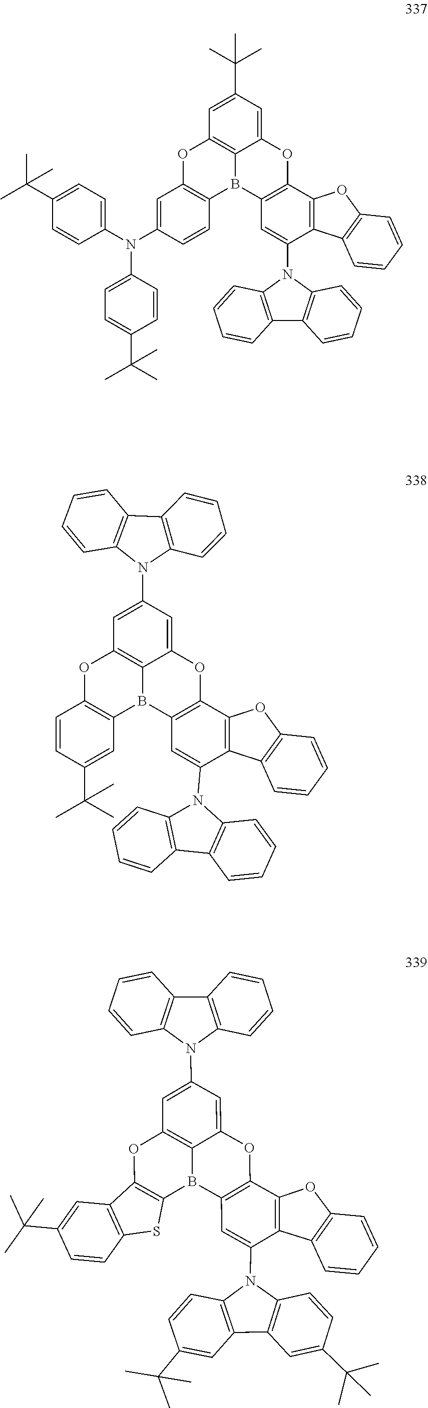 [SMILES: CC(C)(C)c1ccc(N(c2ccc(C(C)(C)C)cc2)c2ccc3c(c2)Oc2cc(C(C)(C)C)cc4c2B3c2cc(-n3c5ccccc5c5ccccc53)c3c(oc5ccccc53)c2O4)cc1 ; CC(C)(C)c1ccc2c(c1)B1c3cc(-n4c5ccccc5c5ccccc54)c4c(oc5ccccc54)c3Oc3cc(-n4c5ccccc5c5ccccc54)cc(c31)O2 ; CC(C)(C)c1ccc2sc3c(c2c1)Oc1cc(-n2c4ccccc4c4ccccc42)cc2c1B3c1cc(-n3c4ccc(C(C)(C)C)cc4c4cc(C(C)(C)C)ccc43)c3c(oc4ccccc43)c1O2]

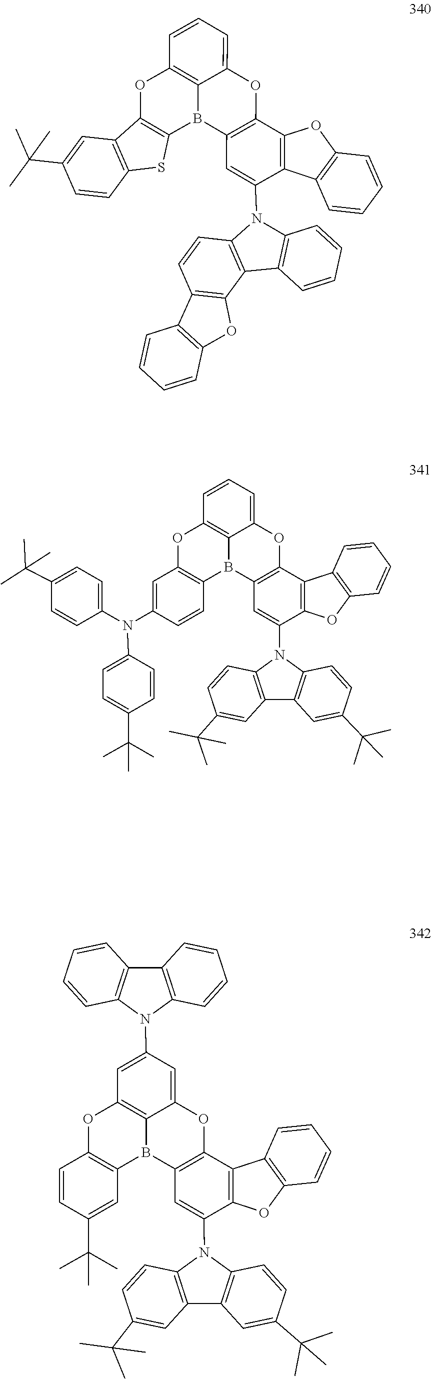

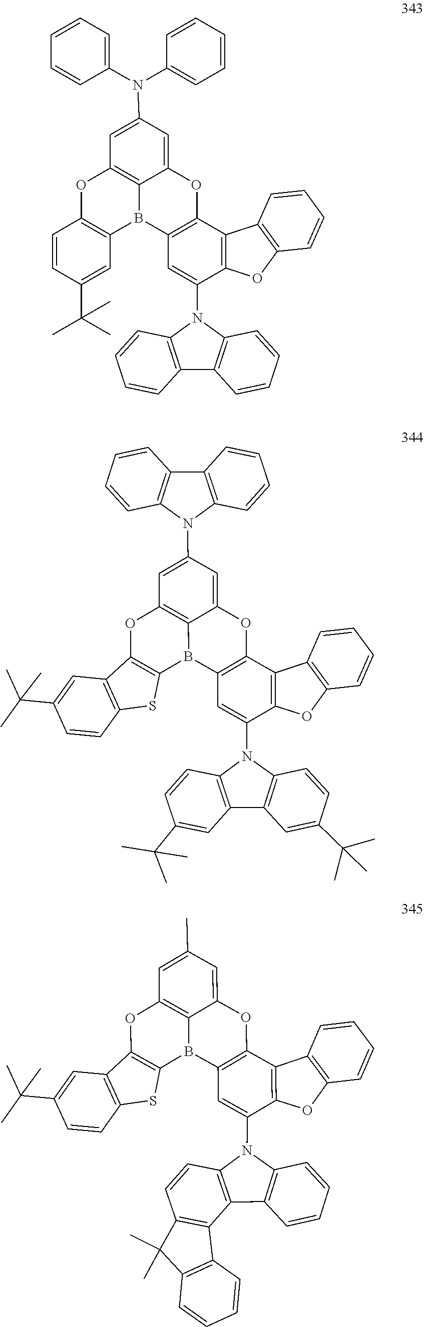

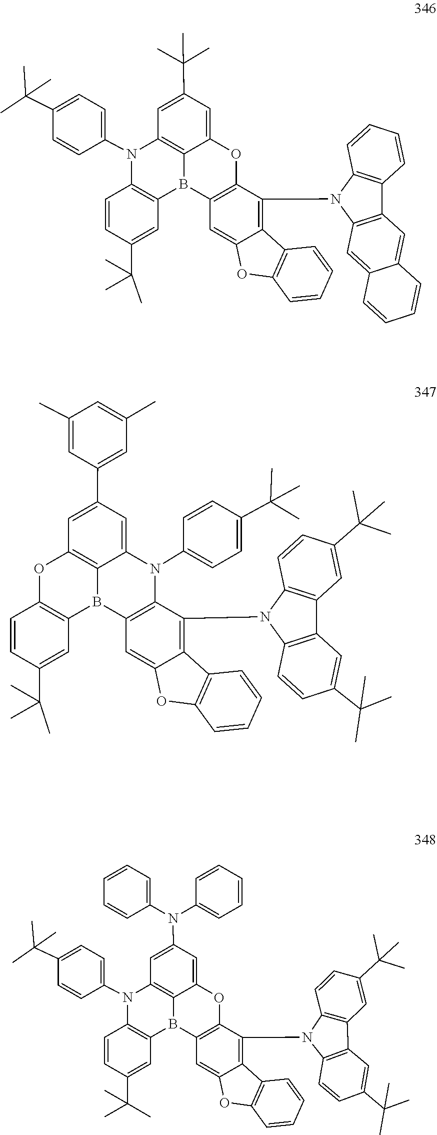

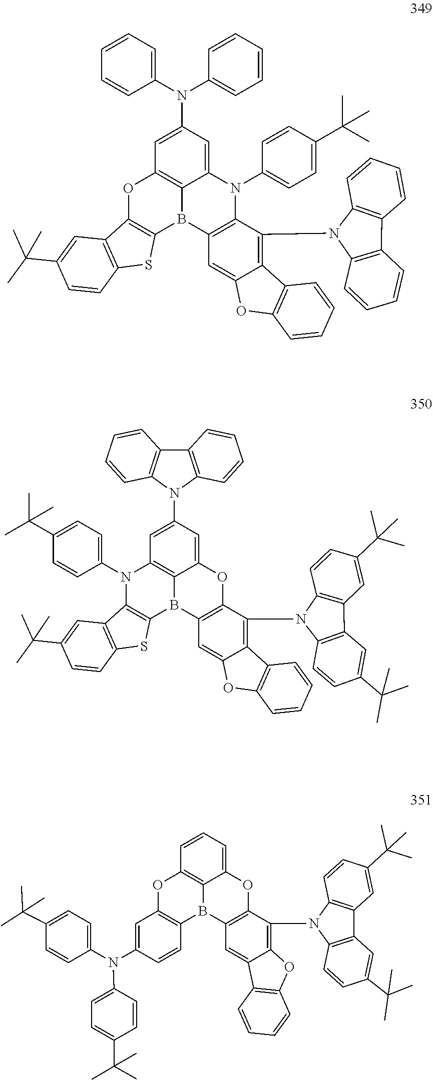

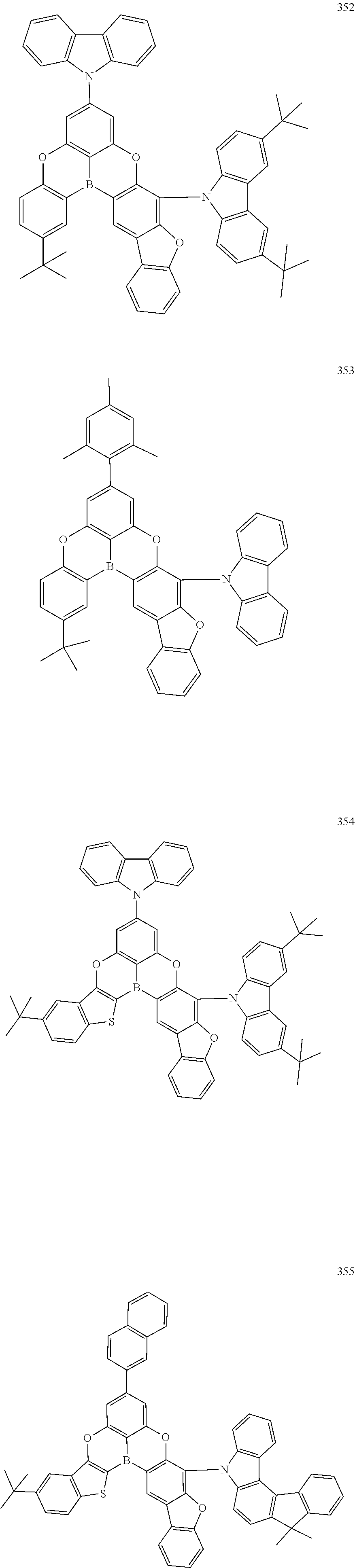

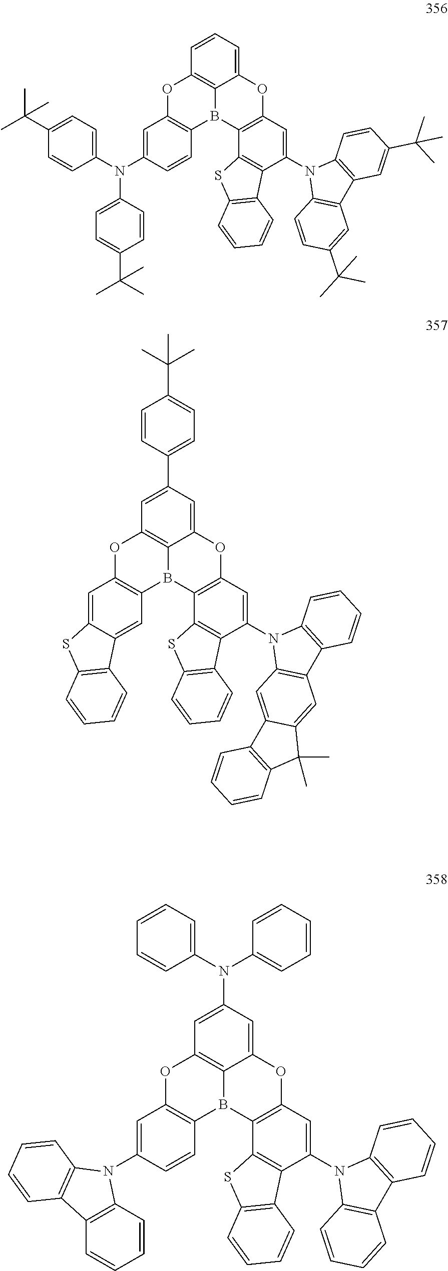 [SMILES: CC(C)(C)c1ccc(N(c2ccc(C(C)(C)C)cc2)c2ccc3c(c2)Oc2cccc4c2B3c2c(cc(-n3c5ccc(C(C)(C)C)cc5c5cc(C(C)(C)C)ccc53)c3c2sc2ccccc23)O4)cc1 ; CC(C)(C)c1ccc(-c2cc3c4c(c2)Oc2cc(-n5c6ccccc6c6cc7c(cc65)-c5ccccc5C7(C)C)c5c(sc6ccccc65)c2B4c2cc4c(cc2O3)sc2ccccc24)cc1 ; c1ccc(N(c2ccccc2)c2cc3c4c(c2)Oc2cc(-n5c6ccccc6c6ccccc65)c5c(sc6ccccc65)c2B4c2ccc(-n4c5ccccc5c5ccccc54)cc2O3)cc1]

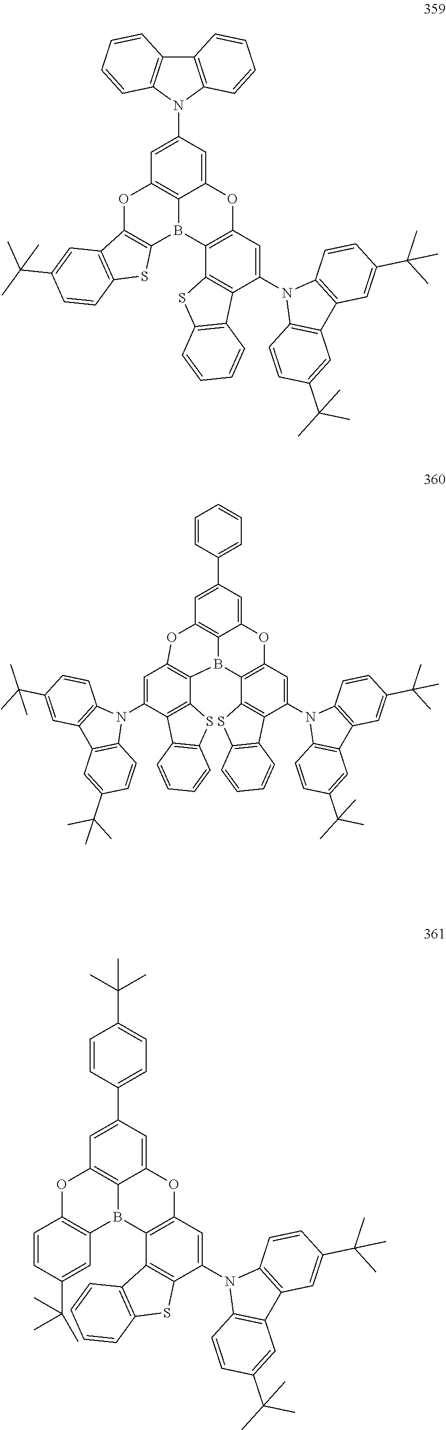

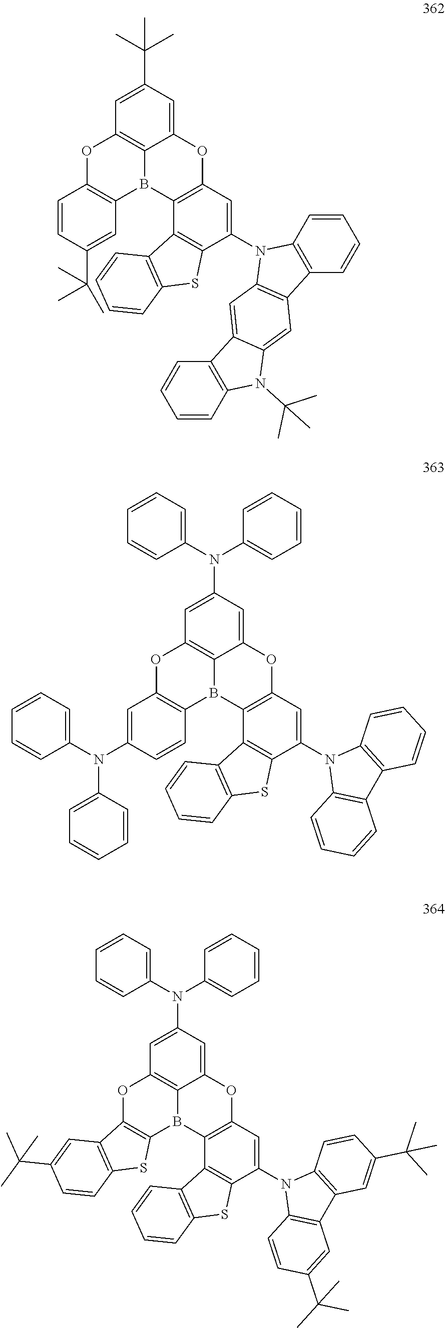 [SMILES: CC(C)(C)c1cc2c3c(c1)Oc1cc(-n4c5ccccc5c5cc6c(cc54)c4ccccc4n6C(C)(C)C)c4sc5ccccc5c4c1B3c1cc(C(C)(C)C)ccc1O2 ; c1ccc(N(c2ccccc2)c2ccc3c(c2)Oc2cc(N(c4ccccc4)c4ccccc4)cc4c2B3c2c(cc(-n3c5ccccc5c5ccccc53)c3sc5ccccc5c23)O4)cc1 ; CC(C)(C)c1ccc2sc3c(c2c1)Oc1cc(N(c2ccccc2)c2ccccc2)cc2c1B3c1c(cc(-n3c4ccc(C(C)(C)C)cc4c4cc(C(C)(C)C)ccc43)c3sc4ccccc4c13)O2]

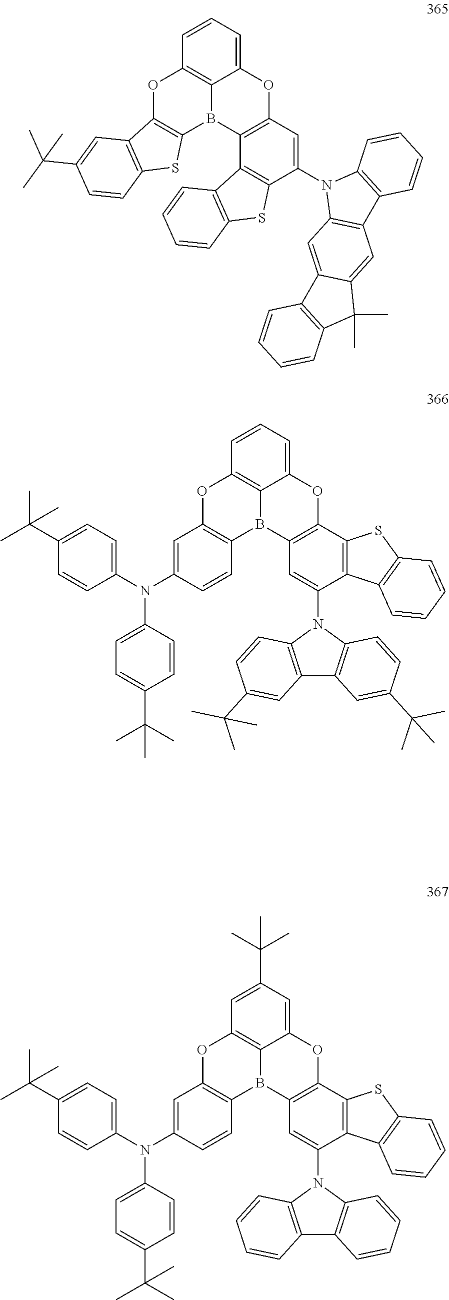 [SMILES: CC(C)(C)c1ccc2sc3c(c2c1)Oc1cccc2c1B3c1c(cc(-n3c4ccccc4c4cc5c(cc43)-c3ccccc3C5(C)C)c3sc4ccccc4c13)O2 ; CC(C)(C)c1ccc(N(c2ccc(C(C)(C)C)cc2)c2ccc3c(c2)Oc2cccc4c2B3c2cc(-n3c5ccc(C(C)(C)C)cc5c5cc(C(C)(C)C)ccc53)c3c(sc5ccccc53)c2O4)cc1 ; CC(C)(C)c1ccc(N(c2ccc(C(C)(C)C)cc2)c2ccc3c(c2)Oc2cc(C(C)(C)C)cc4c2B3c2cc(-n3c5ccccc5c5ccccc53)c3c(sc5ccccc53)c2O4)cc1]

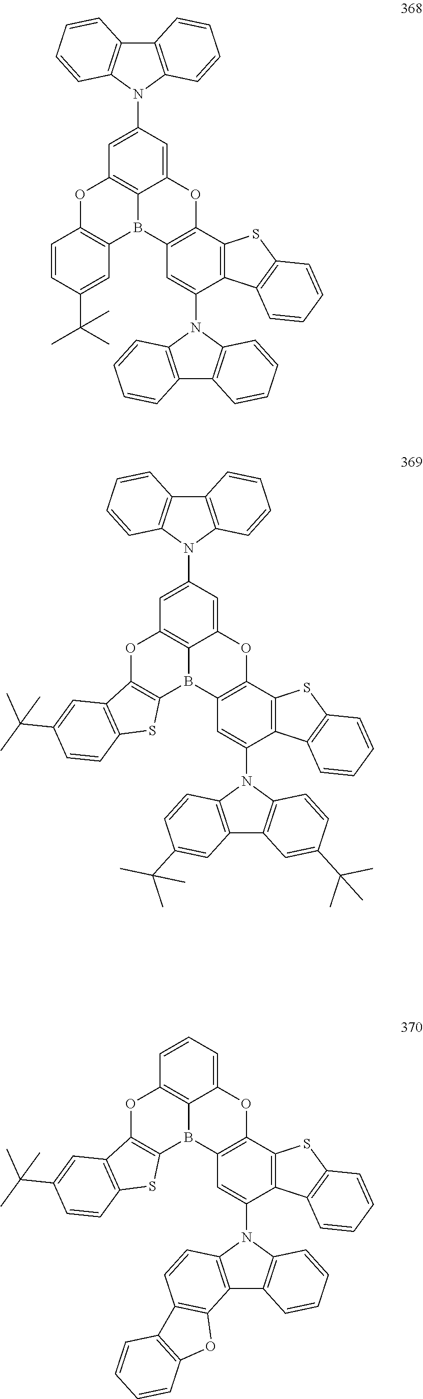 [SMILES: CC(C)(C)c1ccc2c(c1)B1c3cc(-n4c5ccccc5c5ccccc54)c4c(sc5ccccc54)c3Oc3cc(-n4c5ccccc5c5ccccc54)cc(c31)O2 ; CC(C)(C)c1ccc2sc3c(c2c1)Oc1cc(-n2c4ccccc4c4ccccc42)cc2c1B3c1cc(-n3c4ccc(C(C)(C)C)cc4c4cc(C(C)(C)C)ccc43)c3c(sc4ccccc43)c1O2 ; CC(C)(C)c1ccc2sc3c(c2c1)Oc1cccc2c1B3c1cc(-n3c4ccccc4c4c5oc6ccccc6c5ccc43)c3c(sc4ccccc43)c1O2]

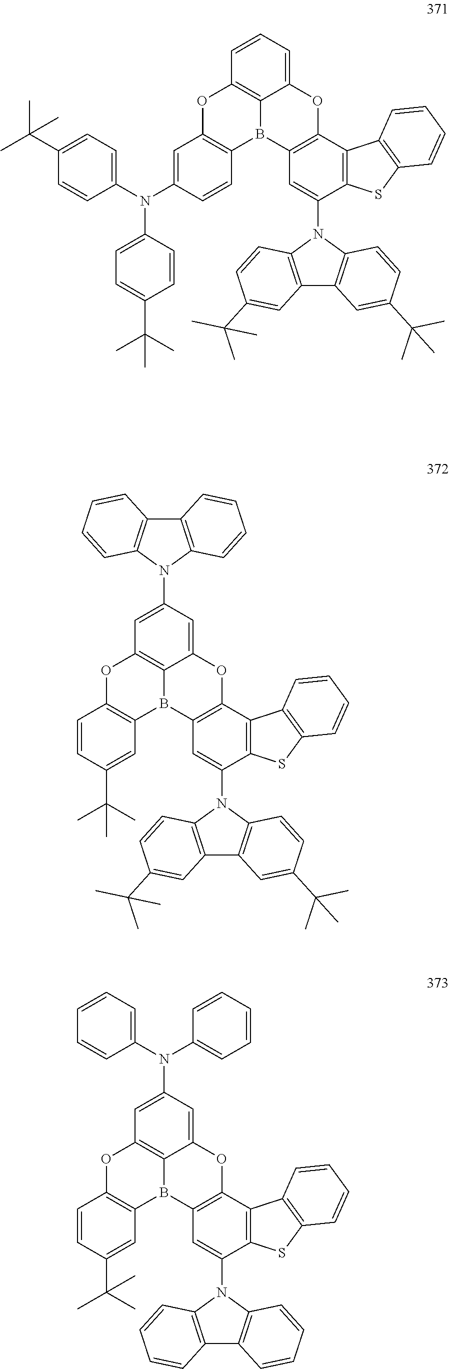 [SMILES: CC(C)(C)c1ccc(N(c2ccc(C(C)(C)C)cc2)c2ccc3c(c2)Oc2cccc4c2B3c2cc(-n3c5ccc(C(C)(C)C)cc5c5cc(C(C)(C)C)ccc53)c3sc5ccccc5c3c2O4)cc1 ; CC(C)(C)c1ccc2c(c1)B1c3cc(-n4c5ccc(C(C)(C)C)cc5c5cc(C(C)(C)C)ccc54)c4sc5ccccc5c4c3Oc3cc(-n4c5ccccc5c5ccccc54)cc(c31)O2 ; CC(C)(C)c1ccc2c(c1)B1c3cc(-n4c5ccccc5c5ccccc54)c4sc5ccccc5c4c3Oc3cc(N(c4ccccc4)c4ccccc4)cc(c31)O2]

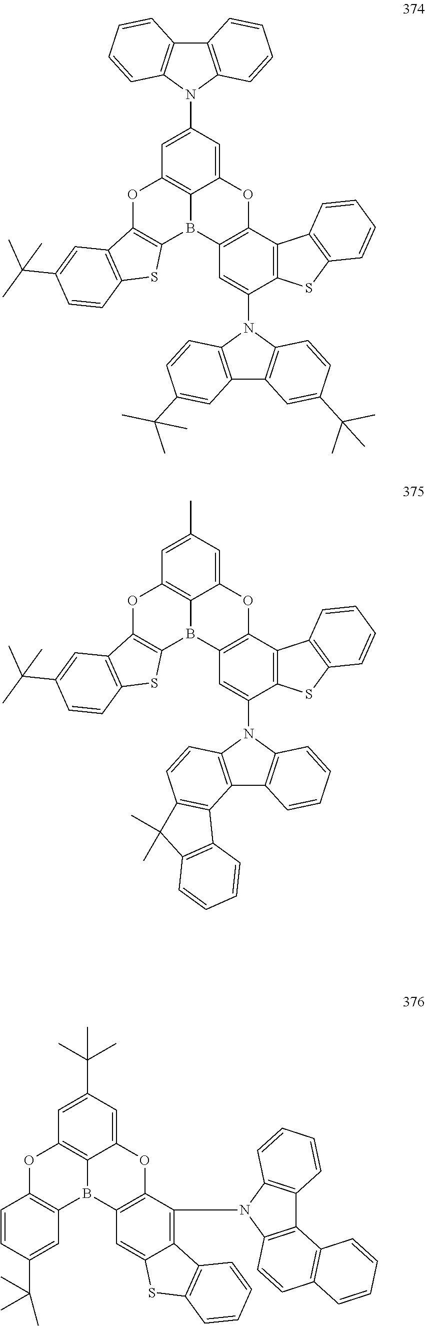 [SMILES: CC(C)(C)c1ccc2sc3c(c2c1)Oc1cc(-n2c4ccccc4c4ccccc42)cc2c1B3c1cc(-n3c4ccc(C(C)(C)C)cc4c4cc(C(C)(C)C)ccc43)c3sc4ccccc4c3c1O2 ; Cc1cc2c3c(c1)Oc1c(cc(-n4c5ccccc5c5c6c(ccc54)C(C)(C)c4ccccc4-6)c4sc5ccccc5c14)B3c1sc3ccc(C(C)(C)C)cc3c1O2 ; CC(C)(C)c1cc2c3c(c1)Oc1c(cc4sc5ccccc5c4c1-n1c4ccccc4c4c5ccccc5ccc41)B3c1cc(C(C)(C)C)ccc1O2]

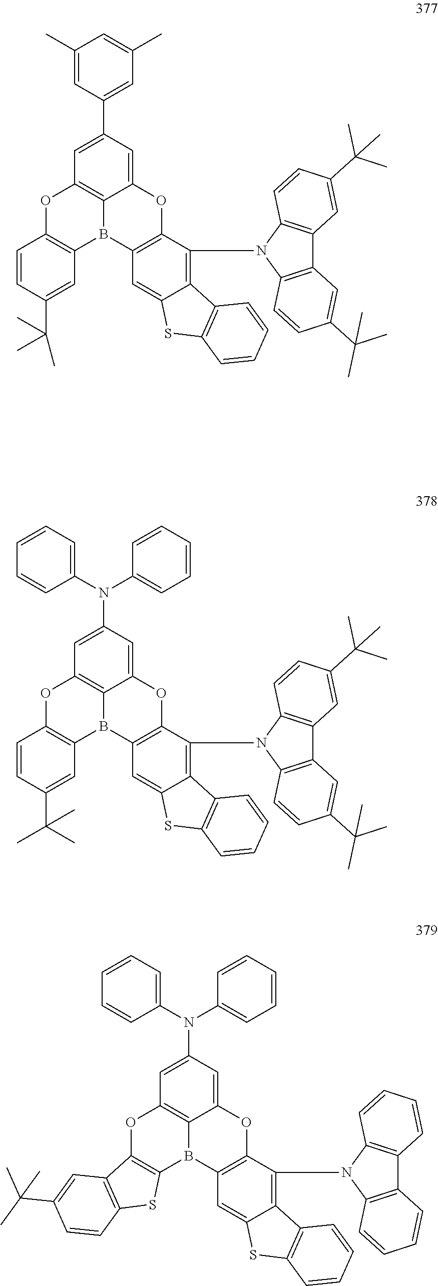

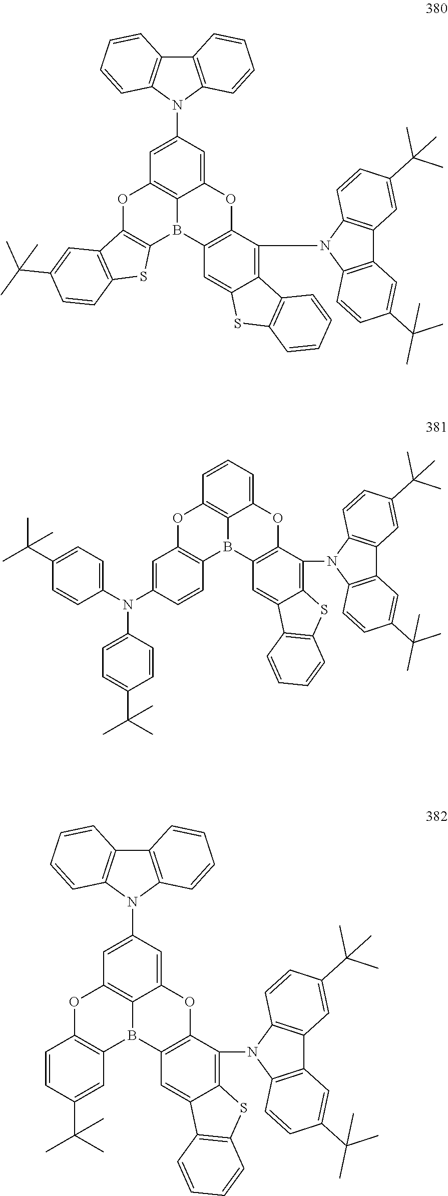

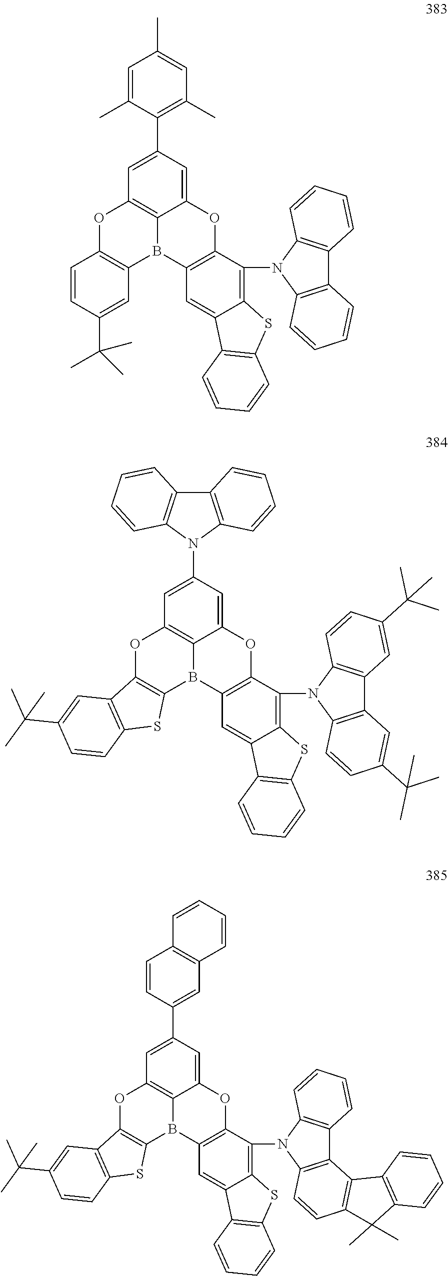

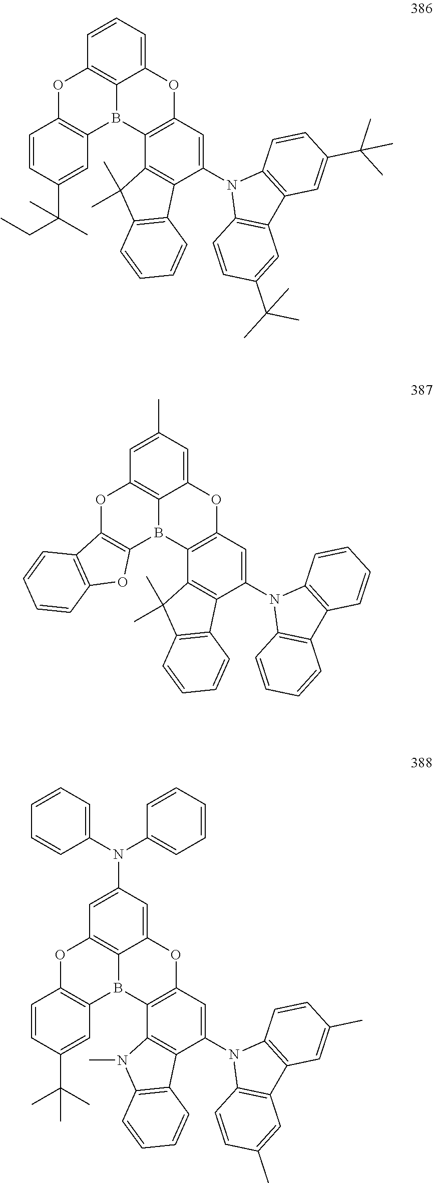 [SMILES: CCC(C)(C)c1ccc2c(c1)B1c3c(cccc3Oc3cc(-n4c5ccc(C(C)(C)C)cc5c5cc(C(C)(C)C)ccc54)c4c(c31)C(C)(C)c1ccccc1-4)O2 ; Cc1cc2c3c(c1)Oc1c(oc4ccccc14)B3c1c(cc(-n3c4ccccc4c4ccccc43)c3c1C(C)(C)c1ccccc1-3)O2 ; Cc1ccc2c(c1)c1cc(C)ccc1n2-c1cc2c(c3c1c1ccccc1n3C)B1c3cc(C(C)(C)C)ccc3Oc3cc(N(c4ccccc4)c4ccccc4)cc(c31)O2]

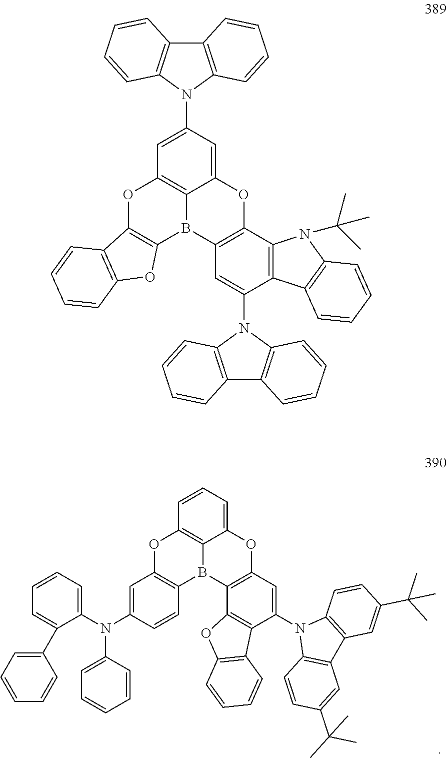 [SMILES: CC(C)(C)n1c2ccccc2c2c(-n3c4ccccc4c4ccccc43)cc3c(c21)Oc1cc(-n2c4ccccc4c4ccccc42)cc2c1B3c1oc3ccccc3c1O2 ; CC(C)(C)c1ccc2c(c1)c1cc(C(C)(C)C)ccc1n2-c1cc2c(c3oc4ccccc4c13)B1c3ccc(N(c4ccccc4)c4ccccc4-c4ccccc4)cc3Oc3cccc(c31)O2]

In the organic compound provided by the embodiments of the present disclosure, the aromatic ring and heteroaromatic ring are connected through the heterocyclic ring to form a larger conjugated system and a larger rigid plane, effectively suppressing the vibration relaxation caused by the vibration and rotation of organic compound molecules, which improves luminous efficiency and thermal stability. Moreover, the organic compound provided by the embodiments of the present disclosure, by introducing carbazole-like groups, further enhances the conjugation and resonance effects of the organic compound, improves the performance of the organic compound, increases the luminous efficiency of the light-emitting element applying the organic compound and extends the luminescent life of the light-emitting element.

The present disclosure further provides a mixture, which includes at least one organic compound as described in any one of the above-mentioned organic compounds and an organic functional material. The organic functional material is selected from at least one of a hole transport material, a hole injection material, a hole blocking material, an electron injection material, an electron transport material, a host material, or a guest material.

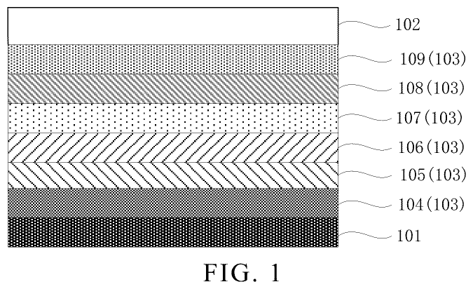

Referring to FIG. 1, embodiments of the present disclosure further provide a light-emitting element, which includes a pair of electrodes that includes a first electrode 101 and a second electrode 102, and an organic functional layer 103 disposed between the first electrode 101 and the second electrode 102. A material of the organic functional layer 103 includes one or more organic compounds as described above. The first electrode 101 can be an anode, and the second electrode 102 can be a cathode.

In some embodiments, the light-emitting elements can be applied to an organic light-emitting diode, an organic photovoltaic cell, an organic light-emitting cell, an organic field-effect transistor, an organic light-emitting field-effect transistor, an organic laser, an organic spin electron device, an organic sensor, an organic plasmon emission diode, or the like, preferably applied to the organic light-emitting diode, the organic light-emitting cell, or the organic light-emitting field-effect transistor.

In some embodiments, the light-emitting element can be applied to various electronic devices, such as a display panel, an illumination device, a light source, and the like.

In some embodiments, the organic functional layer 103 can be a single layer, which may be a mixture layer, and a mixture in the mixture layer includes a first compound and a second compound. The first compound is selected from one or more of the organic compounds mentioned above, and the second compound is selected from one or more of a hole injection material, a hole transport material, an electron transport material, a hole blocking material, a light-emitting guest material, a light-emitting host material, or an organic dye.

When the second compound is selected from one or more of the hole injection material, the hole transport material, the electron transport material, the hole blocking material, the light-emitting guest material, the light-emitting host material, or the organic dye, a mass ratio of the first compound to the second compound ranges from 1:99 to 30:70, preferably ranges from 1:99 to 10:90.

When the second compound is the light-emitting guest material, the mass ratio of the first compound to the second compound ranges from 99:1 to 70:30, preferably ranges from 99:1 to 90:10.

In some embodiments, the organic functional layer 103 may include multiple layers. When the organic functional layer 103 includes multiple layers, the organic functional layer 103 includes at least a light-emitting layer 107. Preferably, the organic functional layer 103 includes a hole injection layer 104, a hole transport layer 105, a light-emitting layer 107, an electron blocking layer 106, an electron injection layer 109, an electron transport layer 108, or a hole blocking layer.

In some embodiments, the anode is an electrode used for injecting holes, and the holes in the anode can be injected into the organic functional layer 103. For example, the holes in the anode can be injected into the hole injection layer, the hole transport layer, or the light-emitting layer. A material of the anode may include at least one of conductive metal, conductive metal oxide, and conductive polymer. Preferably, absolute value of a difference between work function of the anode and highest occupied molecular orbital (HOMO) energy level or valence band energy level of a light-emitting material of the light-emitting layer, or a p-type semiconductor material of the hole injection layer, the hole transport layer, or the electron blocking layer is less than 0.5 eV, preferably less than 0.3 eV, more preferably less than 0.2 eV The material of the anode includes, but is not limited to, at least one of aluminum (Al), copper (Cu), aurum (Au), argentum (Ag), magnesium (Mg), ferrum (Fe), cobalt (Co), nickel (Ni), manganese (Mn), palladium (Pd), platinum (Pt), indium tin oxide (ITO), aluminum doped zinc oxide (AZO), or other suitable anode materials known in the art, which can be easily selected and used by those skilled in the art. The material of the anode can be deposited using any suitable technology, such as a suitable physical vapor deposition method including RF magnetron sputtering, vacuum thermal evaporation, electron beam (e-beam), or the like. In some embodiments, the anode is a patterned structure, such as a patterned ITO conductive substrate that can be commercially available and used to prepare devices according to the present disclosure.

In some embodiments, the cathode is an electrode used for injecting electrons, and the electrons in the cathode can be easily injected into the organic functional layer. For example, the electrons in the cathode can be easily injected into the electron injection layer, the electron transport layer, or the light-emitting layer. A material of the cathode may include at least one of conductive metal and conductive metal oxide. Preferably, absolute value of a difference between work function of the cathode and lower unoccupied molecular orbital (LUMO) energy level or valence band energy level of the light-emitting material of the light-emitting layer, or a n-type semiconductor material of the electron injection layer, the electron transport layer, or the hole blocking layer is less than 0.5 eV, preferably less than 0.3 eV, more preferably 0.2 eV. All materials that can be used in the cathode of an organic electronic device may be used as the material of the cathode of the organic electronic device of the present disclosure. The material of the cathode includes, but not limited to, at least one of Al, Au, Ag, calcium (Ca), barium (Ba), Mg, LiF/Al, MgAg alloy, BaF₂/Al, Cu, Fe, Co, Ni, Mn, Pd, Pt, ITO, or the like. The material of the cathode may be deposited using any suitable technology, such as a suitable physical vapor deposition method including RF magnetron sputtering, vacuum thermal evaporation, electron beam (e-beam), or the like.

In some embodiments, the hole injection layer 104 is used for promoting an injection of holes from the anode to the light-emitting layer 107. The hole injection layer 104 includes a hole injection material that is a material used to receive holes injected from a positive electrode at low voltages. Preferably, HOMO energy level of the hole injection material is between work function of the material of the anode and HOMO energy level of a functional material of film layers at a side of the hole injection layer away from the anode (such as the hole transport material of the hole transport layer). The hole injection material includes, but is not limited to, at least one of metalloporphyrin, oligothiophene, an organic material based on arylamine, an organic material based on hexacyano hexaazabenzophenanthrene, an organic material based on quinacridone, an organic material based on perylene, anthraquinone, conductive polymer based on polyaniline, polythiophene, or the like.

In some embodiments, the hole transport layer 105 is used for transmitting holes. The hole transport layer 105 includes a hole transport material used to receive holes transmitted from the anode or the hole injection layer and transmit the holes to the light-emitting layer. The hole transport material is a material known in the art to have high hole mobility. The hole transport material may include, but is not limited to, at least one of an organic material based on aromatic amine, an organic material based on carbazolyl group, conductive polymer, block copolymer with both conjugated and non-conjugated portions, or the like.

In some embodiments, the electron transport layer 108 is used for transmitting electrons. The electron transport layer 108 includes an electron transport material used to receive electrons injected from a negative electrode and transmit the electrons to the light-emitting layer 107. The electron transport material is a material known in the art to have high electron mobility. The electron transport material may include, but is not limited to, at least one of an Al-based complex of 8-hydroxyquinoline, a complex containing Alq₃, an organic radical compound, a hydroxyflavone metal complex, 8-hydroxyquinoline lithium (LiQ), and a compound based on benzimidazole.

In some embodiments, the electron injection layer 109 is used for injecting electrons. The electron injection layer 109 includes an electron injection material. Preferably, the electron injection material has ability to transmit electrons, and can achieve an effect of injecting electrons from a negative electrode and an excellent effect of injecting electrons into the light-emitting layer 107 or the light-emitting material, preventing excitons generated by the light-emitting layer 107 from transferring to the hole injection layer. Further, the electron injection material has excellent ability to form a thin film. The electron injection material may include, but is not limited to, at least one of 8-hydroxyquinoline lithium (LiQ), fluorenone, anthraquinone dia methyl group, biphenylquinone, thian dioxide, azole, diazole, triazole, imidazole, perylene tetracarboxylic acid, fluorene methane, anthrone, derivatives thereof, a metal complex, a 5-membered ring derivative containing nitrogen, or the like.

In some embodiments, the hole blocking layer can be used to block holes from reaching the negative electrode, and is generally formed under the same condition as the hole injection layer 104. The hole blocking layer includes a hole blocking material, which includes, but is not limited to, at least one of a diazole derivative, a triazole derivative, a phenanthroline derivative, BCP, an aluminum complex, or the like.

Preferably, the light-emitting layer 107 includes a host material and a guest material, and the guest material is one or more of the organic compounds mentioned above.

Preferably, a mass ratio of the host material to the guest material ranges from 99:1 to 70:30. For example, the mass ratio ranges from 90:10, 85:15, 80:20, 75:25, or the like. The guest material is dispersed in the host material, and the mass ratio of the host material to the guest material ranges from 99:1 to 70:30, which is conducive to inhibiting crystallization of the light-emitting layer 107 and suppressing concentration quenching of the guest material caused by high concentration, thus improving luminous efficiency of the light-emitting element.

Preferably, the host material can be a host material based on anthracene, boron oxide ring, or exciplex.

An emission wavelength of the light-emitting element may range from 300 nm to 1,000 nm, preferably from 350 nm to 900 nm, and more preferably from 400 nm to 800 nm. Light emitted by the light-emitting element can be red light, green light, or blue light, preferably blue light.

In some embodiments, the light-emitting element further includes a substrate, the first electrode 101, the hole injection layer 104, the hole transport layer 105, the electron blocking layer 106, the light-emitting layer 107, the electron transport layer 108, the electron injection layer 109, and the second electrode 102 are sequentially stacked on the substrate. The substrate may be a transparent substrate or an opaque substrate. When the substrate is the transparent substrate, a transparent light-emitting element can be made. The substrate may be a rigid substrate or a flexible substrate with elasticity. A material of the substrate may include, but is not limited to, plastic, polymer, metal, a semiconductor wafer, a glass, or the like. Preferably, the substrate includes at least one smooth surface for forming the anode. More preferably, the substrate may be a substrate without surface defects. Preferably, the material of the substrate may include, but is not limited to, a polymer film or plastic, such as polyethylene terephthalate (PET) or polyethylene naphthyl-2,6-dicarboxylate (PEN). A glass transition temperature Tg of the material of the substrate may be greater than or equal to 150° C., preferably greater than or equal to 200° C., more preferably greater than or equal to 250° C., most preferably greater than or equal to 300° C.

In some embodiments, the material of the organic functional layer, the material of the mixture layer, or the material of the light-emitting layer can be prepared using the composition, and the preparation process can be a printing process or a coating process. The composition includes at least one organic compound or the mixture as described above, and at least one organic solvent. The printing process or coating process includes inkjet printing, nozzle printing, letterpress printing, screen printing, dip coating, rotating coating, scraper coating, roller printing, torsion roller printing, lithographic printing, flexographic printing, rotary printing, spray coating, brush coating, transfer printing, slit extrusion coating, or the like. Preferably, the printing or coating process is gravure printing, nozzle printing, or inkjet printing.

The composition can be a solution or suspension, and the composition may include a dispersion agent and a dispersion aid. The dispersion agent is one or more of the above-mentioned organic compounds and the dispersion aid is used to disperse the dispersion agent.

The mass fraction of the above-mentioned organic compound in the composition may range from 0.01% to 10%, preferably range from 0.1% to 15%, more preferably 0.2% to 5%, most preferably 0.25% to 3%.

Preferably, the Hansen solubility parameter of the dispersion acid is within the following ranges: δd (dispersion force) ranges from 17.0 MPa^{1/2} to 23.2 MPa^{1/2}, preferably ranges from 18.5 MPa^{1/2} to 21.0 MPa^{1/2}; Sp (polarity force) ranges from 0.2 MPa^{1/2} to 12.5 MPa^{1/2}, preferably ranges from 2.0 MPa^{1/2} to 6.0 MPa^{1/2}; δh (hydrogen bonding force) ranges from 0.9 MPa^{1/2} to 14.2 MPa^{1/2}, preferably ranges from 2.0 MPa^{1/2} to 6.0 MPa^{1/2}.

Preferably, a boiling point of the dispersion acid is greater than or equal to 150° C., preferably greater than or equal to 180° C., more preferably greater than or equal to 200° C., further preferably greater than or equal to 250° C., most preferably greater than or equal to 300° C. The boiling point of the dispersion acid is at least greater than or equal to 150° C., which is beneficial to prevent nozzles of inkjet printing heads from clogging, and the higher the boiling point, the more beneficial it is for preventing clogging.

The dispersion aid may include at least one organic solvent, and the organic solvent can evaporate from the solvent system to form a film containing functional materials. The organic solvent may include at least one first organic solvent. In some embodiments, the first organic solvent may be an aromatic-based solvent or a heteroaromatic-based solvent. Specifically, the first organic solvent may be selected from p-diisopropylbenzene, pentyl benzene, tetrahydroa naphthyl group, cyclohexylbenzene, chloroa naphthyl group, 1,4-dimethyla naphthyl group, 3-isopropylbia phenyl group, p-methylisopropyl benzene, dipentyl benzene, tripentyl benzene, pentyl toluene, o-diethylbenzene, m-diethylbenzene, p-diethylbenzene, 1,2,3,4-tetratoluene, 1,2,3,5-tetratoluene, 1,2,4,5-tetratoluene, butadiene benzene, dodecylbenzene, dihexylbenzene, dibutylbenzene, p-diisopropylbenzene, cyclohexylbenzene, benzylbutylbenzene, dimethyla naphthyl group, 3-isopropylbia phenyl group, p-methylcumene, 1-methyla naphthyl group, 1,2,4-trichlorobenzene, 4,4-difluorodiphenylmethane, 1,2-dimethoxy-4-(1-propenyl) benzene, diphenylmethane, 2-phenylpyridine, 3-phenylpyridine, N-methyldiphenylamine, 4-isopropylbia phenyl group, α,α-dichlorodiphenylmethane, 4-(3-phenylpropyl) pyridine, benzyl benzoate, 1,1-bis(3,4-dimethylphenyl) ethane, 2-isopropyla naphthyl group, quinoline, isoquinoline, methyl 2-furanoate, ethyl 2-furanoate, or the like.

In some embodiments, the first organic solvent may be an aromatic ketone-based solvent. Specifically, the first organic solvent may be selected from 1-tetrahydronaphthalenone, 2-tetrahydronaphthalenone, 2-(phenyl epoxy) tetrahydronaphthalenone, 6-(methoxyl) tetrahydronaphthalenone, acetophenone, phenylacetone, benzophenone, and derivatives of these compounds. For example, the above-mentioned derivatives may be selected from at least one of 4-methylacetophenone, 3-methylacetophenone, 2-methylacetophenone, 4-methylphenylacetone, 3-methylphenylacetone, 2-methylphenylacetone, or the like.

In some embodiments, the first organic solvent may be an aromatic ether-based solvent. Specifically, the first organic solvent may be selected from 3-phenoxytoluene, butoxybenzene, p-anisaldehyde dimethyl acetal, tetrahydro-2-phenoxy-2H-pyran, 1,2-dimethoxy-4-(1-propenyl)benzene, 1,4-benzodioxane, 1,3-dipropylbenzene, 2,5-dimethoxytoluene, 4-ethylbasic ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-p-propenylanisole, 1,2-dimethoxybenzene, 1-methoxya naphthyl group, diphenyl ether, 2-phenoxymethyl ether, 2-phenoxytetrahydrofuran, ethyl-2-naphthyl ether, or the like.

In some embodiments, the first organic solvent may be an aliphatic ketone-based solvent. Specifically, the first organic solvent may be selected from 2-nonone, 3-nonone, 5-nonone, 2-decanone, 2,5-hexanedione, 2,6,8-trimethyl-4-nonone, fenchone, phorone, isophorone, and/or di-n-pentyl ketone. In some embodiments, the first organic solvent may be an aliphatic ether-based solvent, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, or the like.

In some embodiments, the first organic solvent may be an ester-based solvent. Specifically, the first organic solvent may be selected from octanoate, sebacate, stearate, benzoate, phenylacetate, cinnamate, oxalate, maleate, alkyl lactone, oleate, and the like. Preferably, the first organic solvent may be selected from octyl octanoate, diethyl sebacate, diallyl phthalate, isononyl isononanoate, or the like.

The organic solvent may further include a second organic solvent, and the second organic solvent may be selected from at least one of methanol, ethanol, 2-methoxyethanol, dichloromethane, chloroform, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethyl sulfoxide, tetralin, naphthane, and indene.

In some embodiments, other than the dispersion agent and the dispersion acid, the composition may further include one or more components such as a surfactant, a lubricant, a wetting agent, a hydrophobic agent, an adhesive, or the like., for adjusting viscosity, improving forming performance of a film and adhesion.

Exemplary preparation methods of the organic compound provided by the present disclosure are shown in the following exemplary examples 1 to 17.

### Example 1

### Synthesis of Organic Compound 1

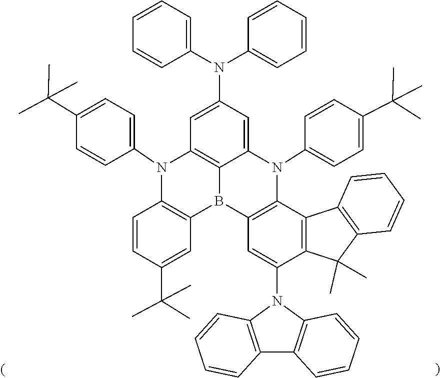 [SMILES: CC(C)(C)c1ccc(N2c3ccc(C(C)(C)C)cc3B3c4cc(-n5c6ccccc6c6ccccc65)c5c(c4N(c4ccc(C(C)(C)C)cc4)c4cc(N(c6ccccc6)c6ccccc6)cc2c43)-c2ccccc2C5(C)C)cc1]

Synthetic Route of the Organic Compound 1 is as follows:

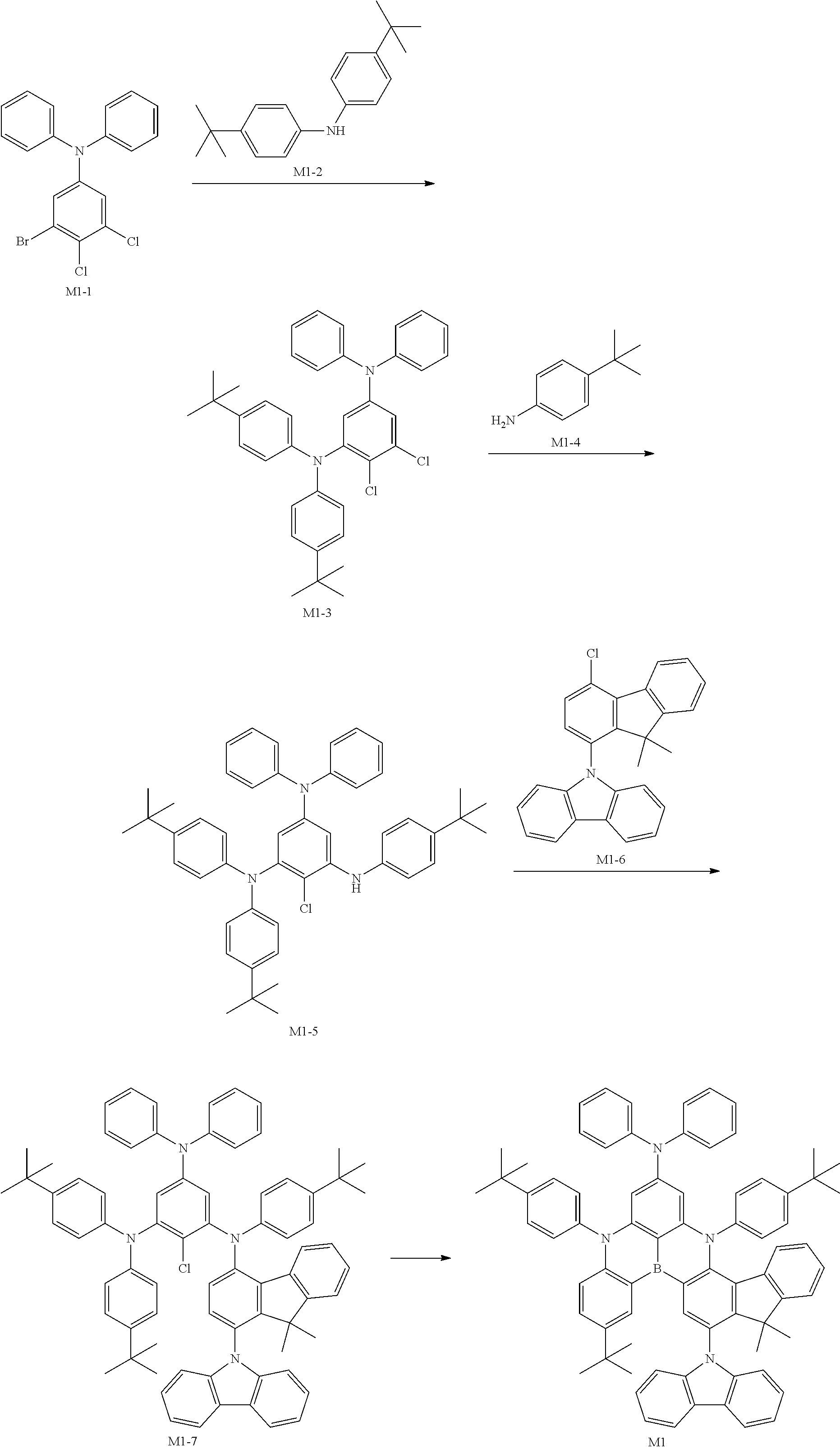

Synthesis steps of the Organic Compound M1 are as follows:

(1) Synthesis of Intermediate M1-3: in a nitrogen environment, intermediate M1-1 (39.3 g, 100 mmol), compound M1-2 (28.1 g, 100 mmol), bis(benzylidene)acetone-palladium (Pd₂(dba)₃, 2.76 g, 3 mmol), tert-butyl phosphine (1.2 g, 6 mmol), tert-butanol sodium (18.2 g, 200 mmol), and anhydrous toluene (250 mL) were mixed, heated to a temperature of 60° C., and stirred for 6 hours. After the reaction was completed, the reaction solution was cooled to room temperature and quenched with water. Most of the solvent was removed from the reaction solution by rotary evaporation. Then, the resultant reaction solution was dissolved with dichloromethane and washed with water three times. The organic liquid was collected and mixed with silica gel for column chromatography purification to obtain the intermediate M1-3 with yield of 70%.

(2) Synthesis of Intermediate M1-5: in a nitrogen environment, intermediate M1-3 (35.6 g, 60 mmol), compound M1-4 (8.9 g, 60 mmol), Pd₂(dba)₃ (1.66 g, 1.8 mmol), tert-butyl phosphine (0.72 g, 3.6 mmol), tert-butanol sodium (11 g, 120 mmol), and anhydrous toluene (150 mL) were mixed, heated to a temperature of 90° C., and stirred for 6 hours. After the reaction was completed, the reaction solution was cooled to room temperature and quenched with water. Most of the solvent was removed from the reaction solution by rotary evaporation. Then, the resultant reaction solution was dissolved with dichloromethane and washed with water three times. The organic liquid was collected and mixed with silica gel for column chromatography purification to obtain the intermediate M1-5 with yield of 65%.

(3) Synthesis of Intermediate M1-7: in a nitrogen environment, intermediate M1-6 (15.8 g, 40 mmol), compound M1-5 (28.2 g, 40 mmol), Pd₂(dba)₃ (1.1 g, 1.2 mmol), tert-butyl phosphine (0.48 g, 2.4 mmol), tert-butanol sodium (7.3 g, 80 mmol), and anhydrous toluene (100 mL) were mixed, heated to a temperature of 90° C., and stirred for 6 hours. After the reaction was completed, the reaction solution was cooled to room temperature and quenched with water. Most of the solvent was removed from the reaction solution by rotary evaporation. Then, the resultant reaction solution was dissolved with dichloromethane and washed with water three times. The organic liquid was collected and mixed with silica gel for column chromatography purification to obtain the intermediate M1-7 with yield of 68%.

(4) Synthesis of the Organic Compound M1: in a nitrogen environment, compound M1-7 (21.3 g, 20 mmol) and anhydrous tetrahydrofuran (100 mL) were mixed and cooled to a temperature of −30° C., then 25 mmol of tert-butyl lithium solution was slowly added into the solution. After the dripping was completed, the temperature of the reaction solution was raised to 60° C., stirred for 2 hours, and cooled to −30° C., then 30 mmol of boron tribromide was added at once. Subsequently, the temperature of the reaction solution was naturally raised to room temperature and carried out for 1 hours, then 40 mmol of N, N-diisopropylethylamine was added, the temperature of the reaction solution was slowly raised to 100° C. and the reaction was carried out for 3 hours. After the reaction was completed, the reaction solution was cooled to room temperature, and sodium acetate aqueous solution was added into the reaction solution to quench the reaction. Most of the solvent was removed by rotary evaporation to obtain a crude product. The crude product was dissolved with dichloromethane and washed with water three times. The organic liquid was collected and mixed with silica gel for column chromatography purification to obtain the organic compound M1 with yield of 28%. The result of the atmospheric pressure solid analysis probe-mass spectrometry (ASAP-MS) of the organic compound M1 was as follows: MS (ASAP)=1038.

### Example 2

### Synthesis of Organic Compound 2

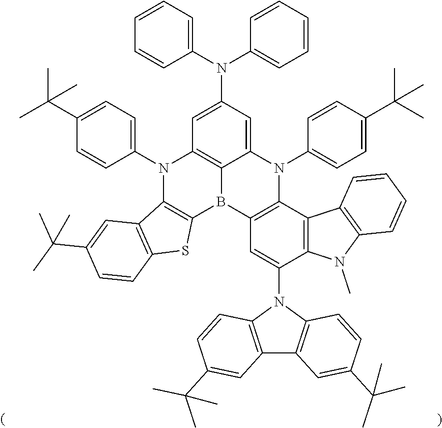 [SMILES: Cn1c2ccccc2c2c3c(cc(-n4c5ccc(C(C)(C)C)cc5c5cc(C(C)(C)C)ccc54)c21)B1c2sc4ccc(C(C)(C)C)cc4c2N(c2ccc(C(C)(C)C)cc2)c2cc(N(c4ccccc4)c4ccccc4)cc(c21)N3c1ccc(C(C)(C)C)cc1]

Synthetic Route of the Organic Compound 2 is as follows:

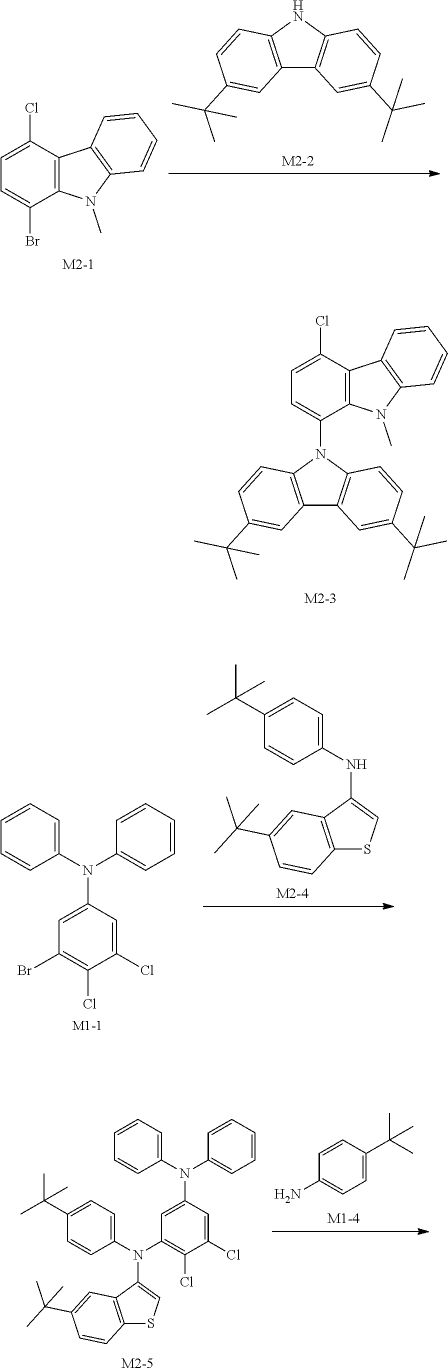

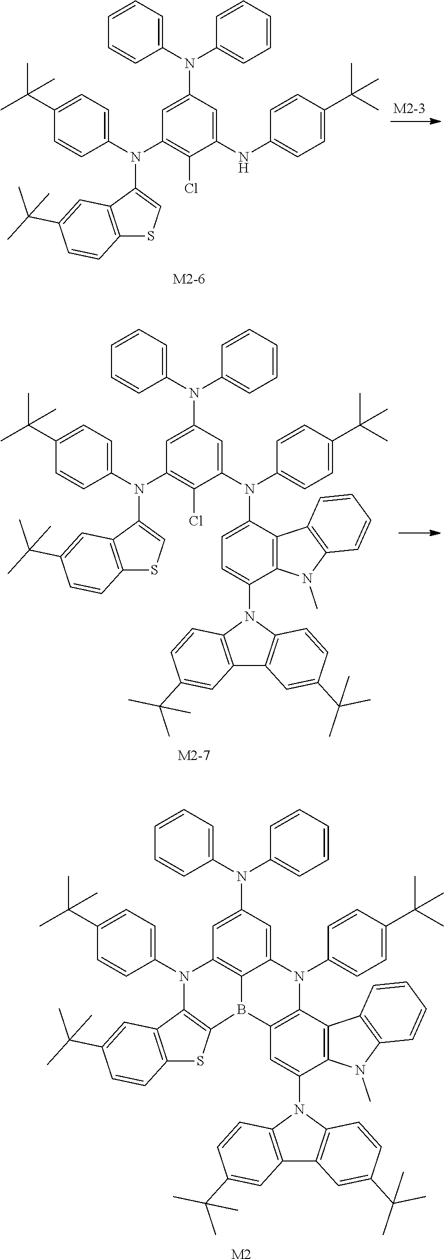

Synthesis steps of the Organic Compound M2 are as follows:

(1) Synthesis of Intermediate M2-3: in a nitrogen environment, compound M2-1 (29.5 g, 100 mmol), compound M2-2 (27.9 g, 100 mmol), cuprous iodide (9.5 g, 50 mmol), trans-1,2-cyclohexanediamine of (2.3 g, 20 mmol), tripotassium phosphate (21.2 g, 100 mmol), and xylene (500 mL) were added into a two necked flask (1000 mL), heated to a temperature of 100° C., and stirred for 12 hours. After the reaction was completed, the resultant reaction solution was cooled to room temperature and washed with water three times. The organic liquid was collected and purified by column chromatography after rotary evaporation to obtain the intermediate M2-3 with yield of 68%.

(2) Synthesis of Intermediate M2-5: according to the synthesis method of compound M1-3, compound M2-4 was substituted for compound M1-2 to obtain the intermediate M2-5 with yield of 72%.

(3) Synthesis of Intermediate M2-6: according to the synthesis method of compound M1-5, compound M2-5 was substituted for compound M1-3 to obtain the intermediate M2-6 with yield of 66%.

(4) Synthesis of Intermediate M2-7: according to the synthesis method of compound M1-7, compound M2-6 and compound M2-3 were substituted for compound M1-5 and compound 1-6, respectively, to obtain the intermediate M2-7 with yield of 67%.

(5) Synthesis of Organic Compound M2: according to the synthesis method of organic compound M1, compound M2-7 was substituted for compound M1-7 to obtain the organic compound M2 with yield of 26%. The result of the atmospheric pressure solid analysis probe-mass spectrometry (ASAP-MS) of the organic compound M2 was as follows: MS (ASAP)=1293.

### Example 3

### Synthesis of Organic Compound 3

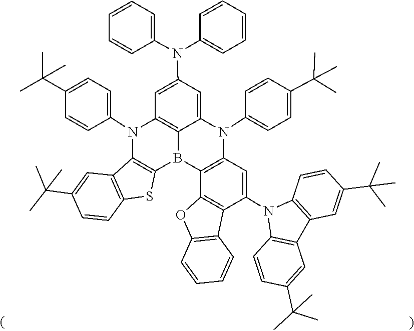 [SMILES: CC(C)(C)c1ccc(N2c3cc(N(c4ccccc4)c4ccccc4)cc4c3B(c3sc5ccc(C(C)(C)C)cc5c3N4c3ccc(C(C)(C)C)cc3)c3c2cc(-n2c4ccc(C(C)(C)C)cc4c4cc(C(C)(C)C)ccc42)c2c3oc3ccccc32)cc1]

Synthetic Route of the Organic Compound 3 is as follows:

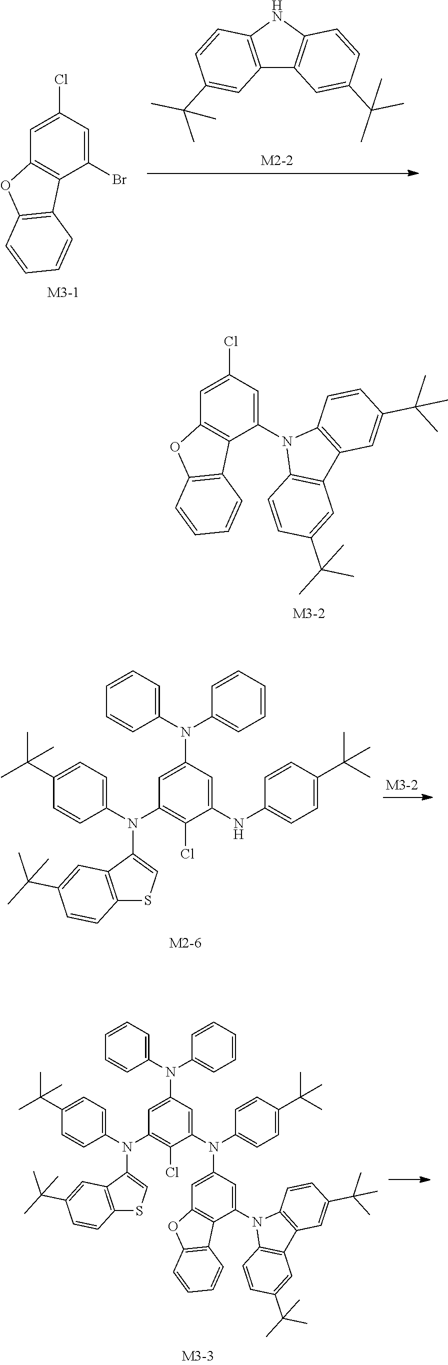

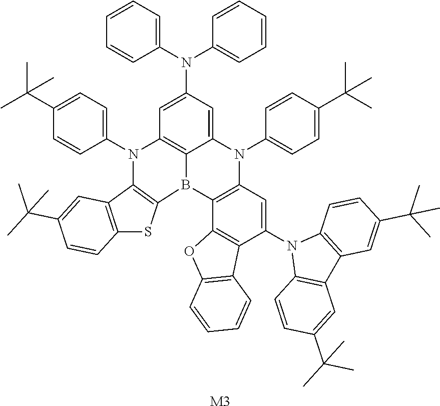 [SMILES: CC(C)(C)c1ccc(N2c3cc(N(c4ccccc4)c4ccccc4)cc4c3B(c3sc5ccc(C(C)(C)C)cc5c3N4c3ccc(C(C)(C)C)cc3)c3c2cc(-n2c4ccc(C(C)(C)C)cc4c4cc(C(C)(C)C)ccc42)c2c3oc3ccccc32)cc1 ; "M3"]

Synthesis steps of the Organic Compound M3 are as follows:

(1) Synthesis of Intermediate M3-2: according to the synthesis method of compound M2-3, compound M3-1 was substituted for compound M2-1 to obtain the intermediate M3-2 with yield of 70%.

(2) Synthesis of Intermediate M3-3: according to the synthesis method of compound M1-7, compound M2-6 and compound M3-2 were substituted for compound M1-5 and compound 1-6, respectively, to obtain the intermediate M3-3 with yield of 68%.

(3) Synthesis of Organic Compound M3: according to the synthesis method of organic compound M1, compound M3-3 was substituted for compound M1-7 to obtain the organic compound M3 with yield of 30%. The result of the atmospheric pressure solid analysis probe-mass spectrometry (ASAP-MS) of the organic compound M3 was as follows: MS (ASAP)=1180.

### Example 4

### Synthesis of Organic Compound

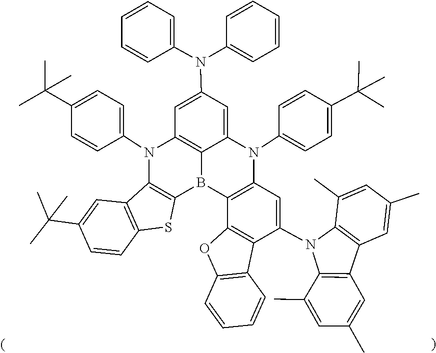 [SMILES: Cc1cc(C)c2c(c1)c1cc(C)cc(C)c1n2-c1cc2c(c3oc4ccccc4c13)B1c3sc4ccc(C(C)(C)C)cc4c3N(c3ccc(C(C)(C)C)cc3)c3cc(N(c4ccccc4)c4ccccc4)cc(c31)N2c1ccc(C(C)(C)C)cc1]

Synthetic Route of the Organic Compound 4 is as follows:

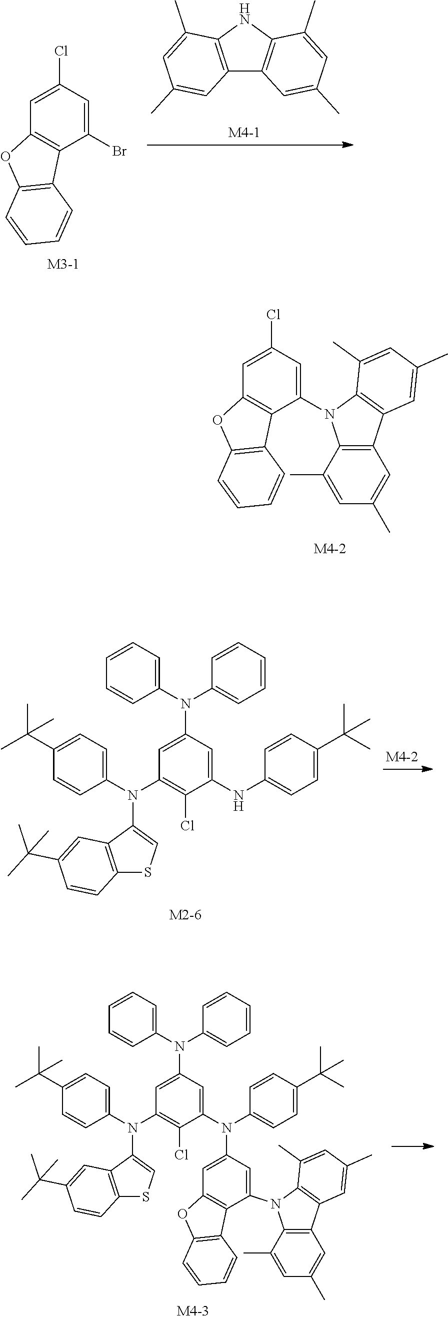

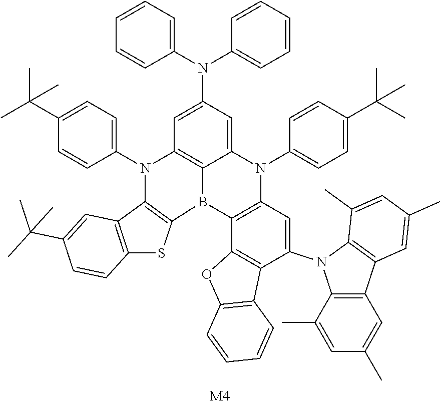

Synthesis steps of the Organic Compound M4 are as follows:

(1) Synthesis of Intermediate M4-2: according to the synthesis method of compound M2-3, compound M3-1 and compound M4-1 were substituted for compound M2-1 and compound M2-2, respectively, to obtain the intermediate M4-2 with yield of 65%.

(2) Synthesis of Intermediate M4-3: according to the synthesis method of compound M1-7, compound M2-6 and compound M4-2 were substituted for compound M1-5 and compound M1-6, respectively, to obtain the intermediate M4-3 with yield of 67%.

(3) Synthesis of Organic Compound M4: according to the synthesis method of organic compound M1, compound M4-3 was substituted for compound M1-7 to obtain the organic compound M4 with yield of 27%. The result of the atmospheric pressure solid analysis probe-mass spectrometry (ASAP-MS) of the organic compound M4 was as follows: MS (ASAP)=1123.

### Example 5

### Synthesis of Organic Compound 5

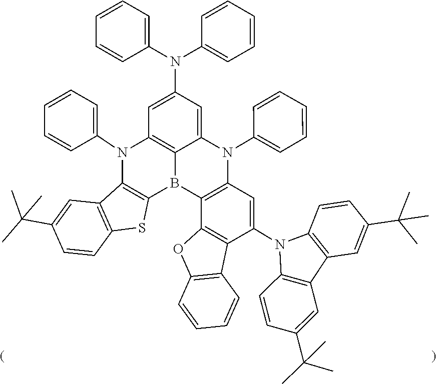 [SMILES: CC(C)(C)c1ccc2sc3c(c2c1)N(c1ccccc1)c1cc(N(c2ccccc2)c2ccccc2)cc2c1B3c1c(cc(-n3c4ccc(C(C)(C)C)cc4c4cc(C(C)(C)C)ccc43)c3c1oc1ccccc13)N2c1ccccc1]

Synthetic Route of the Organic Compound 5 is as follows:

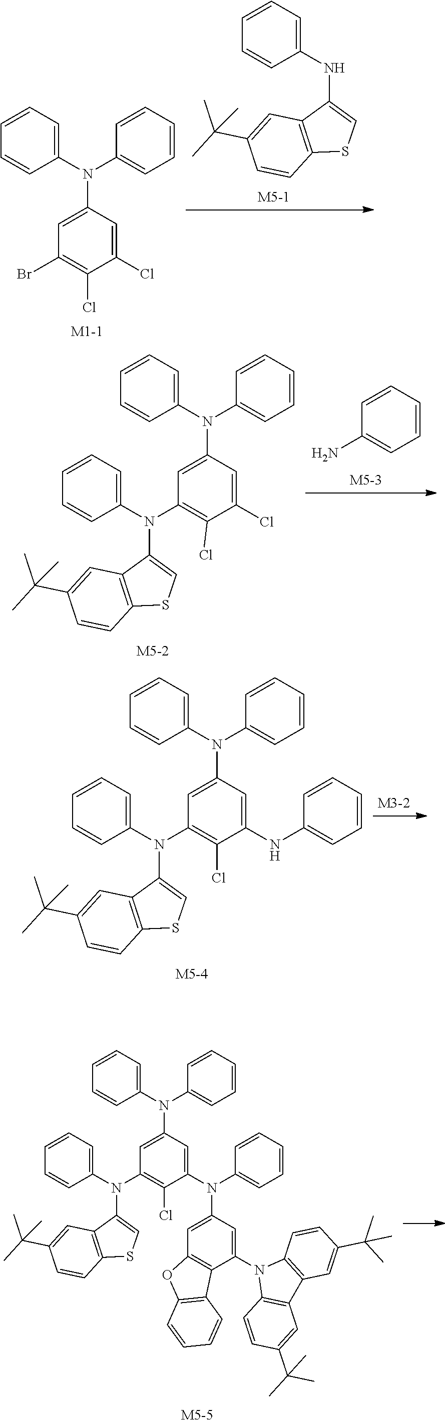

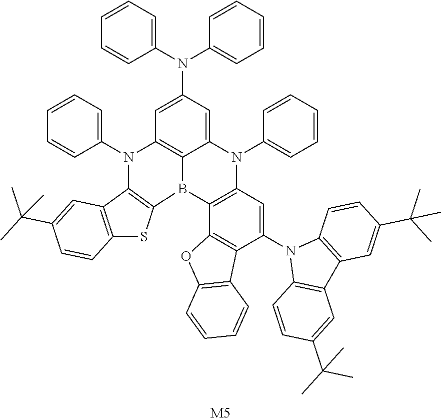 [SMILES: CC(C)(C)c1ccc2sc3c(c2c1)N(c1ccccc1)c1cc(N(c2ccccc2)c2ccccc2)cc2c1B3c1c(cc(-n3c4ccc(C(C)(C)C)cc4c4cc(C(C)(C)C)ccc43)c3c1oc1ccccc13)N2c1ccccc1 ; "M5"]

Synthesis steps of the Organic Compound M5 are as follows:

(1) Synthesis of Intermediate M5-2: according to the synthesis method of compound M1-3, compound M5-1 was substituted for compound M1-2 to obtain the intermediate M5-2 with yield of 74%.

(2) Synthesis of Intermediate M5-4: according to the synthesis method of compound M1-5, compound M5-2 and compound M5-3 were substituted for compound M1-3 and compound 1-4, respectively, to obtain the intermediate M5-4 with yield of 70%.

(3) Synthesis of Intermediate M5-5: according to the synthesis method of compound M1-7, compound M5-4 and compound M3-2 were substituted for compound M1-5 and compound 1-6, respectively, to obtain the intermediate M5-5 with yield of 72%.

(4) Synthesis of Organic Compound M5: according to the synthesis method of organic compound M1, compound M5-5 was substituted for compound M1-7 to obtain the organic compound M5 with yield of 29%. The result of the atmospheric pressure solid analysis probe-mass spectrometry (ASAP-MS) of the organic compound M5 was as follows: MS (ASAP)=1068.

### Example 6

### Synthesis of Organic Compound 6

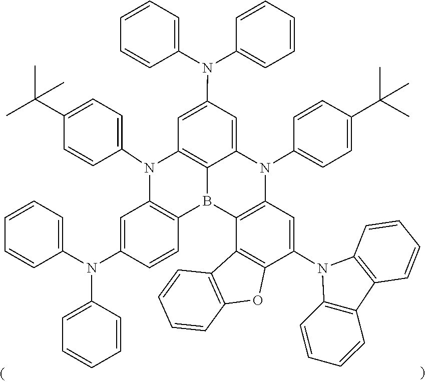 [SMILES: CC(C)(C)c1ccc(N2c3cc(N(c4ccccc4)c4ccccc4)ccc3B3c4c2cc(N(c2ccccc2)c2ccccc2)cc4N(c2ccc(C(C)(C)C)cc2)c2cc(-n4c5ccccc5c5ccccc54)c4oc5ccccc5c4c23)cc1]

Synthetic Route of the Organic Compound 6 is as follows:

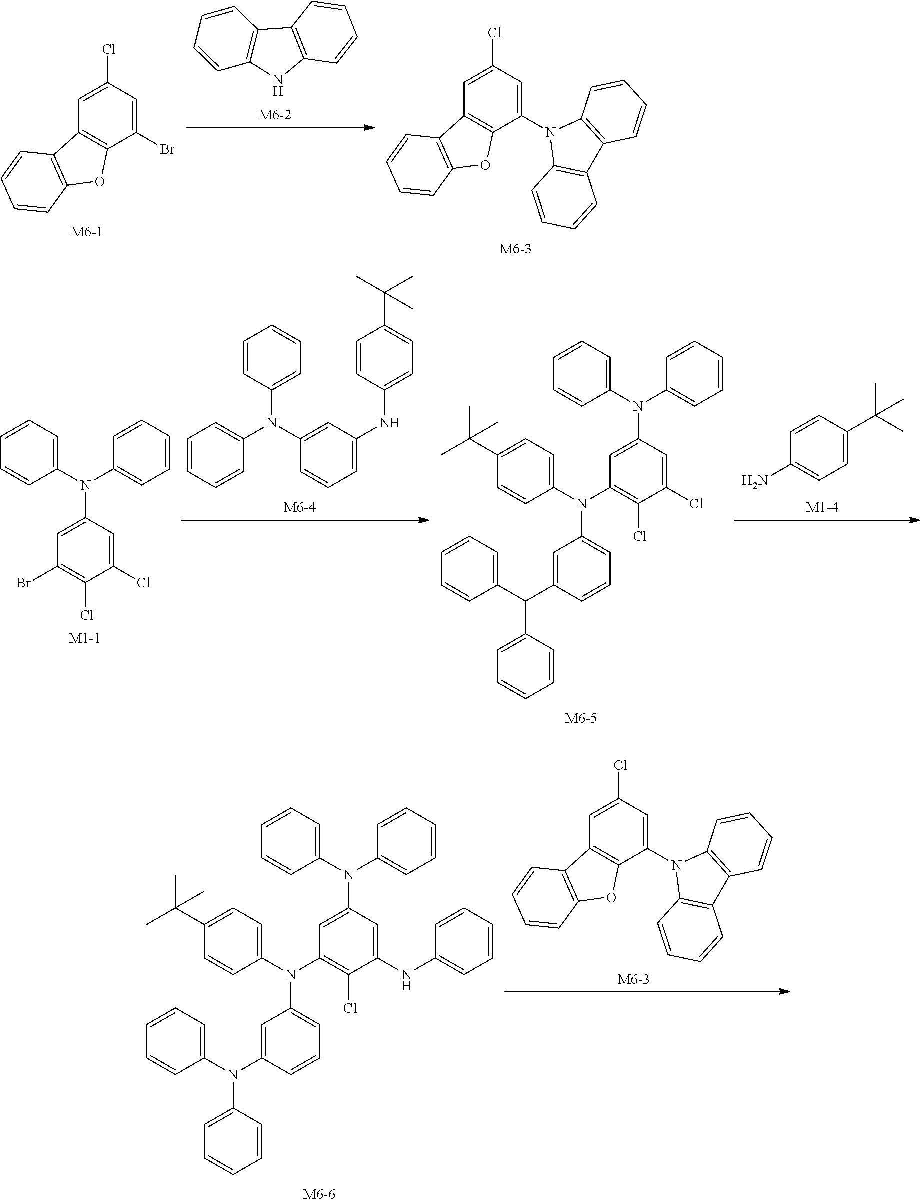

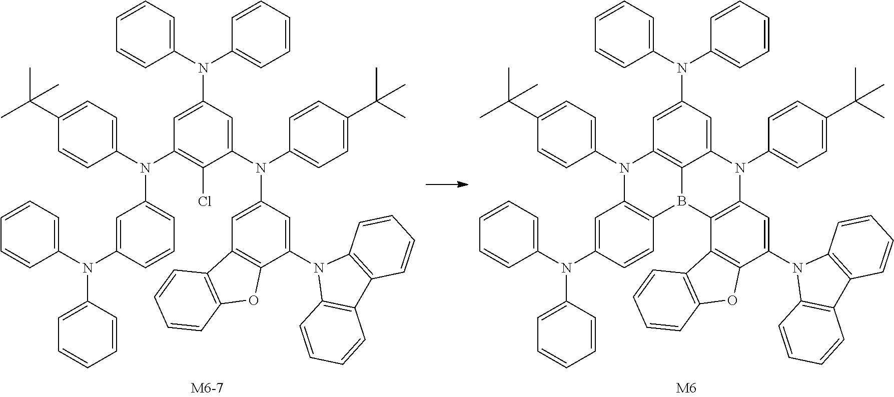 [SMILES: CC(C)(C)c1ccc(N(c2cccc(N(c3ccccc3)c3ccccc3)c2)c2cc(N(c3ccccc3)c3ccccc3)cc(N(c3ccc(C(C)(C)C)cc3)c3cc(-n4c5ccccc5c5ccccc54)c4oc5ccccc5c4c3)c2Cl)cc1 ; CC(C)(C)c1ccc(N2c3cc(N(c4ccccc4)c4ccccc4)ccc3B3c4c2cc(N(c2ccccc2)c2ccccc2)cc4N(c2ccc(C(C)(C)C)cc2)c2cc(-n4c5ccccc5c5ccccc54)c4oc5ccccc5c4c23)cc1 ; "M6"]

Synthesis steps of the Organic Compound M6 are as follows:

(1) Synthesis of Intermediate M6-3: according to the synthesis method of compound M2-3, compound M6-1 and compound M6-2 were substituted for compound M2-1 and compound M2-2, respectively, to obtain the intermediate M6-3 with yield of 70%.

(2) Synthesis of Intermediate M6-5: according to the synthesis method of compound M1-3, compound M6-4 was substituted for compound M1-2 to obtain the intermediate M6-5 with yield of 74%.

(3) Synthesis of Intermediate M6-6: according to the synthesis method of compound M1-5, compound M6-5 was substituted for compound M1-3 to obtain the intermediate M6-6 with yield of 68%.

(4) Synthesis of Intermediate M6-7: according to the synthesis method of compound M1-7, compound M6-6 and compound M6-3 were substituted for compound M1-5 and compound 1-6, respectively, to obtain the intermediate M6-7 with yield of 69%.

(5) Synthesis of Organic Compound M6: according to the synthesis method of organic compound M1, compound M6-7 was substituted for compound M1-7 to obtain the organic compound M6 with yield of 32%. The result of the atmospheric pressure solid analysis probe-mass spectrometry (ASAP-MS) of the organic compound M6 was as follows: MS (ASAP)=1123.

### Example 7

### Synthesis of Organic Compound 7

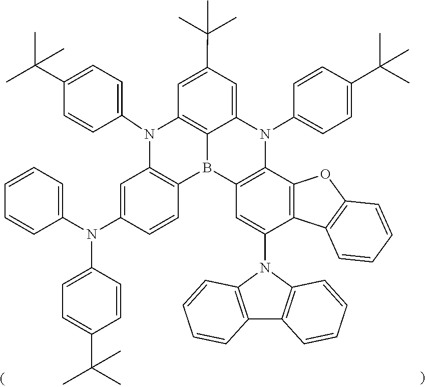 [SMILES: CC(C)(C)c1ccc(N(c2ccccc2)c2ccc3c(c2)N(c2ccc(C(C)(C)C)cc2)c2cc(C(C)(C)C)cc4c2B3c2cc(-n3c5ccccc5c5ccccc53)c3c(oc5ccccc53)c2N4c2ccc(C(C)(C)C)cc2)cc1]

Synthetic Route of the Organic Compound 7 is as follows:

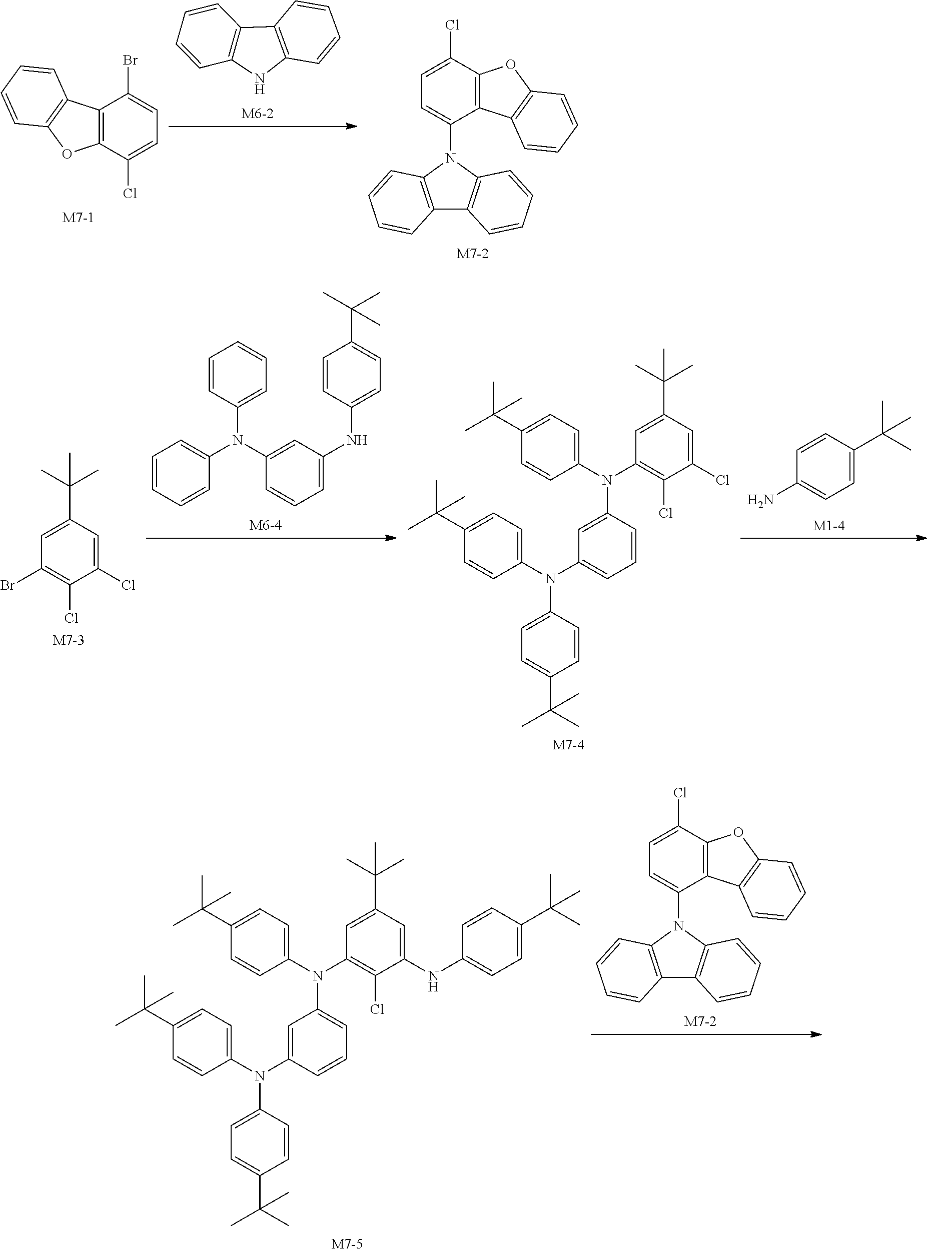

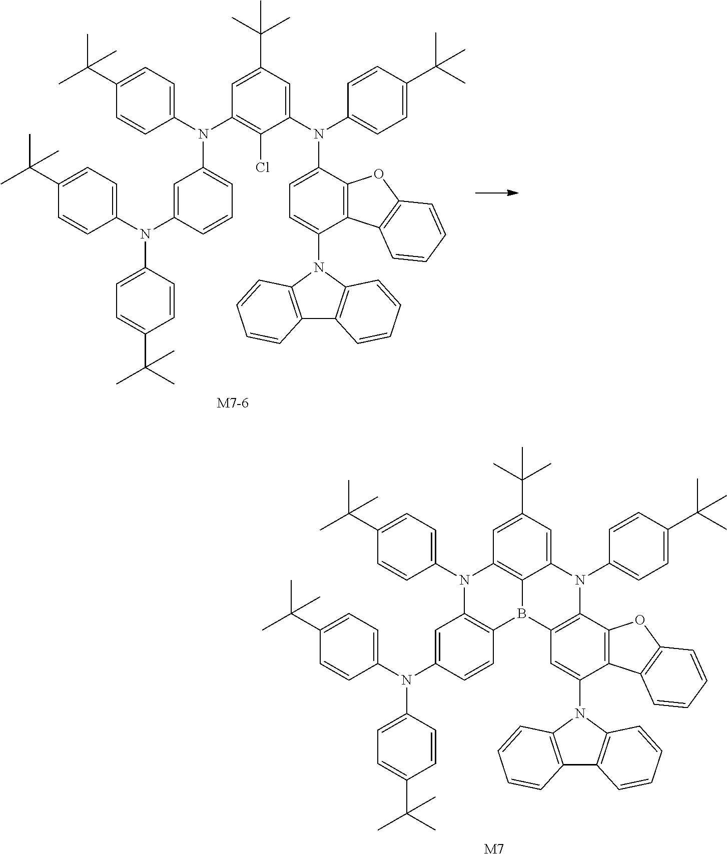

Synthesis steps of the Organic Compound M7 are as follows:

(1) Synthesis of Intermediate M7-2: according to the synthesis method of compound M2-3, compound M7-1 and compound M6-2 were substituted for compound M2-1 and compound M2-2, respectively, to obtain the intermediate M7-2 with yield of 71%.

(2) Synthesis of Intermediate M7-4: according to the synthesis method of compound M1-3, compound M7-3 and compound M6-4 were substituted for compound M1-1 and compound M1-2, respectively, to obtain the intermediate M7-4 with yield of 68%.

(3) Synthesis of Intermediate M7-5: according to the synthesis method of compound M1-5, compound M7-4 was substituted for compound M1-3 to obtain the intermediate M7-5 with yield of 67%.

(4) Synthesis of Intermediate M7-6: according to the synthesis method of compound M1-7, compound M7-5 and compound M7-2 were substituted for compound M1-5 and compound M1-6, respectively, to obtain the intermediate M7-6 with yield of 72%.

(5) Synthesis of Organic Compound M7: according to the synthesis method of organic compound M1, compound M7-6 was substituted for compound M1-7 to obtain the organic compound M7 with yield of 30%. The result of the atmospheric pressure solid analysis probe-mass spectrometry (ASAP-MS) of the organic compound M7 was as follows: MS (ASAP)=1124.

### Example 8

### Synthesis of Organic Compound 8

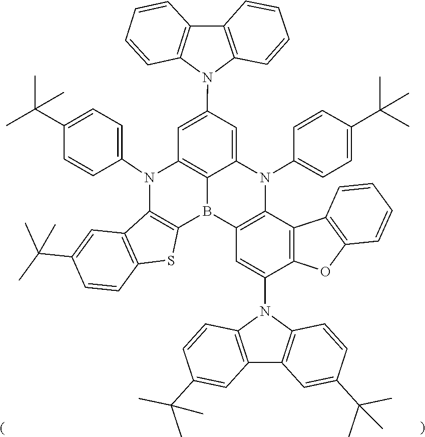 [SMILES: CC(C)(C)c1ccc(N2c3cc(-n4c5ccccc5c5ccccc54)cc4c3B(c3cc(-n5c6ccc(C(C)(C)C)cc6c6cc(C(C)(C)C)ccc65)c5oc6ccccc6c5c3N4c3ccc(C(C)(C)C)cc3)c3sc4ccc(C(C)(C)C)cc4c32)cc1]

Synthetic Route of the Organic Compound 8 is as follows:

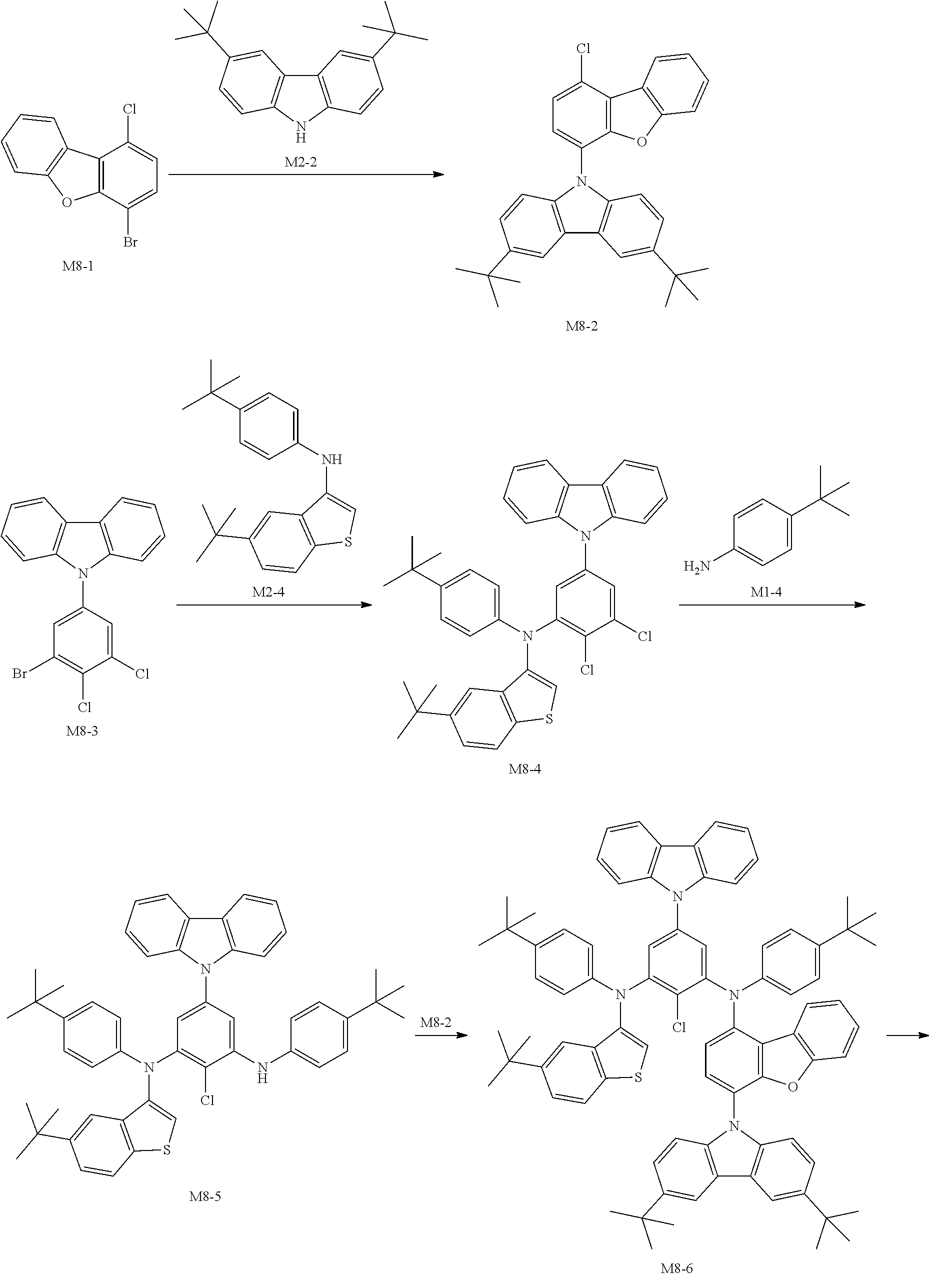

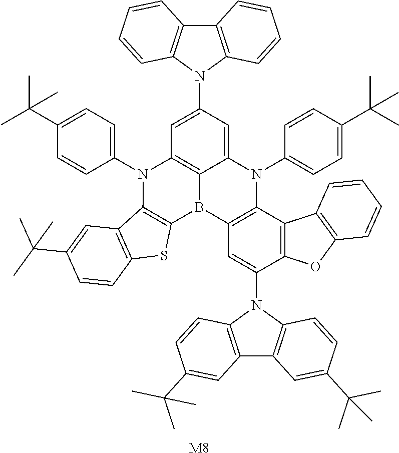

Synthesis steps of the Organic Compound M8 are as follows:

(1) Synthesis of Intermediate M8-2: according to the synthesis method of compound M2-3, compound M8-1 was substituted for compound M2-1 to obtain the intermediate M8-2 with yield of 70%.

(2) Synthesis of Intermediate M8-4: according to the synthesis method of compound M1-3, compound M8-3 and compound M2-4 were substituted for compound M1-1 and compound M1-2, respectively, to obtain the intermediate M8-4 with yield of 67%.

(3) Synthesis of Intermediate M8-5: according to the synthesis method of compound M1-5, compound M8-4 was substituted for compound M1-3 to obtain the intermediate M8-5 with yield of 66%.

(4) Synthesis of Intermediate M8-6: according to the synthesis method of compound M1-7, compound M8-5 and compound M8-2 were substituted for compound M1-5 and compound M1-6, respectively, to obtain the intermediate M8-6 with yield of 71%.

(5) Synthesis of Organic Compound M8: according to the synthesis method of organic compound M1, compound M8-6 was substituted for compound M1-7 to obtain the organic compound M8 with yield of 27%. The result of the atmospheric pressure solid analysis probe-mass spectrometry (ASAP-MS) of the organic compound M8 was as follows: MS (ASAP)=1178.

### Example 9

### Synthesis of Organic Compound 9

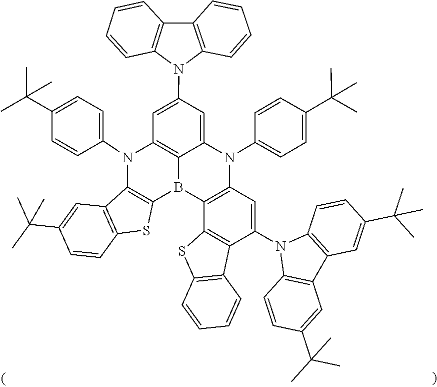 [SMILES: CC(C)(C)c1ccc(N2c3cc(-n4c5ccccc5c5ccccc54)cc4c3B(c3sc5ccc(C(C)(C)C)cc5c3N4c3ccc(C(C)(C)C)cc3)c3c2cc(-n2c4ccc(C(C)(C)C)cc4c4cc(C(C)(C)C)ccc42)c2c3sc3ccccc32)cc1]

Synthetic Route of the Organic Compound 9 is as follows:

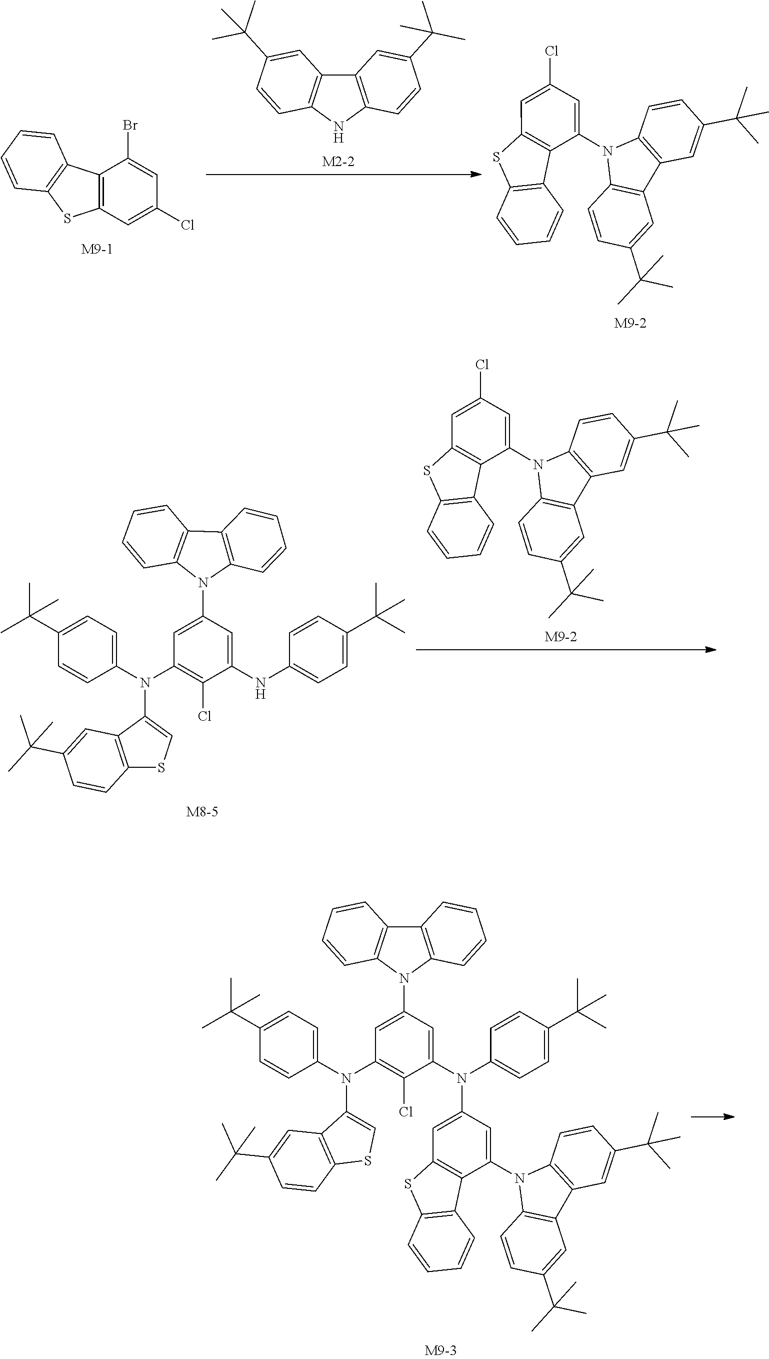 [SMILES: Clc1cc(Br)c2c(c1)sc1ccccc12 ; CC(C)(C)c1ccc2[nH]c3ccc(C(C)(C)C)cc3c2c1 ; CC(C)(C)c1ccc2c(c1)c1cc(C(C)(C)C)ccc1n2-c1cc(Cl)cc2sc3ccccc3c12 ; CC(C)(C)c1ccc(Nc2cc(-n3c4ccccc4c4ccccc43)cc(N(c3ccc(C(C)(C)C)cc3)c3csc4ccc(C(C)(C)C)cc34)c2Cl)cc1 ; CC(C)(C)c1ccc2c(c1)c1cc(C(C)(C)C)ccc1n2-c1cc(Cl)cc2sc3ccccc3c12 ; CC(C)(C)c1ccc(N(c2cc(-n3c4ccc(C(C)(C)C)cc4c4cc(C(C)(C)C)ccc43)c3c(c2)sc2ccccc23)c2cc(-n3c4ccccc4c4ccccc43)cc(N(c3ccc(C(C)(C)C)cc3)c3csc4ccc(C(C)(C)C)cc34)c2Cl)cc1]

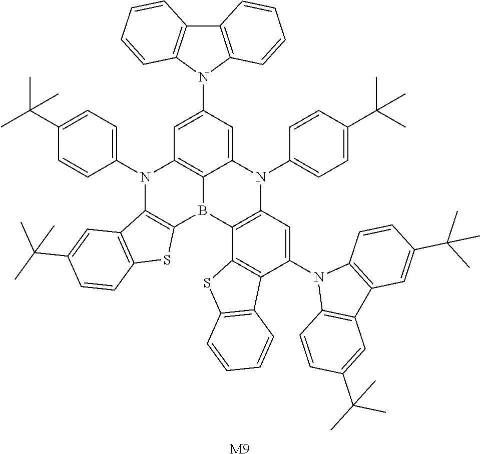 [SMILES: CC(C)(C)c1ccc(N2c3cc(-n4c5ccccc5c5ccccc54)cc4c3B(c3sc5ccc(C(C)(C)C)cc5c3N4c3ccc(C(C)(C)C)cc3)c3c2cc(-n2c4ccc(C(C)(C)C)cc4c4cc(C(C)(C)C)ccc42)c2c3sc3ccccc32)cc1 ; "M9"]

Synthesis steps of the Organic Compound M9 are as follows:

(1) Synthesis of Intermediate M9-2: according to the synthesis method of compound M2-3, compound M9-1 was substituted for compound M2-1 to obtain the intermediate M9-2 with yield of 72%.

(2) Synthesis of Intermediate M9-3: according to the synthesis method of compound M1-7, compound M8-5 and compound M9-2 were substituted for compound M1-5 and compound 1-6, respectively, to obtain the intermediate M9-3 with yield of 70%.

(3) Synthesis of Organic Compound M9: according to the synthesis method of organic compound M1, compound M9-3 was substituted for compound M1-7 to obtain the organic compound M9 with yield of 29%. The result of the atmospheric pressure solid analysis probe-mass spectrometry (ASAP-MS) of the organic compound M9 was as follows: MS (ASAP)=1194.

### Example 10

### Synthesis of Organic Compound 10

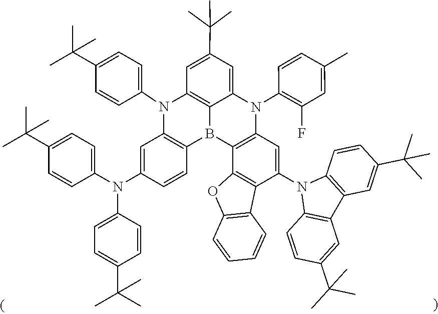 [SMILES: Cc1ccc(N2c3cc(C(C)(C)C)cc4c3B(c3ccc(N(c5ccc(C(C)(C)C)cc5)c5ccc(C(C)(C)C)cc5)cc3N4c3ccc(C(C)(C)C)cc3)c3c2cc(-n2c4ccc(C(C)(C)C)cc4c4cc(C(C)(C)C)ccc42)c2c3oc3ccccc32)c(F)c1]

Synthetic Route of the Organic Compound 10 is as follows:

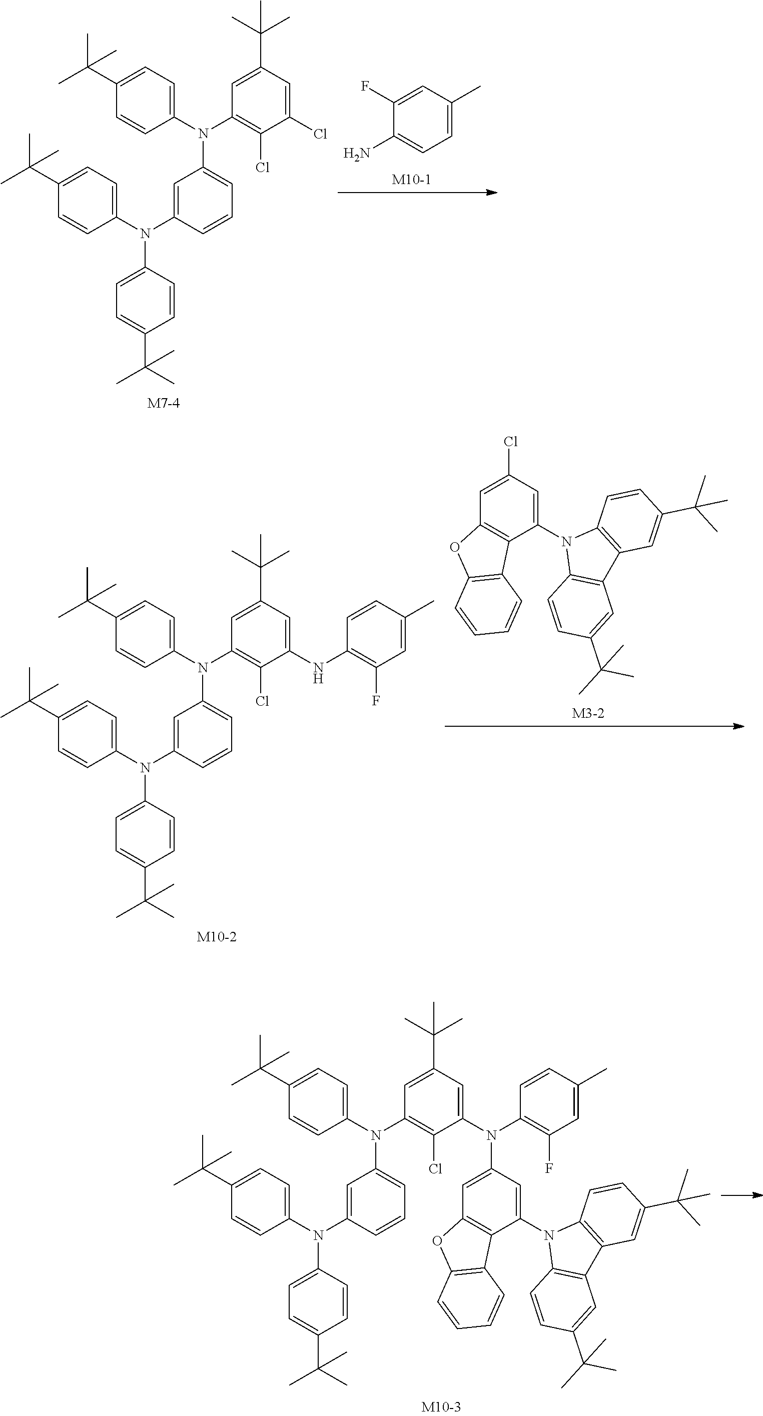

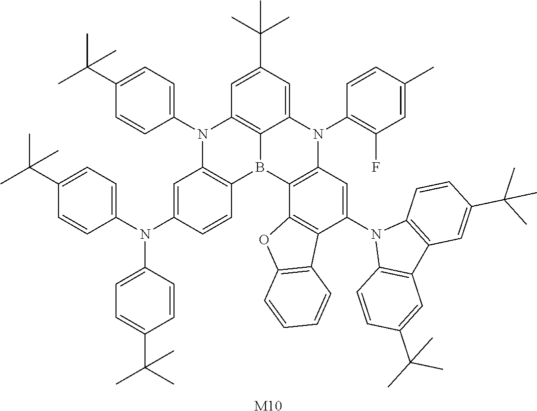 [SMILES: Cc1ccc(N2c3cc(C(C)(C)C)cc4c3B(c3ccc(N(c5ccc(C(C)(C)C)cc5)c5ccc(C(C)(C)C)cc5)cc3N4c3ccc(C(C)(C)C)cc3)c3c2cc(-n2c4ccc(C(C)(C)C)cc4c4cc(C(C)(C)C)ccc42)c2c3oc3ccccc32)c(F)c1 ; "M10"]

Synthesis steps of the Organic Compound M10 are as follows:

(1) Synthesis of Intermediate M10-2: according to the synthesis method of compound M1-5, compound M7-4 and compound M10-2 were substituted for compound M1-3 and compound M1-4, respectively, to obtain the intermediate M10-2 with yield of 65%.

(2) Synthesis of Intermediate M10-3: according to the synthesis method of compound M1-7, compound M10-2 and compound M3-2 were substituted for compound M1-5 and compound M1-6, respectively, to obtain the intermediate M10-3 with yield of 70%.

(3) Synthesis of Organic Compound M10: according to the synthesis method of organic compound M1, compound M10-3 was substituted for compound M1-7 to obtain the organic compound M10 with yield of 26%. The result of the atmospheric pressure solid analysis probe-mass spectrometry (ASAP-MS) of the organic compound M10 was as follows: MS (ASAP)=1212.

### Example 11

### Synthesis of Organic Compound 11

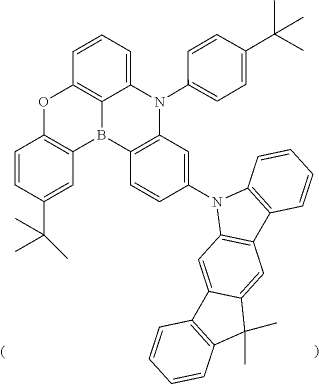 [SMILES: CC(C)(C)c1ccc(N2c3cc(-n4c5ccccc5c5cc6c(cc54)-c4ccccc4C6(C)C)ccc3B3c4cc(C(C)(C)C)ccc4Oc4cccc2c43)cc1]

Synthetic Route of the Organic Compound 11 is as follows:

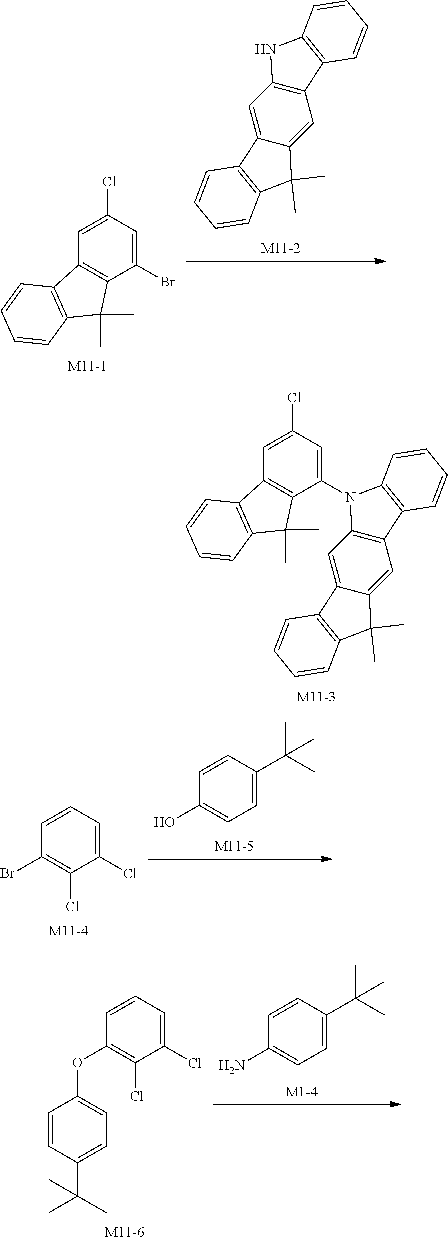

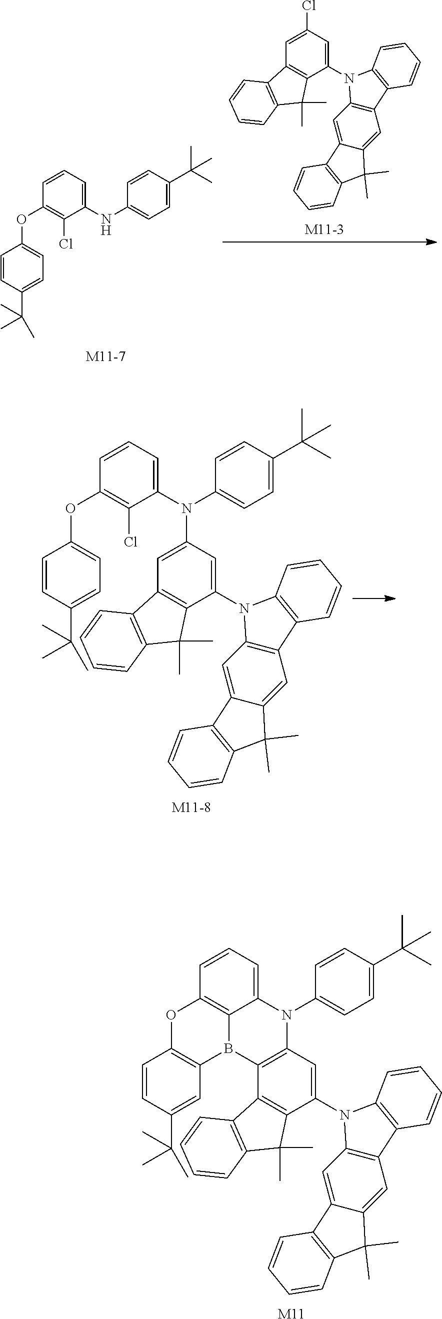

Synthesis steps of the Organic Compound M11 are as follows:

(1) Synthesis of Intermediate M11-3: according to the synthesis method of compound M2-3, compound M11-1 and compound M11-2 were substituted for compound M2-1 and compound M2-2, respectively, to obtain the intermediate M11-3 with yield of 67%.

(2) Synthesis of Intermediate M11-6: in a nitrogen environment, compound M11-4 (19.8 g, 100 mmol), compound M11-5 (9 g, 100 mmol), CuI (1.14 g, 6 mmol), potassium carbonate (20.7 g, 150 mmol), and dimethyl formamide (200 mL) were added into a two necked flask (500 mL), heated to a temperature of 110° C., and stirred for 12 hours. After the reaction was completed, the resultant reaction solution was cooled to room temperature, dissolved with dichloromethane, and washed with water three times. The organic liquid was collected and mixed with silica gel for column chromatography purification to obtain the intermediate M11-6 with yield of 68%.

(3) Synthesis of Intermediate M11-7: according to the synthesis method of compound M1-5, compound M11-6 was substituted for compound M1-3 to obtain the intermediate M11-7 with yield of 65%.

(4) Synthesis of Intermediate M11-8: according to the synthesis method of compound M1-7, compound M11-7 and compound M11-3 were substituted for compound M1-5 and compound 1-6, respectively, to obtain the intermediate M11-8 with yield of 70%.

(5) Synthesis of Organic Compound M11: according to the synthesis method of organic compound M1, compound M11-8 was substituted for compound M1-7 to obtain the organic compound M11 with yield of 32%. The result of the atmospheric pressure solid analysis probe-mass spectrometry (ASAP-MS) of the organic compound M11 was as follows: MS (ASAP)=855.

### Example 12

### Synthesis of Organic Compound 12

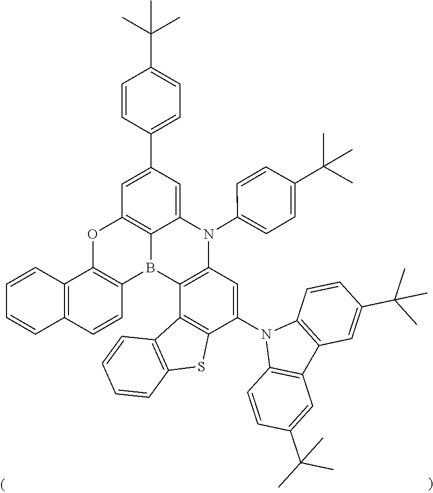 [SMILES: CC(C)(C)c1ccc(-c2cc3c4c(c2)N(c2ccc(C(C)(C)C)cc2)c2cc(-n5c6ccc(C(C)(C)C)cc6c6cc(C(C)(C)C)ccc65)c5sc6ccccc6c5c2B4c2ccc4ccccc4c2O3)cc1]

Synthetic Route of the Organic Compound 12 is as follows:

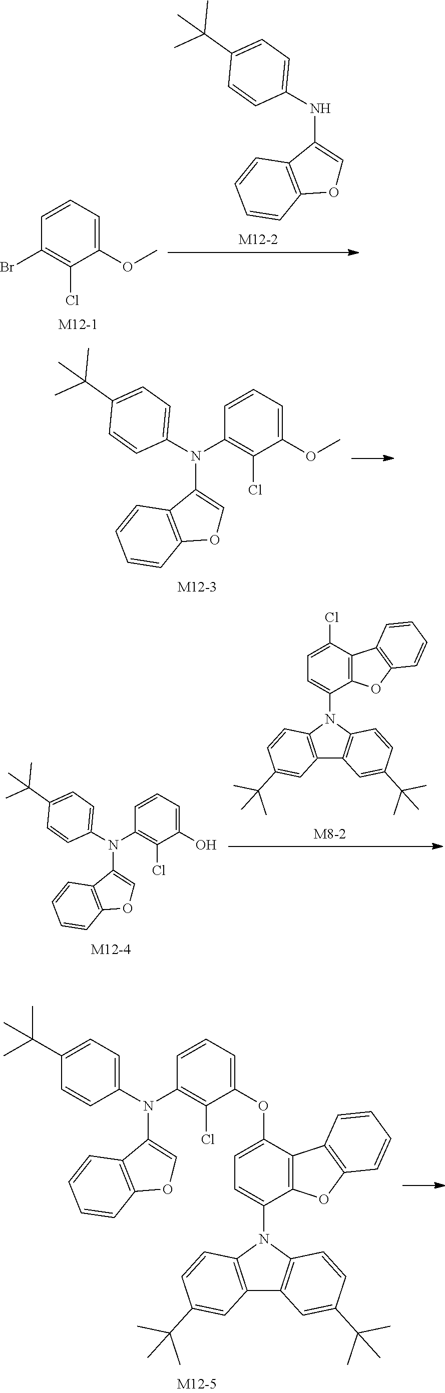

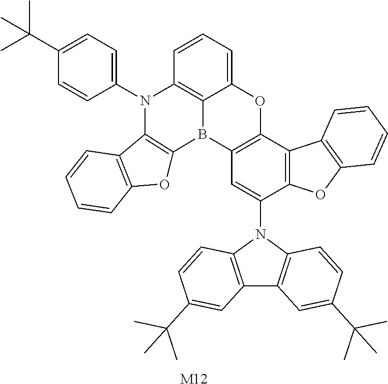

Synthesis steps of the Organic Compound M12 are as follows:

(1) Synthesis of Intermediate M12-3: according to the synthesis method of compound M1-3, compound M12-1 and compound M12-2 were substituted for compound M1-1 and compound M1-2, respectively, to obtain the intermediate M12-3 with yield of 72%.

(2) Synthesis of Intermediate M12-4: in a nitrogen environment, compound M12-3 (24.4 g, 60 mmol) and dichloromethane (100 mL) were added into a three necked flask (500 mL), stirred and dissolved. Boron tribromide (15.1 g, 60 mmol) was added into the solution in batches, then the reaction was stirred and carried out for 6 hours. After the reaction was completed, the reaction solution was poured into 300 mL of water and washed with water three times. The organic liquid was collected and mixed with silica gel for column chromatography purification to obtain the intermediate M12-4 with yield of 78%.

(3) Synthesis of Intermediate M12-5: according to the synthesis method of compound M11-6, compound M12-4 and compound M8-2 were substituted for compound M11-5 and compound M11-4, respectively, to obtain the intermediate M12-5 with yield of 65%.

(4) Synthesis of Organic Compound M12: according to the synthesis method of organic compound M1, compound M12-5 was substituted for compound M1-7 to obtain the organic compound M12 with yield of 30%. The result of the atmospheric pressure solid analysis probe-mass spectrometry (ASAP-MS) of the organic compound M12 was as follows: MS (ASAP)=809.

### Example 13

### Synthesis of Organic Compound 13

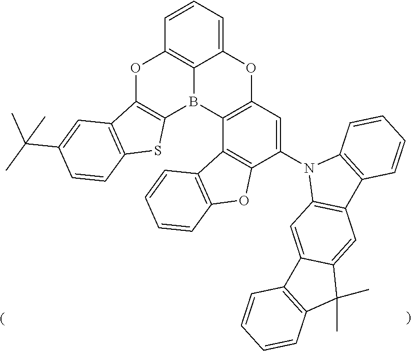 [SMILES: CC(C)(C)c1ccc2sc3c(c2c1)Oc1cccc2c1B3c1c(cc(-n3c4ccccc4c4cc5c(cc43)-c3ccccc3C5(C)C)c3oc4ccccc4c13)O2]

Synthetic Route of the Organic Compound 13 is as follows:

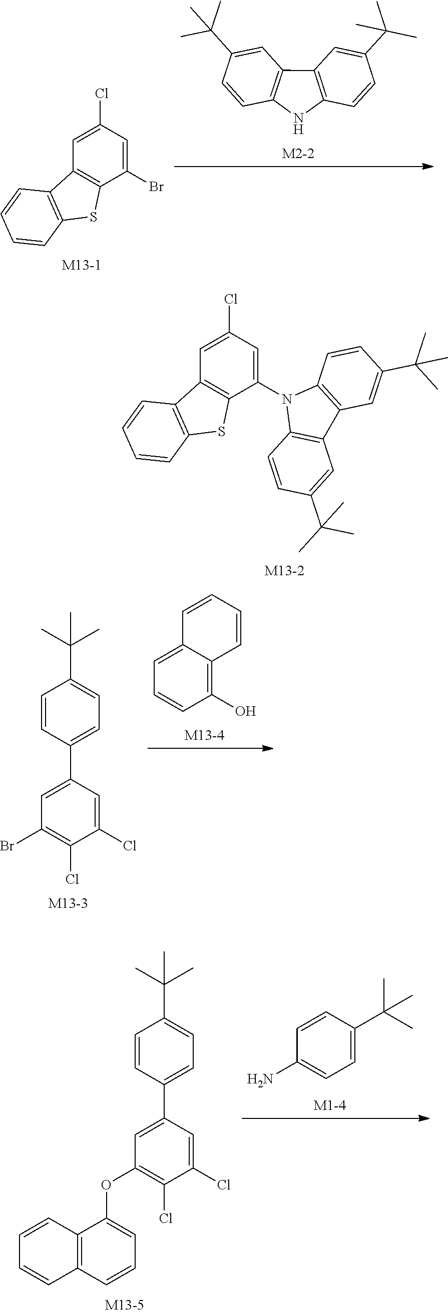

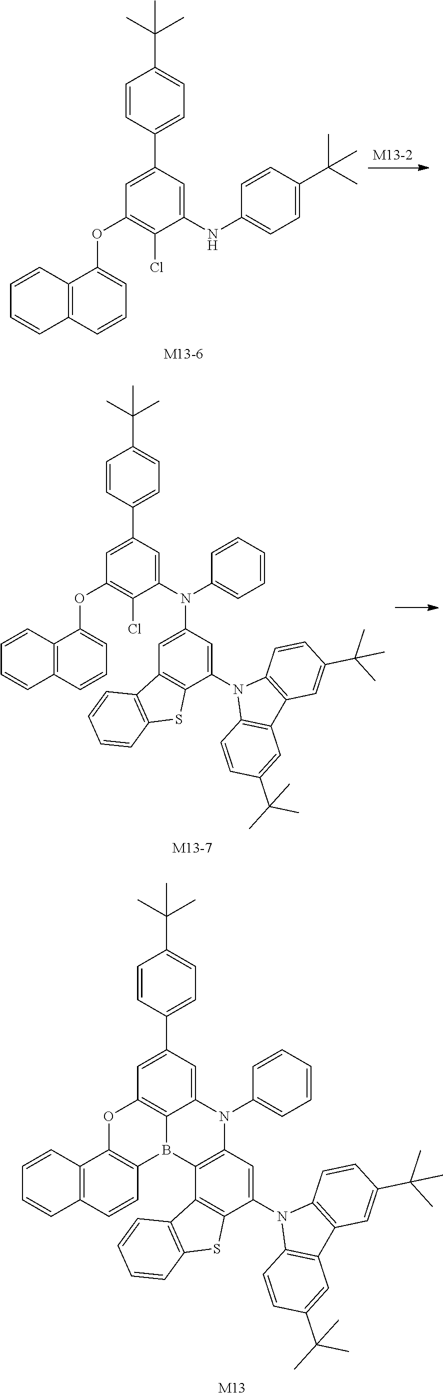 [SMILES: CC(C)(C)c1ccc(Nc2cc(-c3ccc(C(C)(C)C)cc3)cc(Oc3cccc4ccccc34)c2Cl)cc1 ; CC(C)(C)c1ccc(-c2cc(Oc3cccc4ccccc34)c(Cl)c(N(c3ccccc3)c3cc(-n4c5ccc(C(C)(C)C)cc5c5cc(C(C)(C)C)ccc54)c4sc5ccccc5c4c3)c2)cc1 ; CC(C)(C)c1ccc(-c2cc3c4c(c2)N(c2ccccc2)c2cc(-n5c6ccc(C(C)(C)C)cc6c6cc(C(C)(C)C)ccc65)c5sc6ccccc6c5c2B4c2ccc4ccccc4c2O3)cc1 ; "M13"]

Synthesis steps of the Organic Compound M13 are as follows:

(1) Synthesis of Intermediate M13-2: according to the synthesis method of compound M2-3, compound M13-1 was substituted for compound M2-2 to obtain the intermediate M13-2 with yield of 69%.

(2) Synthesis of Intermediate M13-5: according to the synthesis method of compound M11-6, compound M13-3 and compound M13-4 were substituted for compound M11-4 and compound M11-5, respectively, to obtain the intermediate M13-5 with yield of 72%.

(3) Synthesis of Intermediate M13-6: according to the synthesis method of compound M1-5, compound M13-5 was substituted for compound M1-3 to obtain the intermediate M13-6 with yield of 67%.

(4) Synthesis of Intermediate M13-7: according to the synthesis method of compound M1-7, compound M13-6 and compound M13-2 were substituted for compound M1-5 and compound M1-6, respectively, to obtain the intermediate M13-7 with yield of 68%.

(5) Synthesis of Organic Compound M13: according to the synthesis method of organic compound M1, compound M13-7 was substituted for compound M1-7 to obtain the organic compound M13 with yield of 31%. The result of the atmospheric pressure solid analysis probe-mass spectrometry (ASAP-MS) of the organic compound M13 was as follows: MS (ASAP)=968.

### Example 14

### Synthesis of Organic Compound 14

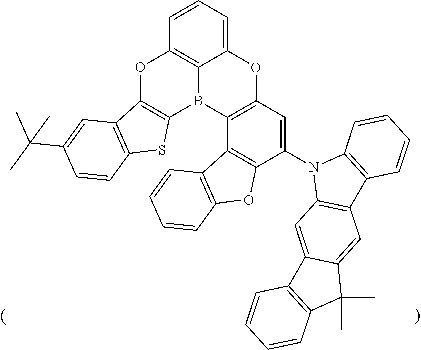 [SMILES: CC(C)(C)c1ccc2sc3c(c2c1)Oc1cccc2c1B3c1c(cc(-n3c4ccccc4c4cc5c(cc43)-c3ccccc3C5(C)C)c3oc4ccccc4c13)O2]

Synthetic Route of the Organic Compound 14 is as follows:

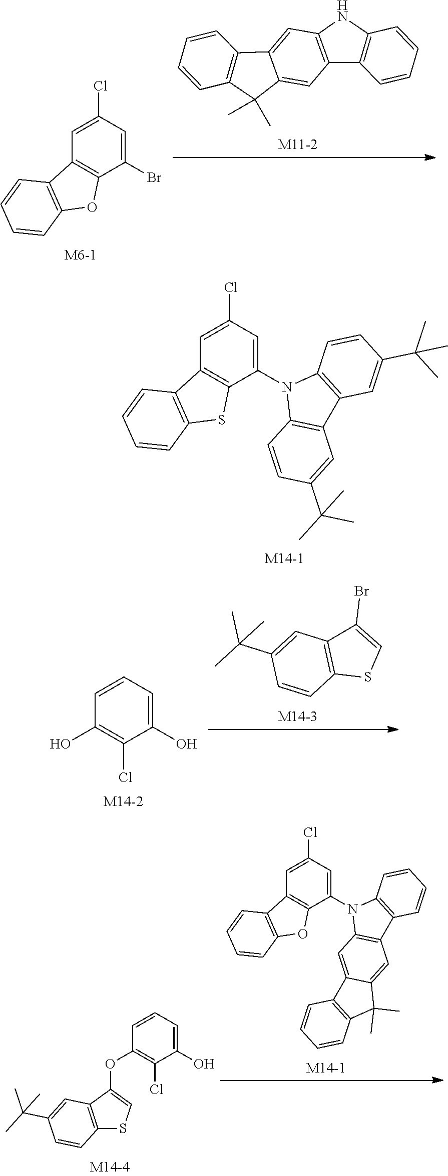

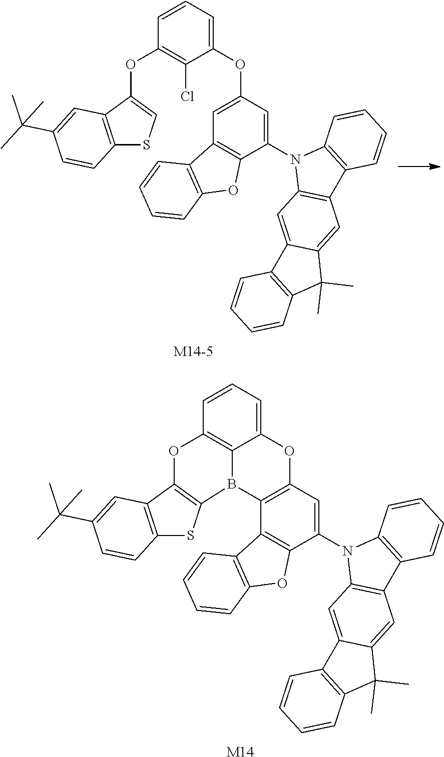 [SMILES: CC(C)(C)c1ccc2scc(Oc3cccc(Oc4cc(-n5c6ccccc6c6cc7c(cc65)-c5ccccc5C7(C)C)c5oc6ccccc6c5c4)c3Cl)c2c1 ; CC(C)(C)c1ccc2sc3c(c2c1)Oc1cccc2c1B3c1c(cc(-n3c4ccccc4c4cc5c(cc43)-c3ccccc3C5(C)C)c3oc4ccccc4c13)O2 ; "M14"]

Synthesis steps of the Organic Compound M14 are as follows:

(1) Synthesis of Intermediate M14-1: according to the synthesis method of compound M2-3, compound M6-1 and compound M11-2 were substituted for compound M2-1 and compound M2-2, respectively, to obtain the intermediate M14-1 with yield of 68%.

(2) Synthesis of Intermediate M14-4: according to the synthesis method of compound M11-6, compound M14-3 and compound M14-2 were substituted for compound M11-4 and compound M11-5, respectively, to obtain the intermediate M14-4 with yield of 65%.

(3) Synthesis of Intermediate M14-5: according to the synthesis method of compound M11-6, compound M14-1 and compound M14-4 were substituted for compound M11-4 and compound M11-5, respectively, to obtain the intermediate M14-5 with yield of 72%.

(4) Synthesis of Organic Compound M14: according to the synthesis method of organic compound M1, compound M14-5 was substituted for compound M1-7 to obtain the organic compound M14 with yield of 33%. The result of the atmospheric pressure solid analysis probe-mass spectrometry (ASAP-MS) of the organic compound M14 was as follows: MS (ASAP)=754.

### Example 15

### Synthesis of Organic Compound 15

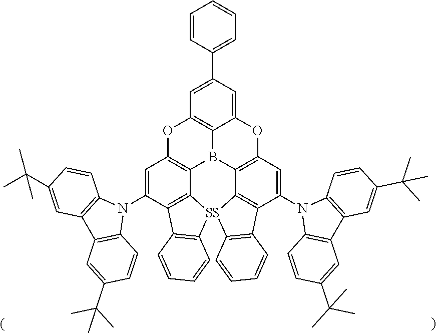 [SMILES: CC(C)(C)c1ccc2c(c1)c1cc(C(C)(C)C)ccc1n2-c1cc2c(c3sc4ccccc4c13)B1c3c(cc(-c4ccccc4)cc3Oc3cc(-n4c5ccc(C(C)(C)C)cc5c5cc(C(C)(C)C)ccc54)c4c(sc5ccccc54)c31)O2]

Synthetic Route of the Organic Compound 15 is as follows:

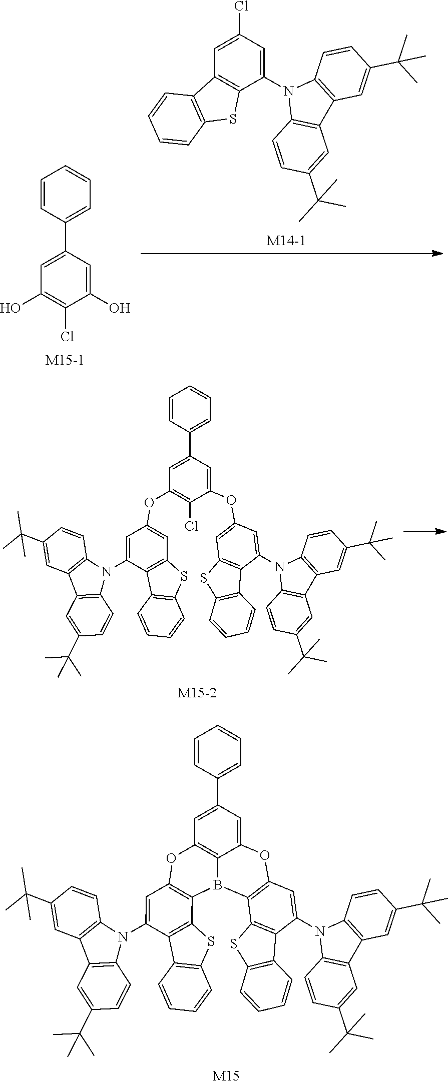

Synthesis steps of the Organic Compound M15 are as follows:

(1) Synthesis of Intermediate M15-2: according to the synthesis method of compound M11-6, twice the amount of compound M14-1 and twice the amount of compound M15-1 were substituted for compound M11-4 and compound M11-5, respectively, to obtain the intermediate M15-2 with yield of 76%.

(2) Synthesis of Organic Compound M15: according to the synthesis method of organic compound M1, compound M15-2 was substituted for compound M1-7 to obtain the organic compound M15 with yield of 34%. The result of the atmospheric pressure solid analysis probe-mass spectrometry (ASAP-MS) of the organic compound M15 was as follows: MS (ASAP)=1114.

### Example 16

### Synthesis of Organic Compound 16

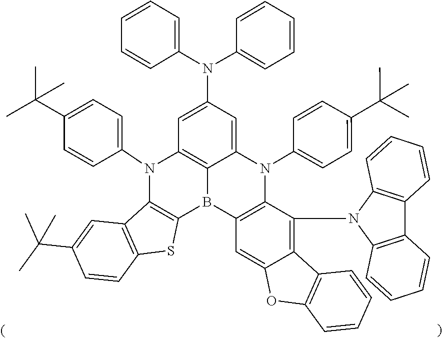 [SMILES: CC(C)(C)c1ccc(N2c3cc(N(c4ccccc4)c4ccccc4)cc4c3B(c3cc5oc6ccccc6c5c(-n5c6ccccc6c6ccccc65)c32)c2sc3ccc(C(C)(C)C)cc3c2N4c2ccc(C(C)(C)C)cc2)cc1]

Synthetic Route of the Organic Compound 16 is as follows:

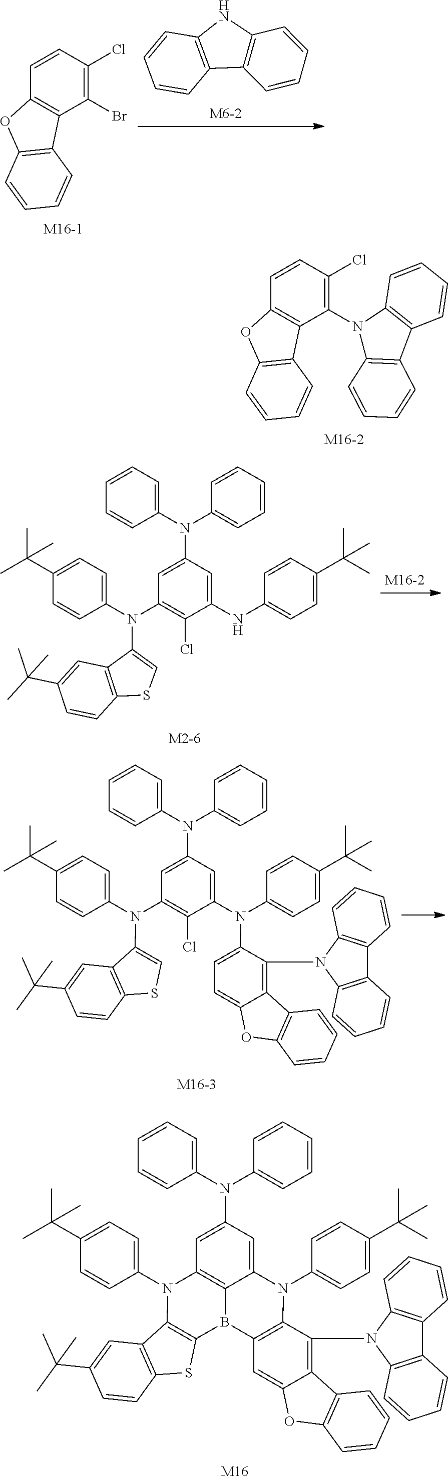

Synthesis steps of the Organic Compound M16 are as follows:

(1) Synthesis of Intermediate M16-2: according to the synthesis method of compound M2-3, compound M16-1 and compound M6-2 were substituted for compound M2-1 and compound M2-2, respectively, to obtain the intermediate M16-2 with yield of 67%.

(2) Synthesis of Intermediate M16-3: according to the synthesis method of compound M1-7, compound M2-6 and compound M16-2 were substituted for compound M1-5 and compound M1-6, respectively, to obtain the intermediate M16-3 with yield of 64%.

(3) Synthesis of Organic Compound M16: according to the synthesis method of organic compound M1, compound M16-3 was substituted for compound M1-7 to obtain the organic compound M16 with yield of 26%. The result of the atmospheric pressure solid analysis probe-mass spectrometry (ASAP-MS) of the organic compound M16 was as follows: MS (ASAP)=1068.

### Example 17

### Synthesis of Organic Compound 17

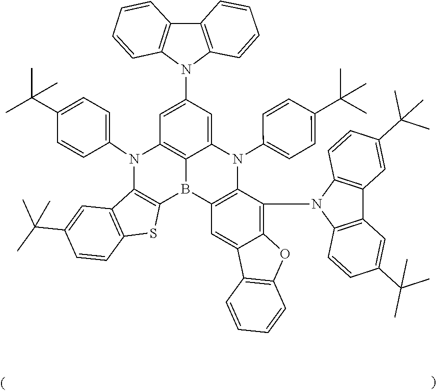 [SMILES: CC(C)(C)c1ccc(N2c3cc(-n4c5ccccc5c5ccccc54)cc4c3B(c3cc5c(oc6ccccc65)c(-n5c6ccc(C(C)(C)C)cc6c6cc(C(C)(C)C)ccc65)c32)c2sc3ccc(C(C)(C)C)cc3c2N4c2ccc(C(C)(C)C)cc2)cc1]

Synthetic Route of the Organic Compound 17 is as follows:

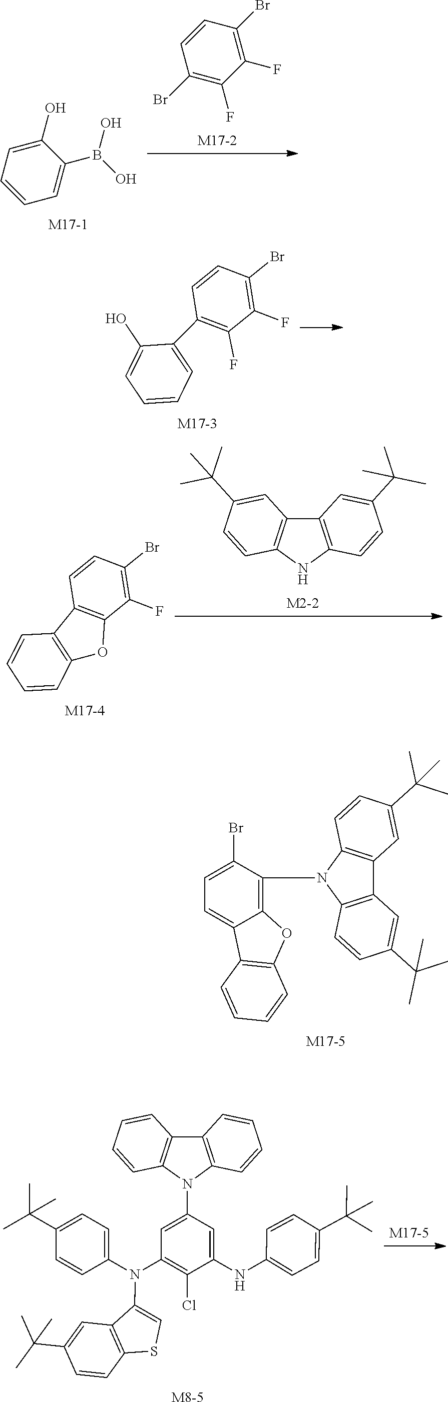

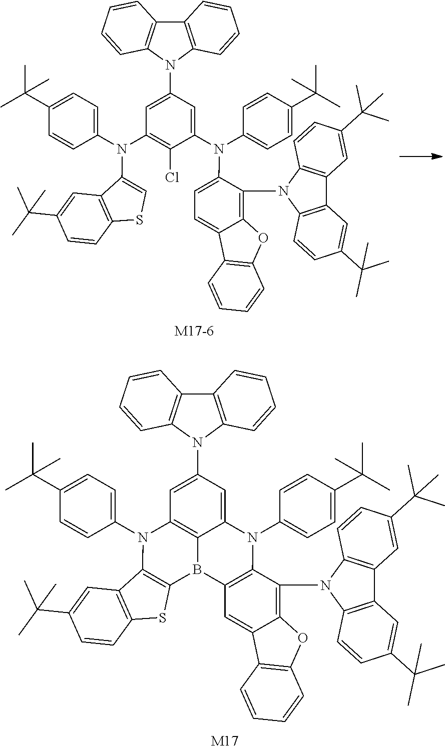

Synthesis steps of the Organic Compound M17 are as follows:

(1) Synthesis of Intermediate M17-3: in a nitrogen environment, compound M17-1 (13.8 g, 100 mmol), compound M17-2 (27.2 g, 100 mmol), tetratriphenylphosphine palladium (3.31 g, 3 mmol), 50 mL aqueous solution of potassium carbonate (27.6 g, 200 mmol), and toluene (200 mL) were added into a three necked flask (500 mL), heated to a temperature of 60° C., and stirred for 12 hours. After the reaction was completed, the reaction solution was cooled to room temperature and performed suction filtration to obtain filtrate. Then most of solvent was removed from the filtrate by rotary evaporation to obtain a crude product. The crude product was dissolved with dichloromethane and washed with water three times. The organic liquid was collected and mixed with silica gel for column chromatography purification to obtain the intermediate M17-3 with yield of 66%.

(2) Synthesis of Intermediate M17-4: in a nitrogen environment, compound M17-3 (17.1 g, 60 mmol), cesium carbonate (32.6 g, 100 mmol), and dimethyl formamide (100 mL) were added into a three necked flask (300 mL), heated to a temperature of 120° C., and stirred for 12 hours. After the reaction was completed, the reaction solution was cooled to room temperature and poured into 300 mL of pure water. The solution was stirred to precipitate the crude product. The crude product was performed suction filtration to obtain filter residue, then the filter residue was collected and recrystallized with a mixed solution of ethyl acetate and ethanol to obtain the intermediate M17-4 with yield of 74%.

(3) Synthesis of Intermediate M17-5: in a nitrogen environment, compound M17-4 (10.6 g, 40 mmol), compound M2-2 (11.2 g, 40 mmol), cesium carbonate (19.6 g, 60 mmol), and N, N-dimethylformamide (100 mL) were added into a three necked flask (300 mL), heated to a temperature of 150° C., and carried out for 12 hours. After the reaction was completed, the reaction solution was cooled to room temperature. Most of solvent was removed from the reaction solution by rotary evaporation. The reaction solution was poured into 300 mL of pure water to precipitate solid, then the solid was performed suction filtration to obtain filter residue. The filter residue was collected and recrystallized for purification to obtain the intermediate M17-5 with yield of 75%.

(4) Synthesis of Intermediate M17-6: according to the synthesis method of compound M1-7, compound M8-5 and compound M17-5 were substituted for compound M1-5 and compound 1-6, respectively, to obtain the intermediate M17-6 with yield of 68%.

(5) Synthesis of Organic Compound M17: according to the synthesis method of organic compound M1, compound M17-6 was substituted for compound M1-7 to obtain the organic compound M17 with yield of 28%. The result of the atmospheric pressure solid analysis probe-mass spectrometry (ASAP-MS) of the organic compound M17 was as follows: MS (ASAP)=1178.

Exemplary preparation steps of the light-emitting elements provided by the present disclosure are shown in the following example 18.

### Example 18

In this example, the light-emitting element includes an anode (ITO), a hole injection layer with a thickness of 40 nm, a hole transport layer with a thickness of 100 nm, a light-emitting layer made of a host material and a guest material with a mass ratio of 3% and having a thickness of 50 nm, an electron transport layer with a thickness of 25 nm, and a cathode including a LiQ layer with a thickness of 1 nm and a Al layer with a thickness of 150 nm, the preparation steps of the light-emitting element are as follows:
step a, a conductive glass substrate was cleaned by various solvents, such as chloroform, ketone, isopropanol, and then UV ozone plasma treatment was performed on the conductive glass substrate;
step b, the hole injection layer with the thickness of 40 nm, the hole transport layer with the thickness of 100 nm, the light-emitting layer with the thickness of 50 nm, and the electron transport layer with the thickness of 25 nm were sequentially formed in high vacuum (1×10⁻⁶ mbar) by a thermal evaporation coating process;
step c, the cathode including the LiQ layer with the thickness of 1 nm and the Al layer with the thickness of 150 nm were sequentially formed on the electron transport layer in high vacuum (1×10⁻⁶ mbar) by a thermal evaporation coating process;
step d, the above-mentioned device was packaged in a nitrogen glove box using UV hardened resin.

According to the example 18, the organic compounds M1 to M17 are used as guest materials to form light-emitting elements 1 to 17, respectively, and compound Ref-1 is used as a guest material to form a comparison element 1.

The compound Ref-1 has the following structure:

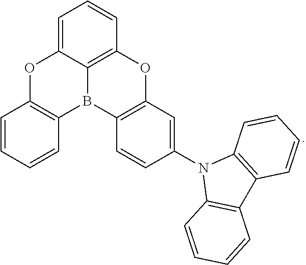 [SMILES: c1ccc2c(c1)Oc1cccc3c1B2c1ccc(-n2c4ccccc4c4ccccc42)cc1O3]

In the preparation methods of the light-emitting elements 1 to 17 and the comparison element 1,
the material of the hole injection layer has the following structure:

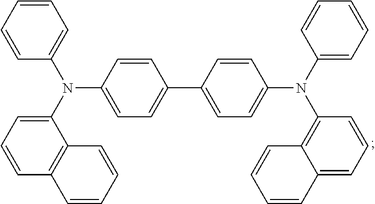 [SMILES: c1ccc(N(c2ccc(-c3ccc(N(c4ccccc4)c4cccc5ccccc45)cc3)cc2)c2cccc3ccccc23)cc1]

the material of the hole transport layer has the following structure:

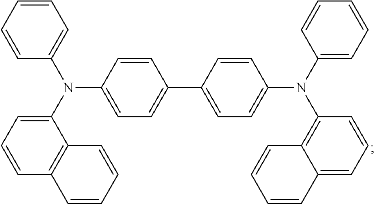 [SMILES: c1ccc(N(c2ccc(-c3ccc(N(c4ccccc4)c4cccc5ccccc45)cc3)cc2)c2cccc3ccccc23)cc1]

the host material of the light-emitting layer has the following structure:

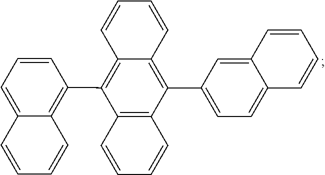 [SMILES: c1ccc2cc(-c3c4ccccc4c(-c4cccc5ccccc45)c4ccccc34)ccc2c1]

the material of the electron transport layer has the following structure:

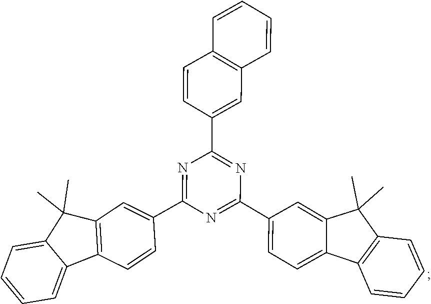 [SMILES: CC1(C)c2ccccc2-c2ccc(-c3nc(-c4ccc5c(c4)C(C)(C)c4ccccc4-5)nc(-c4ccc5ccccc5c4)n3)cc21]

and

LiQ has the following structure:

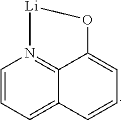

In these examples, external quantum efficiency (EQE) and luminescent life (T90@1000 nits, the time taken for the element to be tested to decay from 1000 nits to 900 nits) of the light-emitting elements 1 to 17 and the comparison element 1 are tested, and the results are shown in table 1.

TABLE 1

| | Guest | | LT90@ |
|---|---|---|---|
| OLED element | material | EQE | 1000 nits |
| Light-emitting element 1 | M1 | 1.63 | 1.72 |
| Light-emitting element 2 | M2 | 1.64 | 1.75 |
| Light-emitting element 3 | M3 | 1.73 | 1.85 |
| Light-emitting element 4 | M4 | 1.75 | 1.86 |
| Light-emitting element 5 | M5 | 1.77 | 1.88 |
| Light-emitting element 6 | M6 | 1.70 | 1.81 |
| Light-emitting element 7 | M7 | 1.69 | 1.80 |
| Light-emitting element 8 | M8 | 1.67 | 1.78 |
| Light-emitting element 9 | M9 | 1.66 | 1.76 |
| Light-emitting element 10 | M10 | 1.72 | 1.83 |
| Light-emitting element 11 | M11 | 1.60 | 1.68 |
| Light-emitting element 12 | M12 | 1.58 | 1.67 |
| Light-emitting element 13 | M13 | 1.61 | 1.70 |
| Light-emitting element 14 | M14 | 1.55 | 1.63 |
| Light-emitting element 15 | M15 | 1.57 | 1.65 |
| Light-emitting element 16 | M16 | 1.66 | 1.77 |
| Light-emitting element 17 | M17 | 1.67 | 1.77 |
| Comparison element 1 | Ref-1 | 1 | 1 |

In can be seen from table 1 that when external quantum efficiency and luminescent life of the comparison element 1 are taken as reference value 1, external quantum efficiency of the light-emitting elements 1 to 17 is significantly improved, and luminescent life of the light-emitting elements 1 to 17 is also effectively prolonged, indicating that the organic compound provided by the present disclosure, by introducing the heterocyclic ring and the carbazole-like group, enhances the conjugation and resonance effects of the organic compound, improves the performance of the organic compound, increases the luminous efficiency of the light-emitting element applying the organic compound and extends the luminescent life of the light-emitting element.

The light-emitting element applying the organic compound provided by the present disclosure, by introducing carbazole-like groups in the organic compound, especially those having both of the heterocyclic ring and the carbazole-like group, enhances the conjugation and resonance effects of the organic compound, improves the performance of the organic compound, increases the luminous efficiency of the light-emitting element and extends the luminescent life of the light-emitting element.

Embodiments of the present disclosure further provide a display panel, which includes any one of the above-mentioned light-emitting elements.

The display panel further includes an array substrate disposed on one side of the light-emitting element, and an encapsulation layer disposed on a side of the light-emitting element away from the array substrate and covering the light-emitting element.

The display panel further includes a polarizer layer disposed on a side of the encapsulation layer away from the light-emitting element, and a cover layer disposed on a side of the polarizer layer away from the light-emitting element. The polarizer layer can be replaced by a color film layer, which may include multiple color resists and a black matrix disposed on two sides of each of the color resists.

The display panel including the light-emitting element that applies the organic compound provided by the embodiments of the present disclosure, by introducing carbazole-like groups in the organic compound, especially those having both of the heterocyclic ring and the carbazole-like group, enhances the conjugation and resonance effects of the organic compound, improves the performance of the organic compound, increases the luminous efficiency of the light-emitting element and extends the luminescent life of the light-emitting element, and further increases the luminous efficiency of the display panel and extends the luminescent life of the display panel.

Embodiments of the present disclosure provide the organic compound, the mixture, the composition, the light-emitting element, and the display panel. The organic compound has a structure represented by formula (1):

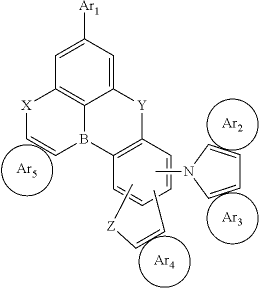

formula (1). The organic compound provided by the embodiments of the present disclosure, by introducing carbazole-like groups, especially those having both of the heterocyclic ring and the carbazole-like group, enhances the conjugation and resonance effects of the organic compound, improves the performance of the organic compound, increases the luminous efficiency of the light-emitting element applying the organic compound and extends the luminescent life of the light-emitting element.

The organic compound, the mixture, the composition, the light-emitting element, and the display panel provided by the embodiments of the present disclosure are described in detail. In this context, specific embodiments are adopted to illustrate a principle and implementation modes of the present disclosure. The description of the above-mentioned embodiments is only used to help understand methods and a core idea of the present disclosure. At the same time, for those skilled in the art, according to the idea of the present disclosure, there might be changes in specific implementation modes and a scope of the present disclosure, which falls within the scope of the protection of the present disclosure. In conclusion, contents of the specification should not be interpreted as a limitation of the present disclosure.

What is claimed is:

1. An organic compound having a structure represented by formula (1): 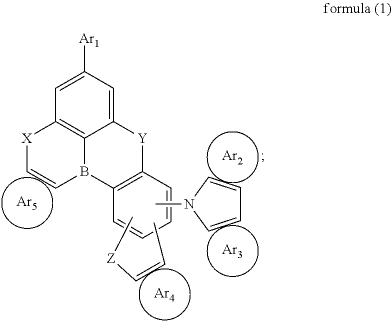
wherein Z is selected from CR₁R₂, NR₃, O, or S;
X and Y are each independently selected from O or NR₄;
R₁—R₄ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group;
R₁ and R₂ are connected to form a ring or independent of each other;
Ar₁ is selected from H, D, a substituted or unsubstituted C₁-C₂₀ alkyl group, a substituted or unsubstituted C₆-C₃₀ aromatic group, or a substituted or unsubstituted C₅-C₃₀ heteroaromatic group;
Ar₂ and Ar₃ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group; and
Ar₄ and Ar₅ are each independently selected from a substituted or unsubstituted C₆-C₃₀ aromatic group, or a substituted or unsubstituted C₅-C₃₀ heteroaromatic group.

2. The organic compound of claim 1, wherein the organic compound has a structure represented by any one of formula (2) to formula (7): 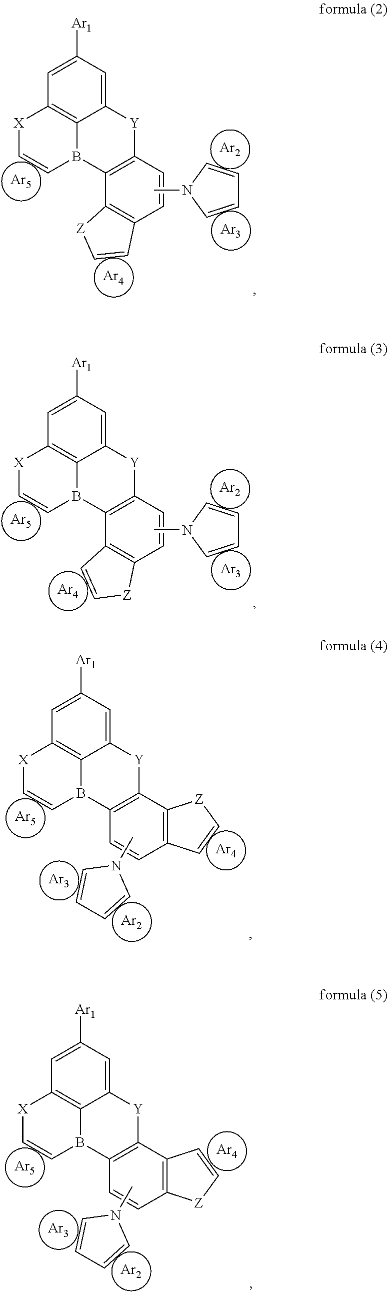 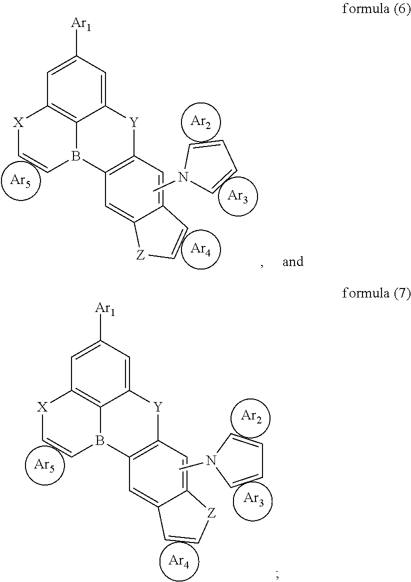
wherein a heteroatom in the substituted or unsubstituted C₅-C₃₀ heteroaromatic group is selected from N, O, or S.

3. The organic compound of claim 2, wherein the organic compound has a structure represented by any one of formula (8) to formula (13):

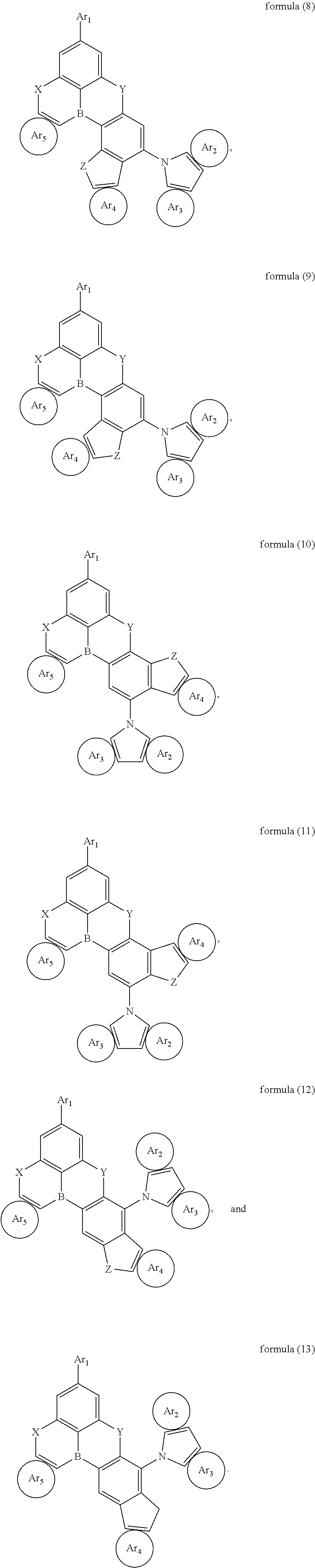

4. The organic compound of claim 1, wherein the organic compound has a structure represented by formula (14) or formula (15): 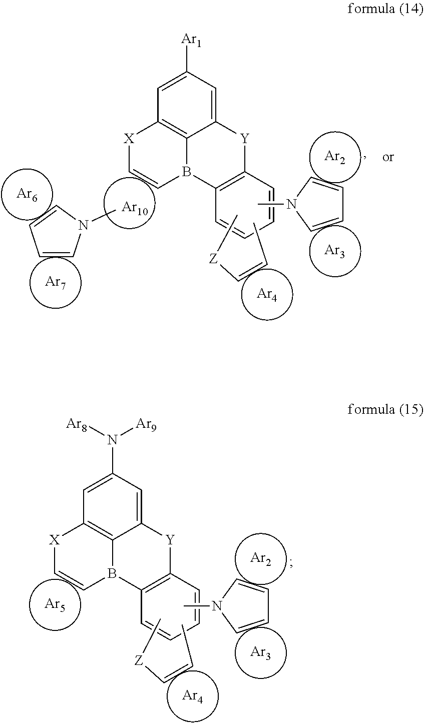
wherein Ar₆—Ar₉ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group; and
Ar₁₀ is independently selected from a substituted or unsubstituted C₆-C₃₀ aromatic group, or a substituted or unsubstituted C₅-C₃₀ heteroaromatic group.

5. The organic compound of claim 4, wherein Ar₆ and Ar₇ are each independently selected from a phenyl group or 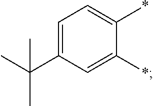
Ar₈ and Ar₉ are each independently selected from a phenyl group, 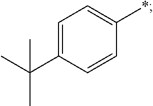
and
Ar₁₀ is a phenyl group;
wherein * indicates a linking site.

6. The organic compound of claim 1, wherein Ar₁ is selected from H, D, a substituted or unsubstituted C₁-C₈alkyl group, a substituted or unsubstituted C₆-C₁₅ aromatic group, or a substituted or unsubstituted C₅-C₁₅ heteroaromatic group;
Ar₂ and Arₙ are each independently selected from a substituted or unsubstituted C₁-C₈ alkyl group, a substituted or unsubstituted C₆-C₁₅ aromatic group, or a substituted or unsubstituted C₅-C₁₅ heteroaromatic group; and
Ar₄ and Ar₅ are each independently selected from a substituted or unsubstituted C₆-C₁₅ aromatic group, or a substituted or unsubstituted C₅-C₁₅ heteroaromatic group.

7. The organic compound of claim 1, wherein R₁—R₄ are each independently selected from a substituted or unsubstituted C₁-C₈ alkyl group, a substituted or unsubstituted C₆-C₁₅ aromatic group, or a substituted or unsubstituted C₅-C₁₅ heteroaromatic group.

8. The organic compound of claim 1, wherein Ar₁ is selected from H, D, a methyl group, an isopropyl group, a tert-butyl group, a tert-pentyl group, a substituted or unsubstituted phenyl group, a substituted or unsubstituted naphthyl group, a substituted or unsubstituted triphenylene group, a substituted or unsubstituted phenanthryl group, a substituted or unsubstituted dibenzofuranyl group, a substituted or unsubstituted dibenzothiophenyl group, a substituted or unsubstituted fluorenyl group, a substituted or unsubstituted carbazolyl group, or a heteroaromatic group containing N;
Ar₂ and Arₙ are each independently selected from a methyl group, a substituted or unsubstituted phenyl group, a substituted or unsubstituted cyclopentyl group, a substituted or unsubstituted cyclohexyl group, a substituted or unsubstituted naphthyl group, a substituted or unsubstituted a phenanthryl group, a substituted or unsubstituted triphenylene group, a substituted or unsubstituted dibenzofuranyl group, a substituted or unsubstituted dibenzothiophenyl group, a substituted or unsubstituted fluorenyl group, or a substituted or unsubstituted carbazolyl group;
Ar₄ and Ar₅ are each independently selected from a substituted or unsubstituted phenyl group, a substituted or unsubstituted naphthyl group, a substituted or unsubstituted phenanthryl group, a substituted or unsubstituted triphenylene group, a substituted or unsubstituted pyrenyl group, a substituted or unsubstituted dibenzofuranyl group, a substituted or unsubstituted dibenzothiophenyl group, a substituted or unsubstituted fluorenyl group, a substituted or unsubstituted carbazolyl group, or a heteroaromatic group containing N;
R₁ and R₂ are each independently selected from a methyl group, an ethyl group, a substituted or unsubstituted phenyl group, a substituted or unsubstituted naphthyl group, or a substituted or unsubstituted dibenzofuranyl group;
R₃ is selected from a methyl group, an ethyl group, a tert-butyl group, a substituted or unsubstituted phenyl group, a substituted or unsubstituted naphthyl group, or a substituted or unsubstituted dibenzofuranyl group; and
R₄ is selected from a methyl group, a substituted or unsubstituted phenyl group, a substituted or unsubstituted naphthyl group, a substituted or unsubstituted dibenzofuranyl group, a substituted or unsubstituted dibenzothiophenyl group, a substituted or unsubstituted fluorenyl group, or a substituted or unsubstituted carbazolyl group.

9. The organic compound of claim 1, wherein Z is selected from CR₁R₂, O, or S; and
X and Y are each independently selected from O or NR₄, and X and Y are not O at the same time.

10. The organic compound of claim 1, wherein R₁ and R₂ are each independently selected from a methyl group, an unsubstituted phenyl group, an ethyl group, 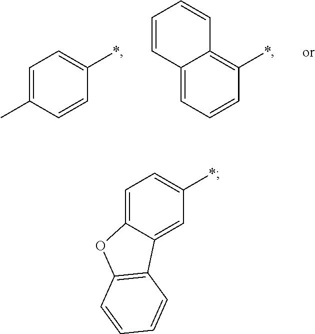
R₃ is selected from a methyl group, a tert-butyl group, a phenyl group, 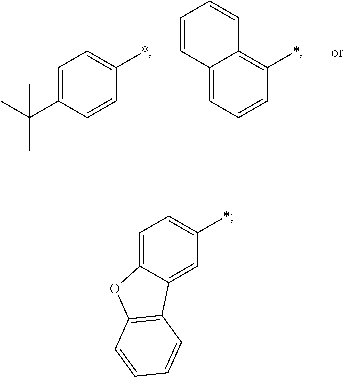
and
R₄ is selected from a methyl group, a phenyl group,

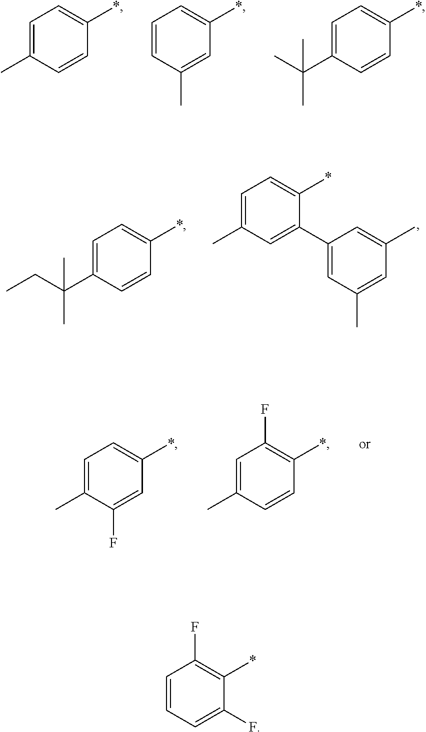

11. The organic compound of claim 1, wherein Ar₁ is selected from H, D, a methyl group, an isopropyl group, a tert-butyl group, a tert-pentyl group, a phenyl group,

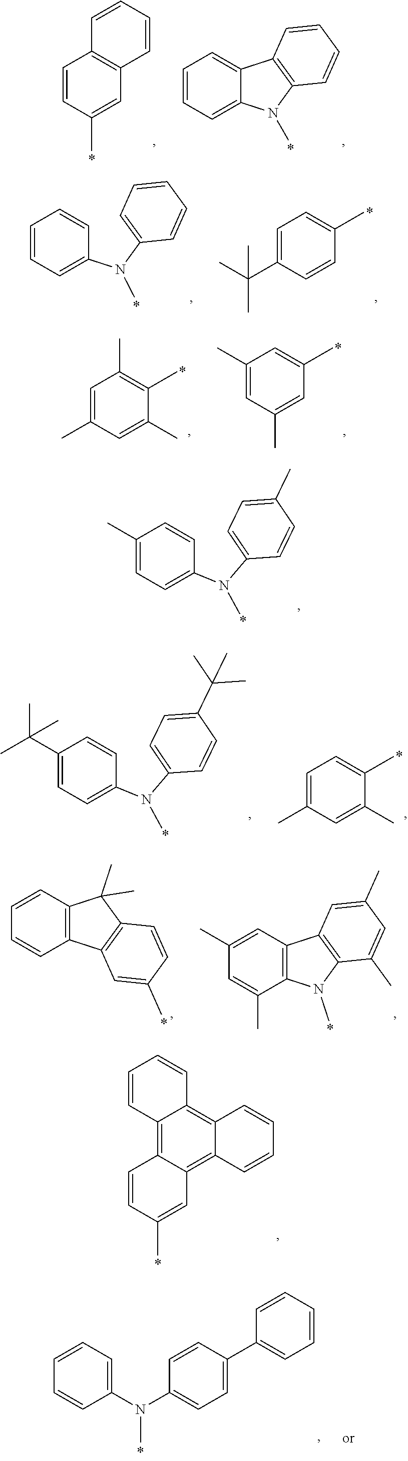

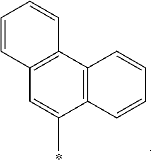

12. The organic compound of claim 1, wherein Ar₂ and Arₙ are each independently selected from a methyl group, a phenyl group,

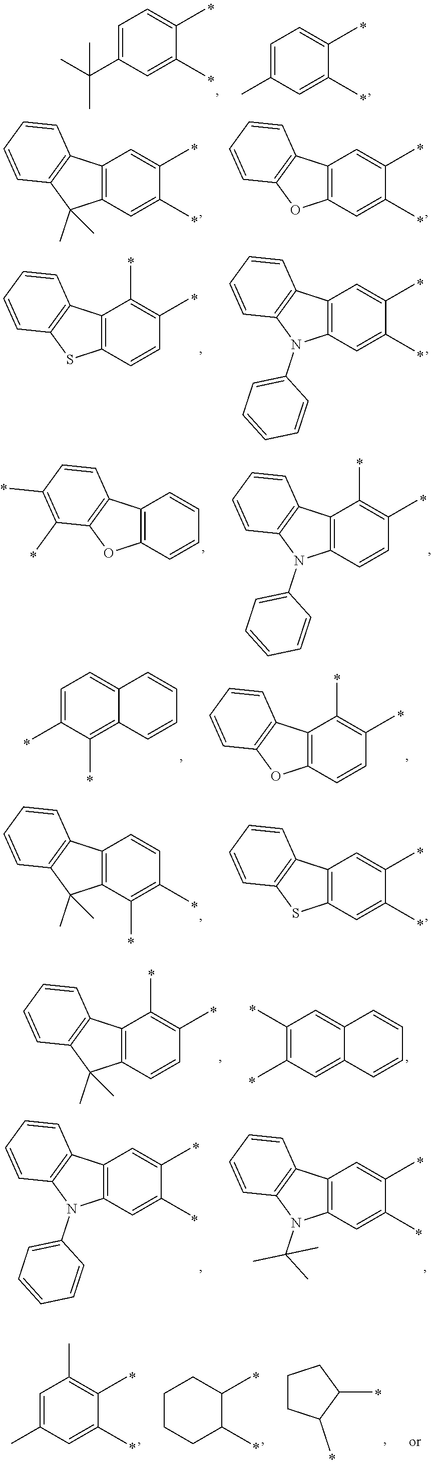

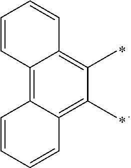 [SMILES: Cc1c(C)c2ccccc2c2ccccc12]

13. The organic compound of claim 1, wherein Ar₄ is a phenyl group.

14. The organic compound of claim 1, wherein Ar₅ is selected from a phenyl group,

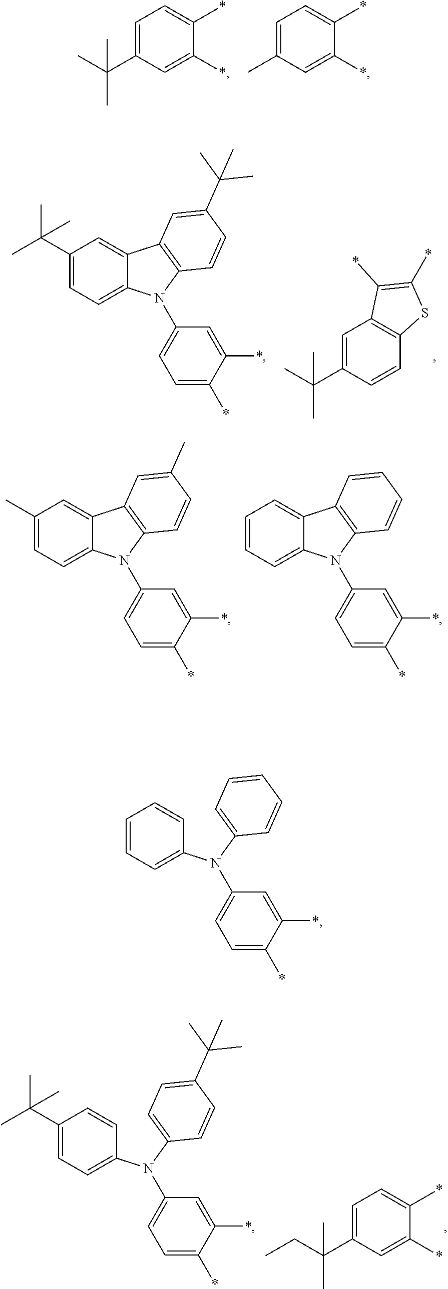

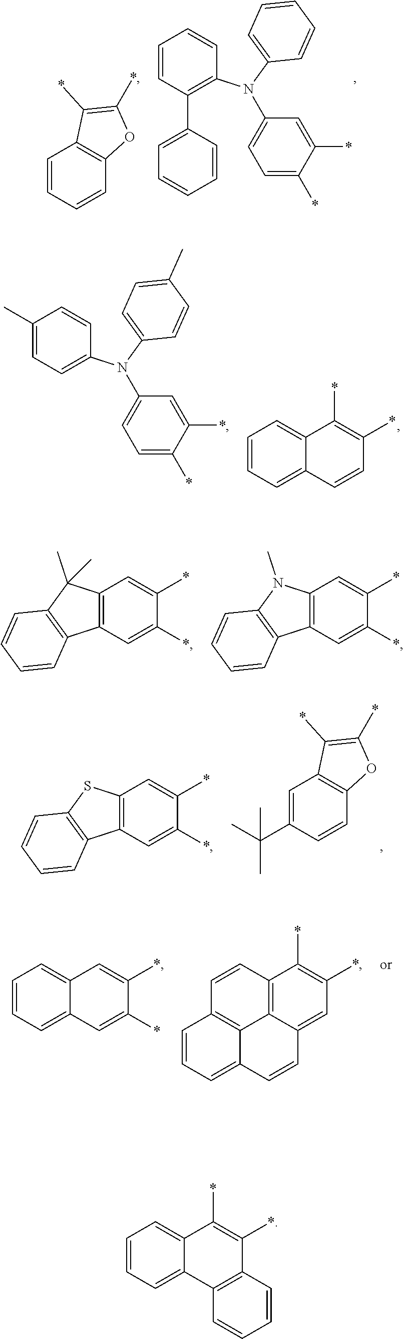

15. The organic compound of claim 1, wherein the organic compound has a structure represented by any one of following structures:

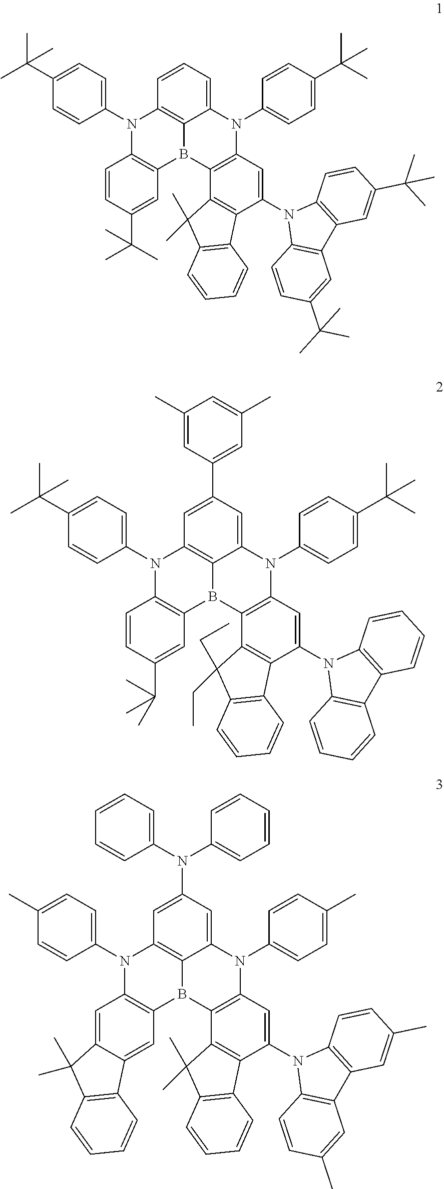

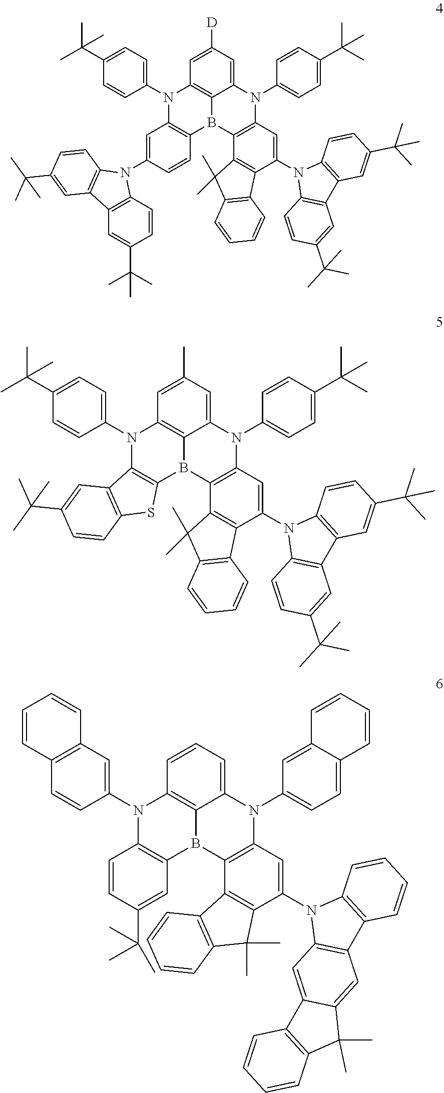

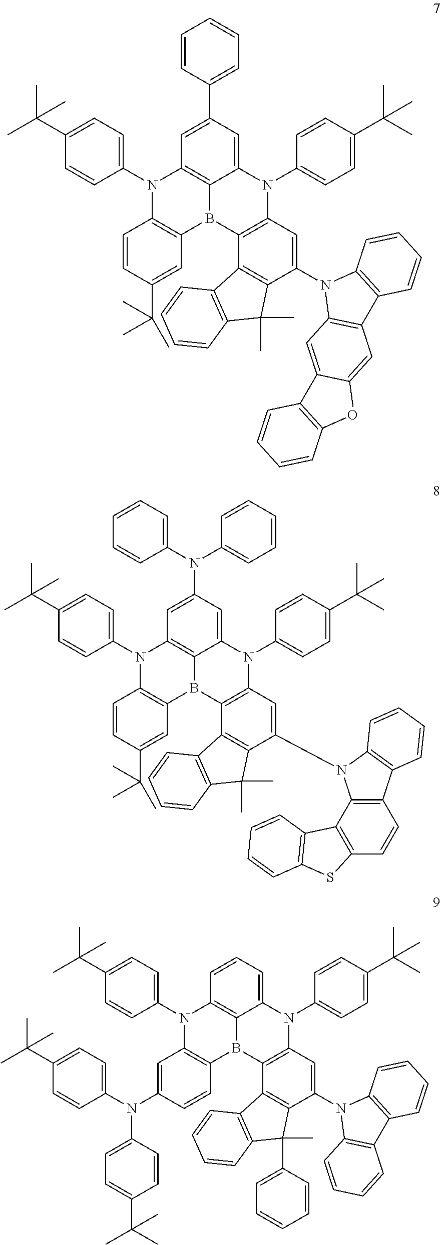 [SMILES: CC(C)(C)c1ccc(N2c3ccc(C(C)(C)C)cc3B3c4c2cc(-c2ccccc2)cc4N(c2ccc(C(C)(C)C)cc2)c2cc(-n4c5ccccc5c5cc6oc7ccccc7c6cc54)c4c(c23)-c2ccccc2C4(C)C)cc1 ; CC(C)(C)c1ccc(N2c3ccc(C(C)(C)C)cc3B3c4c2cc(N(c2ccccc2)c2ccccc2)cc4N(c2ccc(C(C)(C)C)cc2)c2cc(-n4c5ccccc5c5ccc6sc7ccccc7c6c54)c4c(c23)-c2ccccc2C4(C)C)cc1 ; CC(C)(C)c1ccc(N(c2ccc(C(C)(C)C)cc2)c2ccc3c(c2)N(c2ccc(C(C)(C)C)cc2)c2cccc4c2B3c2c(cc(-n3c5ccccc5c5ccccc53)c3c2-c2ccccc2C3(C)c2ccccc2)N4c2ccc(C(C)(C)C)cc2)cc1]

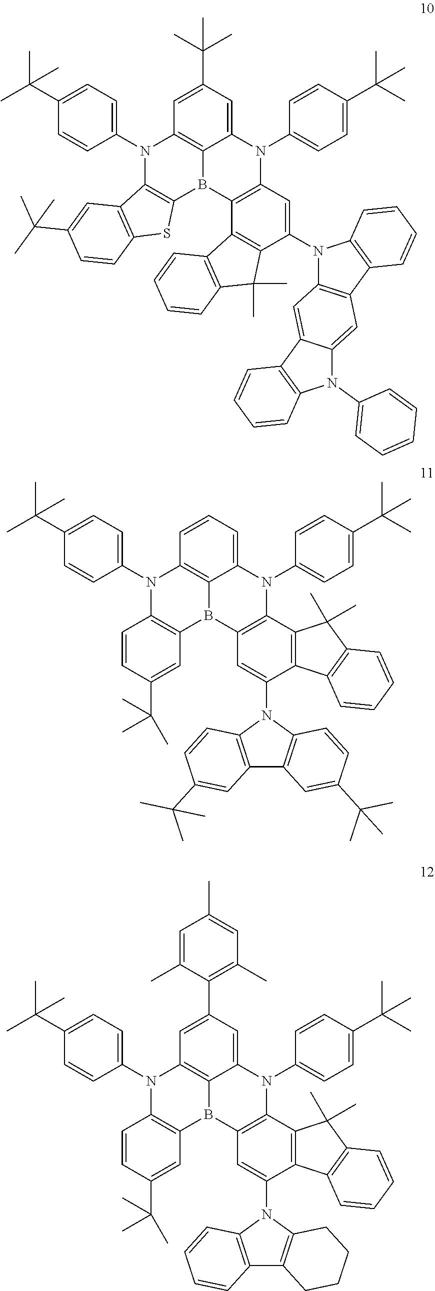

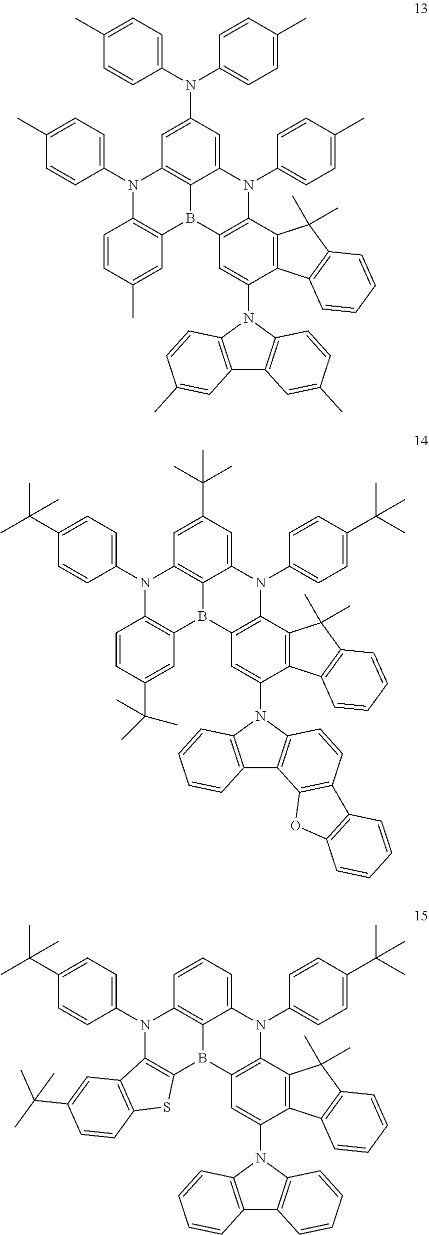

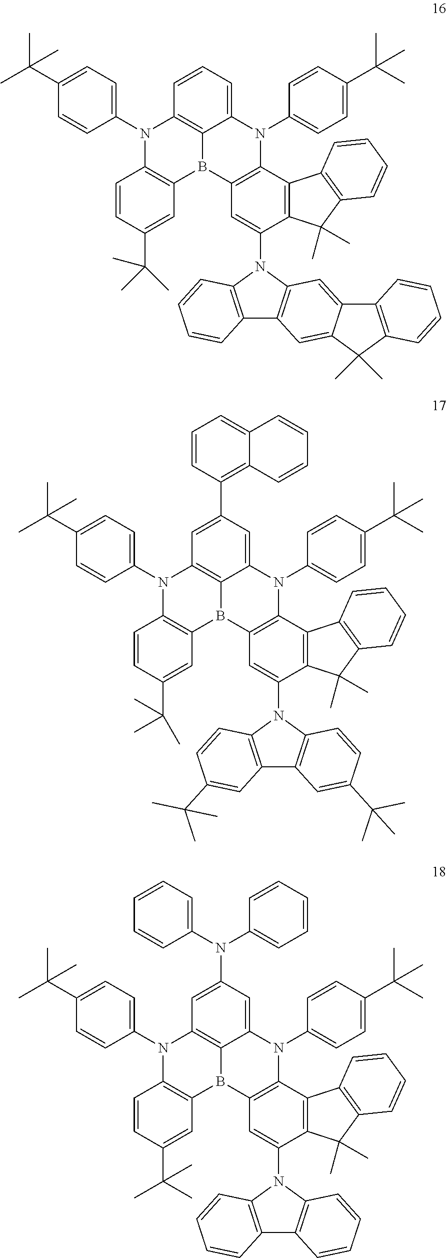

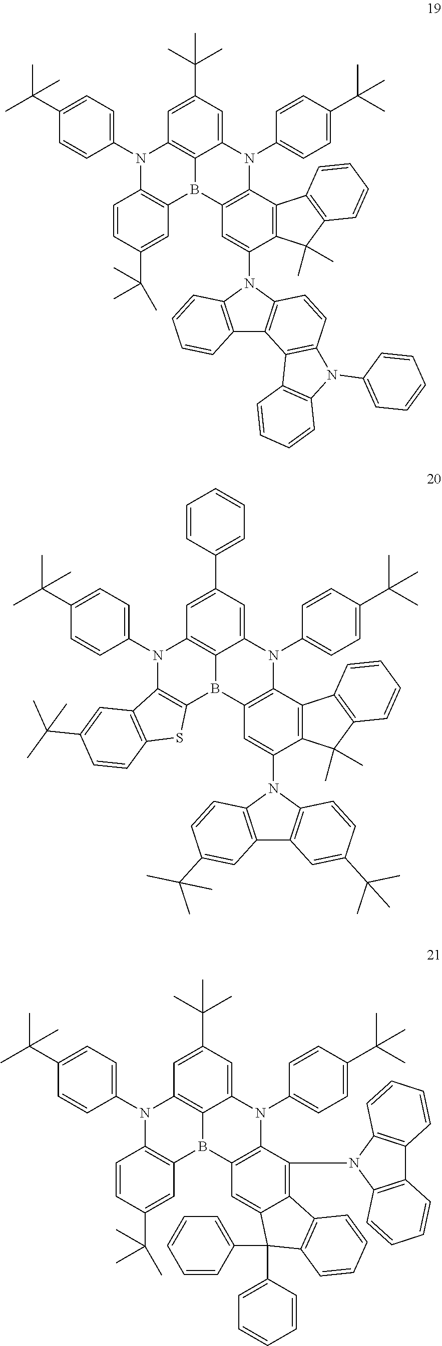

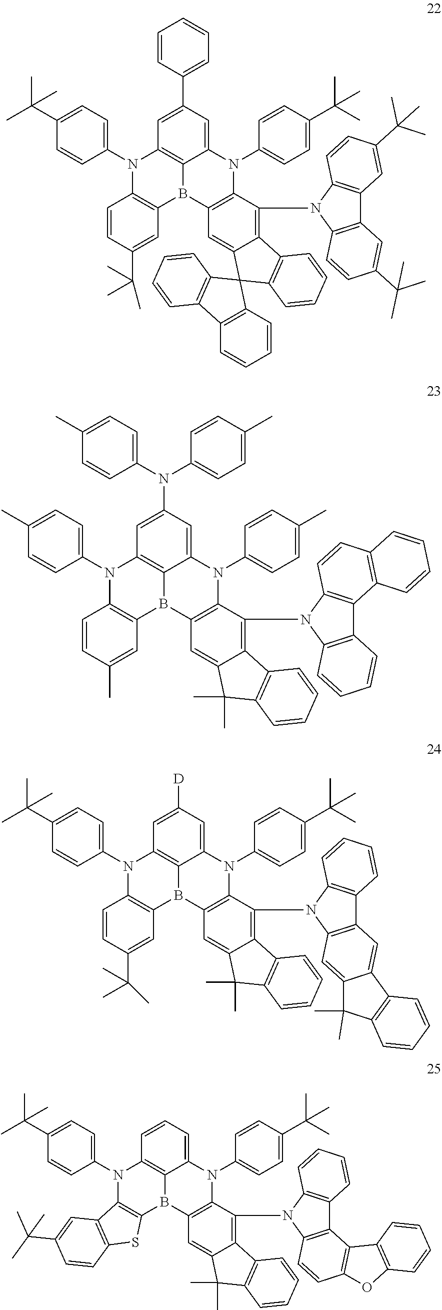

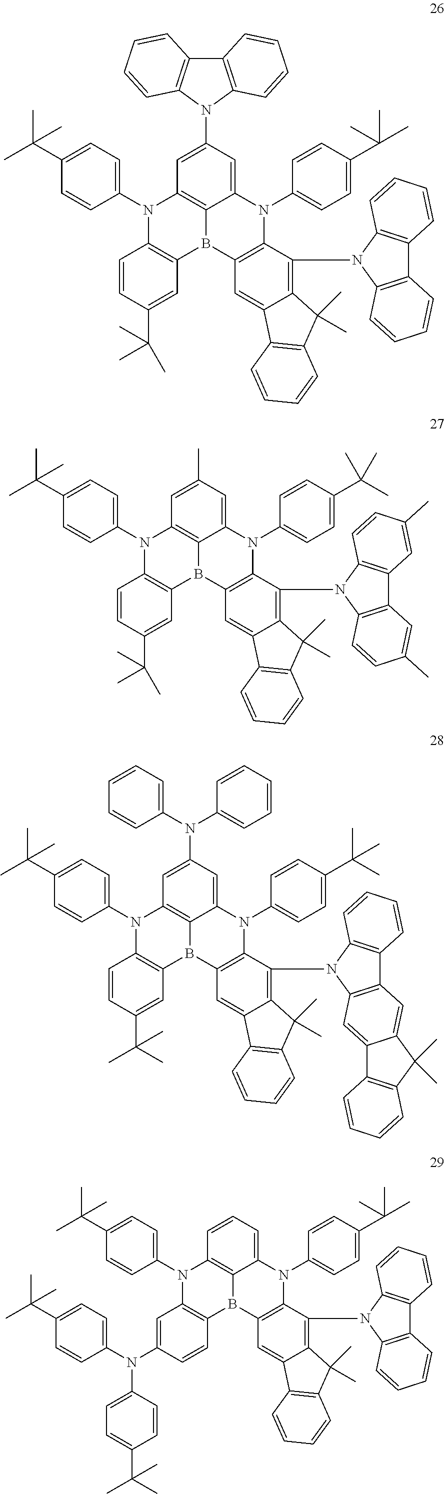

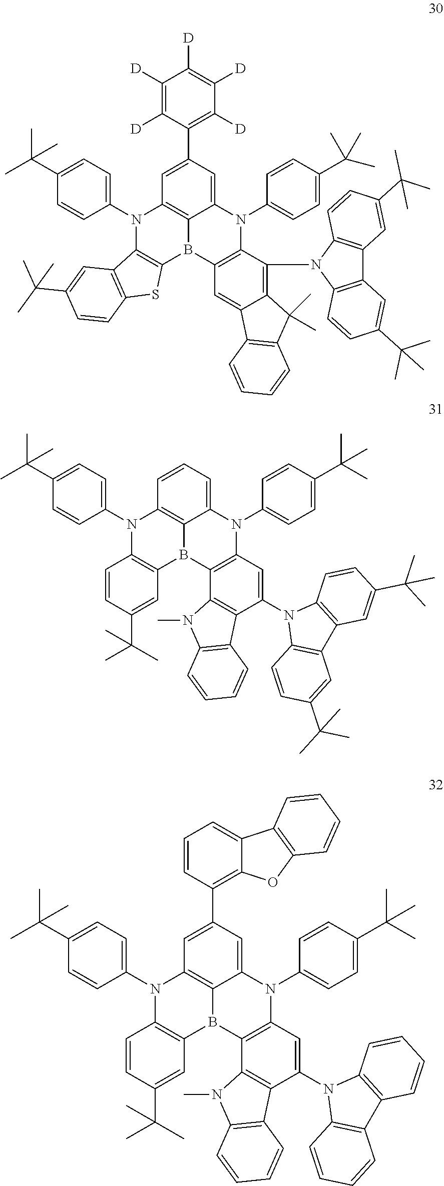

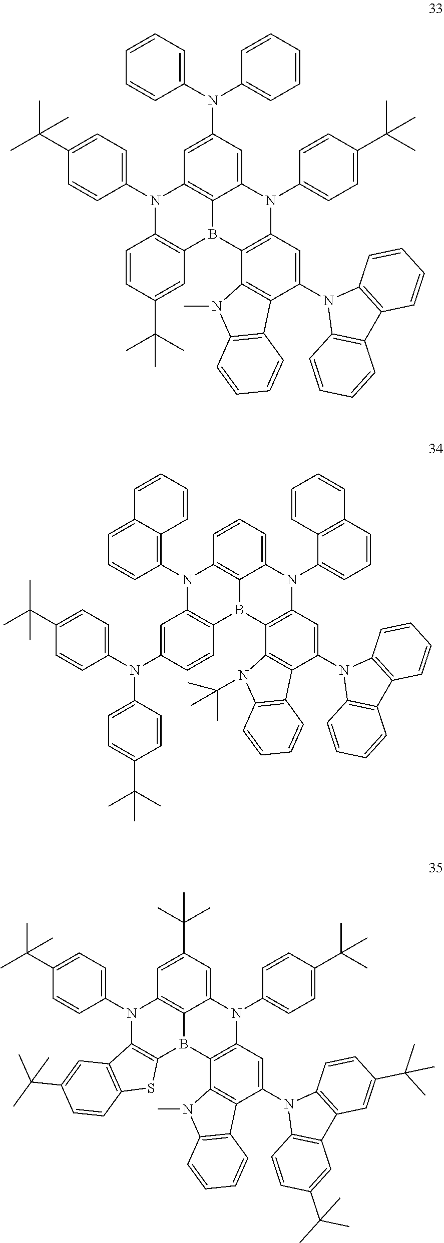 [SMILES: Cn1c2ccccc2c2c(-n3c4ccccc4c4ccccc43)cc3c(c21)B1c2cc(C(C)(C)C)ccc2N(c2ccc(C(C)(C)C)cc2)c2cc(N(c4ccccc4)c4ccccc4)cc(c21)N3c1ccc(C(C)(C)C)cc1 ; CC(C)(C)c1ccc(N(c2ccc(C(C)(C)C)cc2)c2ccc3c(c2)N(c2cccc4ccccc24)c2cccc4c2B3c2c(cc(-n3c5ccccc5c5ccccc53)c3c5ccccc5n(C(C)(C)C)c23)N4c2cccc3ccccc23)cc1 ; Cn1c2ccccc2c2c(-n3c4ccc(C(C)(C)C)cc4c4cc(C(C)(C)C)ccc43)cc3c(c21)B1c2sc4ccc(C(C)(C)C)cc4c2N(c2ccc(C(C)(C)C)cc2)c2cc(C(C)(C)C)cc(c21)N3c1ccc(C(C)(C)C)cc1]

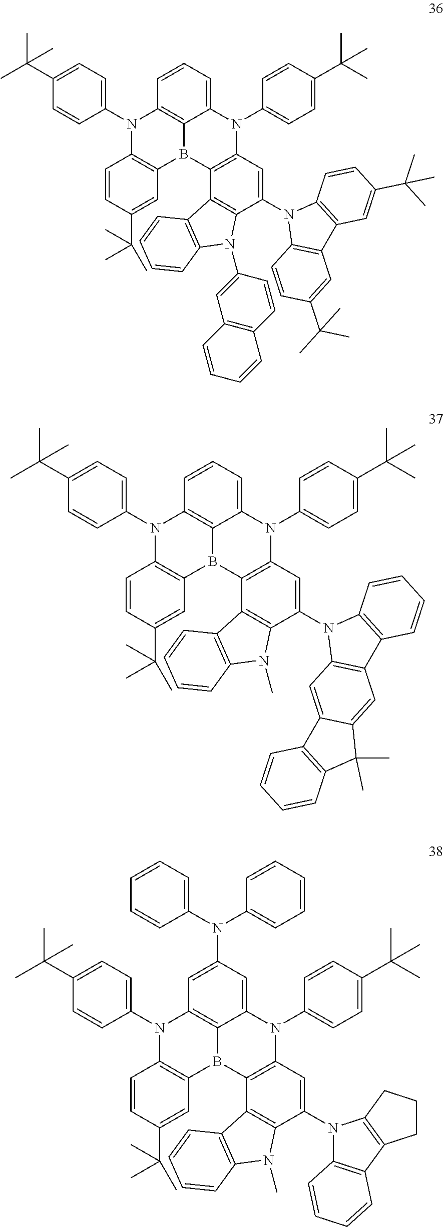

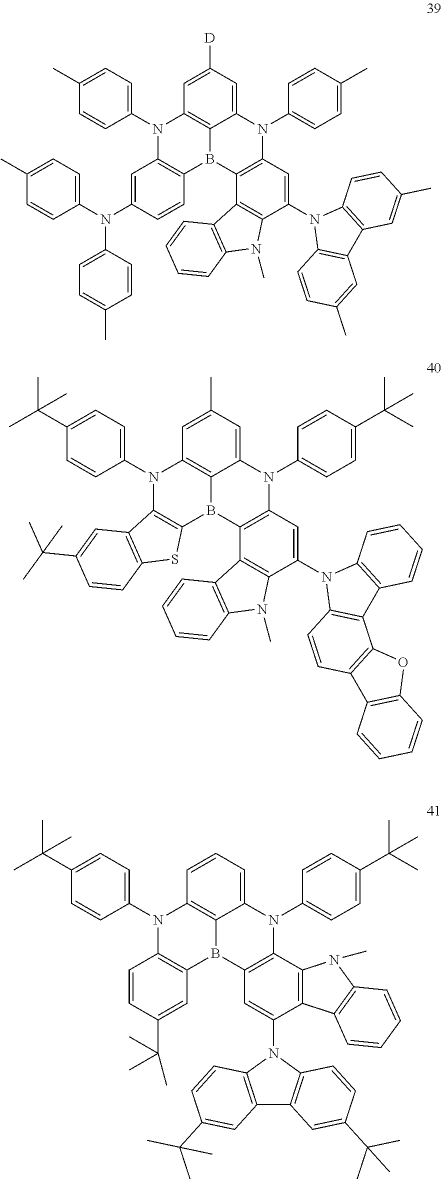

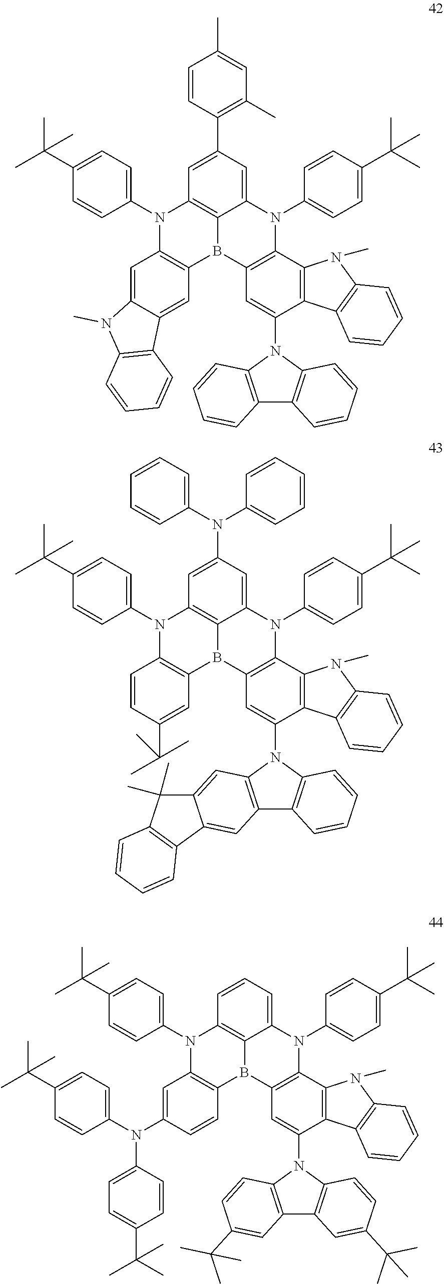

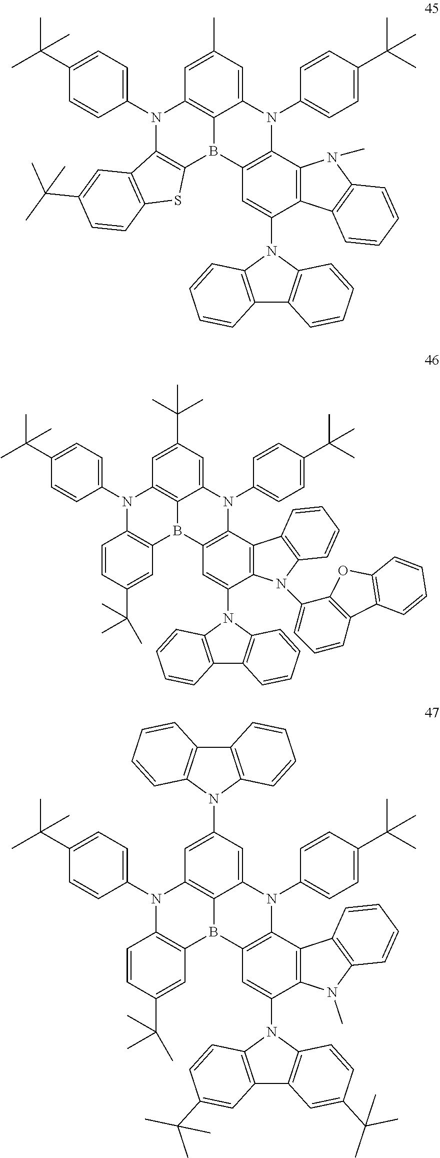

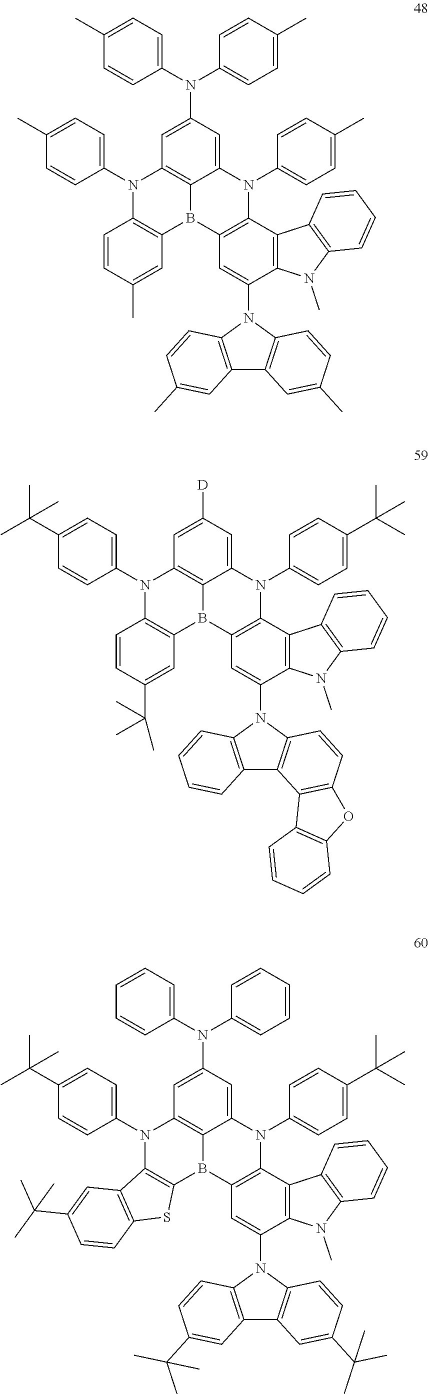

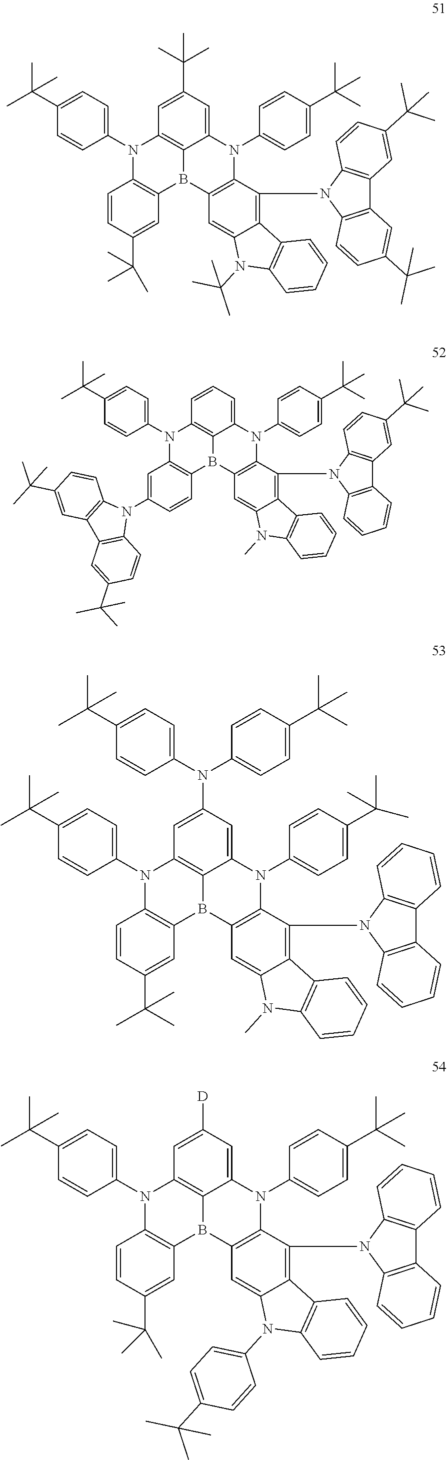

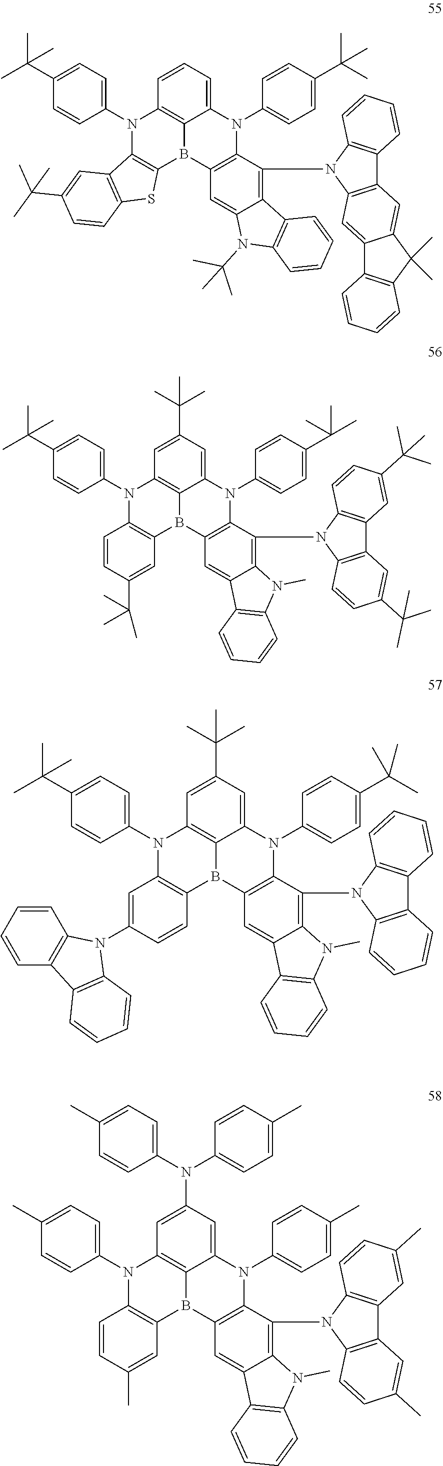

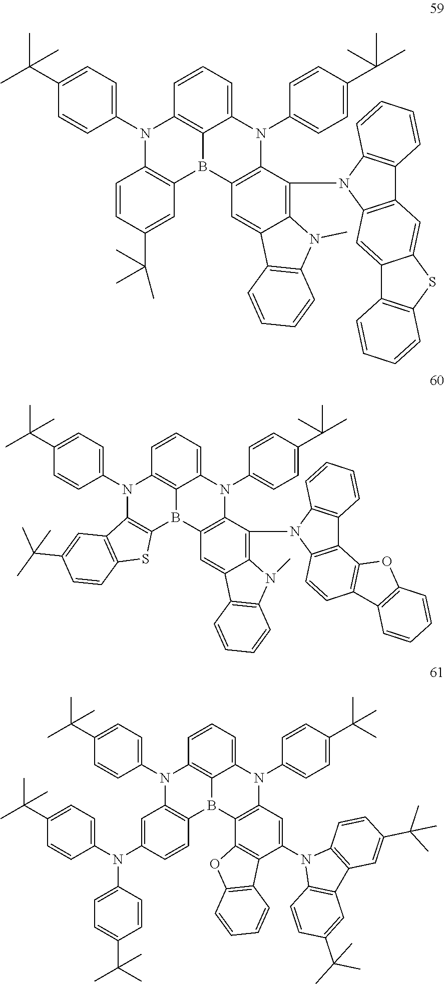 [SMILES: Cn1c2ccccc2c2cc3c(c(-n4c5ccccc5c5cc6sc7ccccc7c6cc54)c21)N(c1ccc(C(C)(C)C)cc1)c1cccc2c1B3c1cc(C(C)(C)C)ccc1N2c1ccc(C(C)(C)C)cc1 ; Cn1c2ccccc2c2cc3c(c(-n4c5ccccc5c5c6oc7ccccc7c6ccc54)c21)N(c1ccc(C(C)(C)C)cc1)c1cccc2c1B3c1sc3ccc(C(C)(C)C)cc3c1N2c1ccc(C(C)(C)C)cc1 ; CC(C)(C)c1ccc(N(c2ccc(C(C)(C)C)cc2)c2ccc3c(c2)N(c2ccc(C(C)(C)C)cc2)c2cccc4c2B3c2c(cc(-n3c5ccc(C(C)(C)C)cc5c5cc(C(C)(C)C)ccc53)c3c2oc2ccccc23)N4c2ccc(C(C)(C)C)cc2)cc1]

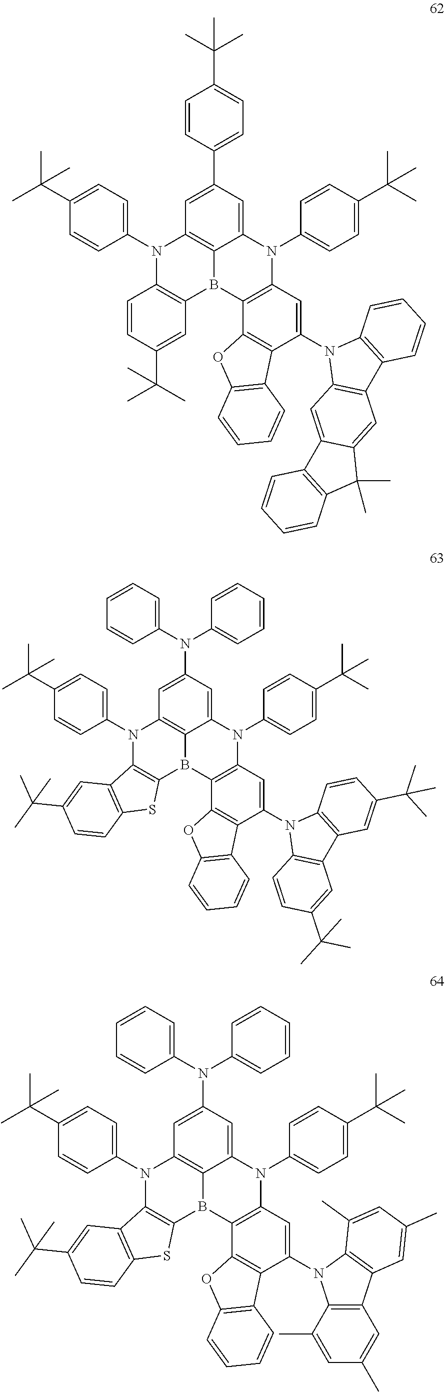

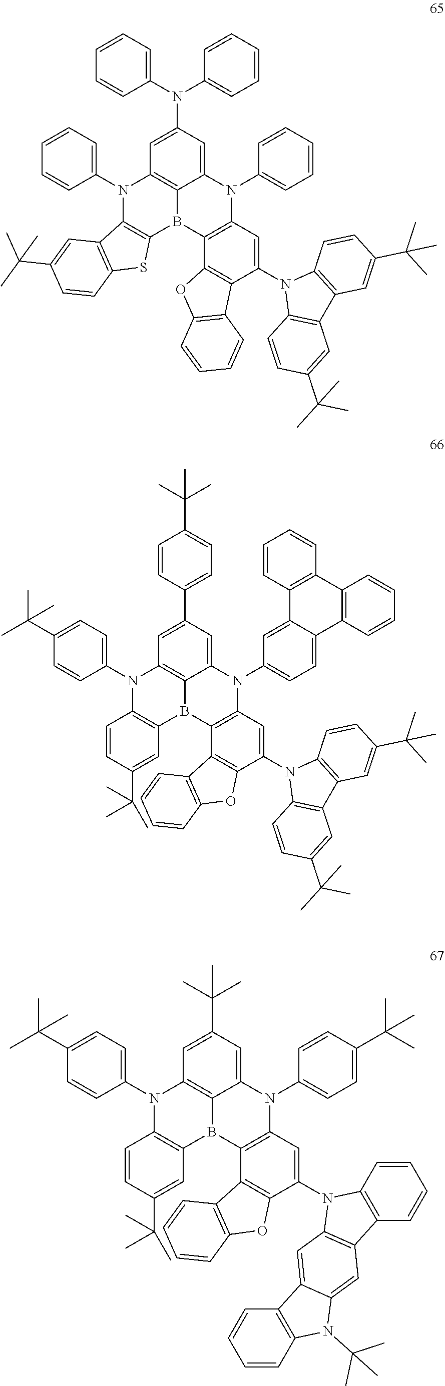

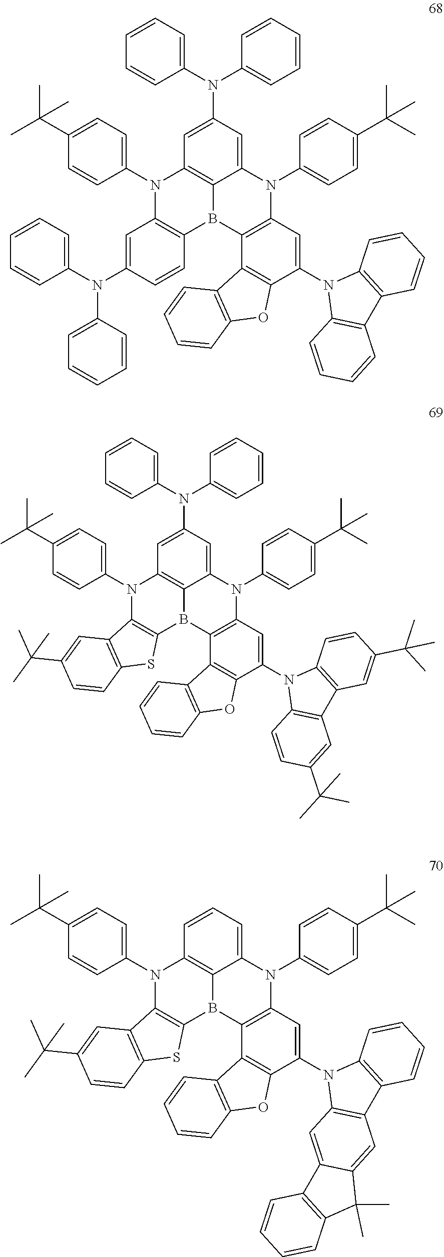

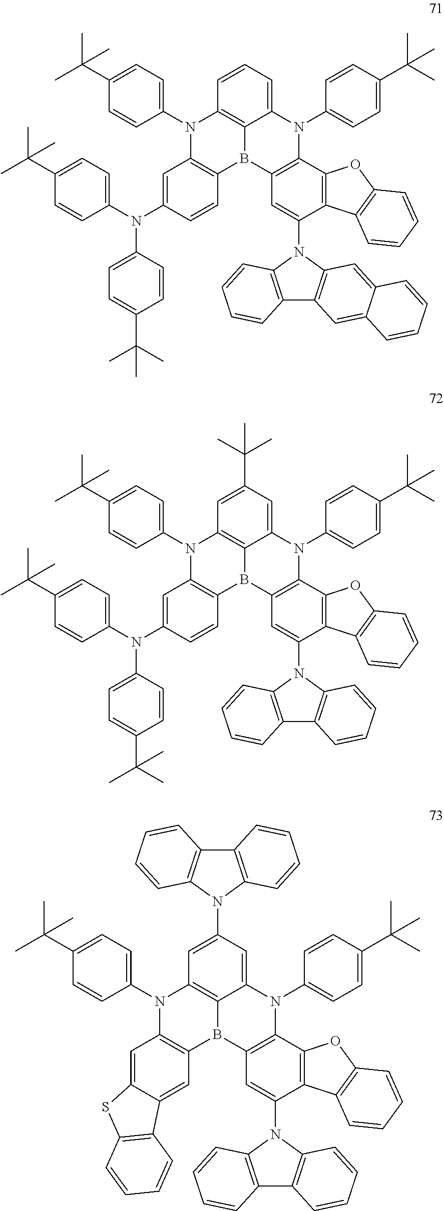

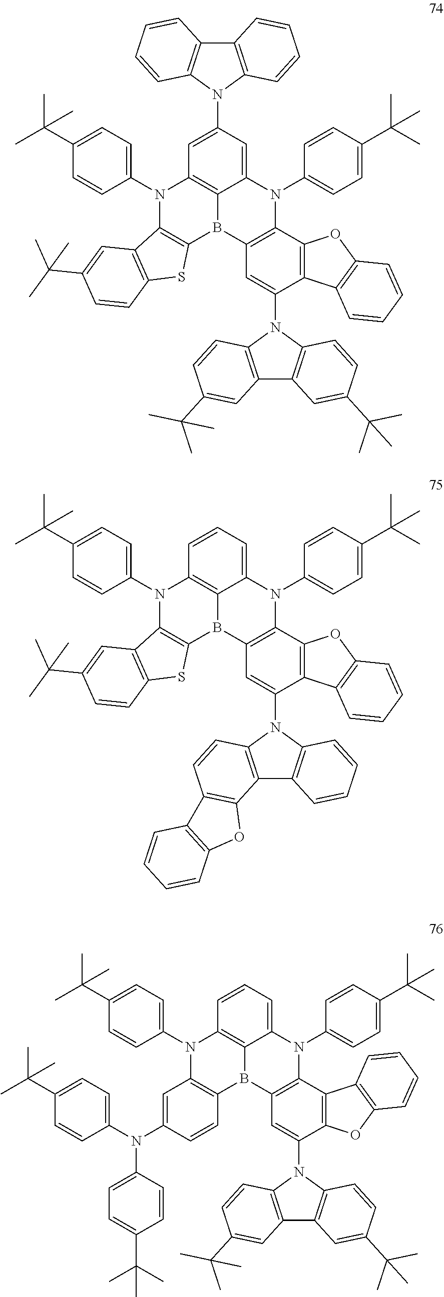

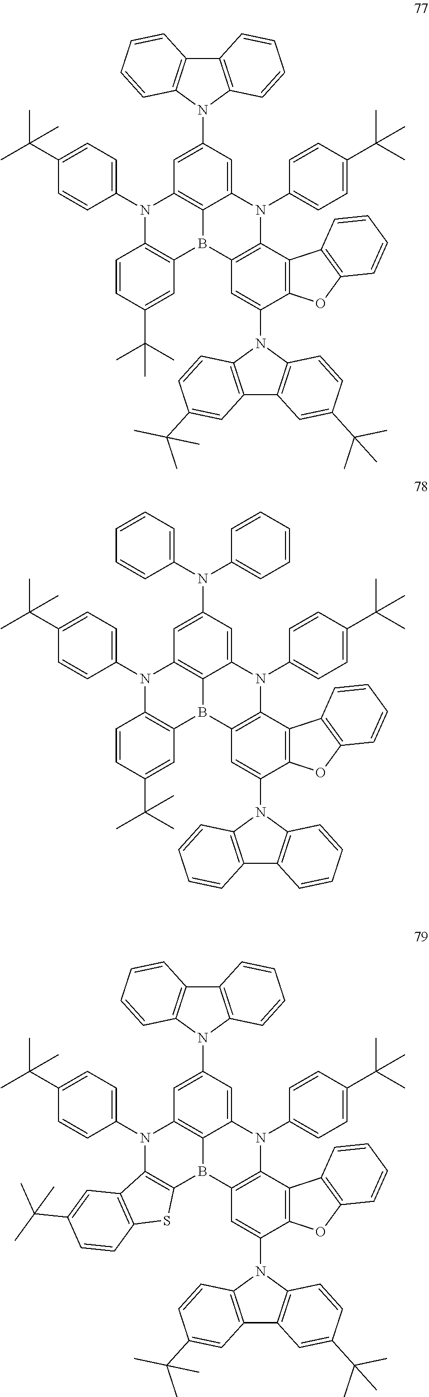

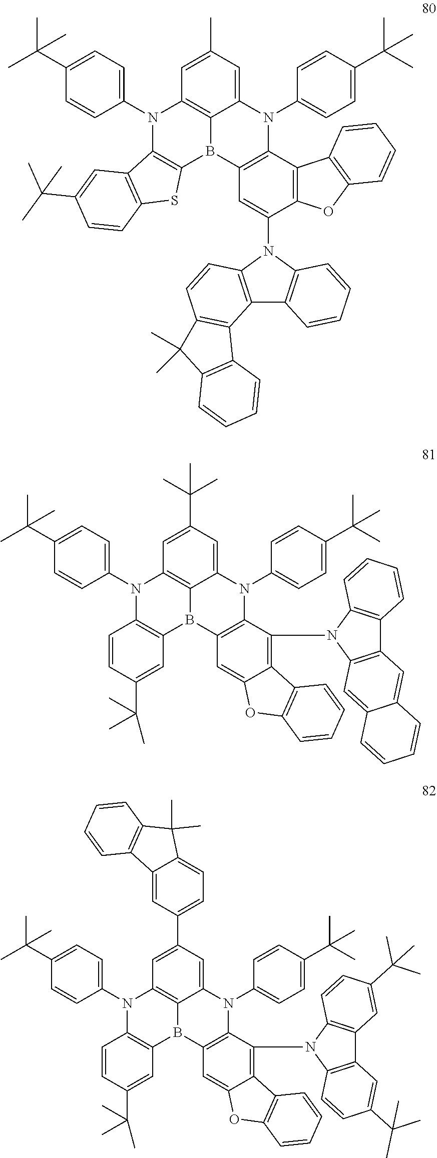

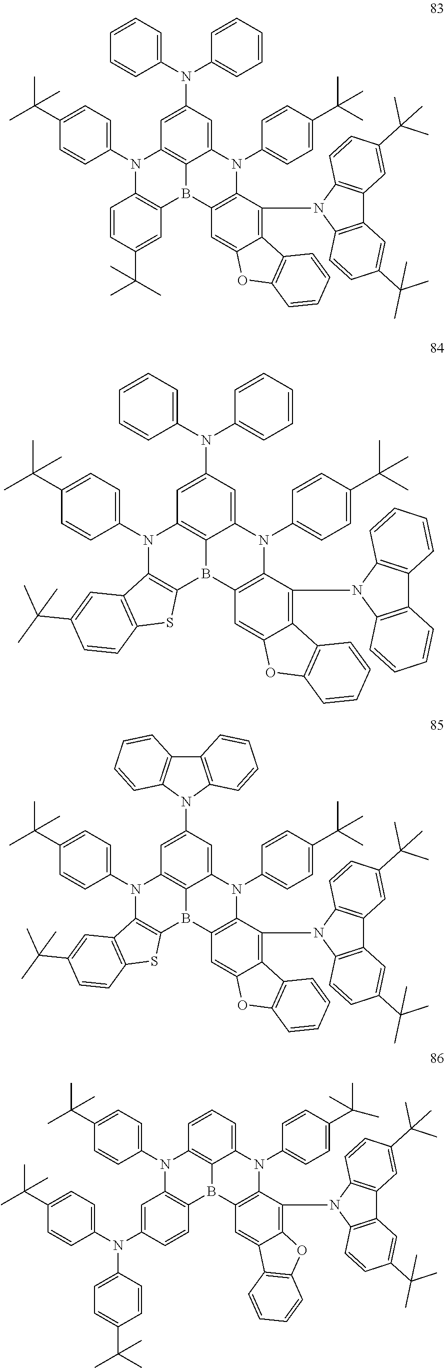

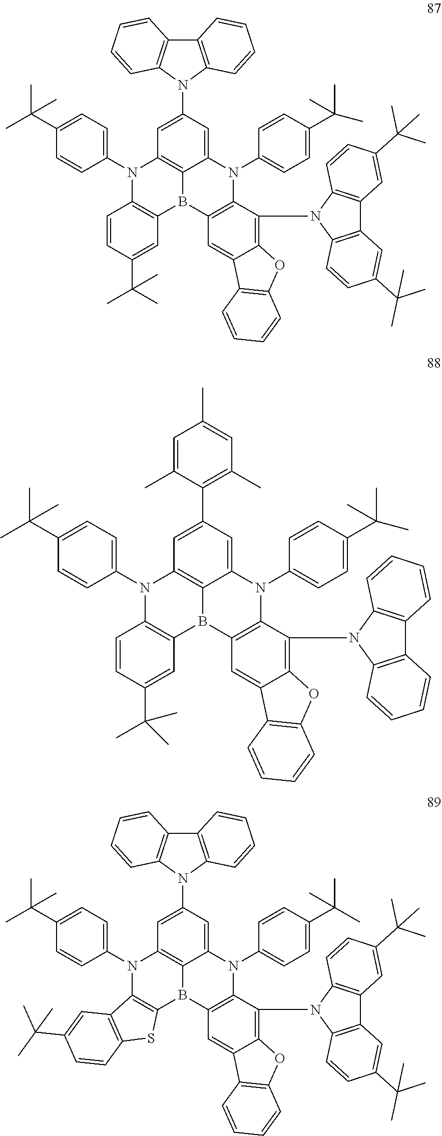

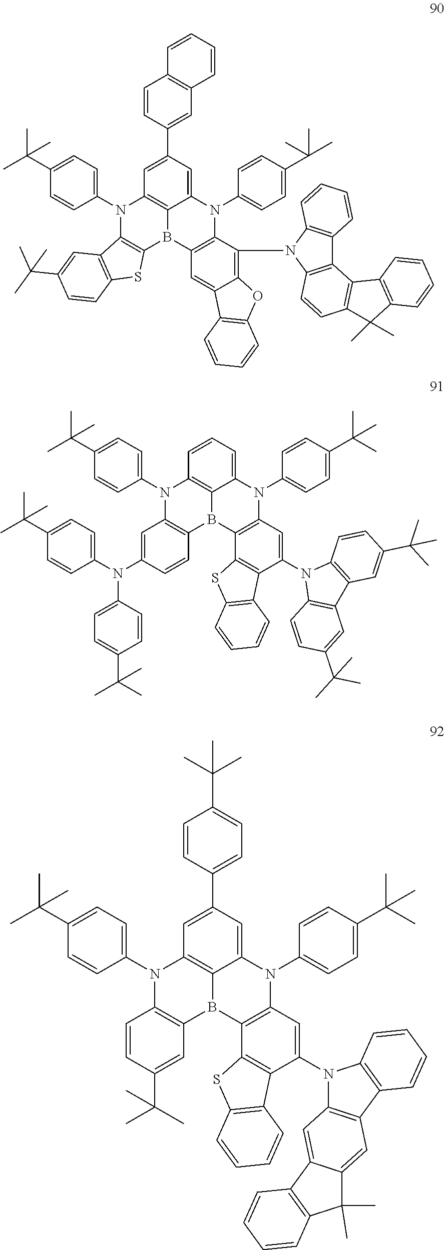

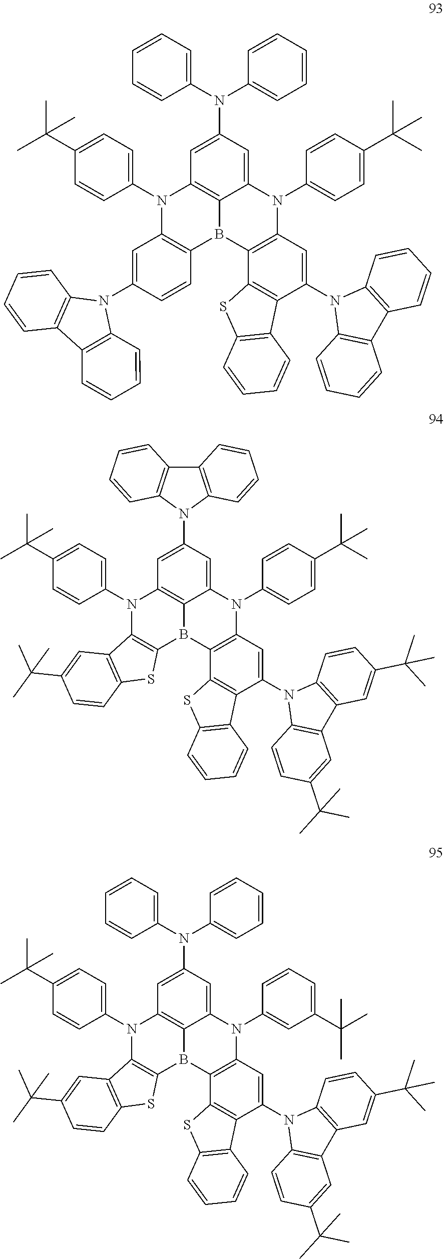

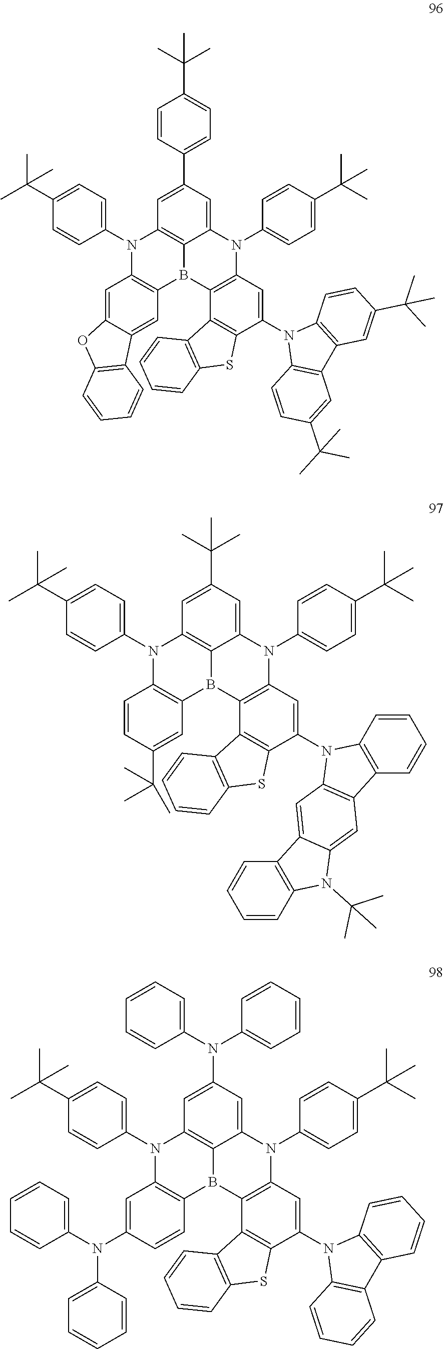

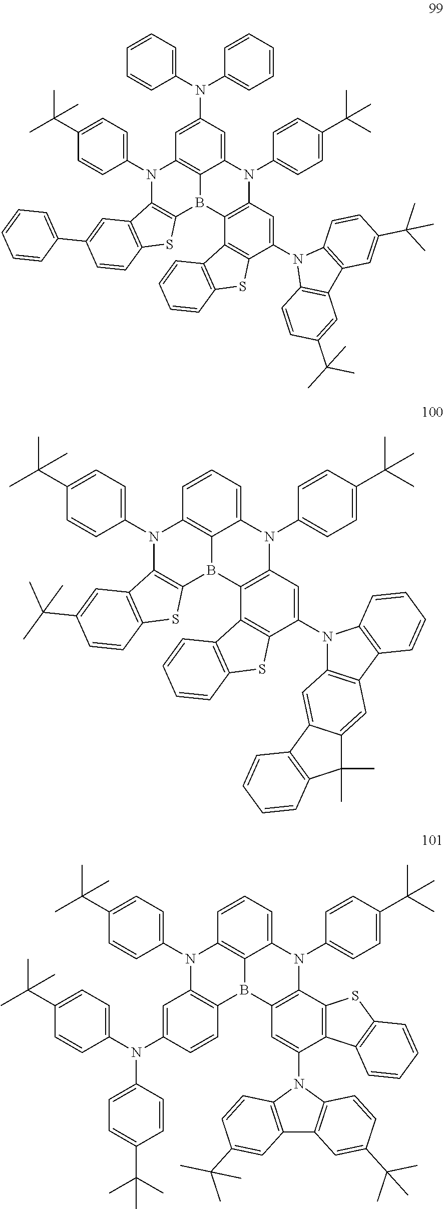

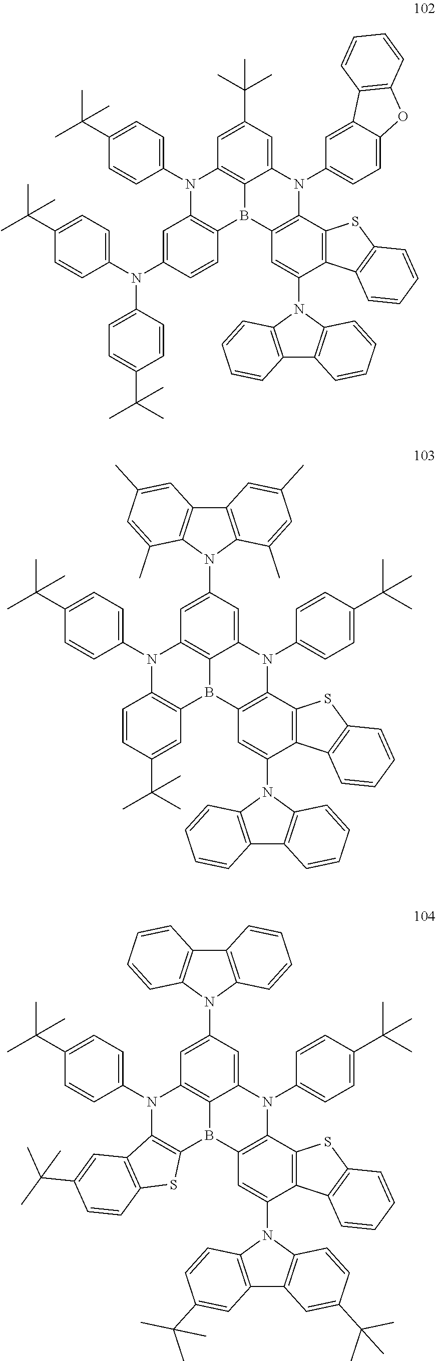

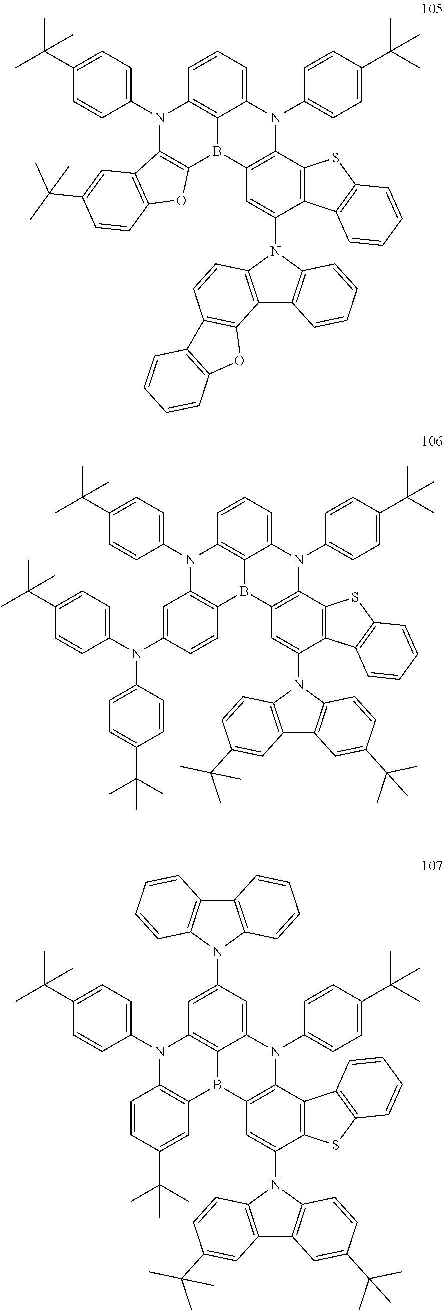

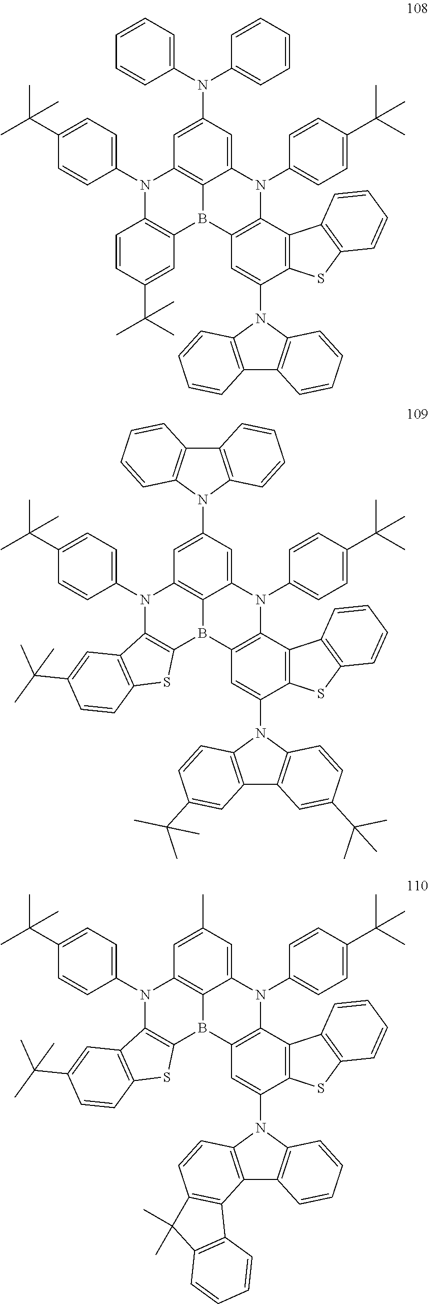

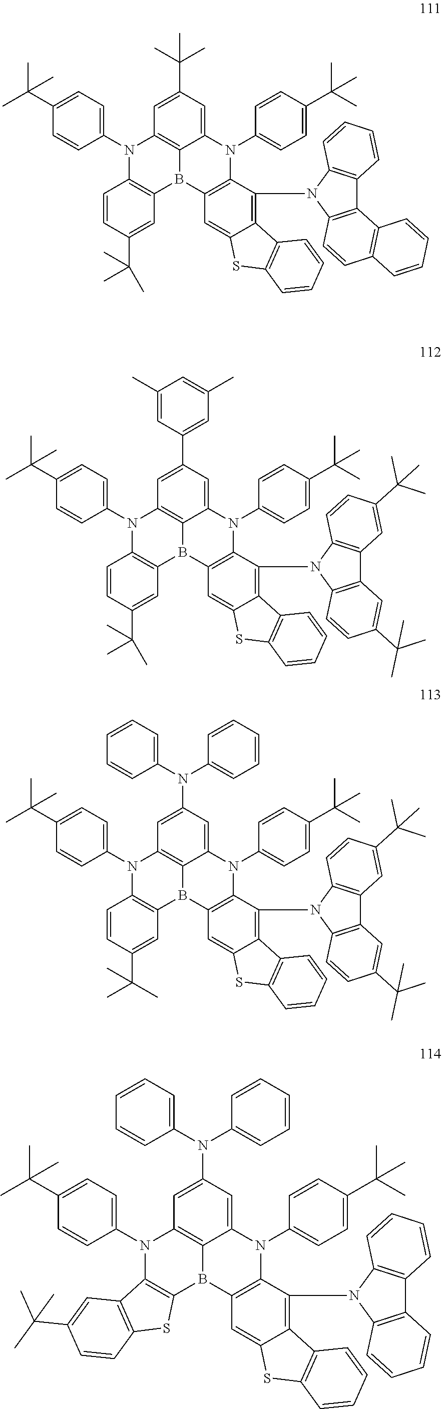

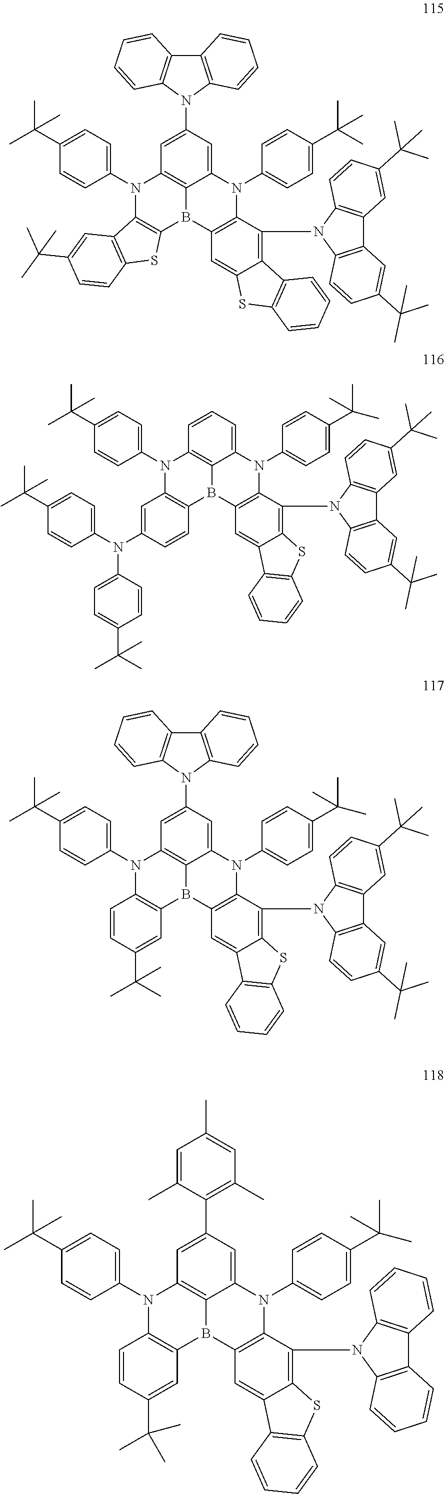

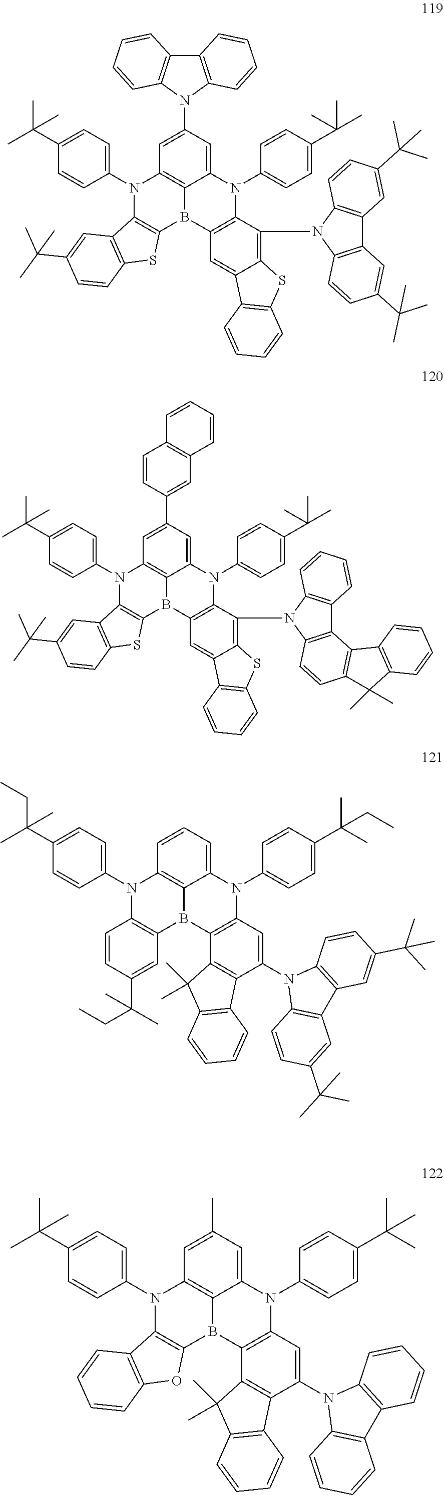

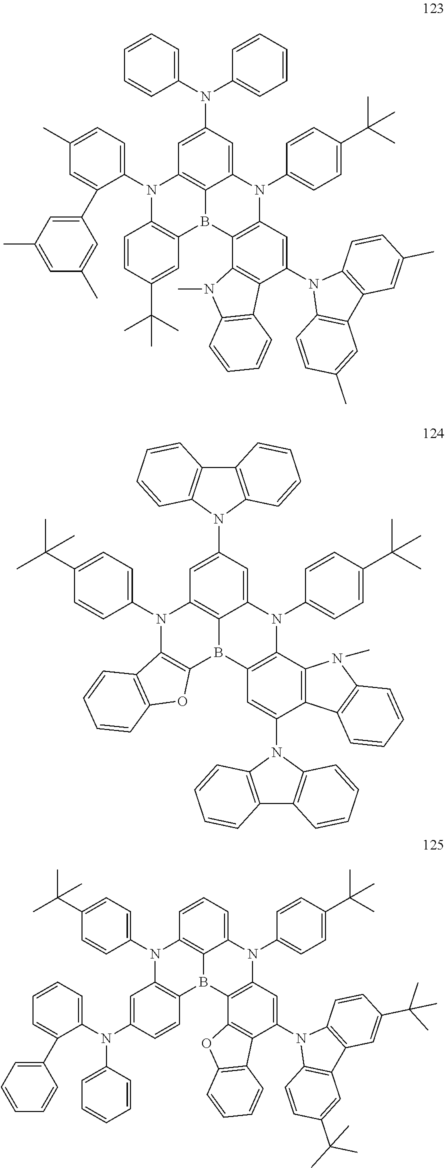

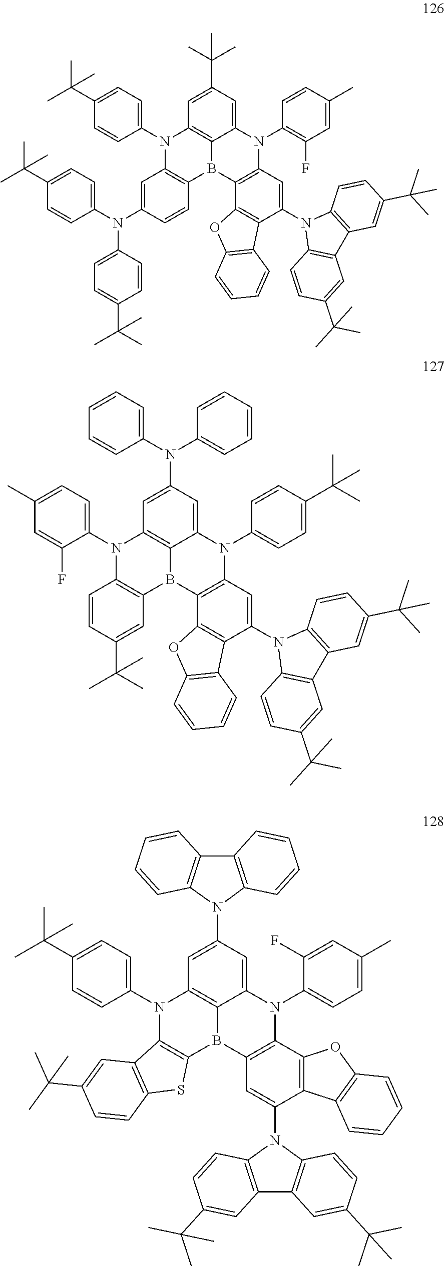

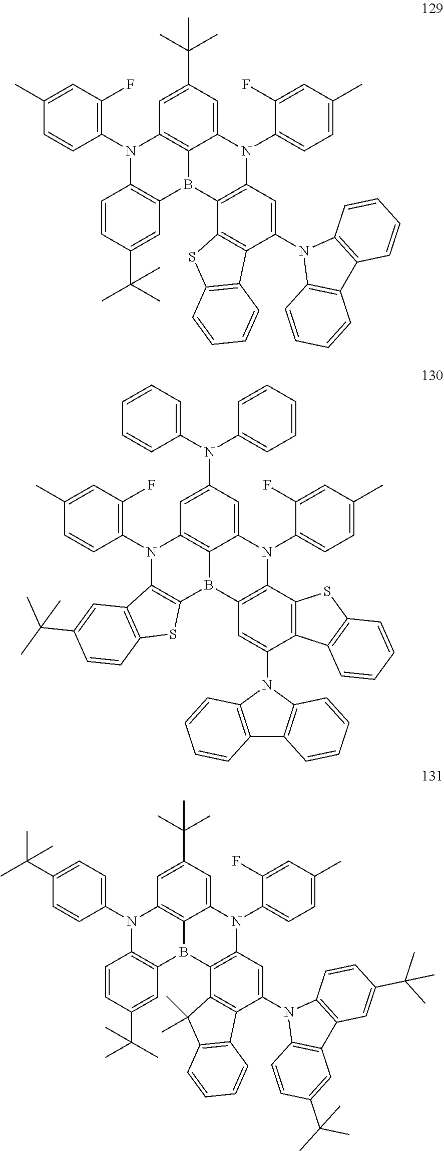 [SMILES: Cc1ccc(N2c3ccc(C(C)(C)C)cc3B3c4c2cc(C(C)(C)C)cc4N(c2ccc(C)cc2F)c2cc(-n4c5ccccc5c5ccccc54)c4c(sc5ccccc54)c23)c(F)c1 ; Cc1ccc(N2c3cc(N(c4ccccc4)c4ccccc4)cc4c3B(c3cc(-n5c6ccccc6c6ccccc65)c5c(sc6ccccc65)c3N4c3ccc(C)cc3F)c3sc4ccc(C(C)(C)C)cc4c32)c(F)c1 ; Cc1ccc(N2c3cc(C(C)(C)C)cc4c3B(c3cc(C(C)(C)C)ccc3N4c3ccc(C(C)(C)C)cc3)c3c2cc(-n2c4ccc(C(C)(C)C)cc4c4cc(C(C)(C)C)ccc42)c2c3C(C)(C)c3ccccc3-2)c(F)c1]

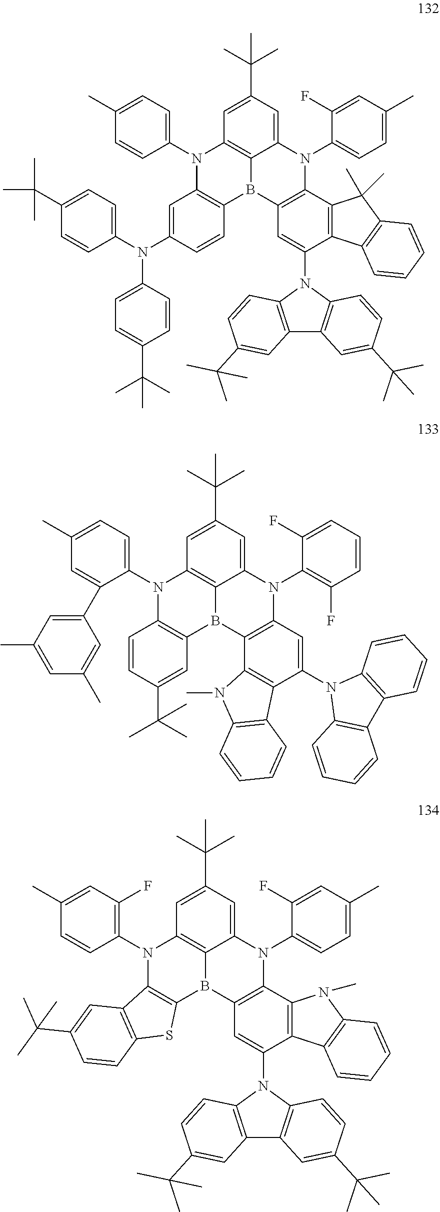 [SMILES: Cc1ccc(N2c3cc(N(c4ccc(C(C)(C)C)cc4)c4ccc(C(C)(C)C)cc4)ccc3B3c4cc(-n5c6ccc(C(C)(C)C)cc6c6cc(C(C)(C)C)ccc65)c5c(c4N(c4ccc(C)cc4F)c4cc(C(C)(C)C)cc2c43)C(C)(C)c2ccccc2-5)cc1 ; Cc1cc(C)cc(-c2cc(C)ccc2N2c3ccc(C(C)(C)C)cc3B3c4c2cc(C(C)(C)C)cc4N(c2c(F)cccc2F)c2cc(-n4c5ccccc5c5ccccc54)c4c5ccccc5n(C)c4c23)c1 ; Cc1ccc(N2c3cc(C(C)(C)C)cc4c3B(c3cc(-n5c6ccc(C(C)(C)C)cc6c6cc(C(C)(C)C)ccc65)c5c6ccccc6n(C)c5c3N4c3ccc(C)cc3F)c3sc4ccc(C(C)(C)C)cc4c32)c(F)c1]

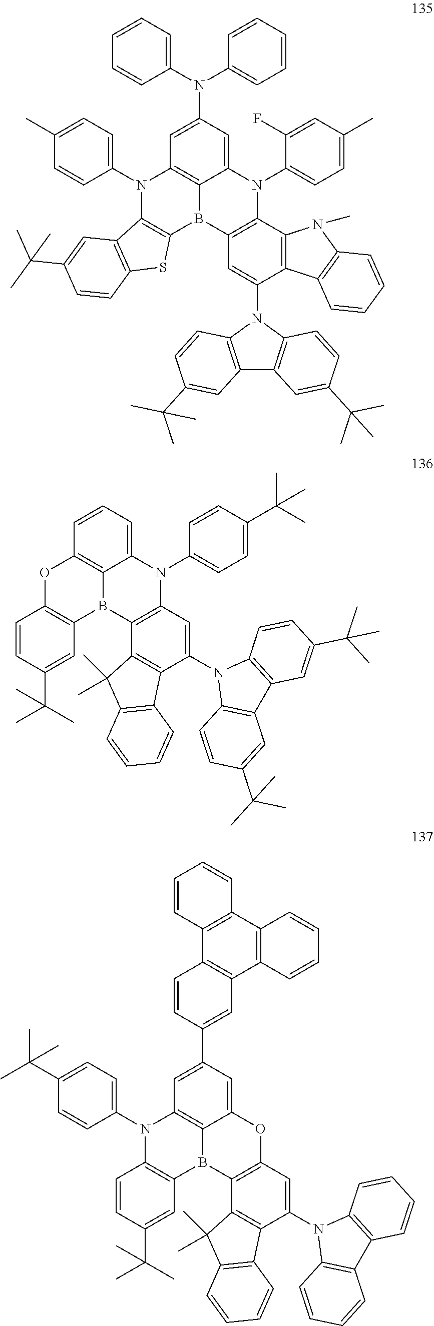

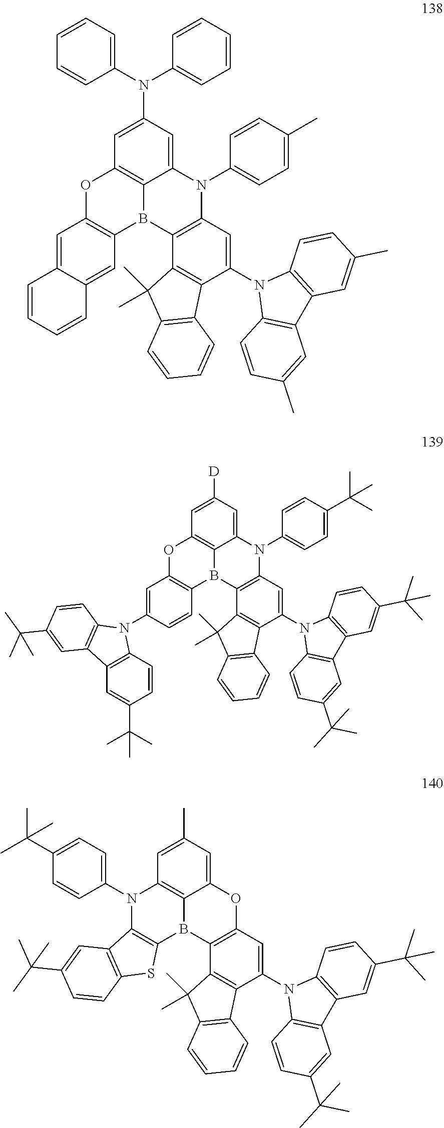

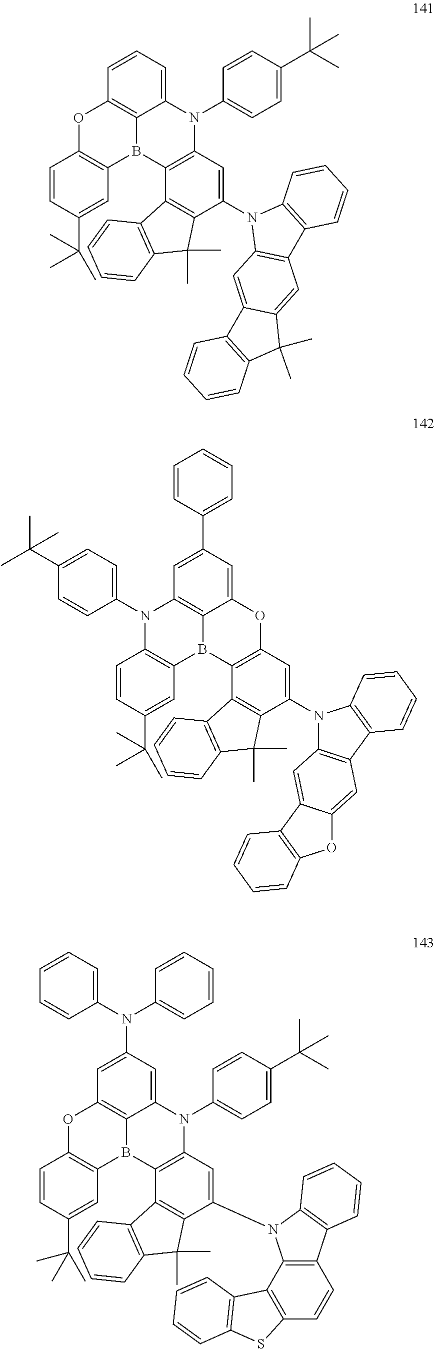 [SMILES: CC(C)(C)c1ccc(N2c3cccc4c3B(c3cc(C(C)(C)C)ccc3O4)c3c2cc(-n2c4ccccc4c4cc5c(cc42)-c2ccccc2C5(C)C)c2c3-c3ccccc3C2(C)C)cc1 ; CC(C)(C)c1ccc(N2c3ccc(C(C)(C)C)cc3B3c4c(cc(-c5ccccc5)cc42)Oc2cc(-n4c5ccccc5c5cc6oc7ccccc7c6cc54)c4c(c23)-c2ccccc2C4(C)C)cc1 ; CC(C)(C)c1ccc(N2c3cc(N(c4ccccc4)c4ccccc4)cc4c3B(c3cc(C(C)(C)C)ccc3O4)c3c2cc(-n2c4ccccc4c4ccc5sc6ccccc6c5c42)c2c3-c3ccccc3C2(C)C)cc1]

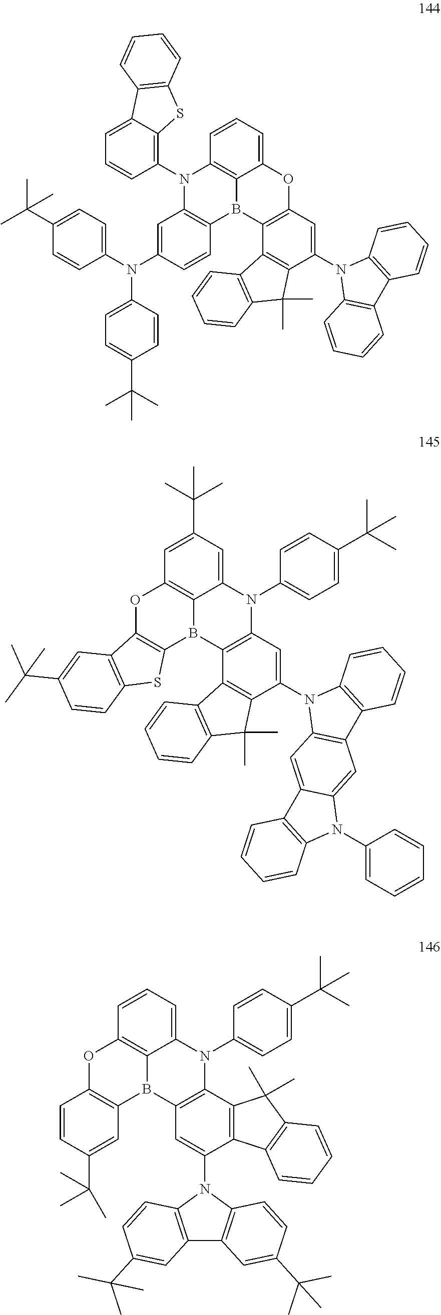 [SMILES: CC(C)(C)c1ccc(N(c2ccc(C(C)(C)C)cc2)c2ccc3c(c2)N(c2cccc4c2sc2ccccc24)c2cccc4c2B3c2c(cc(-n3c5ccccc5c5ccccc53)c3c2-c2ccccc2C3(C)C)O4)cc1 ; CC(C)(C)c1ccc(N2c3cc(C(C)(C)C)cc4c3B(c3sc5ccc(C(C)(C)C)cc5c3O4)c3c2cc(-n2c4ccccc4c4cc5c(cc42)c2ccccc2n5-c2ccccc2)c2c3-c3ccccc3C2(C)C)cc1 ; CC(C)(C)c1ccc(N2c3cccc4c3B(c3cc(C(C)(C)C)ccc3O4)c3cc(-n4c5ccc(C(C)(C)C)cc5c5cc(C(C)(C)C)ccc54)c4c(c32)C(C)(C)c2ccccc2-4)cc1]

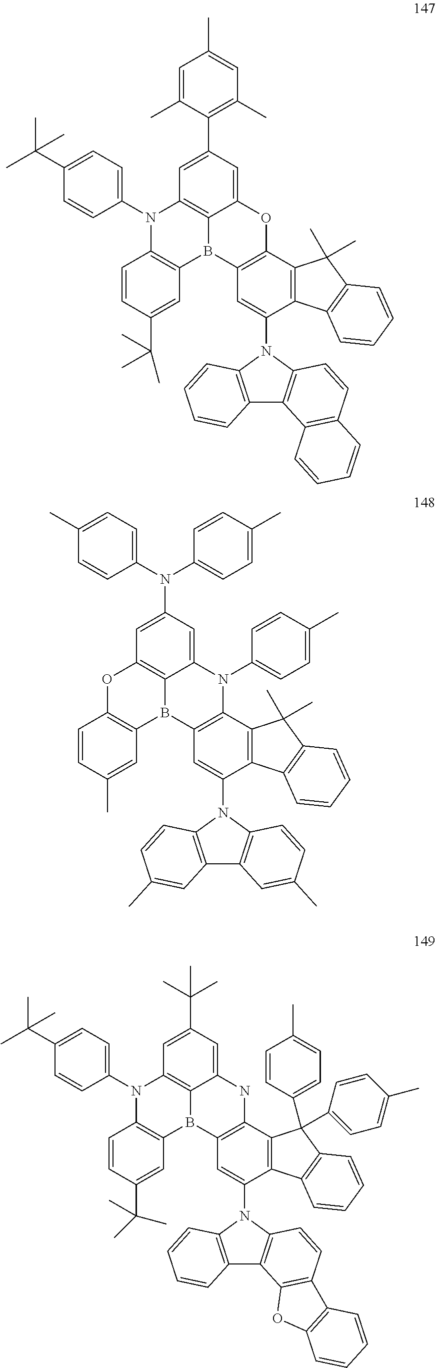

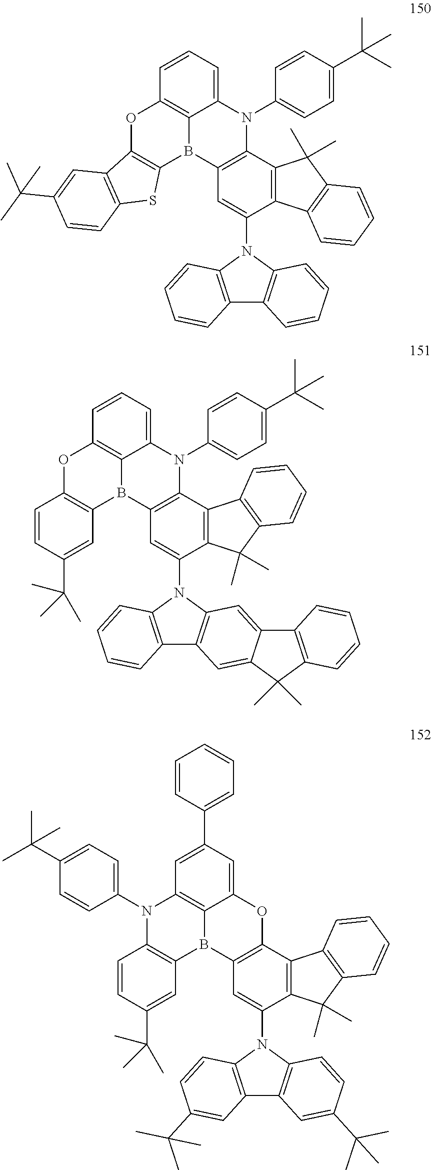

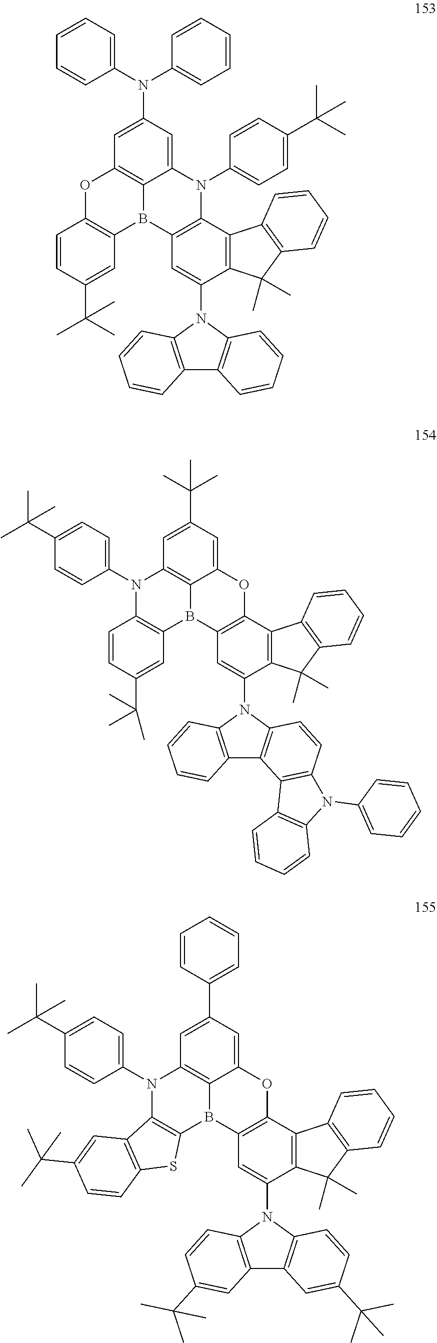

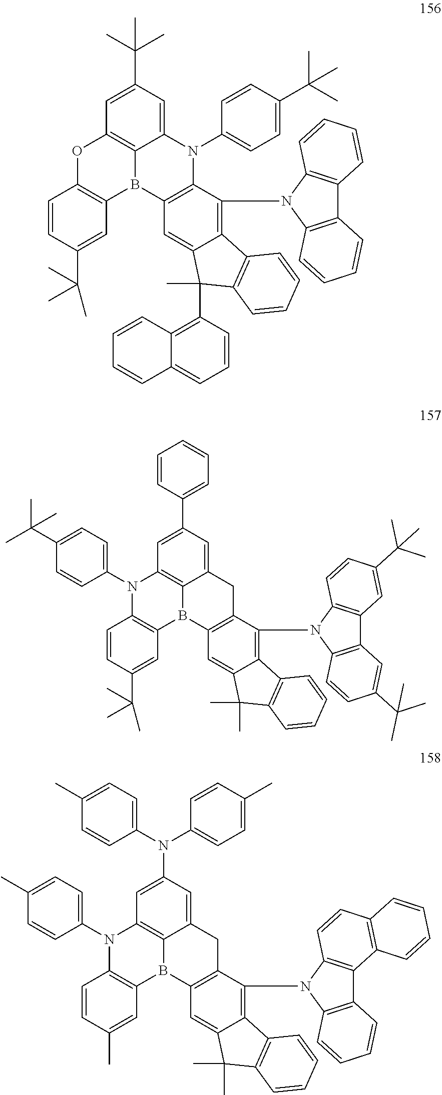

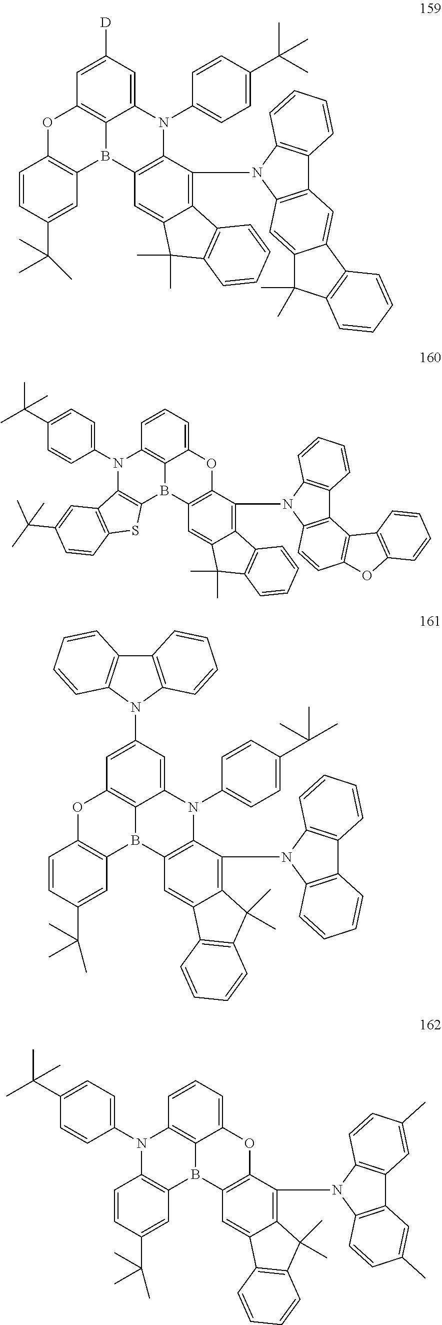

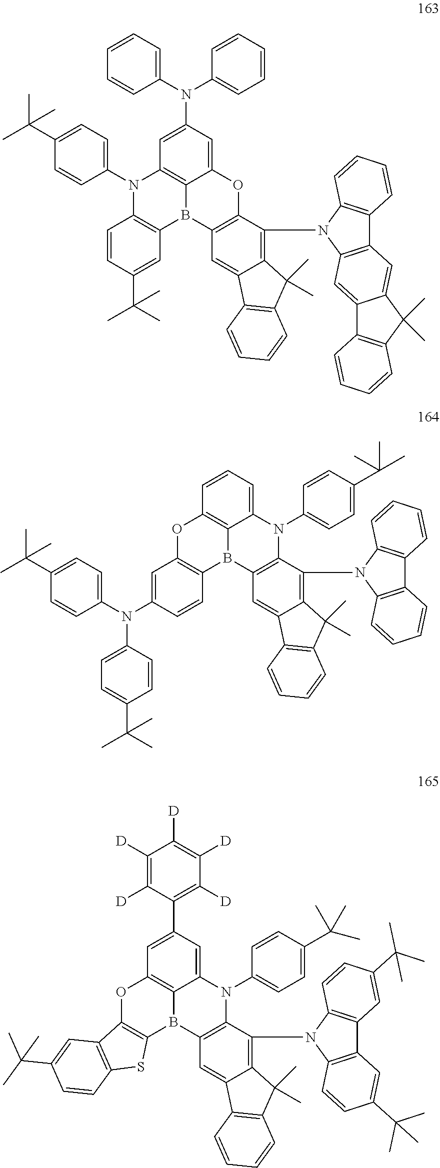

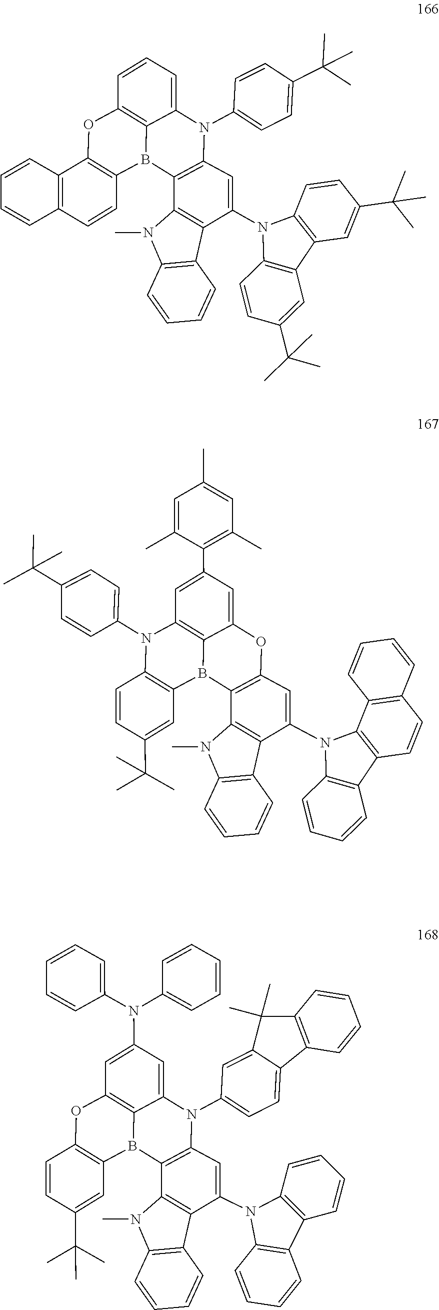

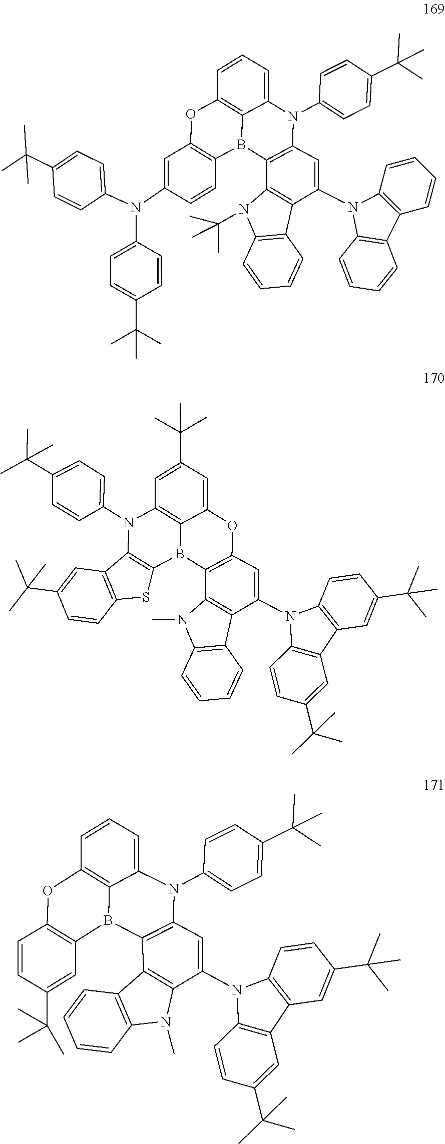

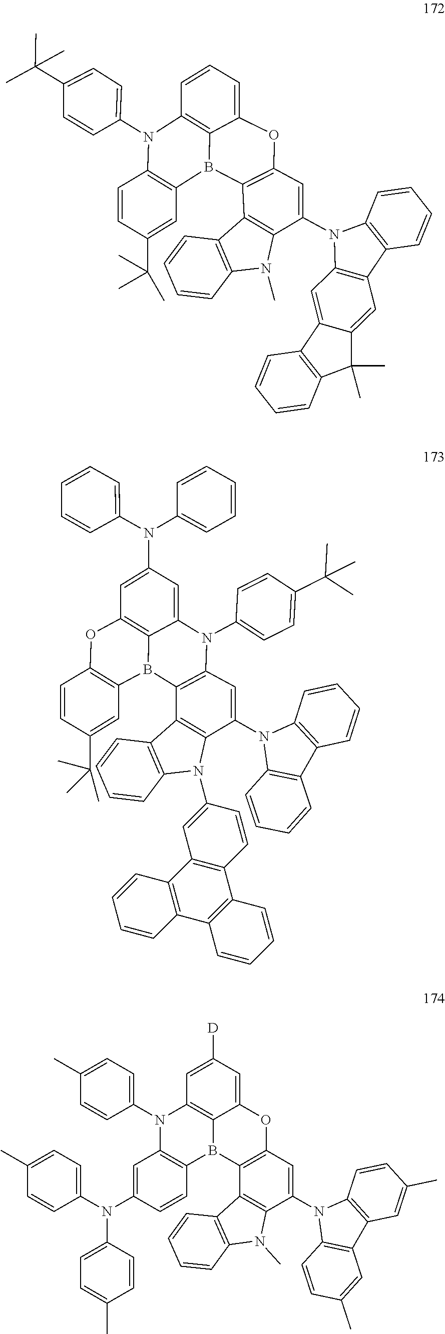

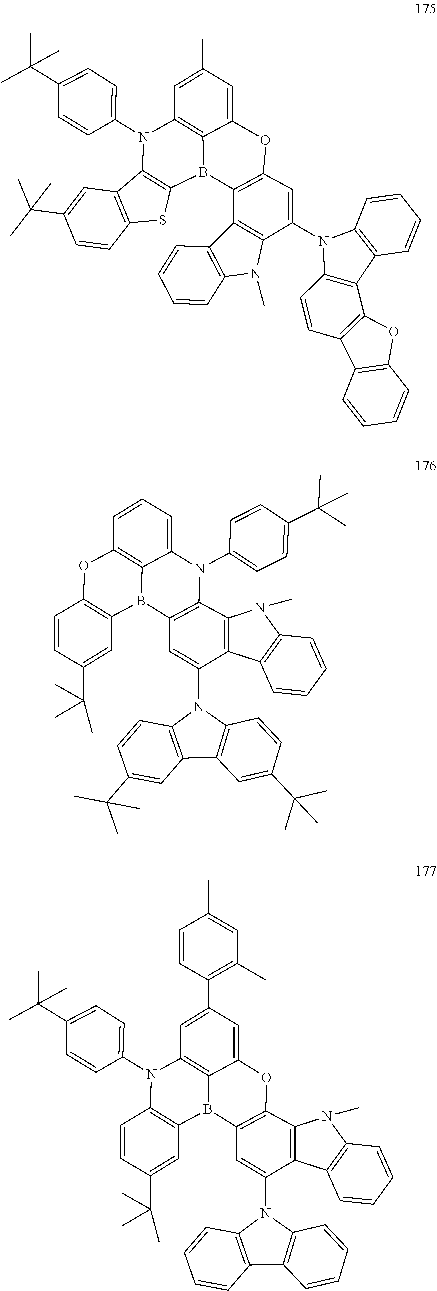

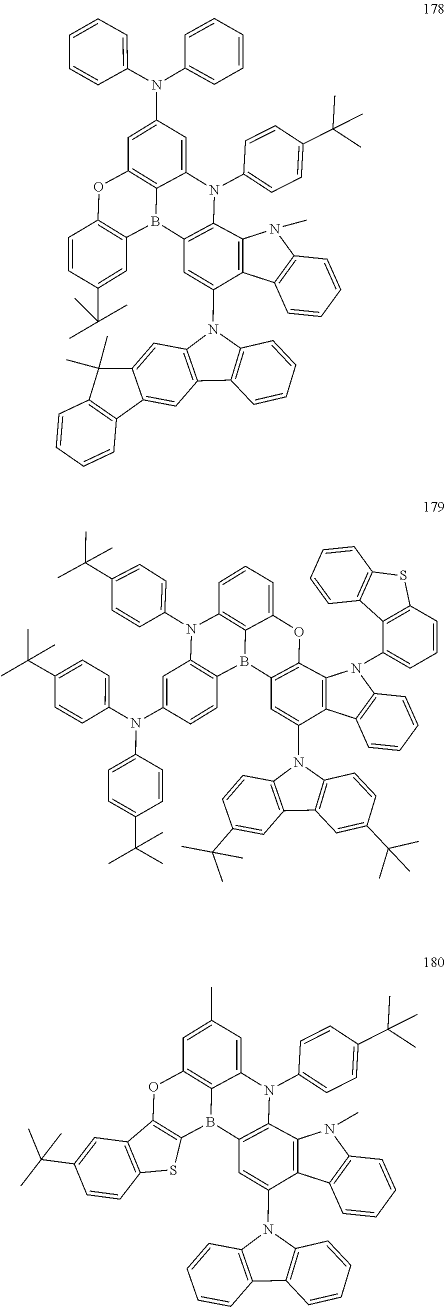

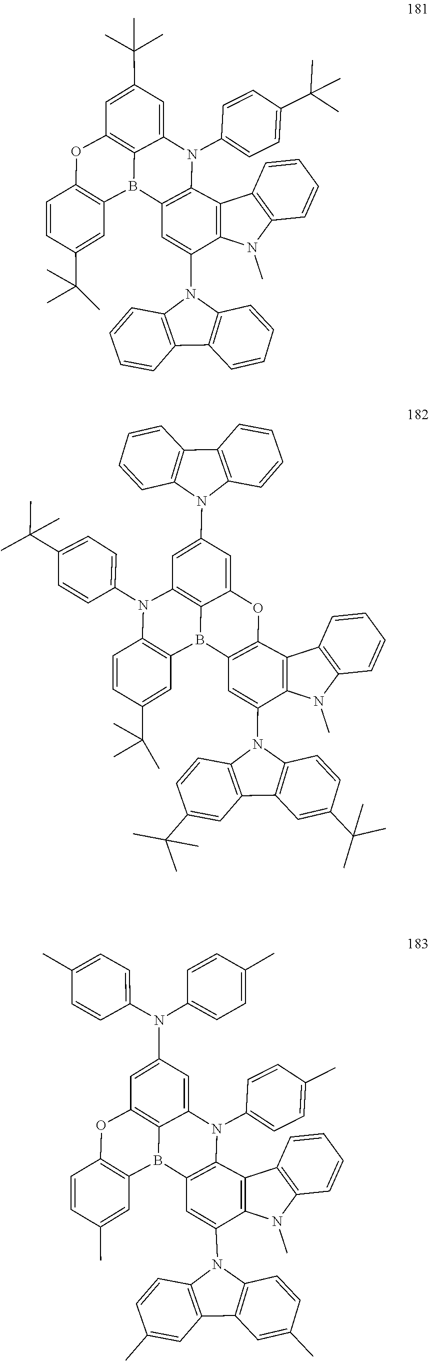

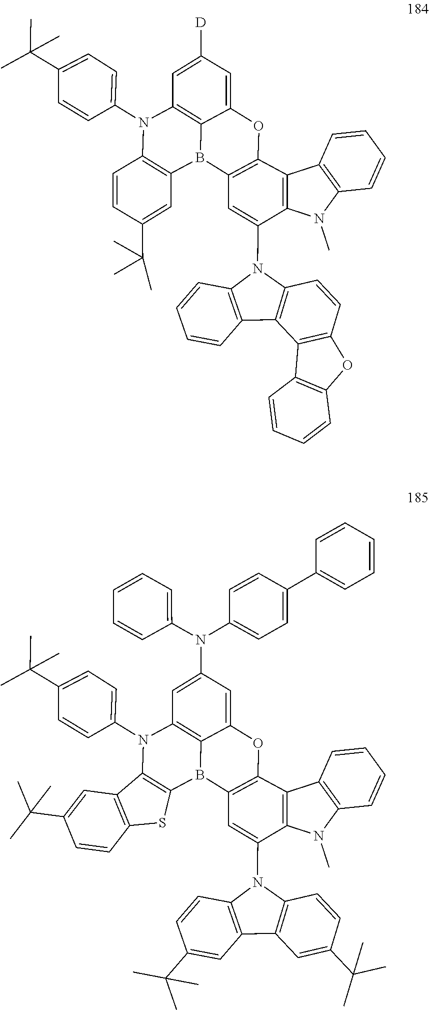 [SMILES: [2H]c1cc2c3c(c1)N(c1ccc(C(C)(C)C)cc1)c1ccc(C(C)(C)C)cc1B3c1cc(-n3c4ccccc4c4c5c(ccc43)oc3ccccc35)c3c(c1O2)c1ccccc1n3C ; Cn1c2ccccc2c2c3c(cc(-n4c5ccc(C(C)(C)C)cc5c5cc(C(C)(C)C)ccc54)c21)B1c2sc4ccc(C(C)(C)C)cc4c2N(c2ccc(C(C)(C)C)cc2)c2cc(N(c4ccccc4)c4ccc(-c5ccccc5)cc4)cc(c21)O3]

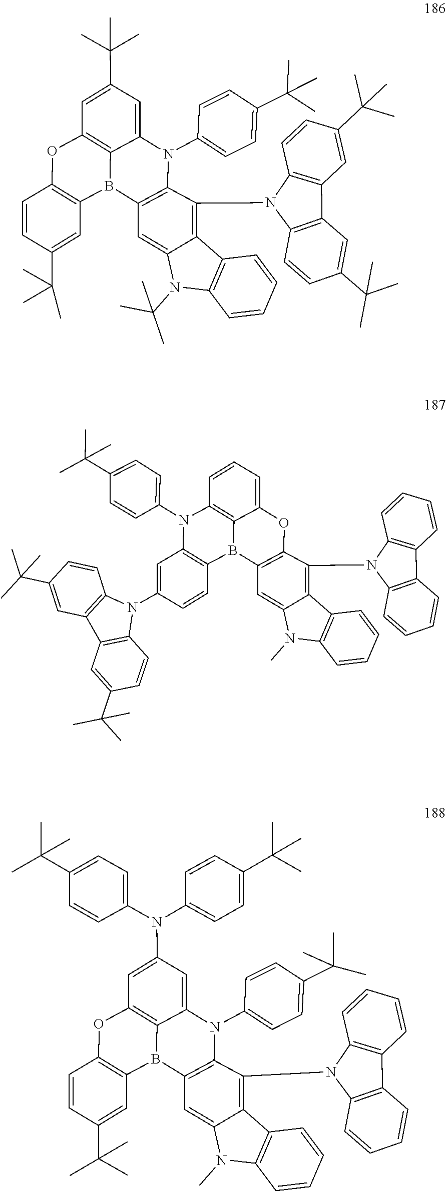

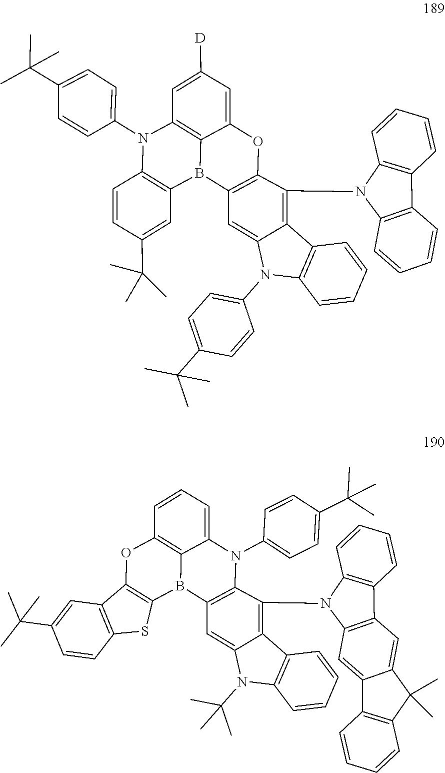 [SMILES: [2H]c1cc2c3c(c1)N(c1ccc(C(C)(C)C)cc1)c1ccc(C(C)(C)C)cc1B3c1cc3c(c(-n4c5ccccc5c5ccccc54)c1O2)c1ccccc1n3-c1ccc(C(C)(C)C)cc1 ; CC(C)(C)c1ccc(N2c3cccc4c3B(c3cc5c(c(-n6c7ccccc7c7cc8c(cc76)-c6ccccc6C8(C)C)c32)c2ccccc2n5C(C)(C)C)c2sc3ccc(C(C)(C)C)cc3c2O4)cc1]

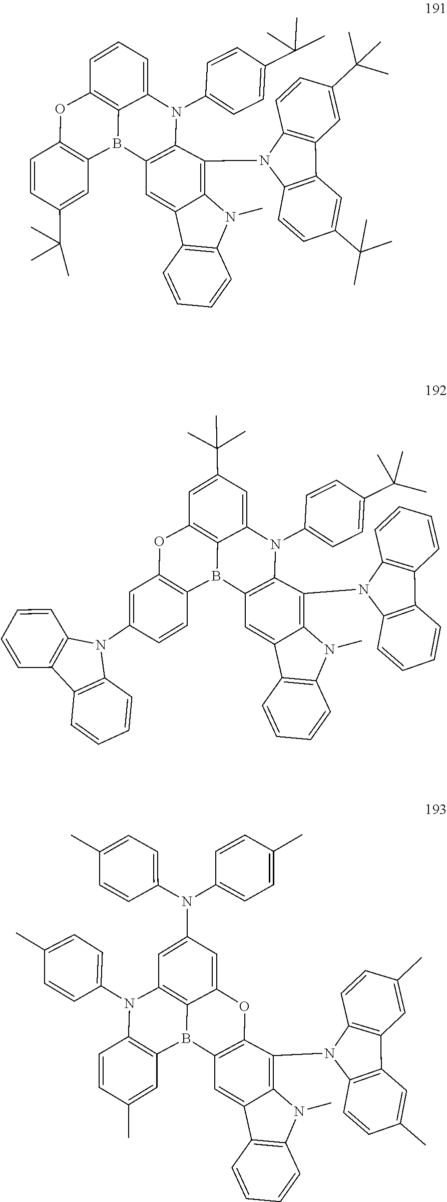

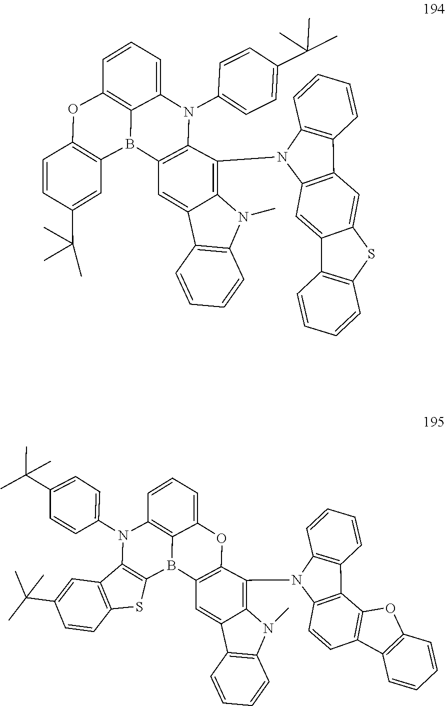 [SMILES: Cn1c2ccccc2c2cc3c(c(-n4c5ccccc5c5cc6sc7ccccc7c6cc54)c21)N(c1ccc(C(C)(C)C)cc1)c1cccc2c1B3c1cc(C(C)(C)C)ccc1O2 ; Cn1c2ccccc2c2cc3c(c(-n4c5ccccc5c5c6oc7ccccc7c6ccc54)c21)Oc1cccc2c1B3c1sc3ccc(C(C)(C)C)cc3c1N2c1ccc(C(C)(C)C)cc1]

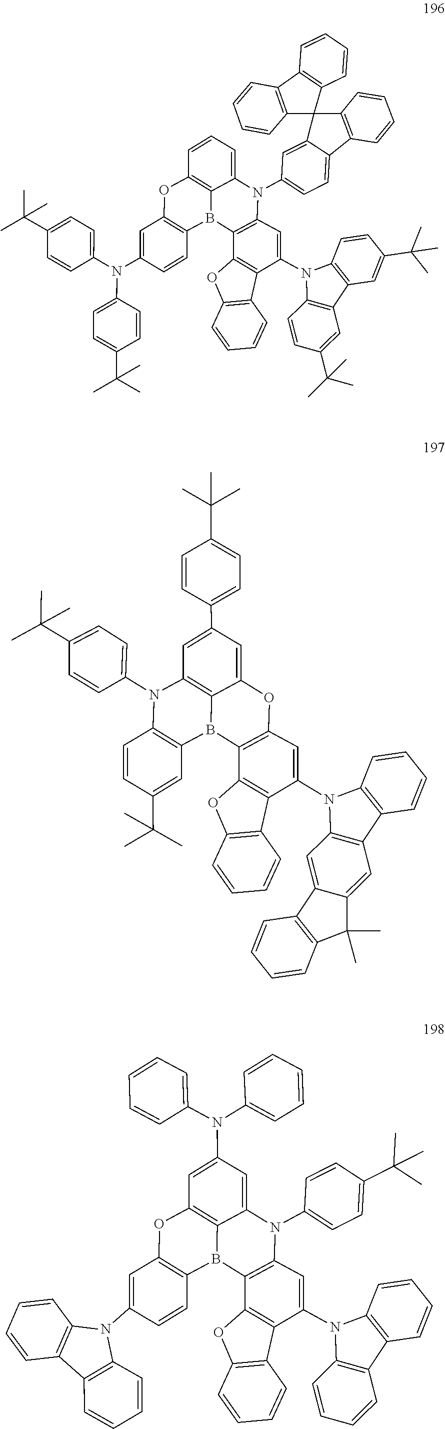

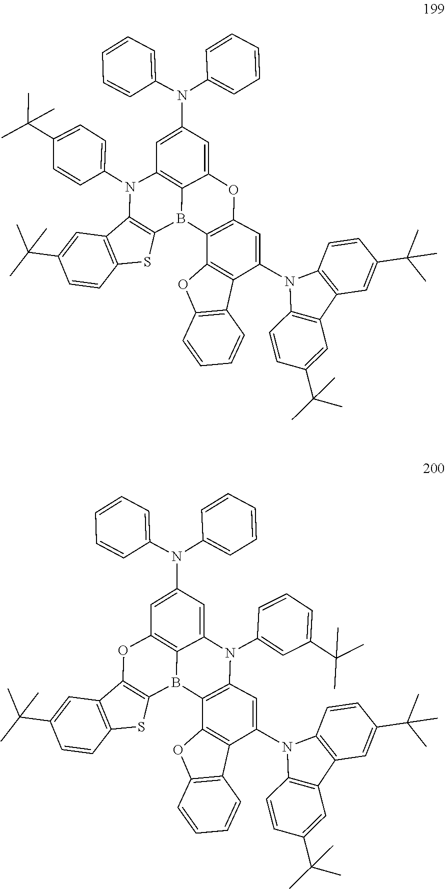

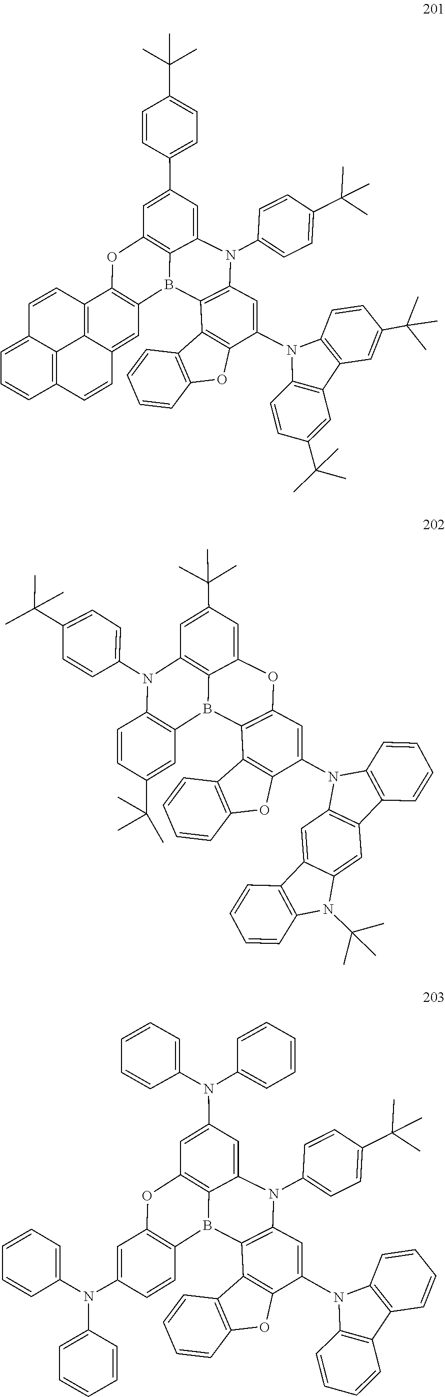

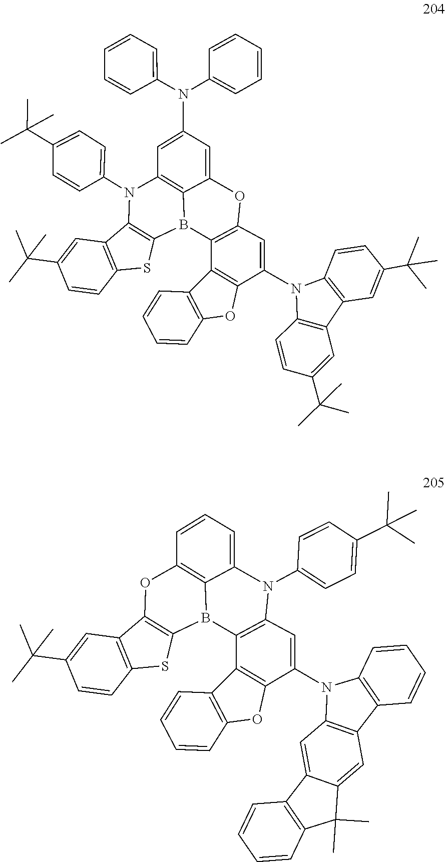

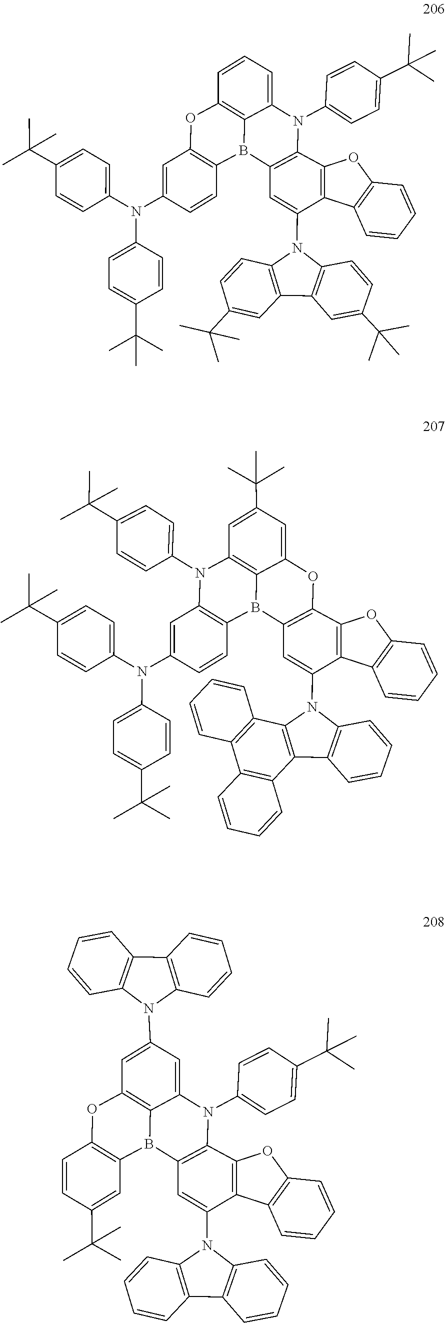

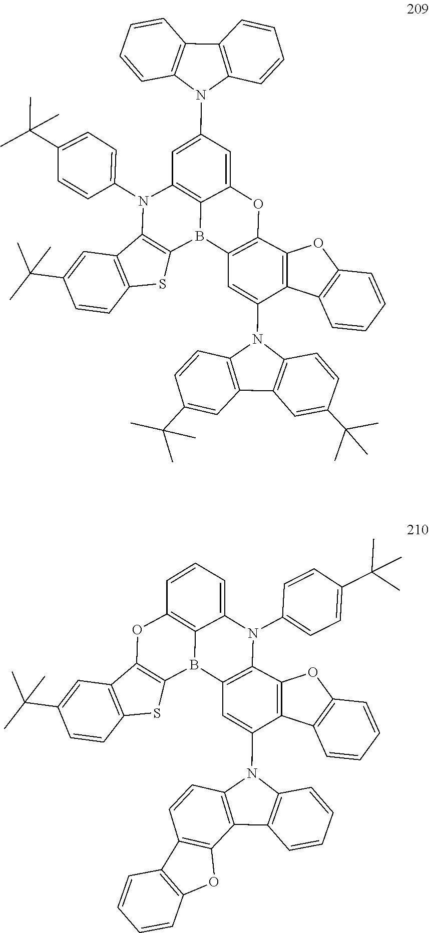 [SMILES: CC(C)(C)c1ccc(N2c3cc(-n4c5ccccc5c5ccccc54)cc4c3B(c3cc(-n5c6ccc(C(C)(C)C)cc6c6cc(C(C)(C)C)ccc65)c5c(oc6ccccc65)c3O4)c3sc4ccc(C(C)(C)C)cc4c32)cc1 ; CC(C)(C)c1ccc(N2c3cccc4c3B(c3cc(-n5c6ccccc6c6c7oc8ccccc8c7ccc65)c5c(oc6ccccc65)c32)c2sc3ccc(C(C)(C)C)cc3c2O4)cc1]

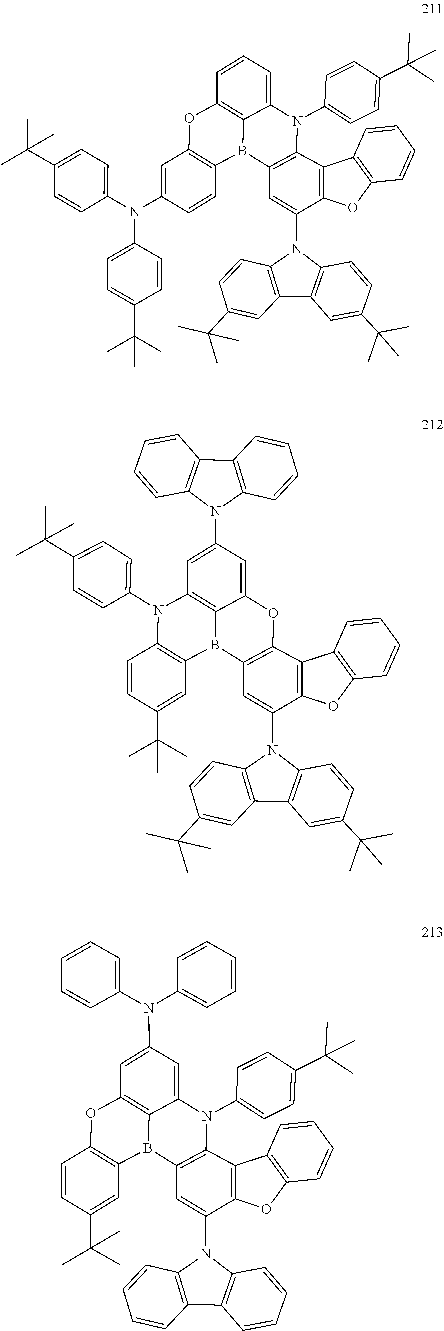

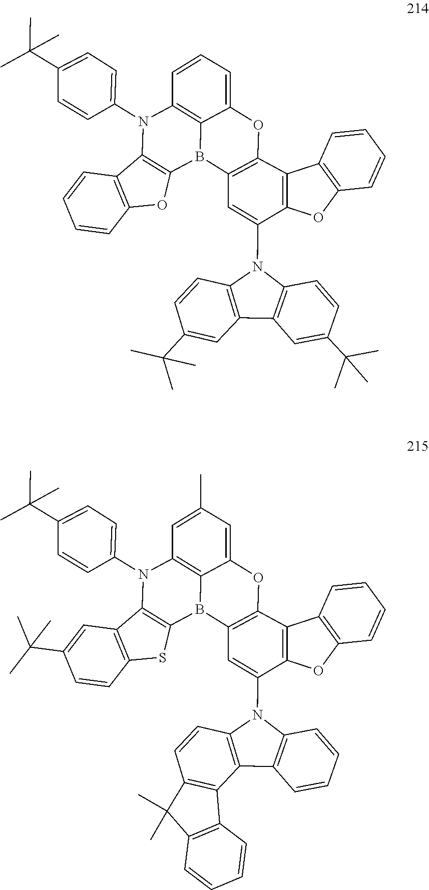 [SMILES: CC(C)(C)c1ccc(N2c3cccc4c3B(c3cc(-n5c6ccc(C(C)(C)C)cc6c6cc(C(C)(C)C)ccc65)c5oc6ccccc6c5c3O4)c3oc4ccccc4c32)cc1 ; Cc1cc2c3c(c1)N(c1ccc(C(C)(C)C)cc1)c1c(sc4ccc(C(C)(C)C)cc14)B3c1cc(-n3c4ccccc4c4c5c(ccc43)C(C)(C)c3ccccc3-5)c3oc4ccccc4c3c1O2]

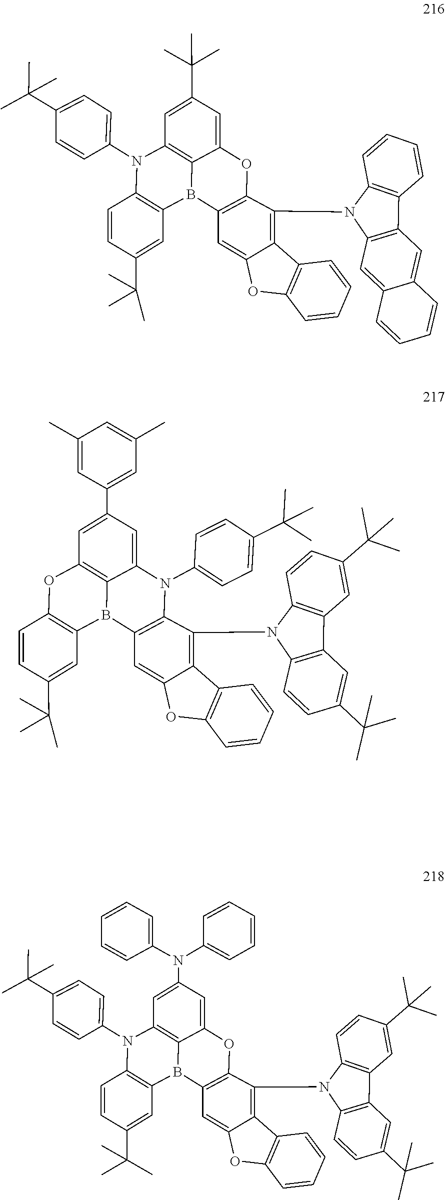

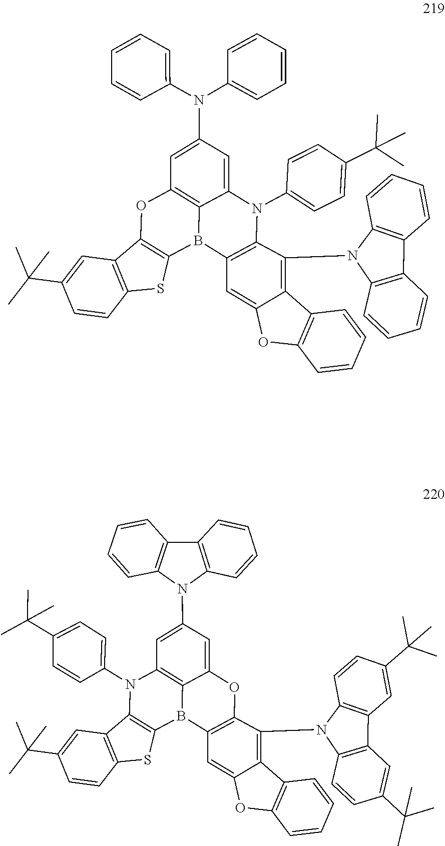 [SMILES: CC(C)(C)c1ccc(N2c3cc(N(c4ccccc4)c4ccccc4)cc4c3B(c3cc5oc6ccccc6c5c(-n5c6ccccc6c6ccccc65)c32)c2sc3ccc(C(C)(C)C)cc3c2O4)cc1 ; CC(C)(C)c1ccc(N2c3cc(-n4c5ccccc5c5ccccc54)cc4c3B(c3cc5oc6ccccc6c5c(-n5c6ccc(C(C)(C)C)cc6c6cc(C(C)(C)C)ccc65)c3O4)c3sc4ccc(C(C)(C)C)cc4c32)cc1]

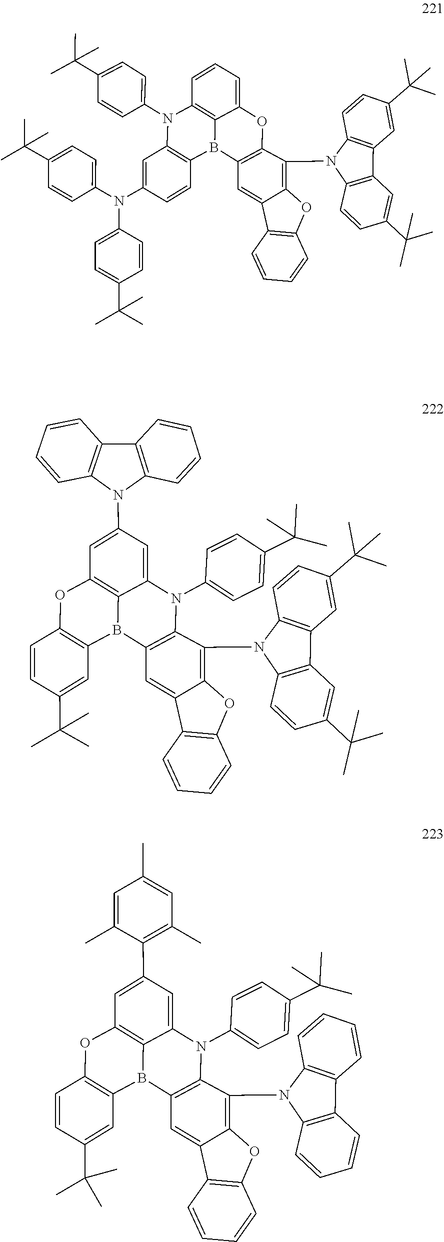 [SMILES: CC(C)(C)c1ccc(N(c2ccc(C(C)(C)C)cc2)c2ccc3c(c2)N(c2ccc(C(C)(C)C)cc2)c2cccc4c2B3c2cc3c(oc5ccccc53)c(-n3c5ccc(C(C)(C)C)cc5c5cc(C(C)(C)C)ccc53)c2O4)cc1 ; CC(C)(C)c1ccc(N2c3cc(-n4c5ccccc5c5ccccc54)cc4c3B(c3cc(C(C)(C)C)ccc3O4)c3cc4c(oc5ccccc54)c(-n4c5ccc(C(C)(C)C)cc5c5cc(C(C)(C)C)ccc54)c32)cc1 ; Cc1cc(C)c(-c2cc3c4c(c2)N(c2ccc(C(C)(C)C)cc2)c2c(cc5c(oc6ccccc65)c2-n2c5ccccc5c5ccccc52)B4c2cc(C(C)(C)C)ccc2O3)c(C)c1]

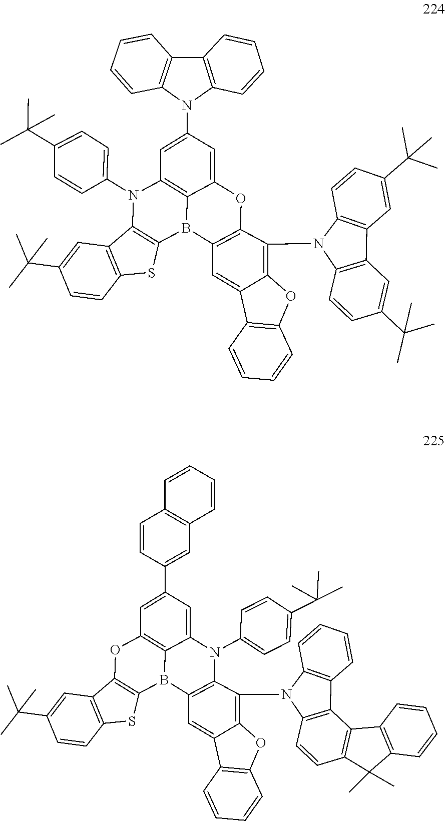

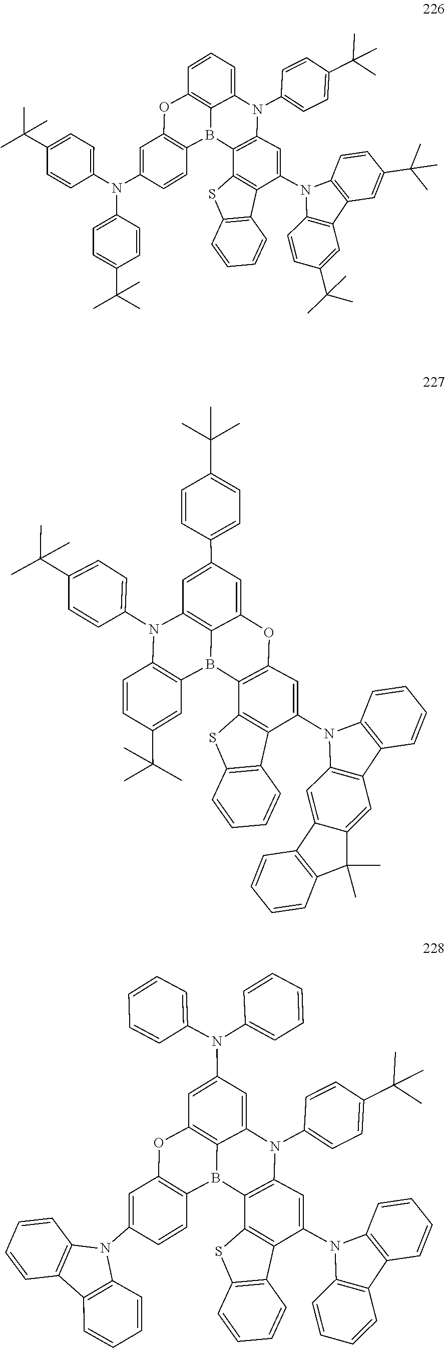

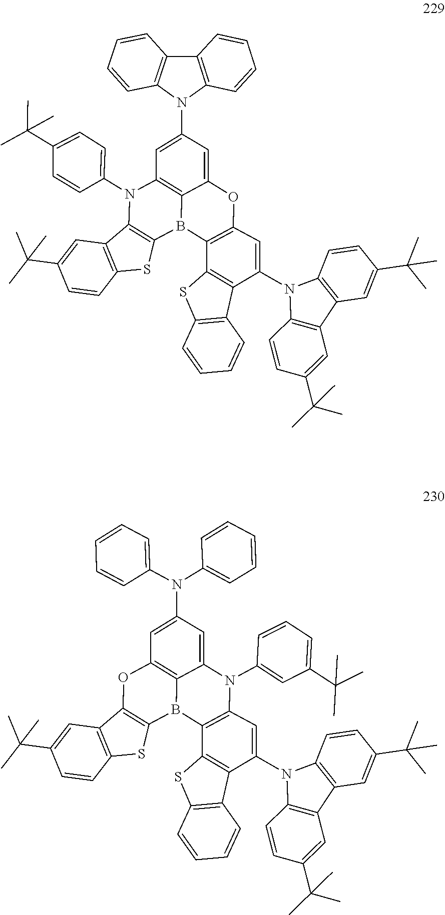

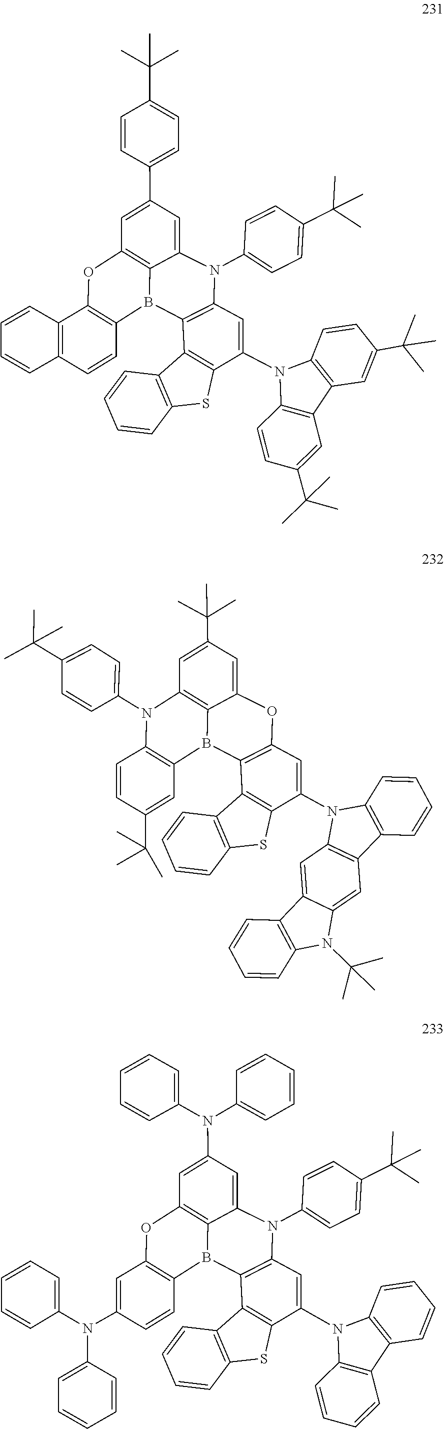

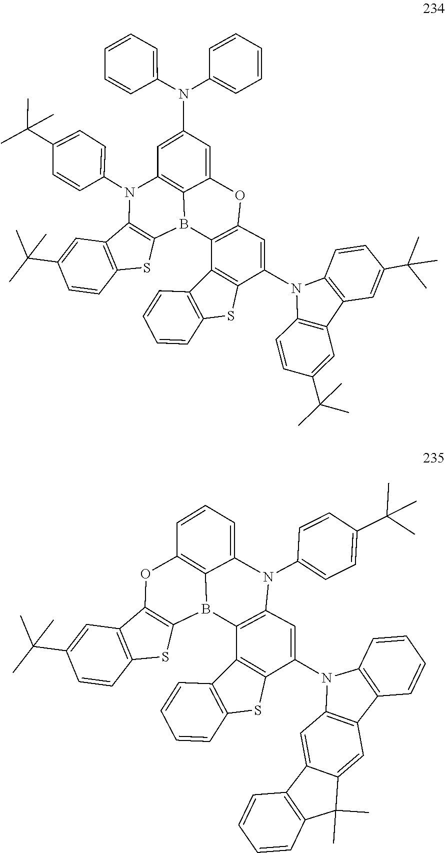

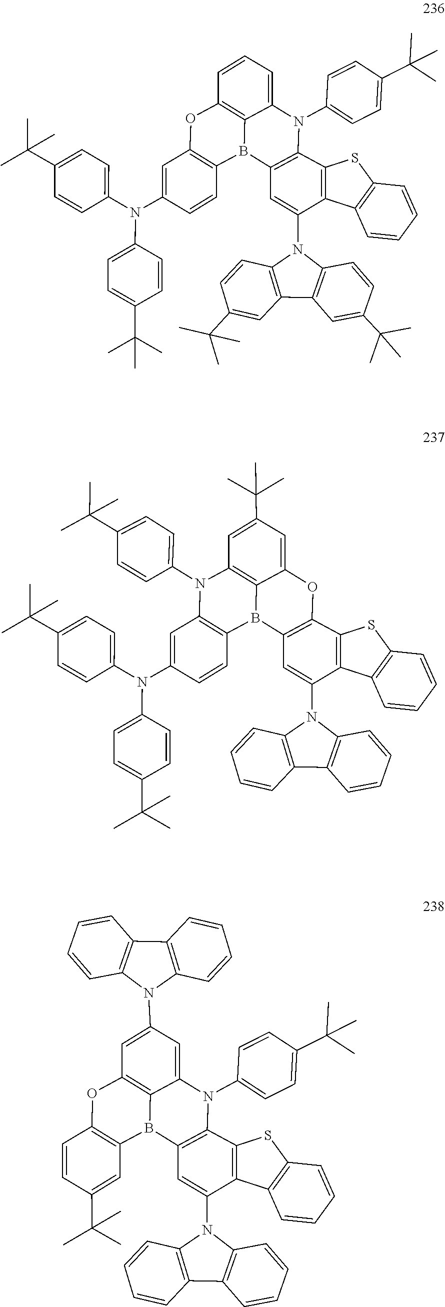

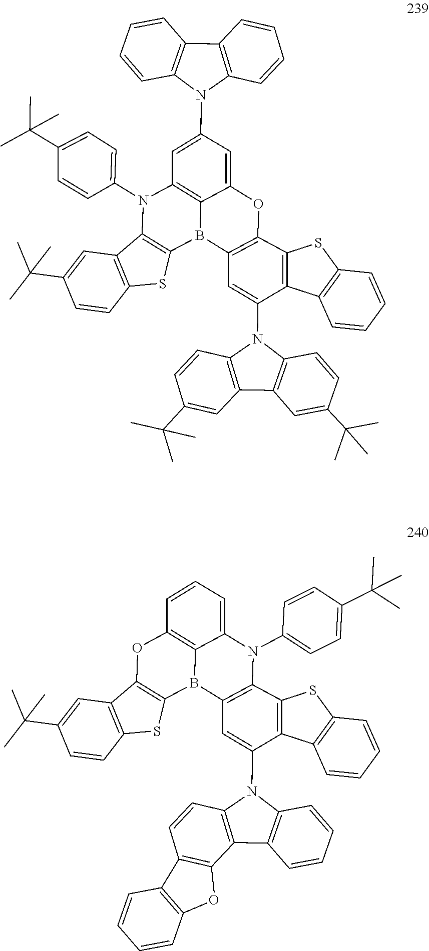 [SMILES: CC(C)(C)c1ccc(N2c3cc(-n4c5ccccc5c5ccccc54)cc4c3B(c3cc(-n5c6ccc(C(C)(C)C)cc6c6cc(C(C)(C)C)ccc65)c5c(sc6ccccc65)c3O4)c3sc4ccc(C(C)(C)C)cc4c32)cc1 ; CC(C)(C)c1ccc(N2c3cccc4c3B(c3cc(-n5c6ccccc6c6c7oc8ccccc8c7ccc65)c5c(sc6ccccc65)c32)c2sc3ccc(C(C)(C)C)cc3c2O4)cc1]

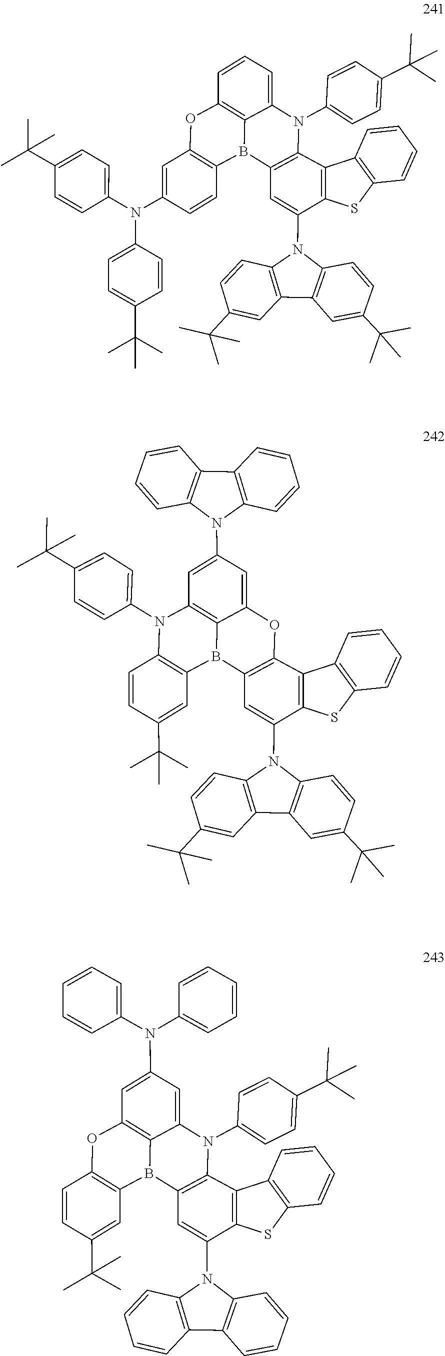

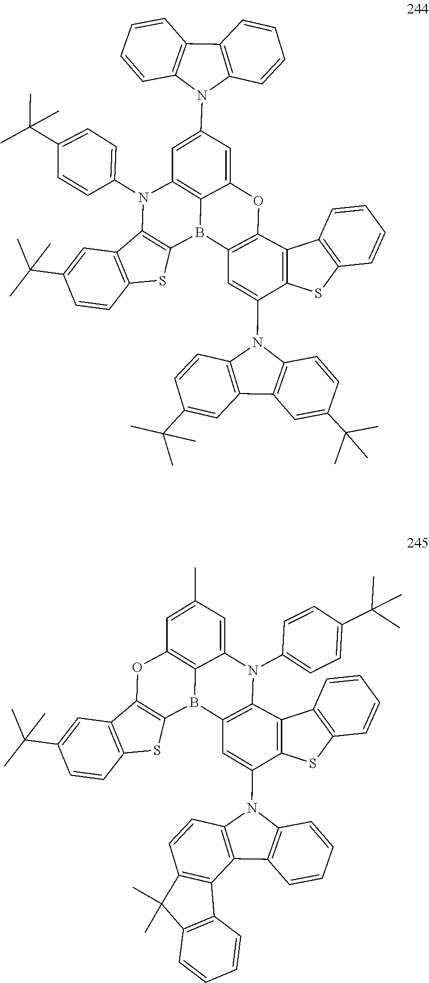 [SMILES: CC(C)(C)c1ccc(N2c3cc(-n4c5ccccc5c5ccccc54)cc4c3B(c3cc(-n5c6ccc(C(C)(C)C)cc6c6cc(C(C)(C)C)ccc65)c5sc6ccccc6c5c3O4)c3sc4ccc(C(C)(C)C)cc4c32)cc1 ; Cc1cc2c3c(c1)N(c1ccc(C(C)(C)C)cc1)c1c(cc(-n4c5ccccc5c5c6c(ccc54)C(C)(C)c4ccccc4-6)c4sc5ccccc5c14)B3c1sc3ccc(C(C)(C)C)cc3c1O2]

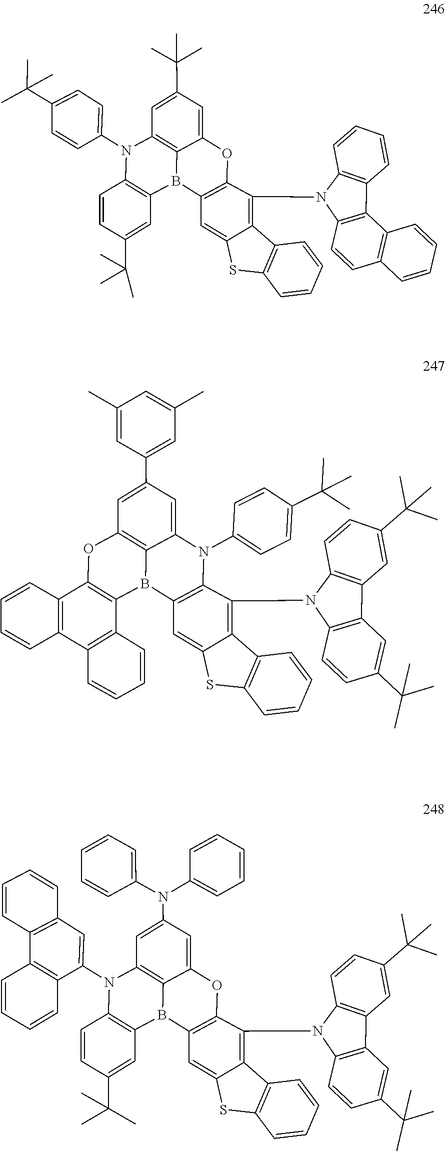 [SMILES: CC(C)(C)c1ccc(N2c3ccc(C(C)(C)C)cc3B3c4cc5sc6ccccc6c5c(-n5c6ccccc6c6c7ccccc7ccc65)c4Oc4cc(C(C)(C)C)cc2c43)cc1 ; Cc1cc(C)cc(-c2cc3c4c(c2)N(c2ccc(C(C)(C)C)cc2)c2c(cc5sc6ccccc6c5c2-n2c5ccc(C(C)(C)C)cc5c5cc(C(C)(C)C)ccc52)B4c2c(c4ccccc4c4ccccc24)O3)c1 ; CC(C)(C)c1ccc2c(c1)B1c3cc4sc5ccccc5c4c(-n4c5ccc(C(C)(C)C)cc5c5cc(C(C)(C)C)ccc54)c3Oc3cc(N(c4ccccc4)c4ccccc4)cc(c31)N2c1cc2ccccc2c2ccccc12]

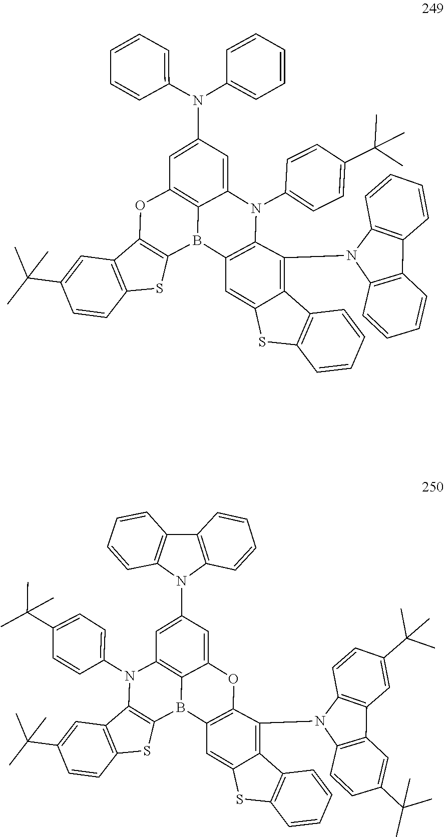 [SMILES: CC(C)(C)c1ccc(N2c3cc(N(c4ccccc4)c4ccccc4)cc4c3B(c3cc5sc6ccccc6c5c(-n5c6ccccc6c6ccccc65)c32)c2sc3ccc(C(C)(C)C)cc3c2O4)cc1 ; CC(C)(C)c1ccc(N2c3cc(-n4c5ccccc5c5ccccc54)cc4c3B(c3cc5sc6ccccc6c5c(-n5c6ccc(C(C)(C)C)cc6c6cc(C(C)(C)C)ccc65)c3O4)c3sc4ccc(C(C)(C)C)cc4c32)cc1]

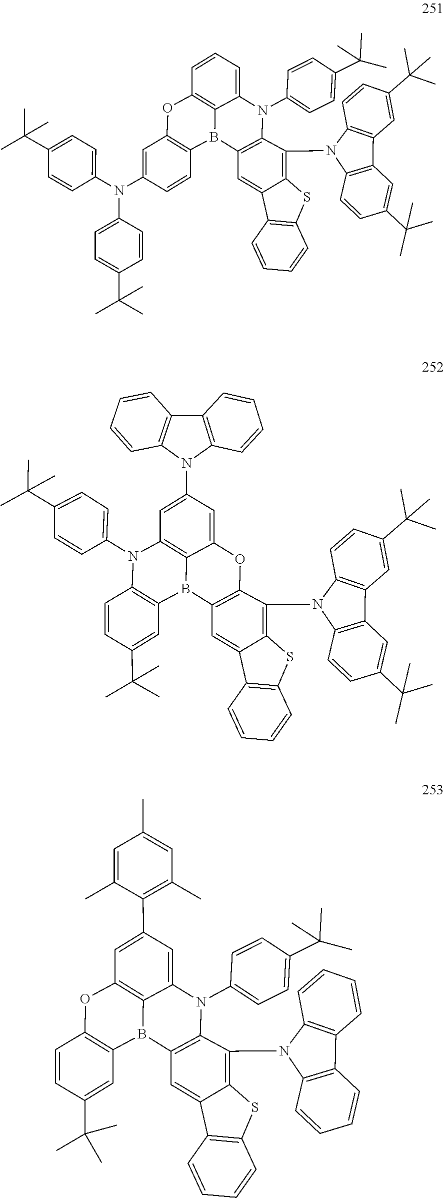

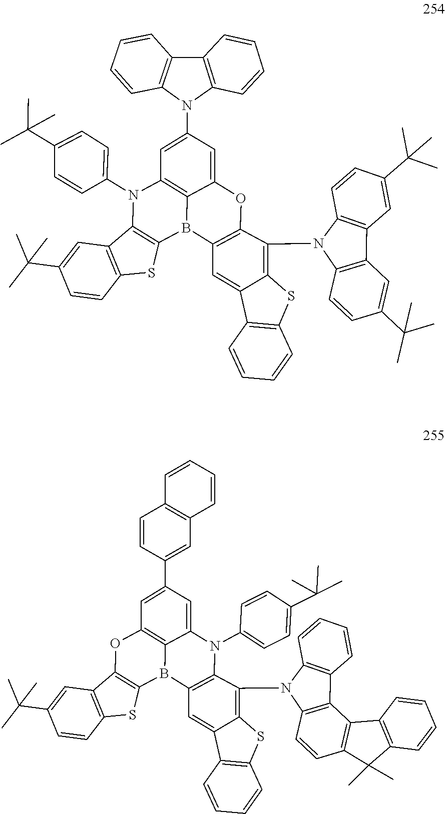

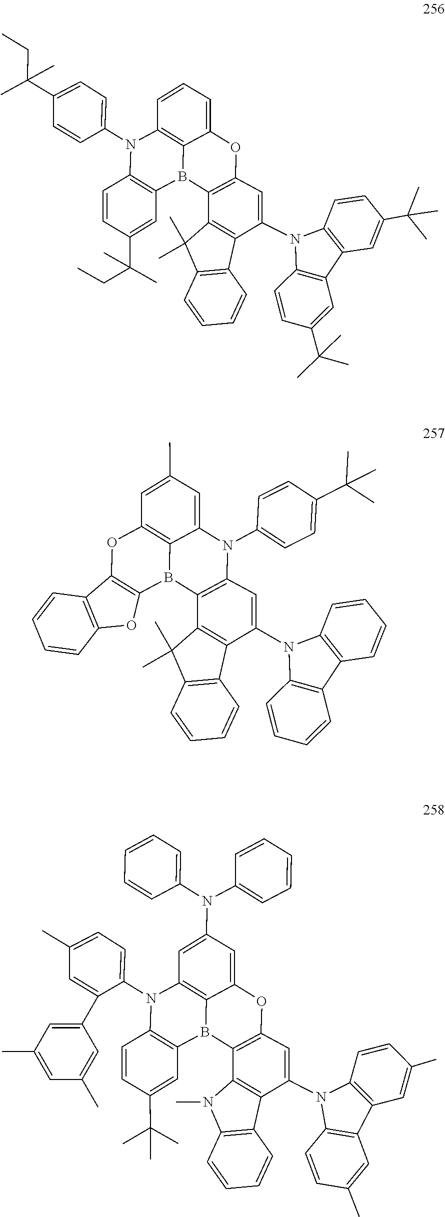

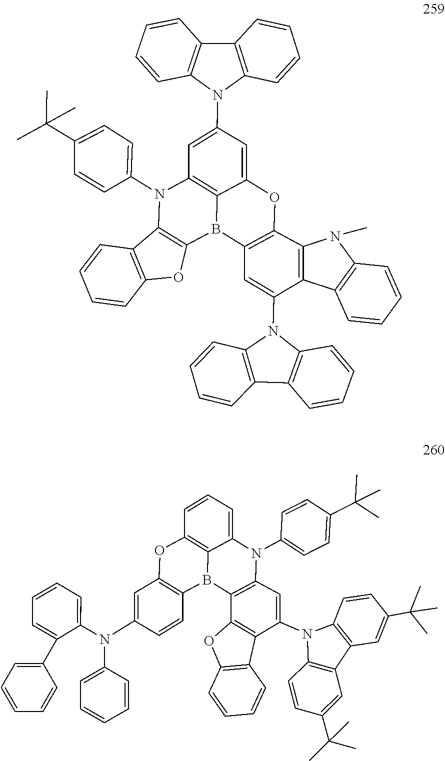 [SMILES: Cn1c2ccccc2c2c(-n3c4ccccc4c4ccccc43)cc3c(c21)Oc1cc(-n2c4ccccc4c4ccccc42)cc2c1B3c1oc3ccccc3c1N2c1ccc(C(C)(C)C)cc1 ; CC(C)(C)c1ccc(N2c3cccc4c3B(c3ccc(N(c5ccccc5)c5ccccc5-c5ccccc5)cc3O4)c3c2cc(-n2c4ccc(C(C)(C)C)cc4c4cc(C(C)(C)C)ccc42)c2c3oc3ccccc32)cc1]

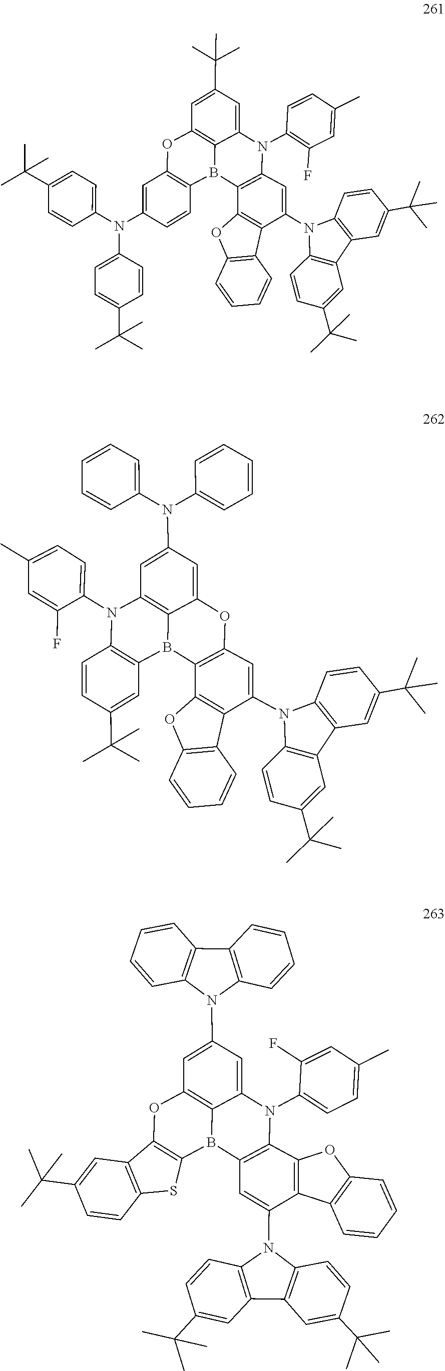

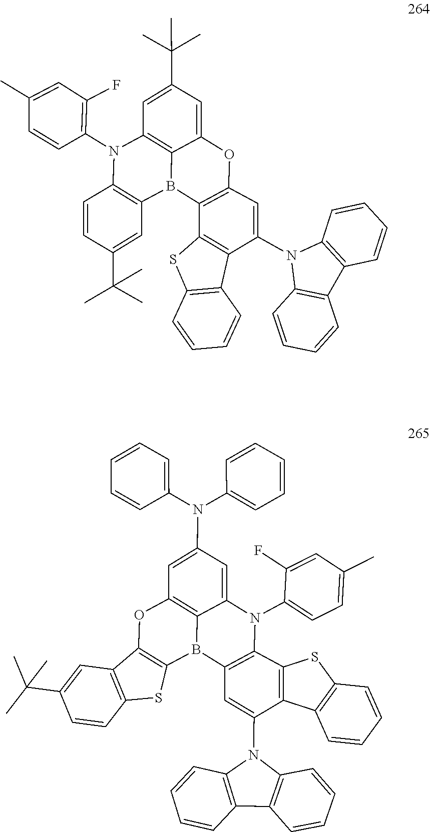 [SMILES: Cc1ccc(N2c3ccc(C(C)(C)C)cc3B3c4c(cc(C(C)(C)C)cc42)Oc2cc(-n4c5ccccc5c5ccccc54)c4c(sc5ccccc54)c23)c(F)c1 ; Cc1ccc(N2c3cc(N(c4ccccc4)c4ccccc4)cc4c3B(c3cc(-n5c6ccccc6c6ccccc65)c5c(sc6ccccc65)c32)c2sc3ccc(C(C)(C)C)cc3c2O4)c(F)c1]

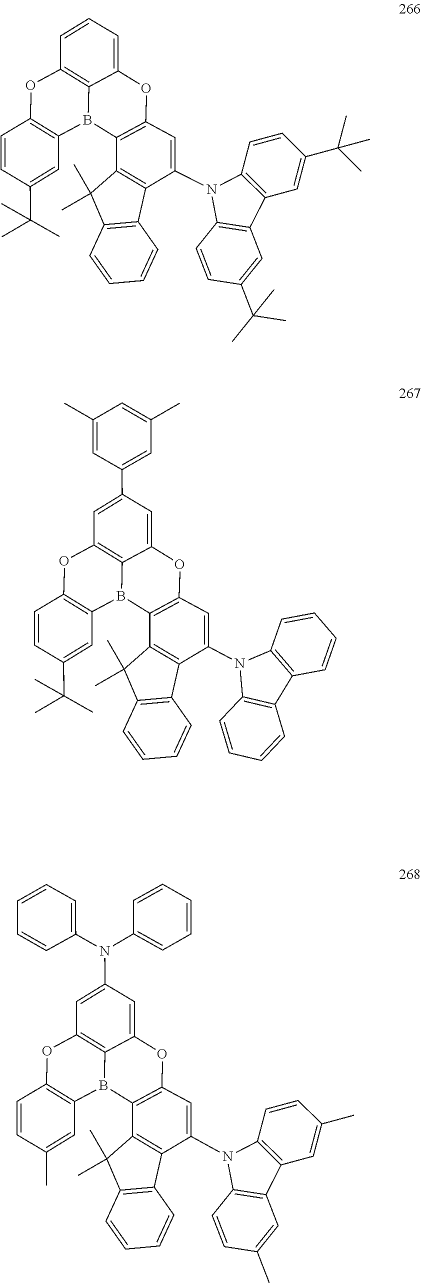 [SMILES: CC(C)(C)c1ccc2c(c1)B1c3c(cccc3Oc3cc(-n4c5ccc(C(C)(C)C)cc5c5cc(C(C)(C)C)ccc54)c4c(c31)C(C)(C)c1ccccc1-4)O2 ; Cc1cc(C)cc(-c2cc3c4c(c2)Oc2cc(-n5c6ccccc6c6ccccc65)c5c(c2B4c2cc(C(C)(C)C)ccc2O3)C(C)(C)c2ccccc2-5)c1 ; Cc1ccc2c(c1)B1c3c(cc(N(c4ccccc4)c4ccccc4)cc3Oc3cc(-n4c5ccc(C)cc5c5cc(C)ccc54)c4c(c31)C(C)(C)c1ccccc1-4)O2]

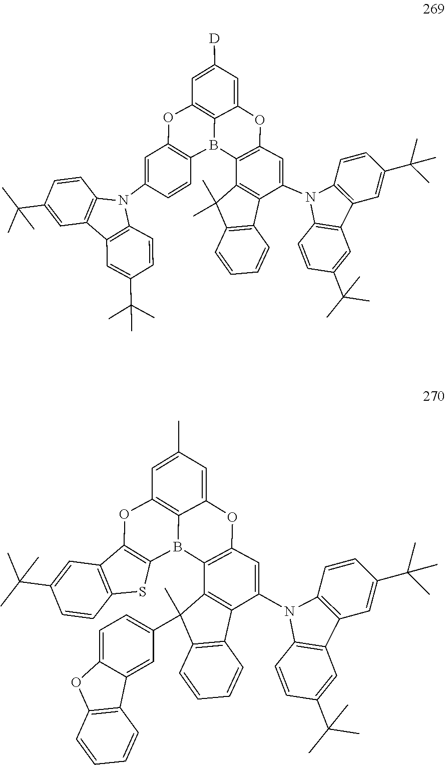

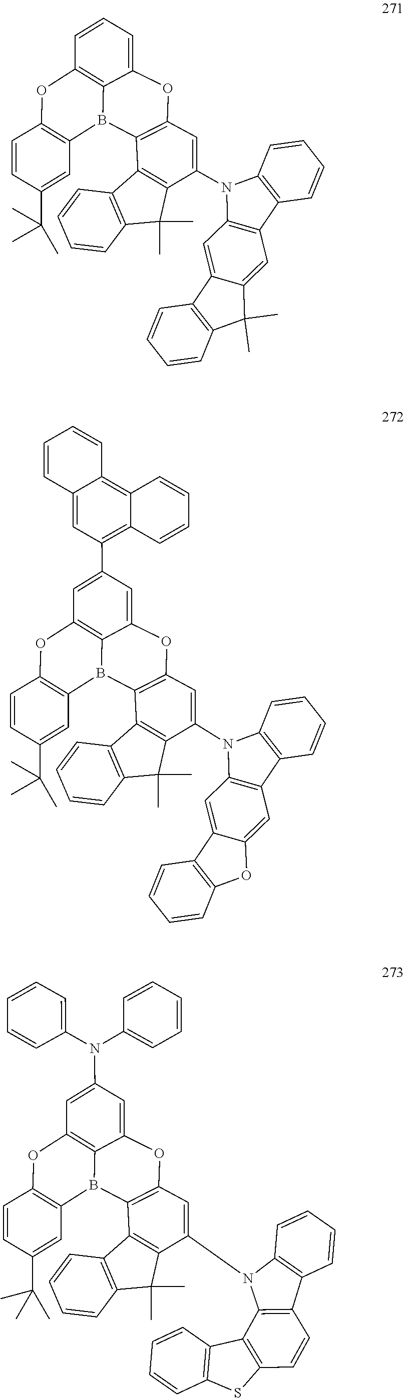 [SMILES: CC(C)(C)c1ccc2c(c1)B1c3c(cccc3Oc3cc(-n4c5ccccc5c5cc6c(cc54)-c4ccccc4C6(C)C)c4c(c31)-c1ccccc1C4(C)C)O2 ; CC(C)(C)c1ccc2c(c1)B1c3c(cc(-c4cc5ccccc5c5ccccc45)cc3Oc3cc(-n4c5ccccc5c5cc6oc7ccccc7c6cc54)c4c(c31)-c1ccccc1C4(C)C)O2 ; CC(C)(C)c1ccc2c(c1)B1c3c(cc(N(c4ccccc4)c4ccccc4)cc3Oc3cc(-n4c5ccccc5c5ccc6sc7ccccc7c6c54)c4c(c31)-c1ccccc1C4(C)C)O2]

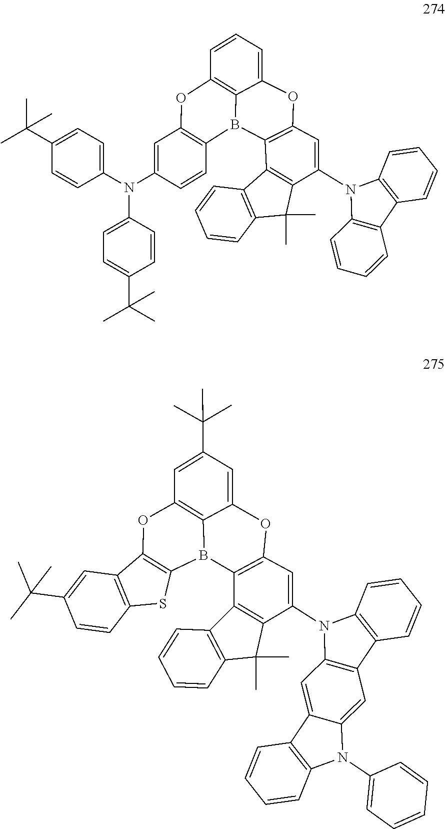 [SMILES: CC(C)(C)c1ccc(N(c2ccc(C(C)(C)C)cc2)c2ccc3c(c2)Oc2cccc4c2B3c2c(cc(-n3c5ccccc5c5ccccc53)c3c2-c2ccccc2C3(C)C)O4)cc1 ; CC(C)(C)c1cc2c3c(c1)Oc1c(sc4ccc(C(C)(C)C)cc14)B3c1c(cc(-n3c4ccccc4c4cc5c(cc43)c3ccccc3n5-c3ccccc3)c3c1-c1ccccc1C3(C)C)O2]

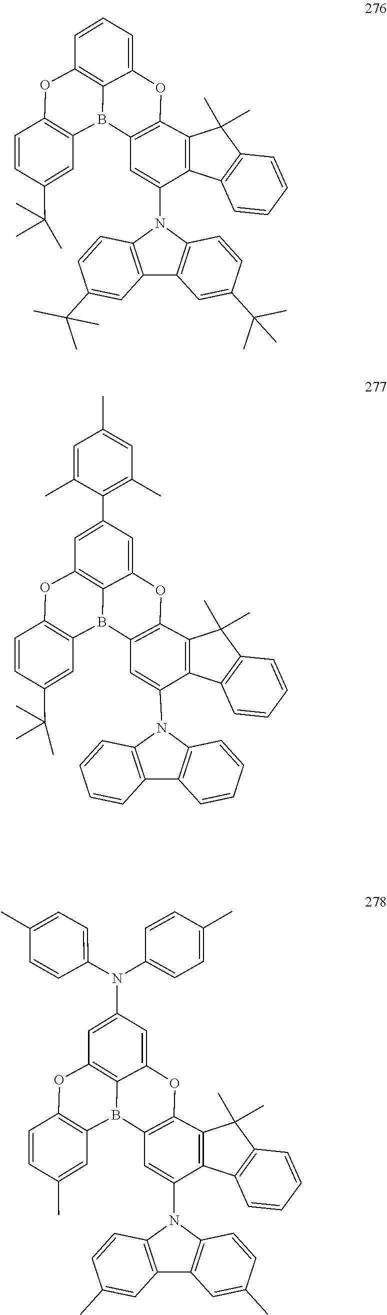 [SMILES: CC(C)(C)c1ccc2c(c1)B1c3cc(-n4c5ccc(C(C)(C)C)cc5c5cc(C(C)(C)C)ccc54)c4c(c3Oc3cccc(c31)O2)C(C)(C)c1ccccc1-4 ; Cc1cc(C)c(-c2cc3c4c(c2)Oc2c(cc(-n5c6ccccc6c6ccccc65)c5c2C(C)(C)c2ccccc2-5)B4c2cc(C(C)(C)C)ccc2O3)c(C)c1 ; Cc1ccc(N(c2ccc(C)cc2)c2cc3c4c(c2)Oc2c(cc(-n5c6ccc(C)cc6c6cc(C)ccc65)c5c2C(C)(C)c2ccccc2-5)B4c2cc(C)ccc2O3)cc1]

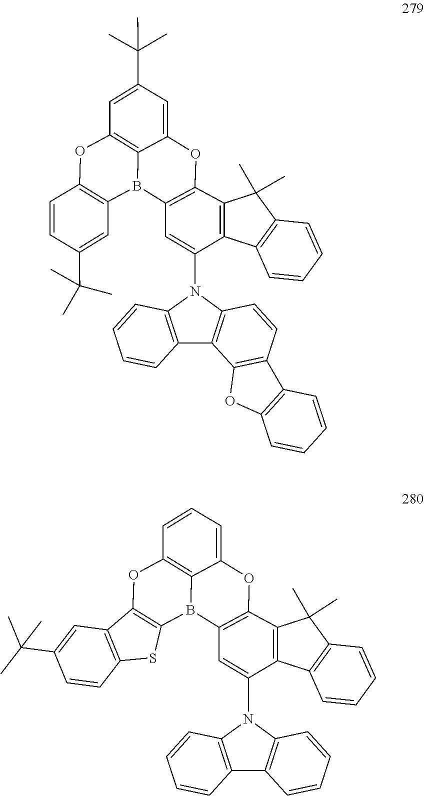 [SMILES: CC(C)(C)c1cc2c3c(c1)Oc1c(cc(-n4c5ccccc5c5c6oc7ccccc7c6ccc54)c4c1C(C)(C)c1ccccc1-4)B3c1cc(C(C)(C)C)ccc1O2 ; CC(C)(C)c1ccc2sc3c(c2c1)Oc1cccc2c1B3c1cc(-n3c4ccccc4c4ccccc43)c3c(c1O2)C(C)(C)c1ccccc1-3]

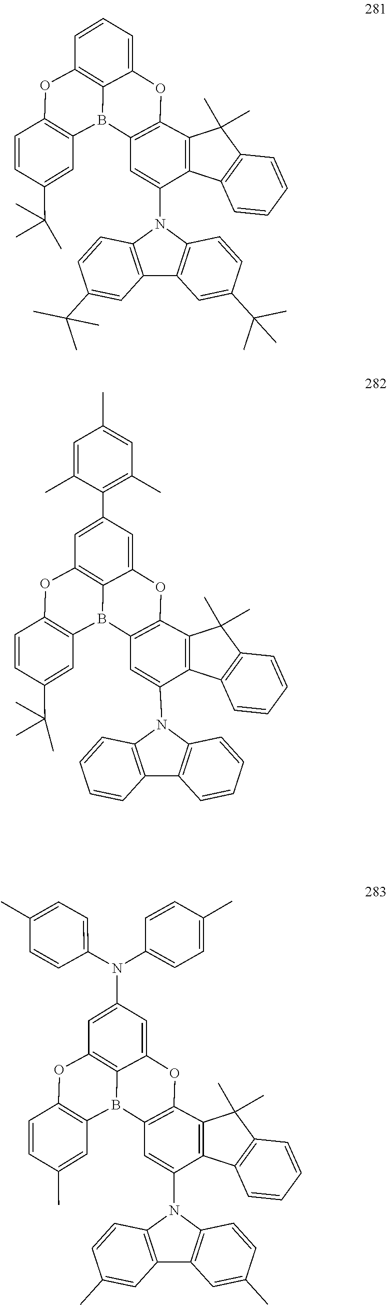 [SMILES: CC(C)(C)c1ccc2c(c1)B1c3cc(-n4c5ccc(C(C)(C)C)cc5c5cc(C(C)(C)C)ccc54)c4c(c3Oc3cccc(c31)O2)C(C)(C)c1ccccc1-4 ; Cc1cc(C)c(-c2cc3c4c(c2)Oc2c(cc(-n5c6ccccc6c6ccccc65)c5c2C(C)(C)c2ccccc2-5)B4c2cc(C(C)(C)C)ccc2O3)c(C)c1 ; Cc1ccc(N(c2ccc(C)cc2)c2cc3c4c(c2)Oc2c(cc(-n5c6ccc(C)cc6c6cc(C)ccc65)c5c2C(C)(C)c2ccccc2-5)B4c2cc(C)ccc2O3)cc1]

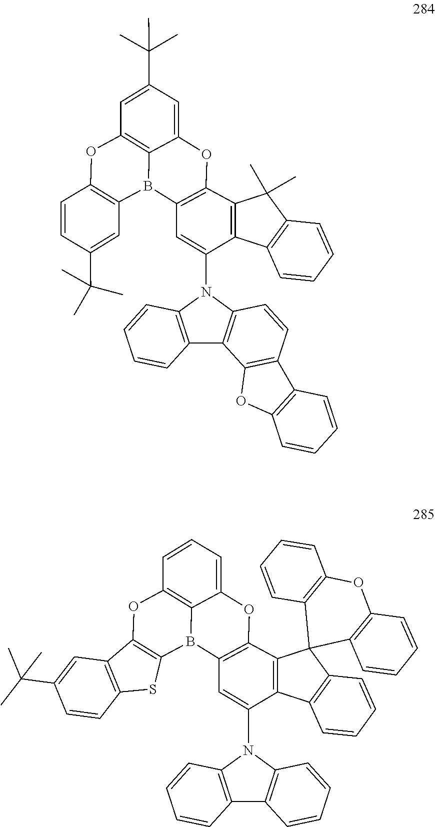 [SMILES: CC(C)(C)c1cc2c3c(c1)Oc1c(cc(-n4c5ccccc5c5c6oc7ccccc7c6ccc54)c4c1C(C)(C)c1ccccc1-4)B3c1cc(C(C)(C)C)ccc1O2 ; CC(C)(C)c1ccc2sc3c(c2c1)Oc1cccc2c1B3c1cc(-n3c4ccccc4c4ccccc43)c3c(c1O2)C1(c2ccccc2Oc2ccccc21)c1ccccc1-3]

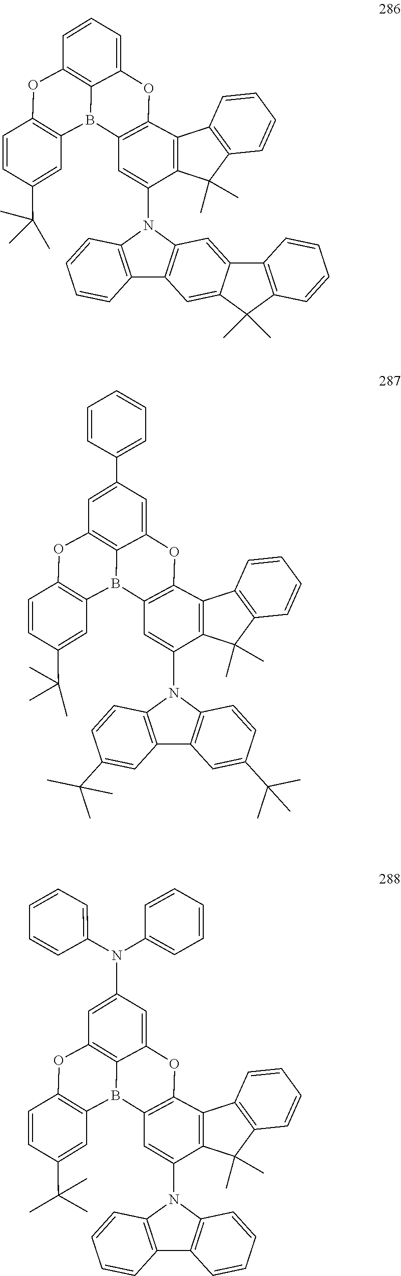 [SMILES: CC(C)(C)c1ccc2c(c1)B1c3cc(-n4c5ccccc5c5cc6c(cc54)-c4ccccc4C6(C)C)c4c(c3Oc3cccc(c31)O2)-c1ccccc1C4(C)C ; CC(C)(C)c1ccc2c(c1)B1c3cc(-n4c5ccc(C(C)(C)C)cc5c5cc(C(C)(C)C)ccc54)c4c(c3Oc3cc(-c5ccccc5)cc(c31)O2)-c1ccccc1C4(C)C ; CC(C)(C)c1ccc2c(c1)B1c3cc(-n4c5ccccc5c5ccccc54)c4c(c3Oc3cc(N(c5ccccc5)c5ccccc5)cc(c31)O2)-c1ccccc1C4(C)C]

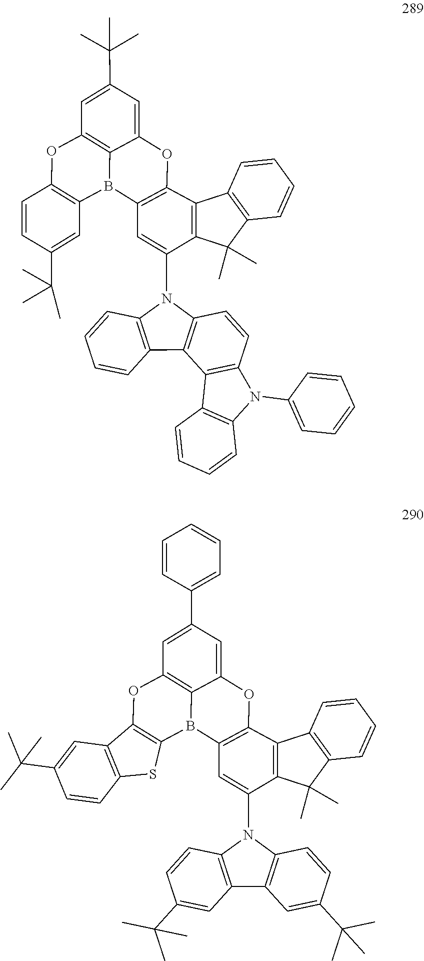 [SMILES: CC(C)(C)c1cc2c3c(c1)Oc1c(cc(-n4c5ccccc5c5c6c7ccccc7n(-c7ccccc7)c6ccc54)c4c1-c1ccccc1C4(C)C)B3c1cc(C(C)(C)C)ccc1O2 ; CC(C)(C)c1ccc2sc3c(c2c1)Oc1cc(-c2ccccc2)cc2c1B3c1cc(-n3c4ccc(C(C)(C)C)cc4c4cc(C(C)(C)C)ccc43)c3c(c1O2)-c1ccccc1C3(C)C]

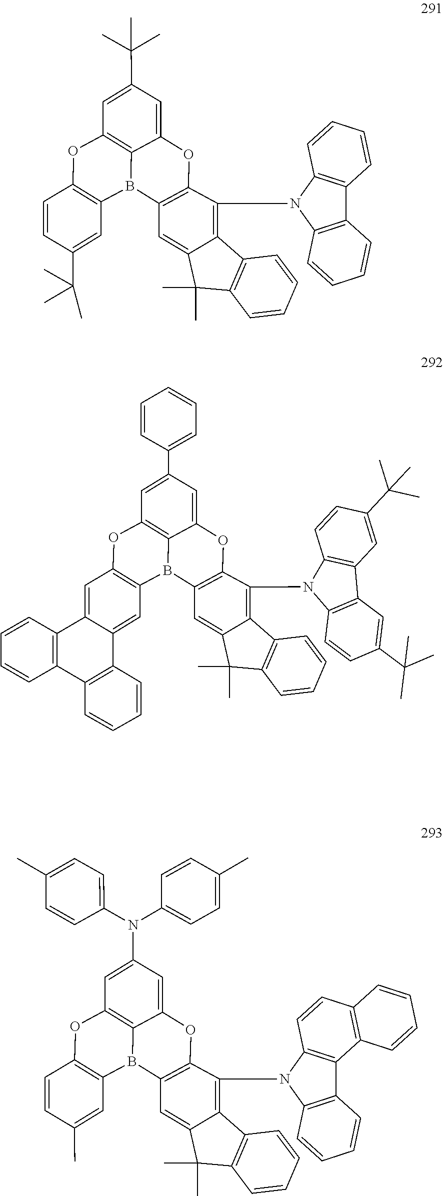

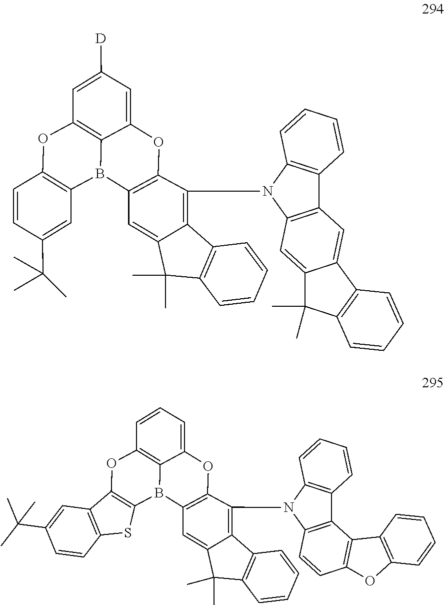 [SMILES: [2H]c1cc2c3c(c1)Oc1c(cc4c(c1-n1c5ccccc5c5cc6c(cc51)C(C)(C)c1ccccc1-6)-c1ccccc1C4(C)C)B3c1cc(C(C)(C)C)ccc1O2 ; CC(C)(C)c1ccc2sc3c(c2c1)Oc1cccc2c1B3c1cc3c(c(-n4c5ccccc5c5c6c(ccc54)oc4ccccc46)c1O2)-c1ccccc1C3(C)C]

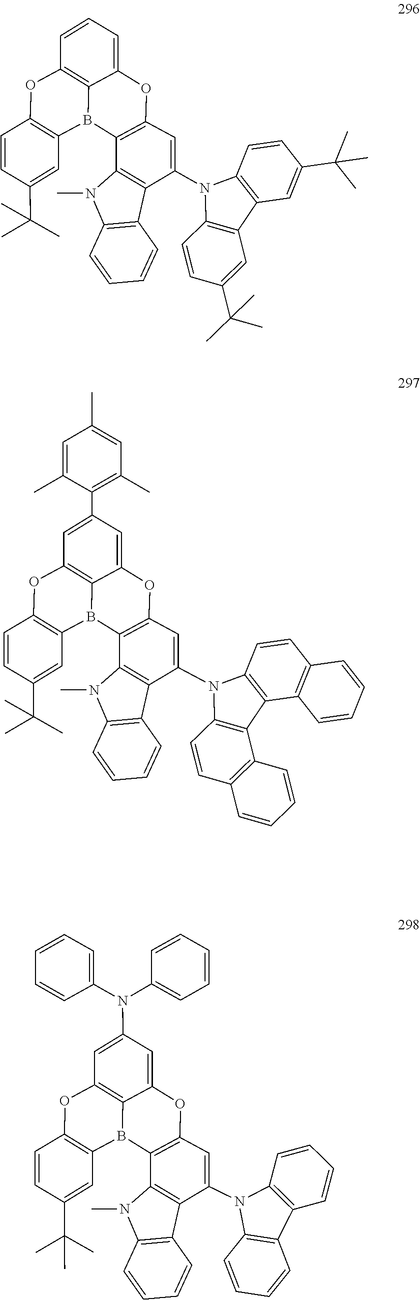 [SMILES: Cn1c2ccccc2c2c(-n3c4ccc(C(C)(C)C)cc4c4cc(C(C)(C)C)ccc43)cc3c(c21)B1c2cc(C(C)(C)C)ccc2Oc2cccc(c21)O3 ; Cc1cc(C)c(-c2cc3c4c(c2)Oc2cc(-n5c6ccc7ccccc7c6c6c7ccccc7ccc65)c5c6ccccc6n(C)c5c2B4c2cc(C(C)(C)C)ccc2O3)c(C)c1 ; Cn1c2ccccc2c2c(-n3c4ccccc4c4ccccc43)cc3c(c21)B1c2cc(C(C)(C)C)ccc2Oc2cc(N(c4ccccc4)c4ccccc4)cc(c21)O3]

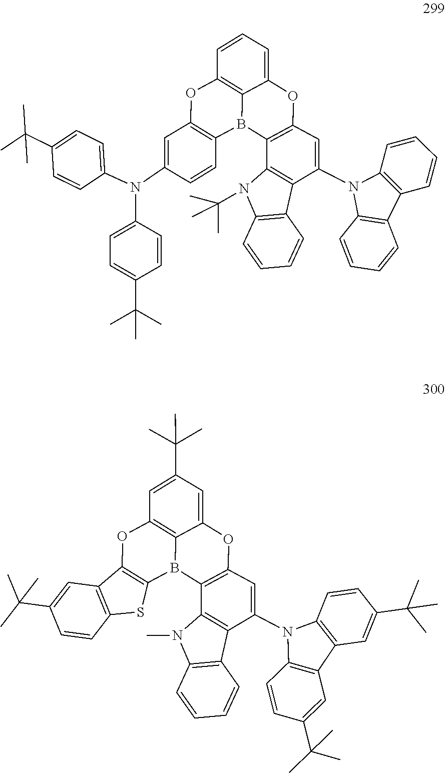 [SMILES: CC(C)(C)c1ccc(N(c2ccc(C(C)(C)C)cc2)c2ccc3c(c2)Oc2cccc4c2B3c2c(cc(-n3c5ccccc5c5ccccc53)c3c5ccccc5n(C(C)(C)C)c23)O4)cc1 ; Cn1c2ccccc2c2c(-n3c4ccc(C(C)(C)C)cc4c4cc(C(C)(C)C)ccc43)cc3c(c21)B1c2sc4ccc(C(C)(C)C)cc4c2Oc2cc(C(C)(C)C)cc(c21)O3]

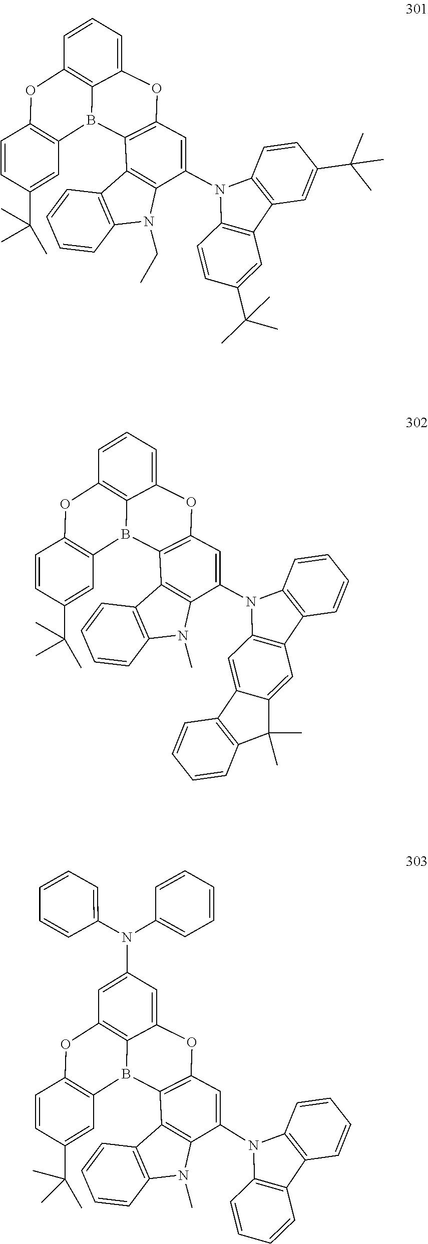

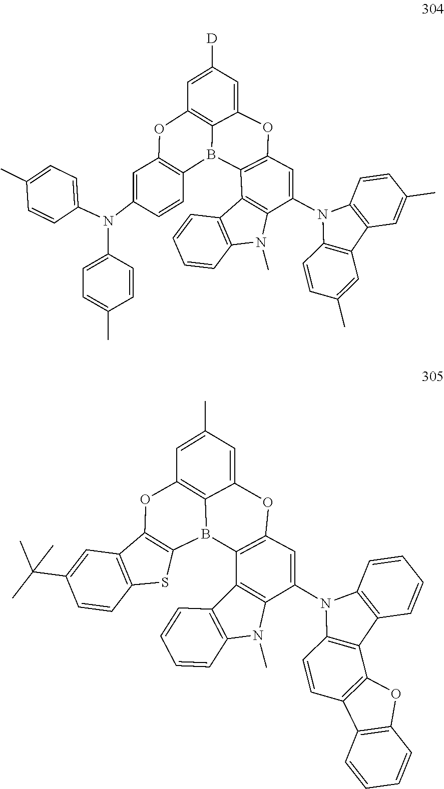

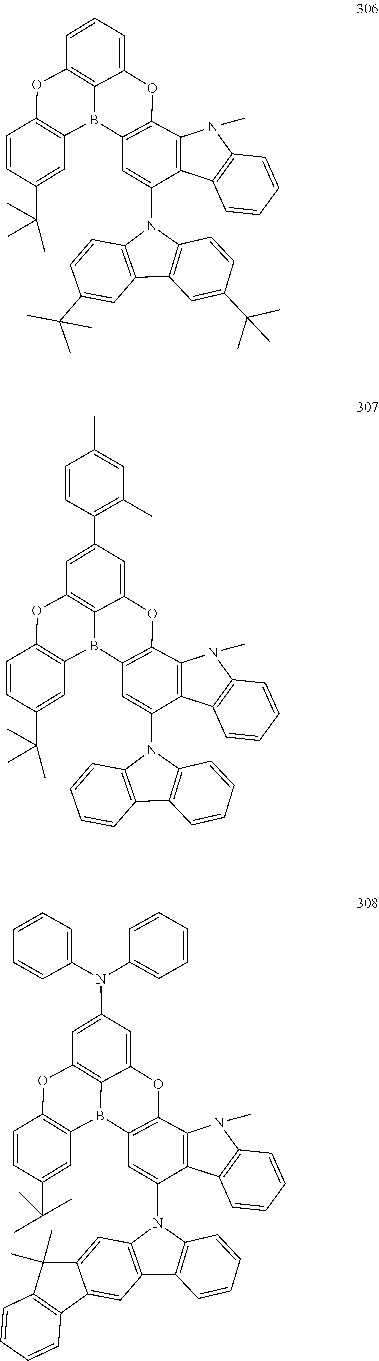 [SMILES: Cn1c2ccccc2c2c(-n3c4ccc(C(C)(C)C)cc4c4cc(C(C)(C)C)ccc43)cc3c(c21)Oc1cccc2c1B3c1cc(C(C)(C)C)ccc1O2 ; Cc1ccc(-c2cc3c4c(c2)Oc2c(cc(-n5c6ccccc6c6ccccc65)c5c6ccccc6n(C)c25)B4c2cc(C(C)(C)C)ccc2O3)c(C)c1 ; Cn1c2ccccc2c2c(-n3c4ccccc4c4cc5c(cc43)C(C)(C)c3ccccc3-5)cc3c(c21)Oc1cc(N(c2ccccc2)c2ccccc2)cc2c1B3c1cc(C(C)(C)C)ccc1O2]

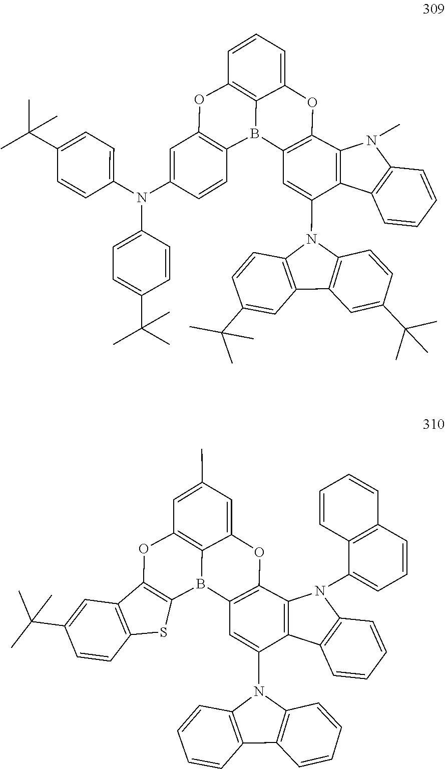

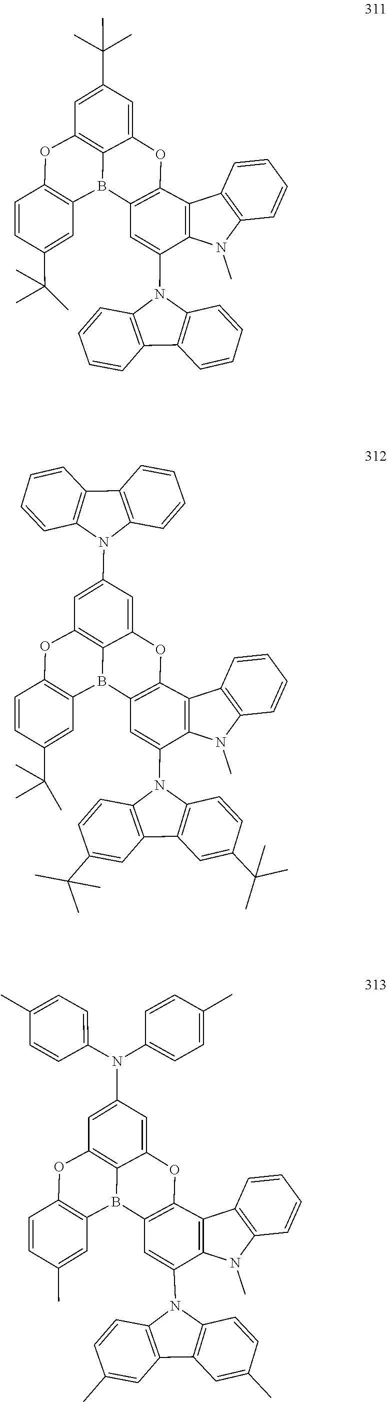

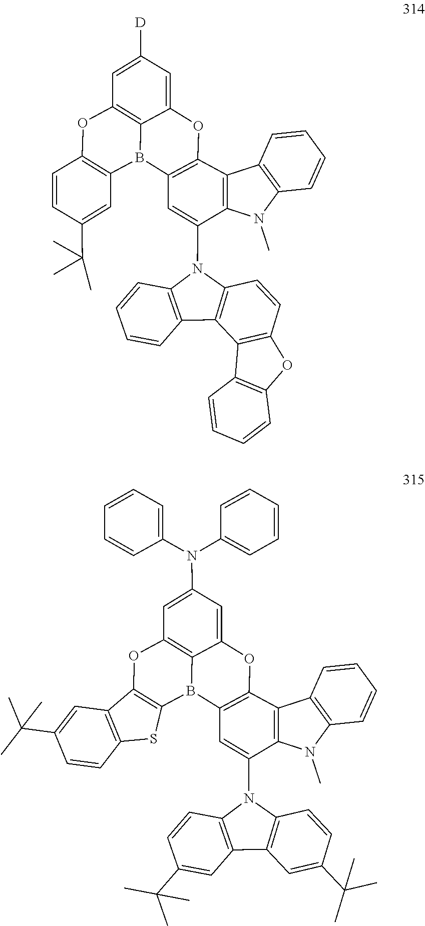

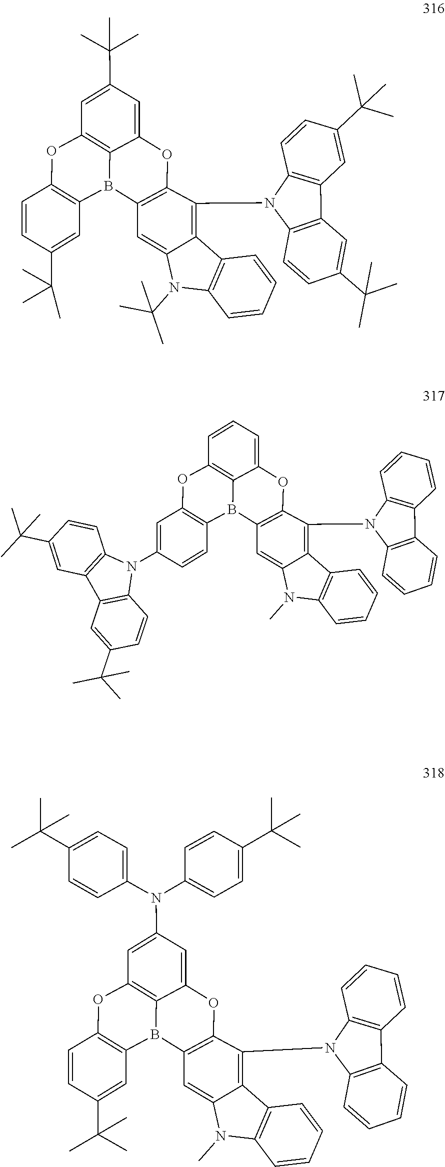

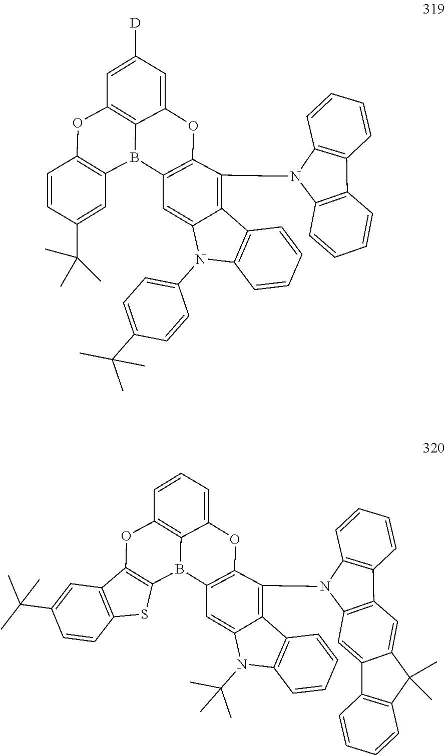 [SMILES: [2H]c1cc2c3c(c1)Oc1c(cc4c(c1-n1c5ccccc5c5ccccc51)c1ccccc1n4-c1ccc(C(C)(C)C)cc1)B3c1cc(C(C)(C)C)ccc1O2 ; CC(C)(C)c1ccc2sc3c(c2c1)Oc1cccc2c1B3c1cc3c(c(-n4c5ccccc5c5cc6c(cc54)-c4ccccc4C6(C)C)c1O2)c1ccccc1n3C(C)(C)C]

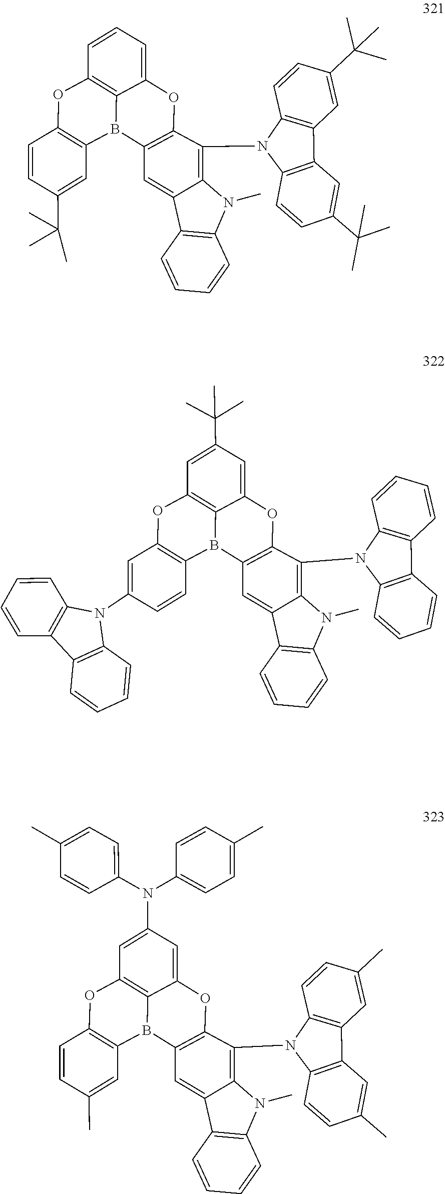

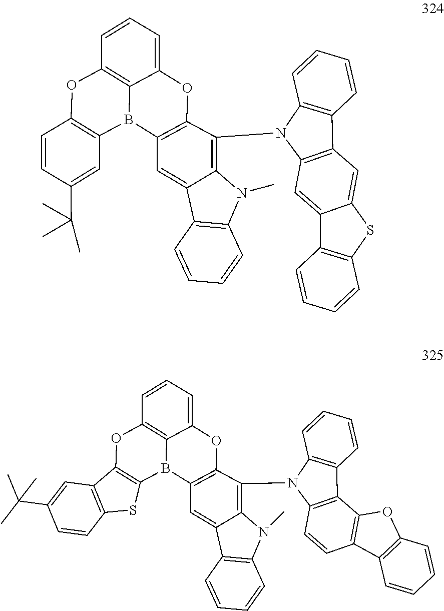 [SMILES: Cn1c2ccccc2c2cc3c(c(-n4c5ccccc5c5cc6sc7ccccc7c6cc54)c21)Oc1cccc2c1B3c1cc(C(C)(C)C)ccc1O2 ; Cn1c2ccccc2c2cc3c(c(-n4c5ccccc5c5c6oc7ccccc7c6ccc54)c21)Oc1cccc2c1B3c1sc3ccc(C(C)(C)C)cc3c1O2]

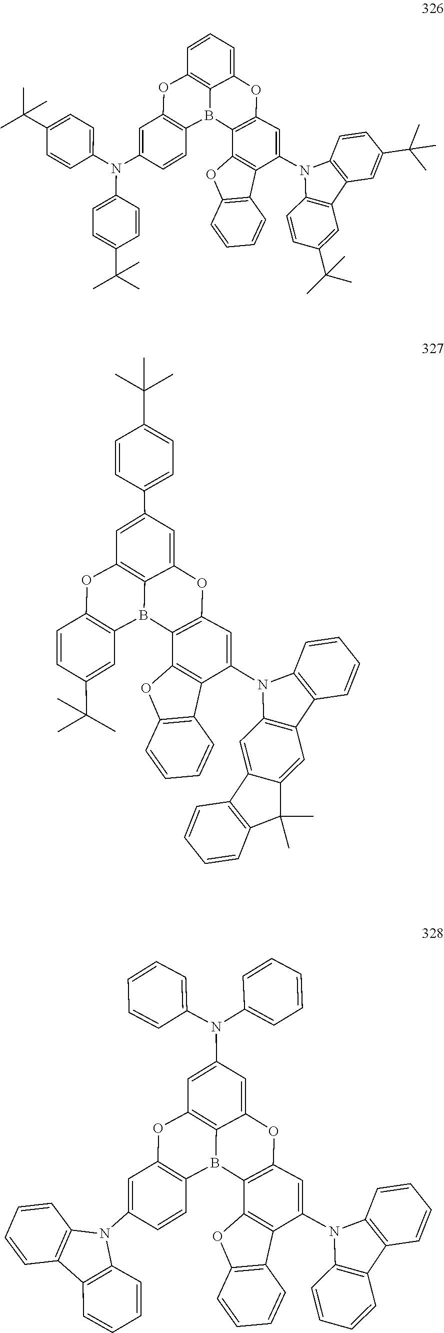 [SMILES: CC(C)(C)c1ccc(N(c2ccc(C(C)(C)C)cc2)c2ccc3c(c2)Oc2cccc4c2B3c2c(cc(-n3c5ccc(C(C)(C)C)cc5c5cc(C(C)(C)C)ccc53)c3c2oc2ccccc23)O4)cc1 ; CC(C)(C)c1ccc(-c2cc3c4c(c2)Oc2cc(-n5c6ccccc6c6cc7c(cc65)-c5ccccc5C7(C)C)c5c(oc6ccccc65)c2B4c2cc(C(C)(C)C)ccc2O3)cc1 ; c1ccc(N(c2ccccc2)c2cc3c4c(c2)Oc2cc(-n5c6ccccc6c6ccccc65)c5c(oc6ccccc65)c2B4c2ccc(-n4c5ccccc5c5ccccc54)cc2O3)cc1]

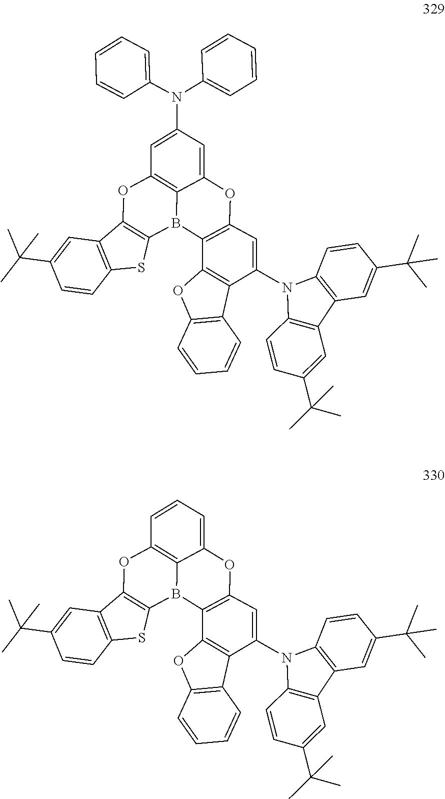

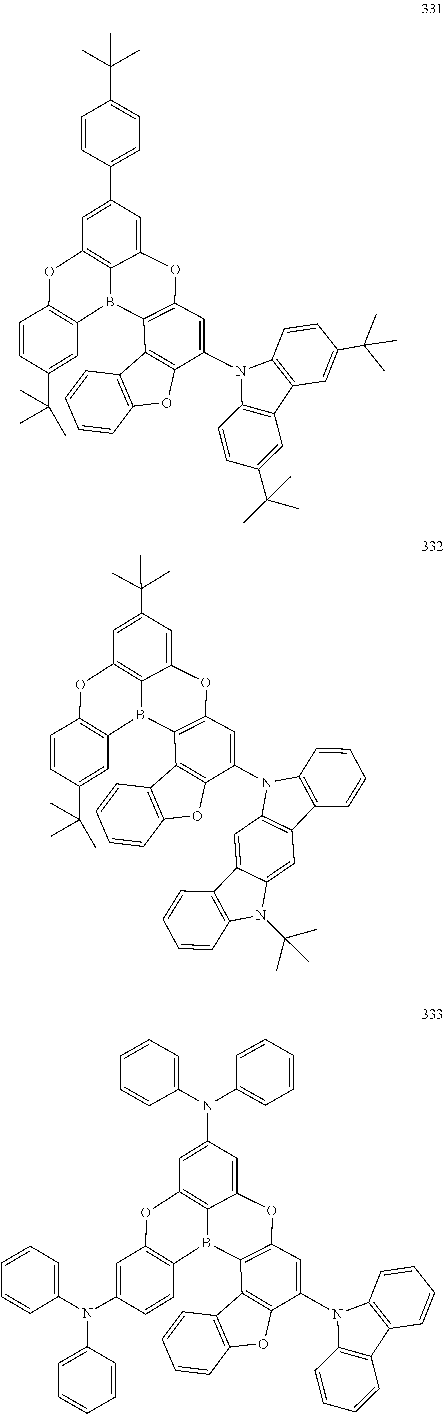 [SMILES: CC(C)(C)c1ccc(-c2cc3c4c(c2)Oc2cc(-n5c6ccc(C(C)(C)C)cc6c6cc(C(C)(C)C)ccc65)c5oc6ccccc6c5c2B4c2cc(C(C)(C)C)ccc2O3)cc1 ; CC(C)(C)c1cc2c3c(c1)Oc1cc(-n4c5ccccc5c5cc6c(cc54)c4ccccc4n6C(C)(C)C)c4oc5ccccc5c4c1B3c1cc(C(C)(C)C)ccc1O2 ; c1ccc(N(c2ccccc2)c2ccc3c(c2)Oc2cc(N(c4ccccc4)c4ccccc4)cc4c2B3c2c(cc(-n3c5ccccc5c5ccccc53)c3oc5ccccc5c23)O4)cc1]

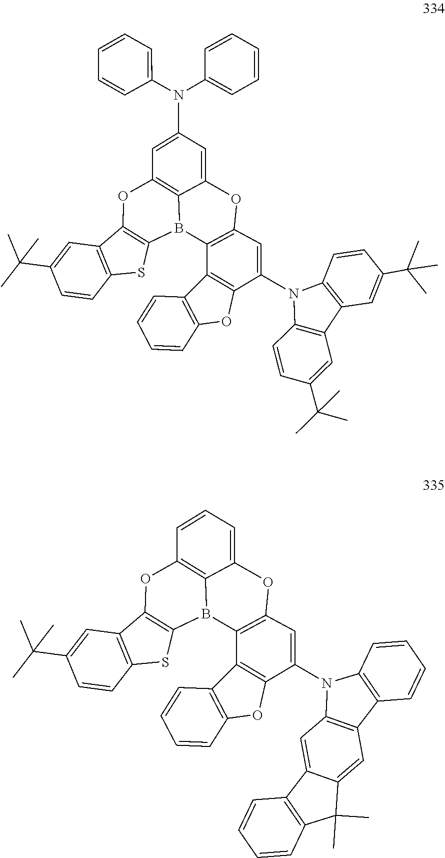

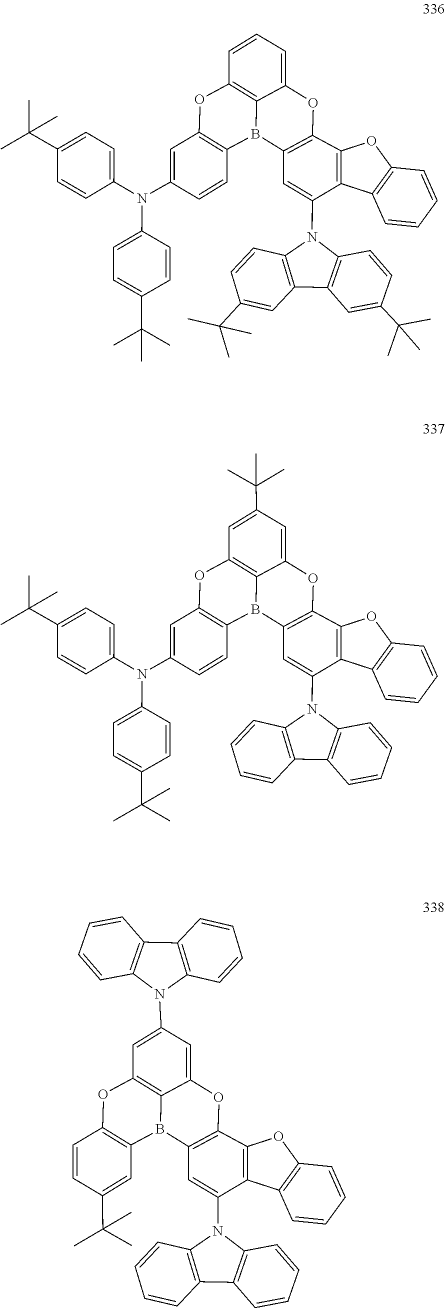 [SMILES: CC(C)(C)c1ccc(N(c2ccc(C(C)(C)C)cc2)c2ccc3c(c2)Oc2cccc4c2B3c2cc(-n3c5ccc(C(C)(C)C)cc5c5cc(C(C)(C)C)ccc53)c3c(oc5ccccc53)c2O4)cc1 ; CC(C)(C)c1ccc(N(c2ccc(C(C)(C)C)cc2)c2ccc3c(c2)Oc2cc(C(C)(C)C)cc4c2B3c2cc(-n3c5ccccc5c5ccccc53)c3c(oc5ccccc53)c2O4)cc1 ; CC(C)(C)c1ccc2c(c1)B1c3cc(-n4c5ccccc5c5ccccc54)c4c(oc5ccccc54)c3Oc3cc(-n4c5ccccc5c5ccccc54)cc(c31)O2]

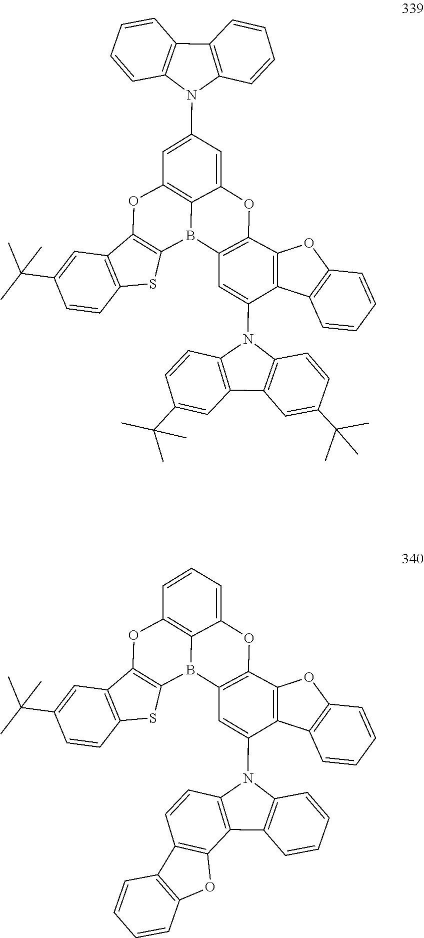 [SMILES: CC(C)(C)c1ccc2sc3c(c2c1)Oc1cc(-n2c4ccccc4c4ccccc42)cc2c1B3c1cc(-n3c4ccc(C(C)(C)C)cc4c4cc(C(C)(C)C)ccc43)c3c(oc4ccccc43)c1O2 ; CC(C)(C)c1ccc2sc3c(c2c1)Oc1cccc2c1B3c1cc(-n3c4ccccc4c4c5oc6ccccc6c5ccc43)c3c(oc4ccccc43)c1O2]

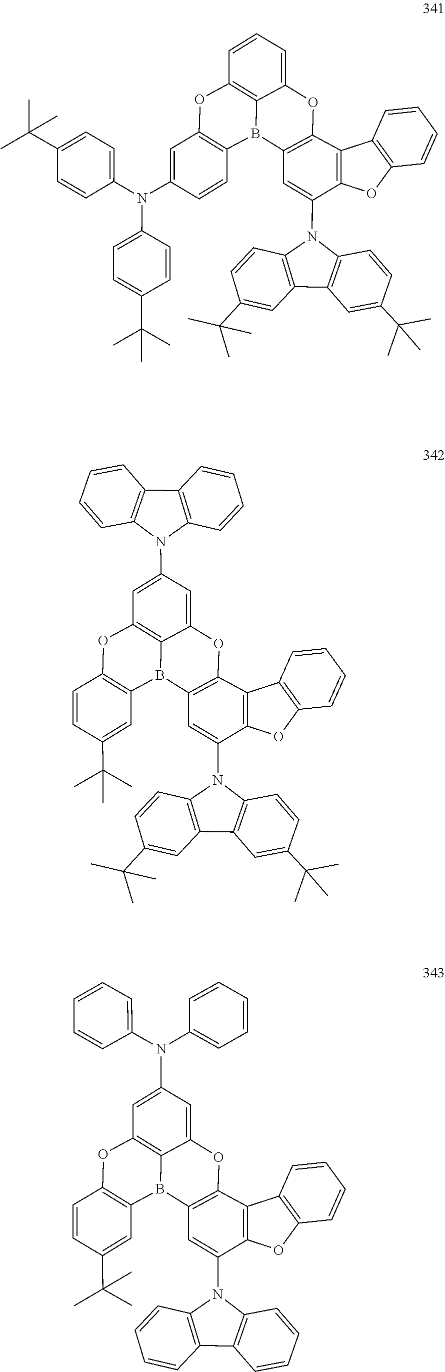 [SMILES: CC(C)(C)c1ccc(N(c2ccc(C(C)(C)C)cc2)c2ccc3c(c2)Oc2cccc4c2B3c2cc(-n3c5ccc(C(C)(C)C)cc5c5cc(C(C)(C)C)ccc53)c3oc5ccccc5c3c2O4)cc1 ; CC(C)(C)c1ccc2c(c1)B1c3cc(-n4c5ccc(C(C)(C)C)cc5c5cc(C(C)(C)C)ccc54)c4oc5ccccc5c4c3Oc3cc(-n4c5ccccc5c5ccccc54)cc(c31)O2 ; CC(C)(C)c1ccc2c(c1)B1c3cc(-n4c5ccccc5c5ccccc54)c4oc5ccccc5c4c3Oc3cc(N(c4ccccc4)c4ccccc4)cc(c31)O2]

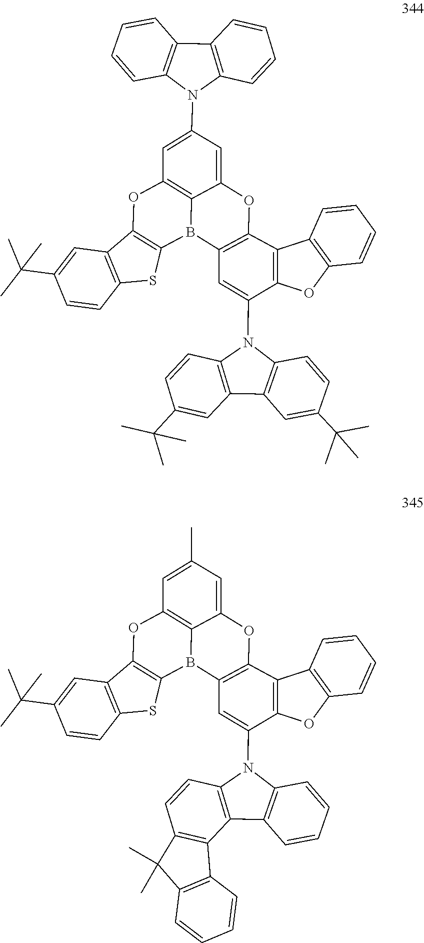 [SMILES: CC(C)(C)c1ccc2sc3c(c2c1)Oc1cc(-n2c4ccccc4c4ccccc42)cc2c1B3c1cc(-n3c4ccc(C(C)(C)C)cc4c4cc(C(C)(C)C)ccc43)c3oc4ccccc4c3c1O2 ; Cc1cc2c3c(c1)Oc1c(cc(-n4c5ccccc5c5c6c(ccc54)C(C)(C)c4ccccc4-6)c4oc5ccccc5c14)B3c1sc3ccc(C(C)(C)C)cc3c1O2]

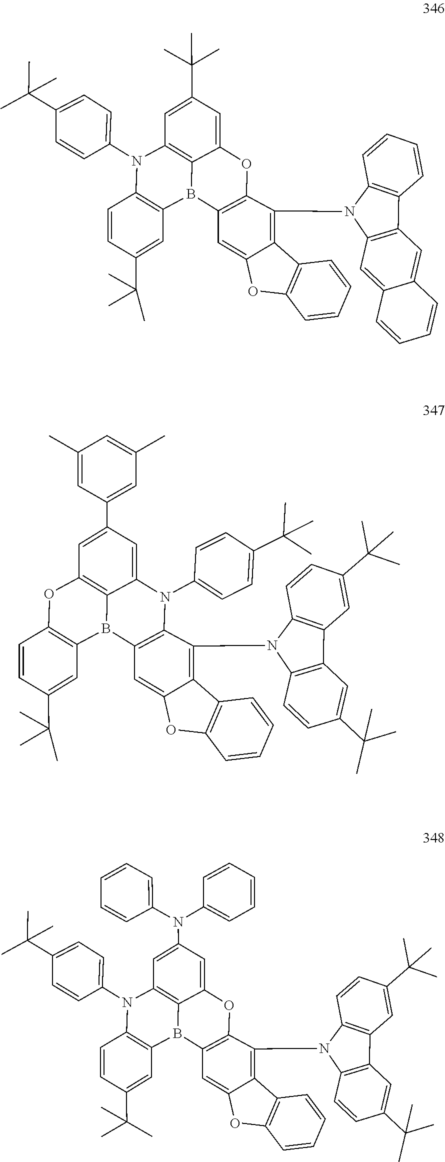

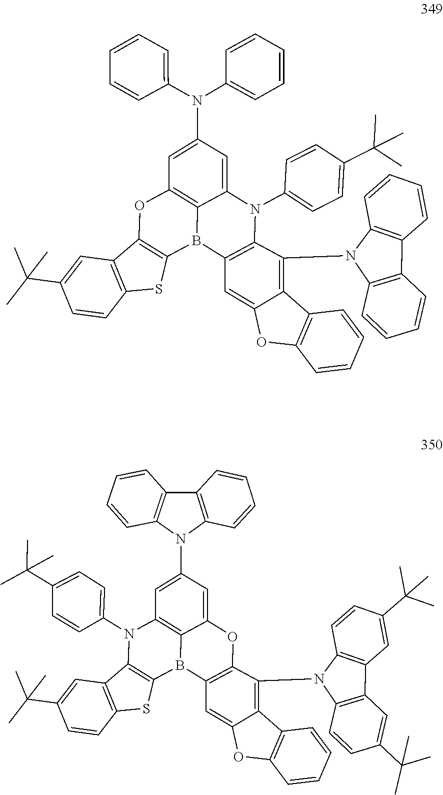 [SMILES: CC(C)(C)c1ccc(N2c3cc(N(c4ccccc4)c4ccccc4)cc4c3B(c3cc5oc6ccccc6c5c(-n5c6ccccc6c6ccccc65)c32)c2sc3ccc(C(C)(C)C)cc3c2O4)cc1 ; CC(C)(C)c1ccc(N2c3cc(-n4c5ccccc5c5ccccc54)cc4c3B(c3cc5oc6ccccc6c5c(-n5c6ccc(C(C)(C)C)cc6c6cc(C(C)(C)C)ccc65)c3O4)c3sc4ccc(C(C)(C)C)cc4c32)cc1]

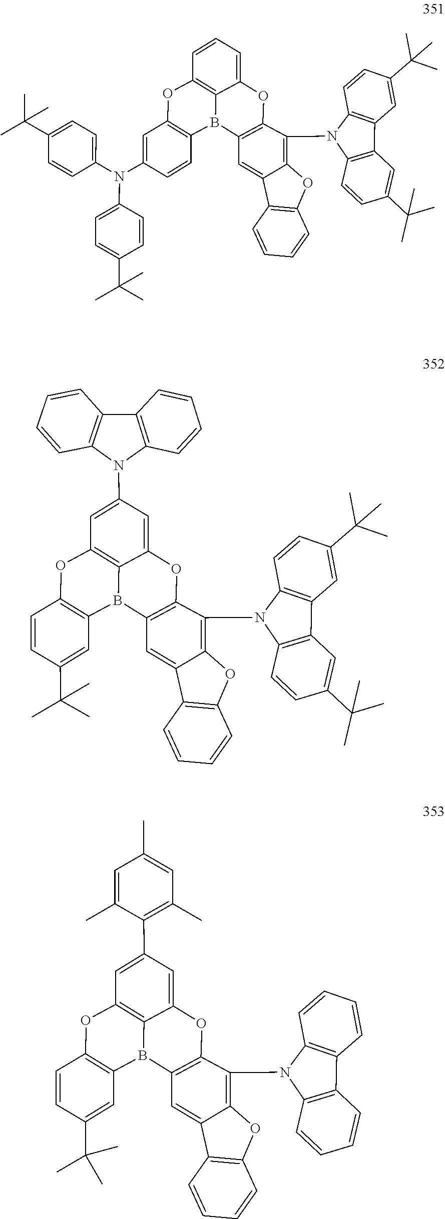 [SMILES: CC(C)(C)c1ccc(N(c2ccc(C(C)(C)C)cc2)c2ccc3c(c2)Oc2cccc4c2B3c2cc3c(oc5ccccc53)c(-n3c5ccc(C(C)(C)C)cc5c5cc(C(C)(C)C)ccc53)c2O4)cc1 ; CC(C)(C)c1ccc2c(c1)B1c3cc4c(oc5ccccc54)c(-n4c5ccc(C(C)(C)C)cc5c5cc(C(C)(C)C)ccc54)c3Oc3cc(-n4c5ccccc5c5ccccc54)cc(c31)O2 ; Cc1cc(C)c(-c2cc3c4c(c2)Oc2c(cc5c(oc6ccccc65)c2-n2c5ccccc5c5ccccc52)B4c2cc(C(C)(C)C)ccc2O3)c(C)c1]

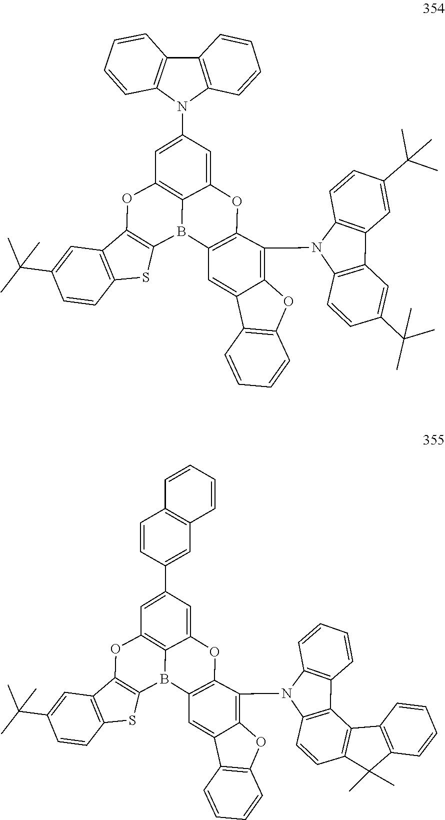

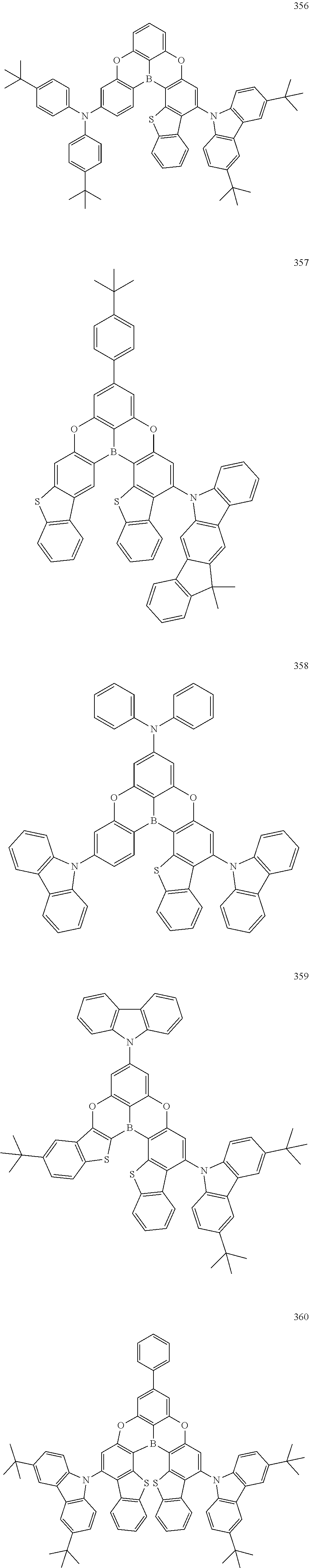

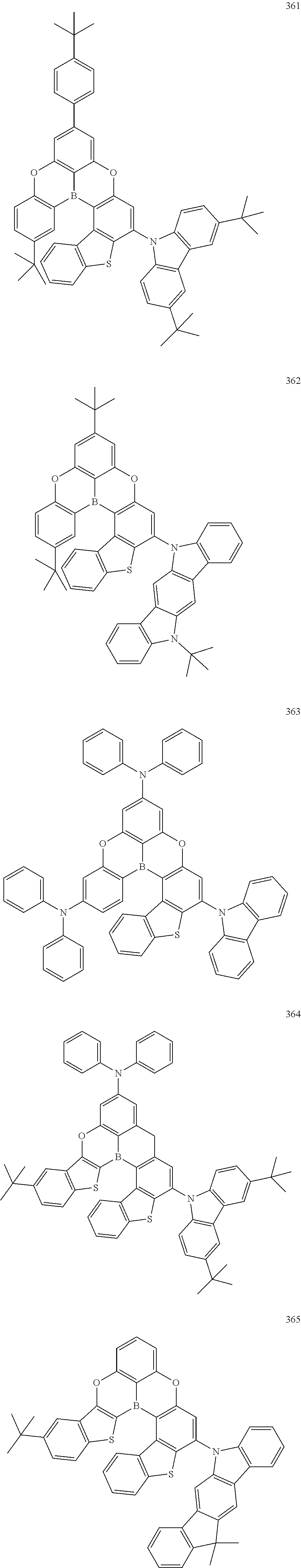

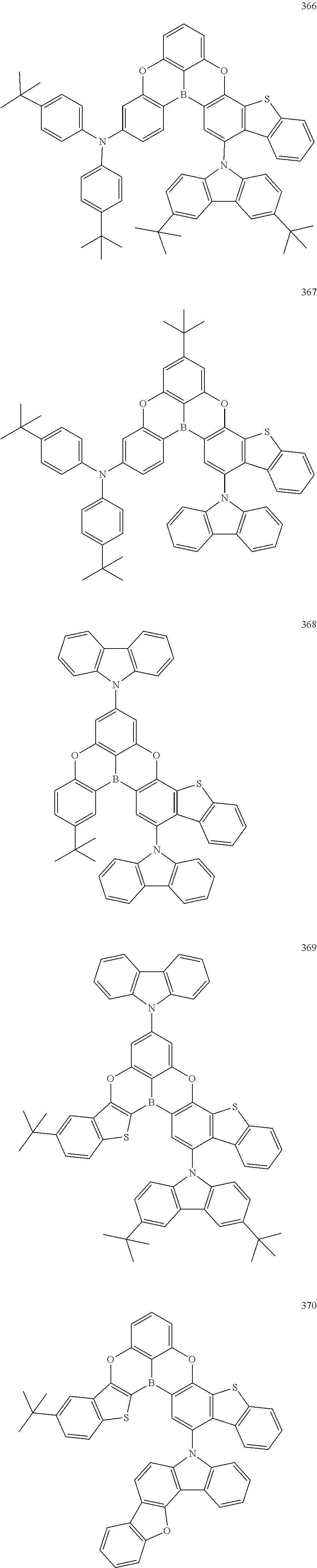

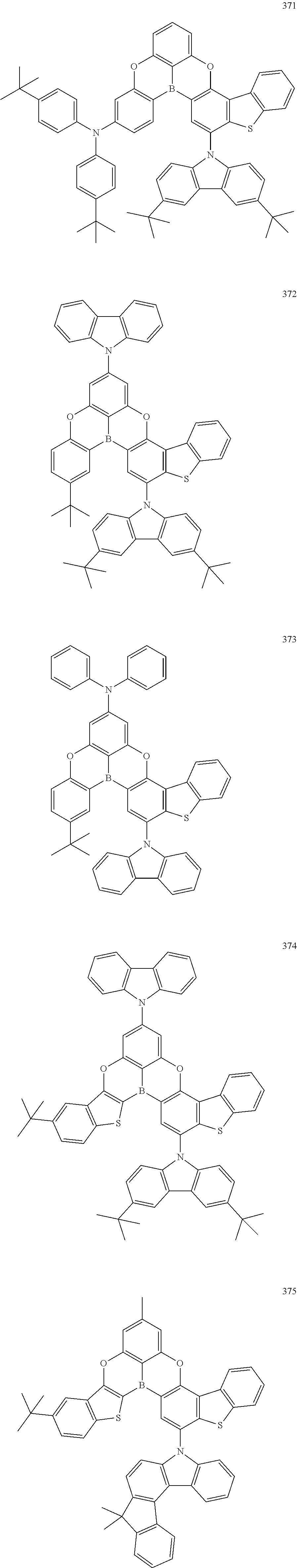

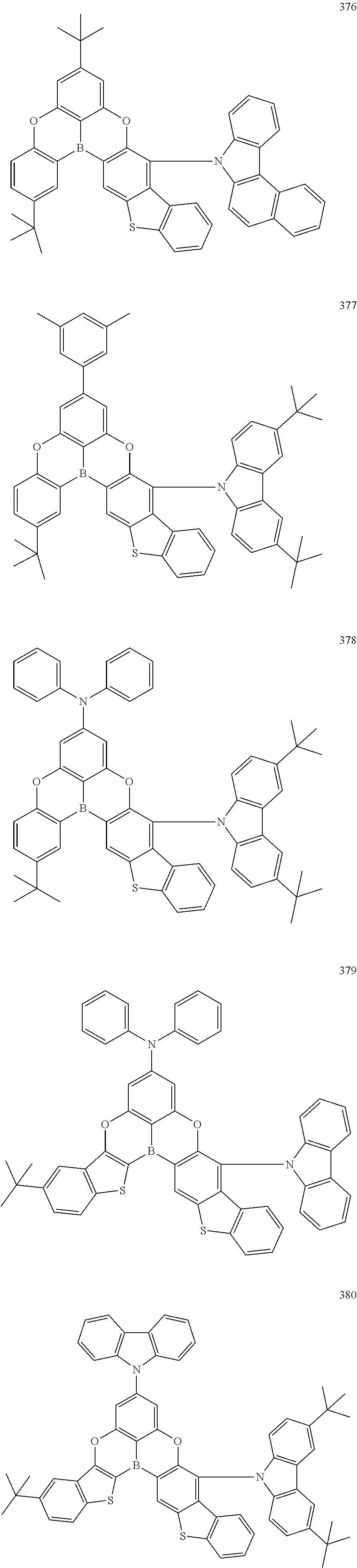

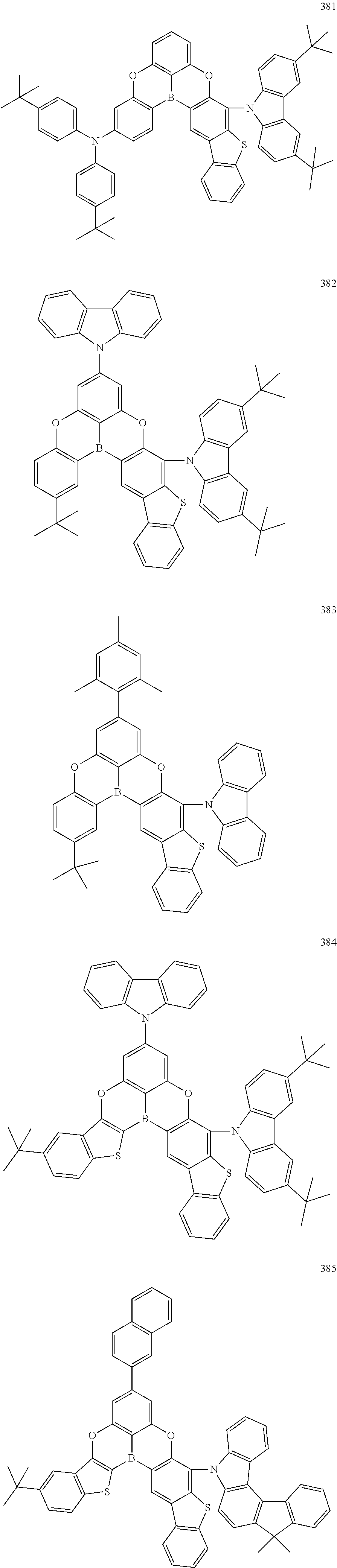

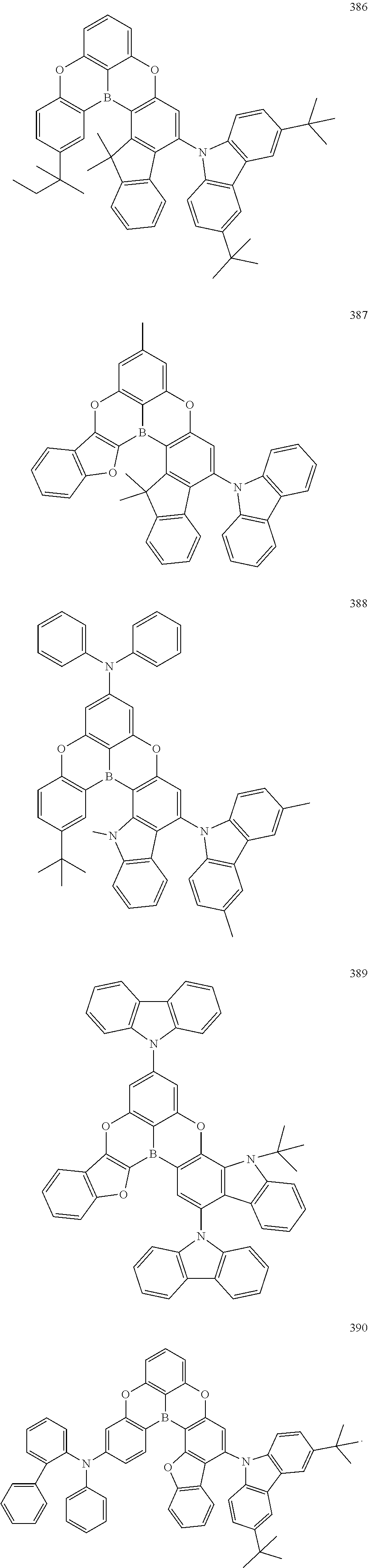

16. A composition comprising an organic compound and at least one organic solvent, wherein the organic compound has a structure represented by formula (1): 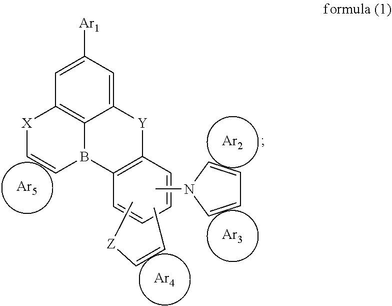
wherein Z is selected from CR₁R₂, NR₃, O, or S;
X and Y are each independently selected from O or NR₄;
R₁—R₄ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group;
R₁ and R₂ are connected to form a ring or independent of each other;
Ar₁ is selected from H, D, a substituted or unsubstituted C₁-C₂₀ alkyl group, a substituted or unsubstituted C₆-C₃₀ aromatic group, or a substituted or unsubstituted C₅-C₃₀ heteroaromatic group;
Ar₂ and Ar₃ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group; and
Ar₄ and Ar₅ are each independently selected from a substituted or unsubstituted C₆-C₃₀ aromatic group, or a substituted or unsubstituted C₅-C₃₀ heteroaromatic group.

17. The composition of claim 16, wherein the composition further comprises an organic functional material, and the organic functional material is selected from at least one of a hole transport material, a hole injection material, a hole blocking material, an electron injection material, an electron transport material, a host material, or a guest material.

18. A light-emitting element, comprising:
a pair of electrodes comprising a first electrode and a second electrode; and
an organic functional layer disposed between the first electrode and the second electrode;
wherein a material of the organic functional layer comprises an organic compound represented by formula (1): 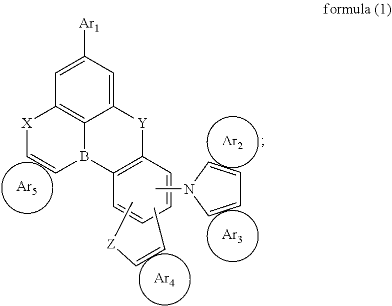
wherein Z is selected from CR₁R₂, NR₃, O, or S;
X and Y are each independently selected from O or NR₄;
R₁—R₄ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group;
R₁ and R₂ are connected to form a ring or independent of each other;
Ar₁ is selected from H, D, a substituted or unsubstituted C₁-C₂₀ alkyl group, a substituted or unsubstituted C₆-C₃₀ aromatic group, or a substituted or unsubstituted C₅-C₃₀ heteroaromatic group;
Ar₂ and Arₙ are each independently selected from a substituted or unsubstituted C₁-C₂₀ alkyl group, a substituted or unsubstituted C₆-C₃₀ aromatic group, or a substituted or unsubstituted C₅-C₃₀ heteroaromatic group; and
Ar₄ and Ar₅ are each independently selected from a substituted or unsubstituted C₆-C₃₀ aromatic group, or a substituted or unsubstituted C₅-C₃₀ heteroaromatic group.

19. The light-emitting element of claim 18, wherein the organic functional layer comprises a light-emitting layer, and the light-emitting layer comprises a host material and a guest material, wherein the guest material is the organic compound.

20. The light-emitting element of claim 18, wherein the light-emitting element is a blue light-emitting element.
